(19) United States
(12) Patent Application Publication
(10) Pub. No.: US 2023/0384496 A1
(43) Pub. Date: Nov. 30, 2023

(54) OPTICAL MEMBER FOR USE IN DISPLAY DEVICE AND DISPLAY DEVICE INCLUDING DISPLAY DEVICE

(71) Applicant: FUJIFILM Corporation, Tokyo (JP)

(72) Inventor: Hiroki KUWAHARA, Kanagawa (JP)

(73) Assignee: FUJIFILM Corporation, Tokyo (JP)

(21) Appl. No.: 18/366,402

(22) Filed: Aug. 7, 2023

Related U.S. Application Data
(63) Continuation of application No. PCT/JP2022/014731, filed on Mar. 25, 2022.

(30) Foreign Application Priority Data
Mar. 29, 2021 (JP) 2021-056294

(51) Int. Cl. G02B 5/22; C09B 23/01; C09B 57/00

(52) U.S. Cl. CPC G02B 5/223; C09B 23/0008; C09B 57/00

(57) ABSTRACT

An optical member for use in a display device having a specific light emitting unit, which includes a specific light bending part and a light absorbing part having an absorption waveform selected from specific absorption waveforms A to D and having absorption waveform B: a specific absorption waveform in which two wavelengths that give an absorbance of half of an absorption maximum are present in a wavelength range larger than λ_{BMax} (a maximum emission wavelength exhibited by blue emission of the display device) and smaller than λ_{GMax} (a maximum emission wavelength exhibited by green emission of the display device) or C: a specific absorption waveform in which two wavelengths that give an absorbance of half of an absorption maximum are present in a wavelength range larger than λ_{GMax} and smaller than λ_{RMax} (a maximum emission wavelength exhibited by red emission of the display device).

### CROSS-REFERENCE TO RELATED APPLICATIONS

This application is a Continuation of PCT International Application No. PCT/JP2022/014731 filed on Mar. 25, 2022, which claims priority under 35 U.S.C. § 119 (a) to Japanese Patent Application No. 2021-056294 filed in Japan on Mar. 29, 2021. Each of the above applications is hereby expressly incorporated by reference, in its entirety, into the present application.

### BACKGROUND OF THE INVENTION

### 1. Field of the Invention

The present invention relates to an optical member for use in a display device and a display device including the display device.

### 2. Description of the Related Art

An organic light emitting diode (OLED) is a kind of a self-luminescent element having a configuration including an anode, an organic light emitting layer, and a cathode. Here, in a case where a voltage is applied between the anode and the cathode, positive holes are injected from the anode into the organic light emitting layer, and electrons are injected from the cathode into the organic light emitting layer. In this case, the positive holes and electrons, which have been injected into the organic light emitting layer, are recombined in the organic light emitting layer to generate excitons, and such excitons emit light while transitioning from the excited state to the ground state.

Therefore, a display device that displays an image using the self-luminescence of the OLED has advantages that a high contrast ratio, a high color reproducibility, a wide viewing angle, a high-speed responsiveness, and a reduction in thickness and weight can be achieved, as compared with various display devices such as a liquid crystal display device and a plasma display device. In addition to these advantages, in terms of flexibility as well, research and development are being actively carried out as a next-generation display device.

On the other hand, since the luminescent substance of OLED is an organic substance, the problem of life due to the deterioration of the organic substance is a core issue in the development of OLED technology, and the technical development for overcoming this problem is being advanced. As a part thereof, a technique of introducing a microcavity (microresonator) structure is known. This technique is a technique that utilizes the resonance effect of light between electrodes. In a case of designing the distance (optical path length) between the electrodes of the anode and the cathode to match each of wavelengths of red (R), green (G), and blue (B) and resonating only light having a wavelength that matches the optical path length to weakening light having the other wavelengths, it is possible to extract light having a narrow half-width and high light intensity to the outside with directivity. As a result, both the brightness and the color purity are increased, and the power consumption can be reduced by improving the brightness, which is expected to lead to a long life of the OLED.

However, in the above-described microcavity structure, it is known that the wavelength of the resonating light changes depending on the angle at which the OLED is visually recognized. Therefore, in a case of being viewed from an oblique direction as compared with a case of being viewed from the front with respect to the OLED, as the angle from the front increases, a phenomenon in which the resonance wavelength shifts to the short wavelength side (blue shift) occurs as compared with a case of being viewed from the front with respect to the OLED.

For example, JP2014-123568A proposes, as a technique for improving the blue shift phenomenon associated with the introduction of the microcavity structure, a method in which a structure including structures having refractive indices different from each other is used, a part of straight light is converted into light in an oblique direction, and light having various wavelengths is diffused in an oblique direction, thereby neutrally adjusting a tint (hereinafter, referred to as “the tint in the oblique direction”) in a case where a display device is viewed from an oblique angle.

### SUMMARY OF THE INVENTION

As a result of carrying out repeated studies, the inventors of the present invention found that in a case where the technique described in JP2014-123568A is used, the tint in the oblique direction can be neutrally adjusted to be neutral, whereas a circularly polarizing plate used for a use application of antireflection of external light does not function effectively, and thus the external light reflection cannot be sufficiently suppressed.

Therefore, an object of the present invention is to provide an optical member which makes it is possible to neutrally adjust the tint in the oblique direction by including a light bending part, even in a case of being used on the front surface of the organic electroluminescent display device having a microcavity structure as described in JP2014-123568A and which makes it is possible to achieve both the suppression of external light reflection and the suppression of a decrease in brightness at an excellent level, and provide a display device including the optical member.

As a result of diligent studies in consideration of the above problems, the inventors of the present invention found that in a case of using a light absorbing part that absorbs a specific light instead of the circularly polarizing plate and applying an optical member including this light absorbing part and a light bending part, although it is possible to suppress external light reflection, it is difficult to say that a sufficient effect of suppressing external light reflection can be obtained as compared with a case of using the circularly polarizing plate, and furthermore, that in a case of increasing the amount of light absorption in order to enhance the effect of suppressing external light reflection, the brightness is decreased. However, it was found that in a case of using a light absorbing part in which a specific absorption waveform is used as the absorption waveform that absorbs light having a wavelength located between blue and green or between green and red, which is exhibited by the light emitting unit of the display device, it is possible to obtain an excellent effect of suppressing external light reflection and an excellent effect of suppressing a decrease in brightness. Further studies have been carried out based on these findings, whereby the present invention has been completed.

That is, the above object has been achieved by the following aspects.

<1>

An optical member for use in a display device,

wherein the display device has a light emitting unit, and the light emitting unit is an organic electroluminescent light emitting element or a micro light emitting diode,

the optical member includes a light bending part that bends and emits a part of a light amount of incident straight light, and a light absorbing part that contains a dye, and

an absorption waveform of the light absorbing part is selected from the following absorption waveforms A to D, and the light absorbing part has the following absorption waveform B or C,

the absorption waveform A: an absorption waveform having a main absorption wavelength band in a wavelength range smaller than λ_{BMax}

the absorption waveform B: an absorption waveform in which two wavelengths that give an absorbance of half of an absorption maximum are present in a wavelength range larger than λ_{BMax} and smaller than λ_{GMax}, and a width FWHM_{b} between the two wavelengths satisfies a relationship of Expression (1)

FWHM_{b}≥50−x/2−y/2 Expression (1)

the absorption waveform C: an absorption waveform in which two wavelengths that give an absorbance of half of an absorption maximum are present in a wavelength range larger than λ_{GMax} and smaller than λ_{RMax}, and a width FWHM_{c} between the two wavelengths satisfies a relationship of Expression (2)

FWHM_{c}≥60−y/2−z/2 Expression (2)

the absorption waveform D: an absorption waveform having a main absorption wavelength band in a wavelength range larger than λ_{RMax}

in description regarding the absorption waveforms A to D, each reference numeral has the following meaning, and

units of all the wavelengths are nm in Expressions (1) and (2),

λ_{BMax}: a maximum emission wavelength exhibited by blue emission of the display device

λ_{GMax}: a maximum emission wavelength exhibited by green emission of the display device

λ_{RMax}: a maximum emission wavelength exhibited by red emission of the display device

x: a width between two wavelengths that give an absorbance of half of a maximum emission exhibited by the blue emission of the display device

y: a width between two wavelengths that give an absorbance of half of a maximum emission exhibited by the green emission of the display device

z: a width between two wavelengths that give an absorbance of half of a maximum emission exhibited by the red emission of the display device.

<2>

The optical member for use in a display device according to <1>, in which the optical member includes a light bending filter that forms the light bending part and a light absorbing filter that forms the light absorbing part.

<3>

The optical member for use in a display device according to <2>, in which the light bending filter bends 1% to 20% of the light amount of the incident straight light.

<4>

The optical member for use in a display device according to <2> or <3>, in which a total light transmittance of the light bending filter is 99% or more.

<5>

The optical member for use in a display device according to any one of <2> to <4>, in which the light bending filter has at least a region I and a region II exhibiting a refractive index different from a refractive index of the region I.

<6>

The optical member for use in a display device according to <5>, in which the region I contains zirconium oxide particles.

<7>

The optical member for use in a display device according to <5> or <6>, in which the region II contains a pressure sensitive adhesive or hollow particles.

<8>

The optical member for use in a display device according to any one of <2> to <7>, in which a dye contained in a light absorbing filter exhibiting the absorption waveform B or C includes a squaraine-based coloring agent represented by General Formula (1),

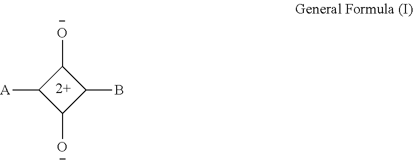

in the formula, A and B each independently represent an aryl group which may have a substituent, a heterocyclic group which may have a substituent, or —CH=G, where G represents a heterocyclic group which may have a substituent.

<9>

The optical member for use in a display device according to any one of <2> to <8>, in which a dye contained in a light absorbing filter exhibiting the absorption waveform A includes a coloring agent represented by General Formula (A1),

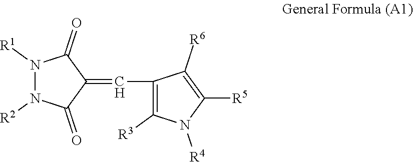

in the formula, R¹ and R² each independently represent an alkyl group or an aryl group, R³ to R⁶ each independently represent a hydrogen atom or a substituent, and R⁵ and R⁶ may be bonded to each other to form a 6-membered ring.

<10>

The optical member for use in a display device according to any one of <2> to <9>, in which a dye contained in a light absorbing filter exhibiting the absorption waveform D includes at least one of a coloring agent represented by General Formula (D1) or a coloring agent represented by General Formula (1),

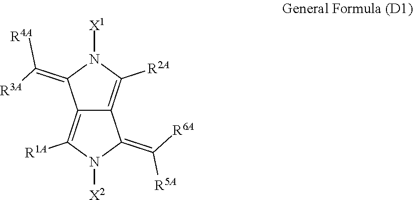

in the formula, R^{1A} and R^{2A} each independently represent an alkyl group, an aryl group, or a heteroaryl group, R^{4A} and R^{5A} each independently represent a heteroaryl group, R^{3A} and R^{6A} each independently represent a substituent, and X¹ and X² each independently represent —BR^{21a}R^{22a}, where R^{21a} and R^{22a} each independently represent a substituent, and R^{21a} and R^{22a} may be bonded to each other to form a ring,

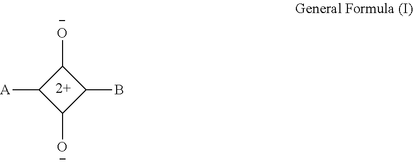

in the formula, A and B each independently represent an aryl group which may have a substituent, a heterocyclic group which may have a substituent, or —CH=G, where G represents a heterocyclic group which may have a substituent.

<11>

The optical member for use in a display device according to any one of <2> to <10>, in which the light absorbing filter contains an antifading agent represented by General Formula (IV),

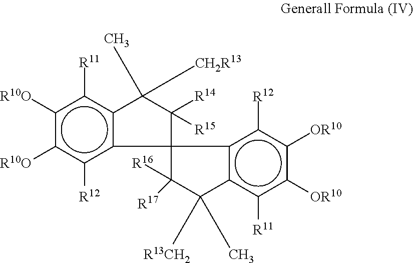

in the formula, R¹⁰'s each independently represent an alkyl group, an alkenyl group, an aryl group, a heterocyclic group, or a group represented by R¹¹CO—, R¹⁹SO₂—, or R²⁰NHCO—, where R¹⁸, R¹⁹, and R²⁰ each independently represent an alkyl group, an alkenyl group, an aryl group, or a heterocyclic group, R¹¹ and R¹² each independently represent a hydrogen atom, a halogen atom, an alkyl group, an alkenyl group, an alkoxy group, or an alkenyloxy group, and R¹³ to R¹⁷ each independently represent a hydrogen atom, an alkyl group, an alkenyl group, or an aryl group.

<12>

The optical member for use in a display device according to any one of <2> to <11>, in which the light absorbing filter contains a polystyrene resin or a cyclic polyolefin resin.

<13>

The optical member for use in a display device according to any one of <2> to <12>, in which the light absorbing filter exhibits all of the absorption waveforms A to D.

<14>

A display device comprising:
the optical member for use in a display device according to any one of <1> to <13>; and
a light emitting unit,
in which the light emitting unit is an organic electroluminescent light emitting element or a micro light emitting diode.

<15>

The display device according to <14>, further comprising:
a quantum dot sheet for wavelength conversion, on a visible side of the light emitting unit of the display device.

<16>

The display device according to <14> or <15>, further comprising:
a matrix that absorbs or scatters external light,
in which the matrix is disposed between light emitting elements constituting the light emitting unit.

In the present invention, in a case where there are a plurality of substituents, linking groups, and the like (hereinafter, referred to as substituents and the like) represented by specific reference numerals or formulae, or in a case where a plurality of substituents and the like are defined at the same time, the respective substituents and the like may be the same as or different from each other unless otherwise specified. The same applies to the definition of the number of substituents or the like. In addition, in a case where a plurality of substituents and the like are close to each other (particularly in a case where the substituents and the like are adjacent to each other), the substituents and the like may also be linked to each other to form a ring unless otherwise specified. In addition, unless otherwise specified, rings, for example, alicyclic rings, aromatic rings, and heterocyclic rings may be further fused to form a fused ring.

In the present invention, unless otherwise specified, one kind of each of components (such as a dye, a resin, an antifading agent for a dye, and other components in addition to these) capable of constituting the light absorbing part may be contained in the light absorbing part, or two or more kinds thereof may be contained therein. Similarly, unless otherwise specified, the light bending part may contain one kind each of the components (a material that constitutes a high refractive index region such as the region I and a material that constitutes a low refractive index region such as the region II) that can form the light bending part, or may contain two or more kinds thereof.

In the present invention, in a case where an E type double bond and a Z type double bond are present in a molecule, the double bond may be any one thereof or may be a mixture thereof, unless otherwise specified.

In the present invention, the representation of a compound (including a complex) is used to mean not only the compound itself but also a salt thereof, and an ion thereof. In addition, it is meant to include those in which a part of the structure is changed as long as the effect of the present invention is not impaired. Furthermore, it is meant that a compound, which is not specified to be substituted or unsubstituted, may have any substituent as long as the effect of the present invention is not impaired. The same applies to the definition of a substituent or a linking group.

In addition, in the present invention, the numerical range indicated by using “to” means a range including the numerical values before and after “to” as the lower limit value and the upper limit value, respectively.

In the present invention, the “composition” includes a mixture in which the component concentration varies within a range in which a desired function is not impaired, in addition to a mixture in which the component concentration is constant (each component is uniformly dispersed).

In the present invention, the description of “having a main absorption wavelength band in a specific wavelength range X” means that a wavelength at which the maximal absorption is exhibited (that is, the maximal absorption wavelength) is present in the specific wavelength range X.

Therefore, in a case where the maximal absorption wavelength is present in the above-described wavelength range X, the entire absorption band including this wavelength may be in the above-described wavelength range X or may also extend up to the outside of the above-described wavelength range X. In addition, in a case where there are a plurality of maximal absorption wavelengths, it suffices that a maximal absorption wavelength at which the highest absorbance is exhibited is present in the above-described wavelength range X. That is, the maximal absorption wavelength other than the maximal absorption wavelength at which the highest absorbance is exhibited may be present either inside or outside the above-described wavelength range of X.

The optical member according to the embodiment of the present invention makes it is possible to neutrally adjust the tint in the oblique direction by including a light bending part, even in a case of being used on the front surface of the organic electroluminescent display device having a microcavity structure as described in JP2014-123568A and which makes it is possible to achieve both the suppression of external light reflection and the suppression of a decrease in brightness at an excellent level.

In addition, the display device according to the present invention is a display device that includes the above-described optical member and can neutrally adjust the tint in the oblique direction, where the display device is also excellent in suppressing external light reflection and suppressing a decrease in brightness.

### BRIEF DESCRIPTION OF THE DRAWINGS

FIG. 1 is a schematic cross-sectional view showing an example of an optical member for use in a display device of the present invention.

FIG. 2 is an enlarged view for explaining a shape of a high refractive index portion in a schematic cross-sectional view of the optical member for use in the display device of the present invention described in FIG. 1.

FIG. 3 is an absorption emission spectrum schematically showing a relationship between absorption waveforms A to D that can be exhibited by a light absorbing part in the optical member for use in the display device of the present invention and an emission waveform of the display device.

### DESCRIPTION OF THE PREFERRED EMBODIMENTS

[Optical Member for Use in Display Device]

An optical member for use in a display device according to the embodiment of the present invention is an optical member for use in a display device having an organic electroluminescent light emitting element or a micro light emitting diode as a light emitting unit.

The optical member for use in the display device according to the embodiment of the present invention includes n light bending part that bends and emits a part of a light amount of incident straight light, and a light absorbing part that contains a dye, and the absorption waveform of this light absorbing part is selected from the absorption waveforms A to D described later, and the light absorbing part has the absorption waveform B or C described later.

In the optical member for use in the display device according to the embodiment of the present invention, the light absorbing part and the light bending part may be mixedly present or may each be present as a single part without being mixedly present as long as the effect of the present invention is not impaired. Examples of the form in which the light absorbing part and the light bending part are mixedly present include a form in which hollow particles corresponding to the light bending part are mixedly present discontinuously in the light absorbing part.

Among the above, it is preferable that the light absorbing part and the light bending part are not mixedly present, and it is more preferable that the light bending part is formed from a light bending filter and the light absorbing part is formed from a light absorbing filter.

The filters in the above-described light bending filter and light absorbing filter mean a film having light bending properties or light absorption properties.

Since the optical member for use in the display device according to the embodiment of the present invention (hereinafter, also simply referred to as “the optical member according to the embodiment of the present invention”) includes the light bending part and the light absorbing part, it can neutrally adjust the tint in the oblique direction in a case of being used on the front surface of the organic electroluminescent display device having a microcavity structure and is excellent in suppressing external light reflection and suppressing a decrease in brightness. The presumable reason for this is conceived to be as follows.

Since the optical member according to the embodiment of the present invention includes the light bending portion, it can neutrally adjust the tint in the oblique direction by providing a light bending part in a case of being used on the front surface of the organic electroluminescent display device having a microcavity structure, as described in JP2014-123568A. Further, it is conceived that in the optical member according to the embodiment of the present invention, a light absorbing part exhibiting a specific absorption waveform is used instead of the circularly polarizing plate, and thus, it is possible to achieve both the effect of suppressing external light reflection and the effect of suppressing a decrease in brightness at an excellent level, solving a problem that the circularly polarizing plate used for the use application of antireflection does not effectively function due to the light bending part, providing an absorption waveform selected from the absorption waveforms A to D, which satisfies a specific relationship with respect to the absorption band of the emission spectrum of the display device, and using a light absorbing part including at least the absorption waveform B or C.

<<Light Absorbing Part>>

In the light absorbing part of the optical member according to the present invention, the absorption waveform of this light absorbing part is selected from the following absorption waveforms A to D, and the light absorbing part has the following absorption waveform B or C.

the absorption waveform A: an absorption waveform having a main absorption wavelength band in a wavelength range smaller than λ_{BMax}

the absorption waveform B: an absorption waveform in which two wavelengths that give an absorbance of half of an absorption maximum are present in a wavelength range larger than λ_{BMax} and smaller than λ_{GMax}, and a width FWHM_{b} between the two wavelengths satisfies a relationship of Expression (1)

FWHM_{b}≥50−x/2−y/2 Expression (1)

the absorption waveform C: an absorption waveform in which two wavelengths that give an absorbance of half of an absorption maximum are present in a wavelength range larger than λ_{GMax} and smaller than λ_{RMax}, and a width FWHM_{c} between the two wavelengths satisfies a relationship of Expression (2)

FWHM_{c}≥60−y/2−z/2 Expression (2)

the absorption waveform D: an absorption waveform having a main absorption wavelength band in a wavelength range larger than λ_{RMax}

In the description of the absorption waveforms A to D, each reference numeral has the following meanings. In addition, in Expressions (1) and (2), the unit of the wavelength is nm.

λ_{BMax}: a maximum emission wavelength exhibited by blue emission of the display device

λ_{GMax}: a maximum emission wavelength exhibited by green emission of the display device

λ_{RMax}: a maximum emission wavelength exhibited by red emission of the display device

x: a width between two wavelengths that give an absorbance of half of a maximum emission exhibited by the blue emission of the display device

y: a width between two wavelengths that give an absorbance of half of a maximum emission exhibited by the green emission of the display device

z: a width between two wavelengths that give an absorbance of half of a maximum emission exhibited by the red emission of the display device.

In the present invention, the main absorption wavelength band of the light absorbing part is measured in a state of the light absorbing part or a base material-attached light absorbing part under the conditions described in the section of the absorption waveform of the light absorbing filter in Examples described later.

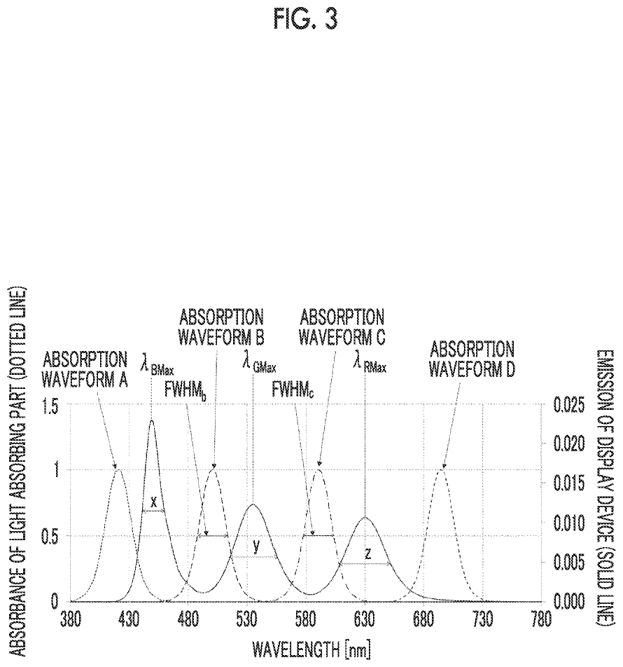

As schematically shown in FIG. 3, the absorption waveforms A to D that can be exhibited by the light absorbing part have a main absorption wavelength band in a region other than the maximum emission wavelengths λ_{BMax}, λ_{GMax}, and λ_{RMax}, which are exhibited by the blue emission, green emission, and red emission of a display device (hereinafter, also referred to as “the display device according to the embodiment of the present invention”) having an organic electroluminescent light emitting element or a micro light emitting diode as a light emitting unit, so that the definition of the present invention is satisfied. Therefore, the light absorbing part in the optical member according to the embodiment of the present invention having the absorption waveform selected from the absorption waveforms A to D can suppress the external light reflection while suppressing the decrease in the brightness of the display device according to the embodiment of the present invention.

It is noted that FIG. 3 is a view schematically illustrating a relationship between the main absorption wavelength bands of the absorption waveforms A to D that can be exhibited by the light absorbing part, the widths FWHM_{b} and FWHM_{c} between two wavelengths that give an absorbance of half of the absorption maximum of the absorption waveforms B and C, the maximum emission wavelengths λ_{BMax}, λ_{GMax}, and λ_{RMax}, exhibited by the blue emission, green emission, and red emission of the display device according to the embodiment of the present invention, and the widths x, y, and z between two wavelengths that give an absorbance of half of the maximum emission of each color. The absorption waveforms A to D in FIG. 3 indicate general absorption waveforms that satisfy the absorption waveforms A to D defined in the present invention.

The maximum emission wavelengths λ_{BMax}, λ_{GMax}, and λ_{RMax}, exhibited by the emissions of respective colors of blue, green, and red of the display device according to the embodiment of the present invention, and the widths x, y, and z between two wavelengths that give an absorbance of half of the maximum emission exhibited by the emission of the respective colors of blue, green, and red of the display device according to the embodiment of the present invention are not particularly limited as long as the light emitting unit is an organic EL light emitting element or a micro LED.

For example, λ_{BMax} includes 400 to 500 nm, and preferably 430 to 480 nm. λ_{Gmax} includes 500 to 600 nm, and is preferably 500 to 550 nm. λ_{Rmax} includes 600 to 700 nm, and preferably 600 to 650 nm.

In addition, for example, x is 15 to 40 nm, and is preferably 15 to 20 nm.

Examples of y include 15 to 50 nm, where 25 to 40 nm is preferable. Examples of z include 15 to 50 nm, where 15 to 40 nm is preferable.

In a case where the light absorbing part exhibits at least one of the absorption waveform B or C located in a wavelength range having a large relative luminous efficiency, it is possible to suppress the external light reflection.

The absorption waveform B satisfies a relationship of Expression (1) (hereinafter, also referred to as Relational Expression (1)). From the viewpoint of absorbing wavelengths other than the light emitting unit in a wider range and further improving the suppression of the reflectivity, it is preferable to satisfy a relationship of Expression (1a), it is more preferable to satisfy a relationship of Expression (1b), it is still more preferable to satisfy a relationship of Expression (1c).

FWHM_{b}≥55−x/2−y/2 Expression (1a)

FWHM_{b}≥60−x/2−y/2 Expression (1b)

FWHM_{b}≥65−x/2−y/2 Expression (1c)

In addition, the absorption waveform C satisfies a relationship of Expression (2) (hereinafter, also referred to as Relational Expression (2)). Similar to the absorption waveform B, regarding the absorption waveform C as well, From the viewpoint of absorbing wavelengths other than the light emitting unit in a wider range and further improving the suppression of the reflectivity, it is preferable to satisfy a relationship of Expression (2a), and it is more preferable to satisfy a relationship of Expression (2b).

FWHM_{c}≥63−y/2−z/2 Expression (2a)

FWHM_{c}≥66−y/2−z/2 Expression (2b)

In Expressions (1a) to (1c), (2a), and (2b), the unit of the wavelength is nm.

The absorption waveform A preferably has a main absorption wavelength band in a wavelength range of λ_{Bmax}−20 or less, and more preferably has a main absorption wavelength band in a wavelength range of λ_{Bmax}−30 or less.

The absorption waveform B is preferably an absorption waveform in which two wavelengths that give an absorbance half of the absorption maximum are present in a wavelength range of λ_{Bmax}+20 or more and λ_{Gmax}−3 or less, and more preferably an absorption waveform in which two wavelengths that give an absorbance half of the absorption maximum are present in a wavelength range of λ_{Bmax}+30 or more and λ_{Gmax}−6 or less.

The absorption waveform C is preferably an absorption waveform in which two wavelengths that give an absorbance half of the absorption maximum are present in a wavelength range of λ_{gMax}+20 or more and λ_{rMax}−10, and more preferably an absorption waveform in which two wavelengths that give an absorbance half of the absorption maximum are present in a wavelength range of λ_{gMax}+30 or more and λ_{rMax}−20.

The absorption waveform D preferably has a main absorption wavelength band in a wavelength range of λ_{rMax}+20 or more, and more preferably has a main absorption wavelength band in a wavelength range of λ_{rMax}+30 or more.

In each of the above-described absorption waveforms A to D, the unit of the wavelength range in the definition of the main absorption wavelength band is nm. For example, the wavelength range of λ_{bMax}−20 or less indicates a wavelength range of [λ_{bMax}−20] nm or less.

As long as the light absorbing part has the absorption waveforms A to D to satisfy the definitions of the present invention and can be used in a display device, it is possible to use a material constituting the light absorbing part without particular limitation. Among the above, it is preferable that the light absorbing part exhibits the absorption waveforms A to D by containing a dye, and it is more preferable that light absorbing part is a light absorbing filter that exhibits the absorption waveforms A to D derived from a dye by containing the above-described dye and a resin described later, and by dispersing this dye (preferably dissolving) in the resin. The dispersion may be any type of dispersion, such as a random type or a regular type.

Hereinafter, the components that can form the light absorbing part will be described in detail.

### <Dye>

It is preferable that the light absorbing part contains dyes exhibiting the absorption waveforms A to D to satisfy the definitions of the present invention.

Examples of the dye include a dye A exhibiting an absorption waveform A in the light absorbing part (hereinafter, also simply referred to as a “dye A”), a dye B exhibiting an absorption waveform B in the light absorbing part (hereinafter, also simply referred to as a “dye B”), a dye C exhibiting an absorption waveform C in the light absorbing part (hereinafter, also simply referred to as a “dye C”), and a dye D exhibiting an absorption waveform D in the light absorbing part (hereinafter, also simply referred to as a “dye D”).

The dyes A to D can be contained in the light absorbing part according to the absorption waveform indicated by the light absorbing part, and in a case where the absorption waveforms A to D of the light absorbing part are indicated with the dye, the light absorbing part in the optical member according to the present invention contains at least the dye B or the dye C.

The dye A that can be contained in the light absorbing part may one kind or two or more kinds. Similar to the above-described dye A, the dyes B to D that can be contained in the light absorbing part may be each independently one kind or two or more kinds.

The light absorbing part may also contain a dye other than the dyes A to D as long as the effect of the present invention is not impaired. That is, the light absorbing part can also exhibit an absorption waveform other than the absorption waveforms A to D as long as the effect of the present invention is not impaired. Such examples include a light absorbing part that exhibits the absorption waveform B and an absorption waveform in which although two wavelengths that give an absorbance of half of an absorption maximum are present in a wavelength range larger than λ_{GMax} and smaller than λ_{RMax}, the relationship of Expression (2) is not satisfied (that is, an absorption waveform c in which the width of the absorption peak is narrower than the definition of the absorption waveform C), and a light absorbing part that exhibits the absorption waveform C and an absorption waveform in which although two wavelengths that give an absorbance of half of an absorption maximum are present in a wavelength range larger than λ_{BMax} and smaller than λ_{GMax}, the relationship of Expression (1) is not satisfied (that is, an absorption waveform b in which the width of the absorption peak is narrower than the definition of the absorption waveform B). In these examples, since the absorption peak of the absorption waveform B or c is too sharp, the effect of suppressing external light reflection cannot be obtained by itself. However, in a case of a light absorbing part that exhibits a combination of the absorption waveforms B and c or a combination of the absorption waveforms b and C, it is possible to achieve both the effect of suppressing external light reflection and the effect of suppressing a decrease in brightness at an excellent level.

In particular, from the viewpoint of obtaining a light absorbing part exhibiting an absorption spectrum having a negative correlation with the emission spectrum exhibited by the light emitting unit, and drawing out the original tint of the image of the display device according to the embodiment of the present invention, the dye A, the dye B, the dye C, and the dye D, which are contained in the light absorbing part are preferably a combination of at least two kinds containing at least the dye B or the dye C, more preferably a combination of at least three kinds containing at least the dye B or the dye C, and it is still more preferable that all the four kinds are contained. It is noted that the kind of the dye described in the present paragraph is counted assuming each of the dye A, the dye B, the dye C, and the dye D as one kind. For example, even in a case where the light absorbing part contains two kinds of dyes, which correspond to the dye A, it is counted such that the light absorbing part contains only one kind of the dye A among the dyes A to D.

That is, the light absorbing part preferably exhibits at least two kinds of absorption waveforms including at least the absorption waveform B or C among the absorption waveforms A to D, and more preferably exhibits at least three kinds of absorption waveforms including at least the absorption waveform B or C, and still more preferably exhibits all the absorption waveforms A to D.

Above all, from the viewpoint of drawing out the original tint of the image of the display device according to the embodiment of the present invention, it is preferable that the light absorbing part contains all of the four dyes A to D and satisfies Relational Expressions (I) to (VI). The light absorbing part having such a configuration can suppress external light reflection and suppress a decrease in brightness, and moreover, can maintain the original tint of the image of the display device according to the embodiment of the present invention at an excellent level.

Ab(450)/Ab(430)<1.0 Relational Expression (I)

Ab(450)/Ab(500)<1.0 Relational Expression (II)

Ab(540)/Ab(500)<1.0 Relational Expression (III)

Ab(540)/Ab(600)<1.0 Relational Expression (IV)

Ab(630)/Ab(600)≤0.5 Relational Expression (V)

Ab(630)/Ab(700)<1.0 Relational Expression (VI)

It is noted that each of the absorbance ratio described in Relational Expressions (I) to (VI) is a value calculated using the value of the absorbance Ab (λ) at a wavelength λ nm, which is measured in a state of the light absorbing part or a base material-attached light absorbing part under the conditions described in the section of the absorption waveform of the light absorbing filter in Examples described later.

Regarding the preferred forms of Relational Expressions (I) to (VI), the description of paragraphs [0016] to [0017] of WO2021/014973 can be preferably applied. In this case, the wavelength selective absorption filter is read as the light absorbing part, and the original tint of the image of the OLED display device is read as the original tint of the display device.

(Dye A)

The dye A is not particularly limited as long as it exhibits the absorption waveform A in the light absorbing part, and various dyes can be used.

The dye A is preferably a coloring agent represented by General Formula (A1) from the viewpoint that the absorption waveform in the main absorption wavelength band can easily satisfy the suitable range of the absorption waveform A, and a display device having an organic electroluminescent light emitting element or a micro light emitting diode as a light emitting unit, to which the optical member according to the embodiment of the present invention is applied, can display brightness without significantly impairing the brightness.

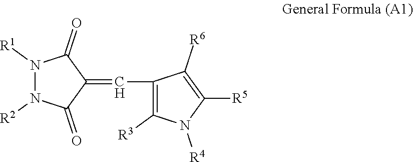

In General Formula (A1), R¹ and R² each independently represent an alkyl group or an aryl group, R³ to R⁶ each independently represent a hydrogen atom or a substituent, and R⁵ and R⁶ may be bonded to each other to form a 6-membered ring.

The alkyl group that can be employed as R¹ and R² may be any one of an unsubstituted alkyl group or a substituted alkyl group having a substituent, may be linear or branched, and may have a cyclic structure.

Examples of the unsubstituted alkyl group include a methyl group, an ethyl group, a normal propyl group, an isopropyl group, and a cyclohexyl group. The number of carbon atoms in the unsubstituted alkyl group is preferably 1 to 12 and more preferably 1 to 6.

Examples of the substituent that can be employed by the substituted alkyl group include a substituent included in the substituent group A below.

(Substituent Group A)

A halogen atom, an alkyl group, a cycloalkyl group, an aralkyl group, an alkenyl group, an alkynyl group, an aryl group, a heterocyclic group, a cyano group, a hydroxy group, a nitro group, a carboxyl group (which may have a form of a salt), an alkoxy group, an aryloxy group, a silyloxy group, a heterocyclic oxy group, an acyloxy group, a carbamoyloxy group, a sulfonyloxy group, an alkoxycarbonyloxy group, an aryloxycarbonyloxy group, an amino group (which includes, in addition to —NH₂, a substituted amino group represented by —NR^{a}₂, where R^{a}'s each independently represent a hydrogen atom, an alkyl group, an aryl group, or a heteroaryl group, provided that least one R^{a} is an alkyl group, an aryl group, or a heteroaryl group), an acylamino group, an aminocarbonylamino group, an alkylcarbonylamino group, an alkoxycarbonylamino group, an aryloxycarbonylamino group, a sulfamoylamino group, an alkylsulfonylamino group, an arylsulfonylamino group, a sulfonamide group, a mercapto group, an alkylthio group, an arylthio group, a heterocyclic thio group, a sulfamoyl group, a sulfo group (which may have a form of a salt), an alkylsulfinyl group, an arylsulfinyl group, an alkylsulfonyl group, an arylsulfonyl group, an acyl group, an aryloxycarbonyl group, an alkoxycarbonyl group, a carbamoyl group, an imide group, a phosphino group, a phosphinyl group, a phosphinyloxy group, a phosphinylamino group, and a silyl group, as well as a monovalent group in which at least two of these are linked.

Among the substituent group A, preferred examples of the substituent that can be contained in the substituted alkyl group include a halogen atom, an aryl group, an alkoxy group, an acyl group, and a hydroxy group.

The total number of carbon atoms in the substituted alkyl group is preferably 1 to 12. Examples thereof include a benzyl group, a hydroxybenzyl group, and a methoxyethyl group.

The total number of carbon atoms in the substituted alkyl group means the number of carbon atoms in the entire substituted alkyl group including the substituent that can be contained in the substituted alkyl group. Hereinafter, this will be used in the same meaning in regard to other groups as well.

In a case where both R¹ and R² represent an alkyl group, the alkyl groups may be the same or different from each other.

The aryl group that can be employed as R¹ and R² may be any one of an unsubstituted aryl group or a substituted aryl group having a substituent.

The unsubstituted aryl group is preferably an aryl group having 6 to 12 carbon atoms, and examples thereof include a phenyl group.

Examples of the substituent that can be employed by the substituted aryl group include a substituent included in the substituent group A below.

Among the substituent group A, preferred examples of the substituent that can be contained in the substituted aryl group include a halogen atom (for example, a chlorine atom, a bromine atom, or an iodine atom), a hydroxy group, a carboxy group, a sulfonamide group, or an amino group, (preferably, a substituted amino group represented by —NR^{a}₂, where R^{a}'s each independently represents a hydrogen atom or an alkyl group, provided that least one R^{a} is an alkyl group, and the amino group preferably has 1 to 4 carbon atoms), an alkyl group (preferably, an alkyl group having 1 to 4 carbon atoms; for example, methyl, ethyl, normal propyl, or isopropyl), an alkoxy group (preferably, an alkoxy group having 1 to 4 carbon atoms; for example, methoxy, ethoxy, normal propoxy, or isopropoxy), an alkoxycarbonyl group (preferably, an alkoxycarbonyl groups having 2 to 5 carbon atoms; for example, methoxycarbonyl, ethoxycarbonyl, normal propoxycarbonyl, or isopropoxycarbonyl), and a sulfonyloxy group, as well as a monovalent group in which at least the two thereof are linked to each other.

The substituted aryl group is preferably an aryl group having a total number of carbon atoms of 6 to 18.

Examples thereof include a 4-chlorophenyl group, a 2,5-dichlorophenyl group, a hydroxyphenyl group, a 4-carboxyphenyl group, a 3,5-dicarboxyphenyl group, a 4-methanesulfonamidephenyl group, a 4-methylphenyl group, a 4-methoxyphenyl group, a 4-(2-hydroxyethoxy)phenyl group, an N,N-dimethylaminophenyl group, a 4-(N-carboxymethyl-N-ethylamino)phenyl group, a 4-ethoxycarbonylphenyl group, and a 4-methanesulfonyloxyphenyl group.

In a case where both R¹ and R² represent an aryl group, the aryl groups may be the same or different from each other.

Examples of the substituent that can be employed as R³, R⁴, R⁵, and R⁶ include substituents included in the substituent group A.

Among the substituent group A, R³, R⁵, and R⁶ are preferably an alkyl group or an aryl group. That is, R³, R⁵, and R⁶ are each independently preferably a hydrogen atom, an alkyl group, or an aryl group.

In addition, in the substituent group A, R⁴ is preferably an alkyl group or an aryl group. That is, R⁴ is preferably a hydrogen atom, an alkyl group, or an aryl group.

The alkyl group that can be employed as R³, R⁵, and R⁶ may be any of an unsubstituted alkyl group or a substituted alkyl group having a substituent, and any of linear or branched, and may have a cyclic structure.

Examples of the unsubstituted alkyl group that can be employed as R³, R⁵, and R⁶ include a methyl group, an ethyl group, a normal propyl group, and an isopropyl group. The number of carbon atoms of the unsubstituted alkyl group that can be employed as R³, R⁵, and R⁶ is preferably 1 to 8 and more preferably 1 to 4.

Examples of the substituent that can be contained in the substituted alkyl group as R³, R⁵, and R⁶ include substituents included in the substituent group A.

Preferred examples of the substituent that can be contained in the substituted alkyl group as R³, R⁵, and R⁶ include an aryl group (preferably a phenyl group), a carboxy group, and a hydroxy group.

The total number of carbon atoms in the substituted alkyl group that can be employed as R³, R⁵, and R⁶ is preferably 1 to 8. For example, a benzyl group, a carboxymethyl group, and a hydroxymethyl group are exemplified.

In a case where all of R³, R⁵, and R⁶ represent alkyl groups, the alkyl groups may be the same or different from each other.

The aryl group that can be employed as R³, R⁵, and R⁶ may be any one of an unsubstituted aryl group or a substituted aryl group which has been substituted.

The unsubstituted aryl group that can be employed as R³, R⁵, and R⁶ is preferably an aryl group having 6 to 10 carbon atoms, and examples thereof include a phenyl group.

Examples of the substituent that can be contained in the substituted aryl group as R³, R⁵, and R⁶ include substituents included in the substituent group A.

Preferred examples of the substituent that can be contained in the substituted aryl group as R³, R⁵, and R⁶ include a halogen atom (for example, a fluorine atom, a chlorine atom, a bromine atom, or an iodine atom), a hydroxy group, a carboxy group, an alkyl group (preferably an alkyl groups having 1 to 4 carbon atoms; for example, methyl, ethyl, normal propyl, or isopropyl).

The substituted aryl group that can be employed as R³, R⁵, and R⁶ is preferably an aryl group having a total number of carbon atoms of 6 to 10. Examples thereof include a 4-chlorophenyl group, a 2,5-dichlorophenyl group, a hydroxyphenyl group, a carboxyphenyl group, a 3,5-dicarboxyphenyl group, and a 4-methylphenyl group.

In a case where both R⁵ and R⁶ are a substituent, R³ is preferably a hydrogen atom from the viewpoint of light resistance and heat resistance.

In a case where R³, R⁵, and R⁶ are all aryl groups, the aryl groups may be the same or different from each other.

The alkyl group that can be employed as R⁴ may be any one of an unsubstituted alkyl group or a substituted alkyl group having a substituent, may be linear or branched, and may have a cyclic structure.

Examples of the unsubstituted alkyl group that can be employed as R⁴ include a methyl group, an ethyl group, a normal propyl group, an isopropyl group, and a cyclohexyl group. The number of carbon atoms of the unsubstituted alkyl group that can be employed as R⁴ is preferably 1 to 8 and more preferably 1 to 4.

Examples of the substituent that can be contained in the substituted alkyl group as R⁴ include substituents included in the substituent group A.

Preferred examples of the substituent that can be contained in the substituted alkyl group as R⁴ include an aryl group (preferably, a phenyl group), a heterocyclic group, a carboxy group, a hydroxy group, an alkyl group (preferably, an alkyl group having 1 to 4 carbon atoms; for example, methyl, ethyl, normal propyl, or isopropyl), an alkoxy group (preferably, an alkoxy group having 1 to 4 carbon atoms; for example, methoxy, ethoxy, normal propoxy, or isopropoxy), an aryloxy group, an alkoxycarbonyl group (preferably, an alkoxycarbonyl groups having 2 to 5 carbon atoms; for example, methoxycarbonyl, ethoxycarbonyl, normal propoxycarbonyl, or isopropoxycarbonyl), an alkylamino group (preferably an alkylamino group having 1 to 4 carbon atoms; for example, a dimethylamino group), an alkylcarbonylamino group (preferably, an alkylcarbonylamino group having 1 to 4 carbon atoms; for example, a methylcarbonylamino group), a cyano group, and an acyl group, as well as a monovalent group in which at least the two thereof are linked to each other.

The total number of carbon atoms in the substituted alkyl group that can be employed as R⁴ is preferably 1 to 18.

For example, a benzyl group, a carboxybenzyl group, a hydroxybenzyl group, a methoxycarbonylethyl group, an ethoxycarbonylmethyl group, a 2-cyanoethyl group, a 2-propionylaminoethyl group, a dimethylaminomethyl group, a methylcarbonylaminopropyl group, a di(methoxycarbonylmethyl)aminopropyl group, and a phenacyl group are exemplified.

The aryl group that can be employed as R⁴ may be any one of an unsubstituted aryl group or a substituted aryl group having a substituent.

The unsubstituted aryl group that can be employed as R⁴ is preferably an aryl group having 6 to 12 carbon atoms, and examples thereof include a phenyl group.

Examples of the substituent that can be contained in the substituted aryl group as R⁴ include substituents included in the substituent group A.

Preferred examples of the substituent that can be contained in the substituted aryl group as R⁴ include a halogen atom (for example, a chlorine atom, a bromine atom, or an iodine atom), a hydroxy group, a carboxy group, a sulfonamide group, an amino group, an alkyl group (preferably, an alkyl group having 1 to 4 carbon atoms; for example, methyl, ethyl, normal propyl, or isopropyl), an alkoxy group (preferably, an alkoxy group having 1 to 4 carbon atoms; for example, methoxy, ethoxy, normal propoxy, or isopropoxy), an alkoxycarbonyl group (preferably, an alkoxycarbonyl groups having 2 to 5 carbon atoms; for example, methoxycarbonyl, ethoxycarbonyl, normal propoxycarbonyl, or isopropoxycarbonyl), and a sulfonyloxy group, as well as a monovalent group in which at least the two thereof are linked to each other.

The amino group that can be contained in the substituted aryl group as R⁴ may be any one of an unsubstituted amino group (—NH₂) or a substituted amino group having a substituent (—NR^{a}₂ in the substituent group A).

In the amino group (—NR^{a}₂) that can be contained in the substituted aryl group as R⁴, examples of R^{a} include the same group as the substituted alkyl group as R⁴.

The substituted amino group is preferably an alkylamino group in which one or two hydrogen atoms in the amino group are substituted with an alkyl group.

Examples of the alkylamino group include a methylamino group, a dimethylamino group, a diethylamino group, and a pyrrolidino group. The number of carbon atoms in the alkylamino group is preferably 1 to 8 and more preferably 1 to 4.

The substituted aryl group that can be employed as R⁴ is preferably an aryl group having a total number of carbon atoms of 6 to 22. Examples thereof include a 4-chlorophenyl group, a 2,5-dichlorophenyl group, a hydroxyphenyl group, a 2,5-methoxyphenyl group, a 2-methoxy-5-ethoxycarbonylphenyl group, a 4-ethyloxycarbonylphenyl group, a 4-propyloxycarbonylphenyl group, a 4-butoxycarbonylphenyl group, a 4-octyloxycarbonylphenyl group, a 4-carboxyphenyl group, a 3,5-dicarboxyphenyl group, a 4-methanesulfonamidephenyl group, a 4-methylphenyl group, a 4-methoxyphenyl group, a 4-ethoxyphenyl group, a 4-(2-hydroxyethoxy)phenyl group, an N,N-dimethylaminophenyl group, an N,N-diethylaminophenyl group, a 4-(N-carboxymethyl-N-ethylamino)phenyl group, a 4-{N,N-di(ethoxycarbonylmethyl)amino}phenyl group, a 4-{di(ethoxycarbonylmethyl)amino}carbonylphenyl group, a 4-ethoxycarbonylphenyl group, a 4-methanesulfonyloxyphenyl group, a 4-acetylsulfamoylphenyl group, and a 4-propionylsulfamoylphenyl group.

R⁵ and R⁶ may be bonded to each other to form a 6-membered ring.

The 6-membered ring formed by R⁵ and R⁶ being bonded to each other is preferably a benzene ring.

In particular, from the viewpoint of light resistance, among R¹ and R² in General Formula (A1), it is preferable that R¹ is an alkyl group, and it is more preferable that R¹ is an alkyl group and R² is an alkyl group or an aryl group. In addition, from the same viewpoint, it is still more preferable that both R¹ and R² are each independently an alkyl group, and it is particularly preferable that both R¹ and R² are an alkyl group having 1 to 8 carbon atoms.

Further, in terms of heat resistance and light resistance, it is also preferable that both R¹ and R² in General Formula (A1) are an aryl group.

In a case where R¹ and R² each independently represent an aryl group, it is preferable that R³, R⁵, and R⁶ are each independently a hydrogen atom, an alkyl group, or an aryl group and that least one of R³ or R⁶ is preferably a hydrogen atom. Among the above, from the viewpoint of heat resistance and light resistance, a case where R³ represents a hydrogen atom, and R⁵ and R⁶ each independently represent an alkyl group or an aryl group is more preferable. A case where R³ represents a hydrogen atom and R⁵ and R⁶ each independently represent an alkyl group is still more preferable. A case where R³ represents a hydrogen atom, R⁵ and R⁶ each independently represent an alkyl group, and R⁵ and R⁶ are bonded to each other to form a ring and fused with a pyrrole ring to form an indole ring together with the pyrrole ring is particularly preferable. That is, the coloring agent represented by General Formula (A1) is particularly preferably a coloring agent represented by General Formula (A2).

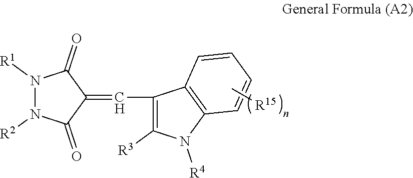

In General Formula (A2), R¹ to R⁴ respectively have the same meanings as R¹ to R⁴ in General Formula (A1), and the same applies to the preferred aspects thereof.

In General Formula (A2), R¹⁵ represents a substituent. Examples of the substituent that can be adopted as R¹⁵ include substituents included in the substituent group A. R¹⁵ is preferably an alkyl group, an aryl group, a halogen atom, an acyl group, or an alkoxycarbonyl group.

The alkyl group and the aryl group that can be employed as R¹⁵ respectively have the same meanings as the alkyl group and the aryl group that can be employed as R³, R⁵, and R⁶, respectively, and the same applies to each of the preferred aspects thereof.

Examples of the halogen atom that can be adopted as R¹⁵ include a chlorine atom, a bromine atom, and an iodine atom.

Examples of the acyl group that can be adopted as R¹⁵ include an acetyl group, a propionyl group, and a butyroyl group.

The alkoxycarbonyl group that can be adopted as R¹⁵, is preferably an alkoxycarbonyl group having 2 to 5 carbon atoms, and examples thereof include methoxycarbonyl, ethoxycarbonyl, normal propoxycarbonyl, and isopropoxycarbonyl.

n represents an integer of 0 to 4. n is not particularly limited, and is, for example, preferably 0 or 1.

Specific examples of the coloring agent represented by General Formula (A1) are shown below. However, the present invention is not limited thereto.

In the specific examples below, Me represents a methyl group.

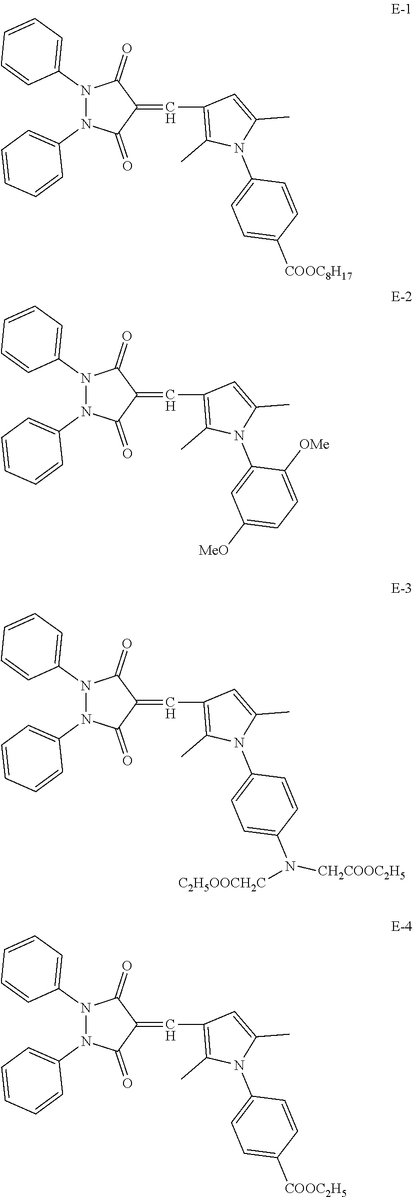

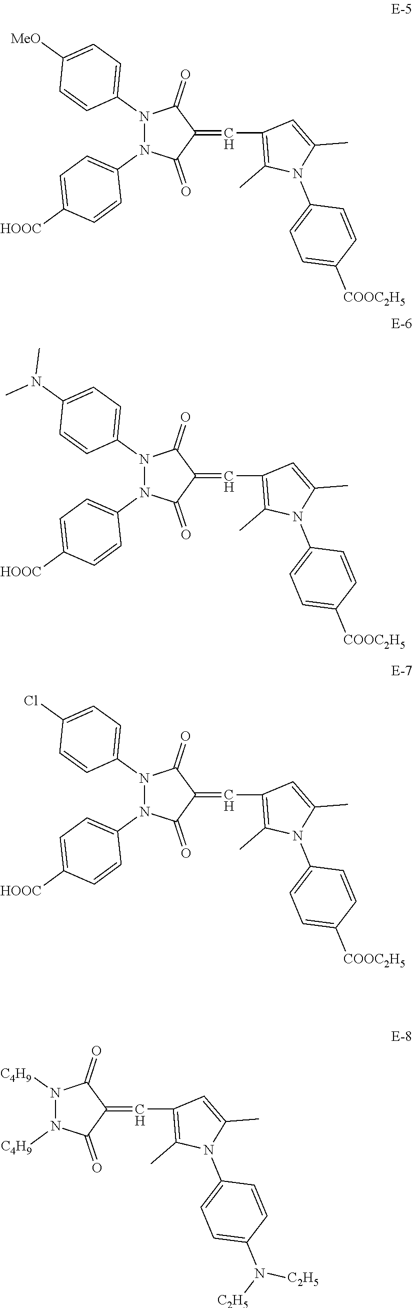

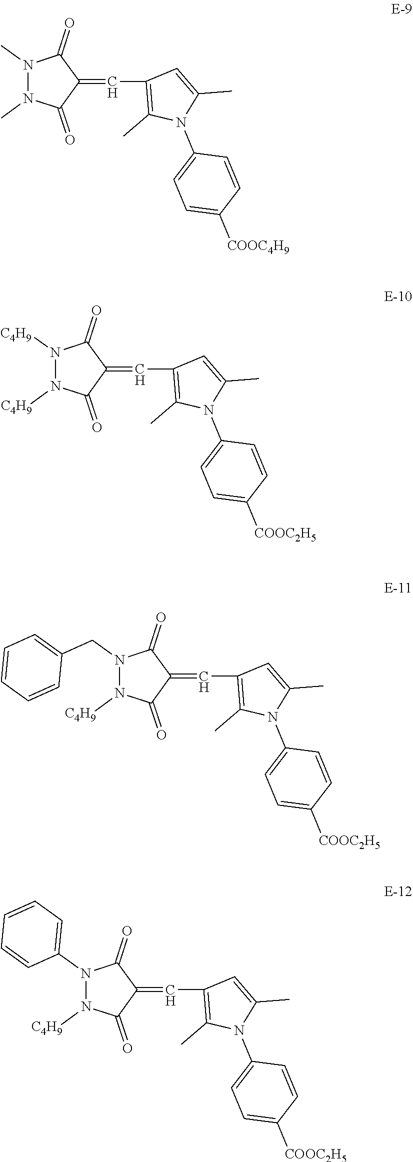

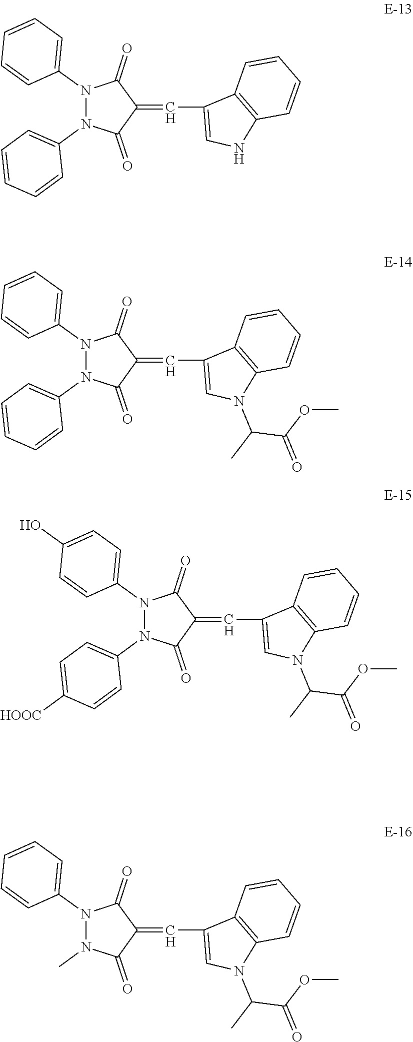 [SMILES: O=C1C(=Cc2c[nH]c3ccccc23)C(=O)N(c2ccccc2)N1c1ccccc1 ; COC(=O)C(C)n1cc(C=C2C(=O)N(c3ccccc3)N(c3ccccc3)C2=O)c2ccccc21 ; COC(=O)C(C)n1cc(C=C2C(=O)N(c3ccc(O)cc3)N(c3ccc(C(=O)O)cc3)C2=O)c2ccccc21 ; COC(=O)C(C)n1cc(C=C2C(=O)N(C)N(c3ccccc3)C2=O)c2ccccc21]

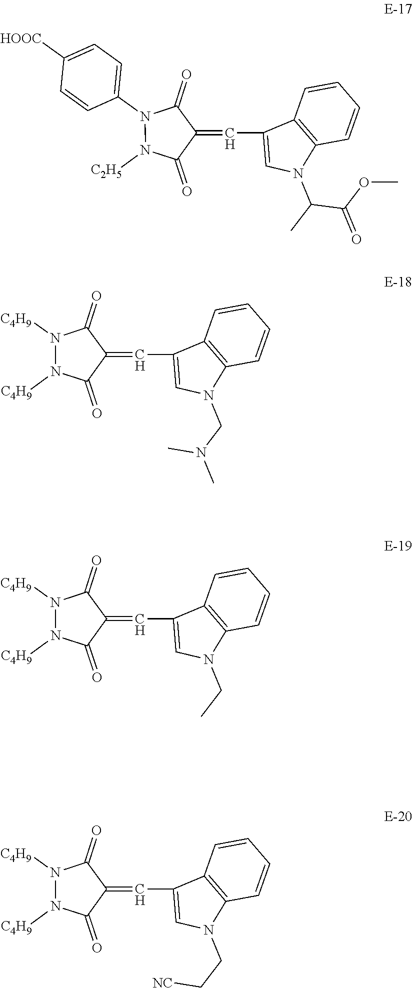

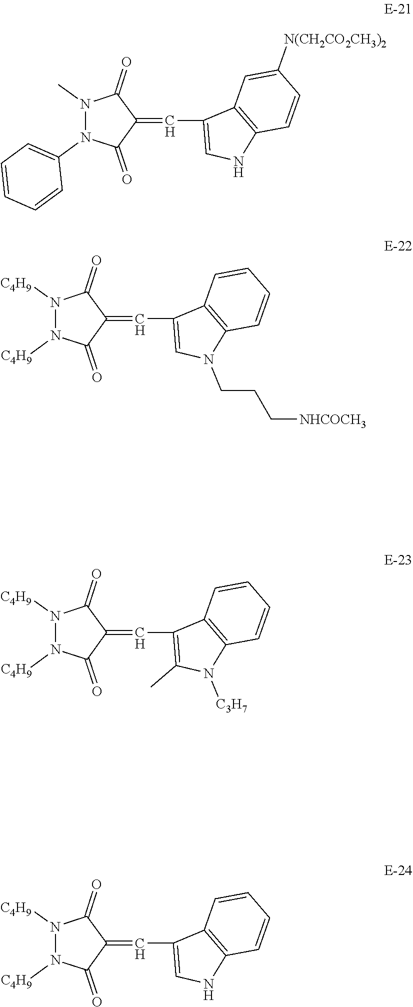

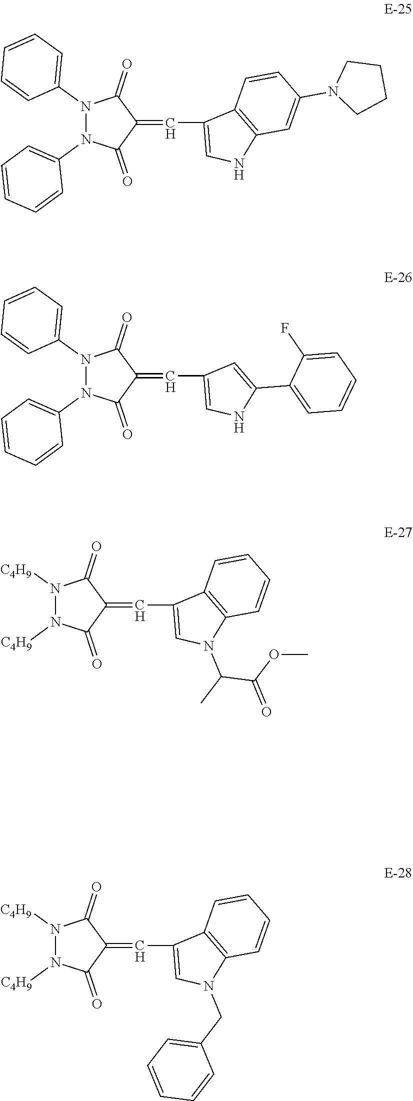

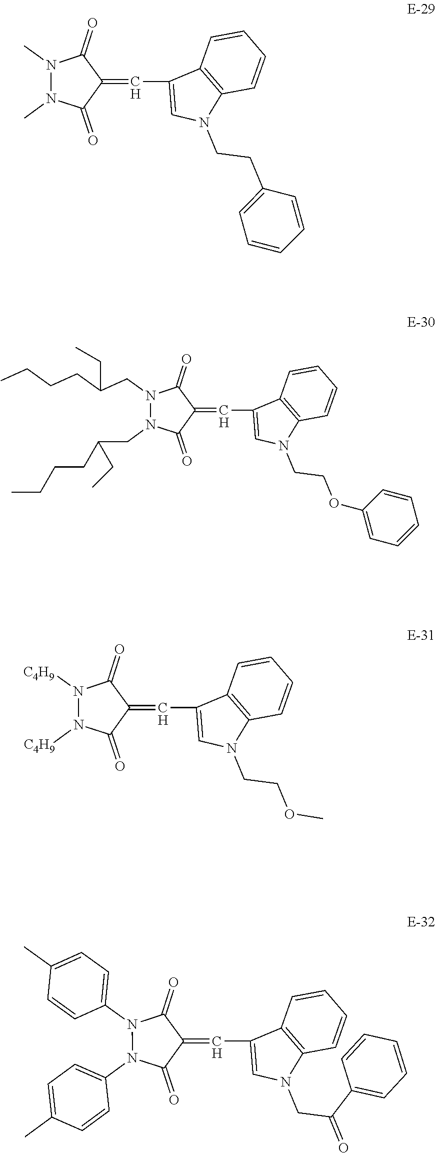

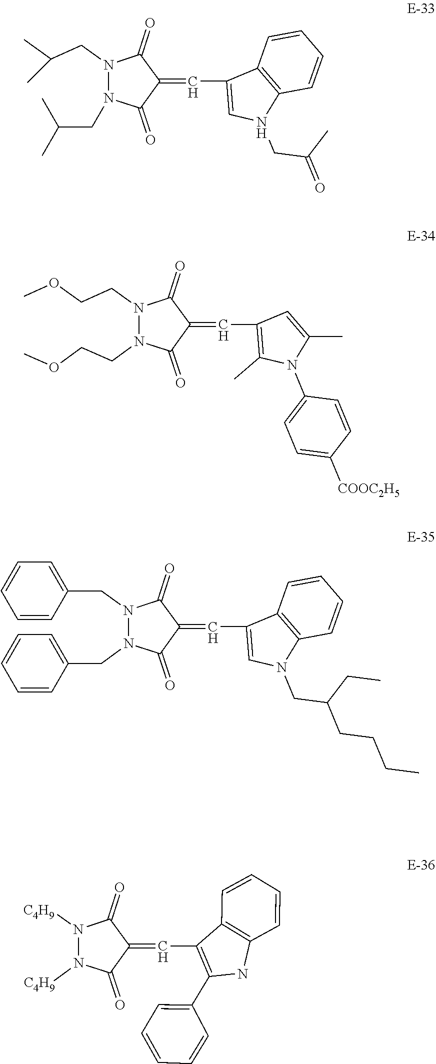

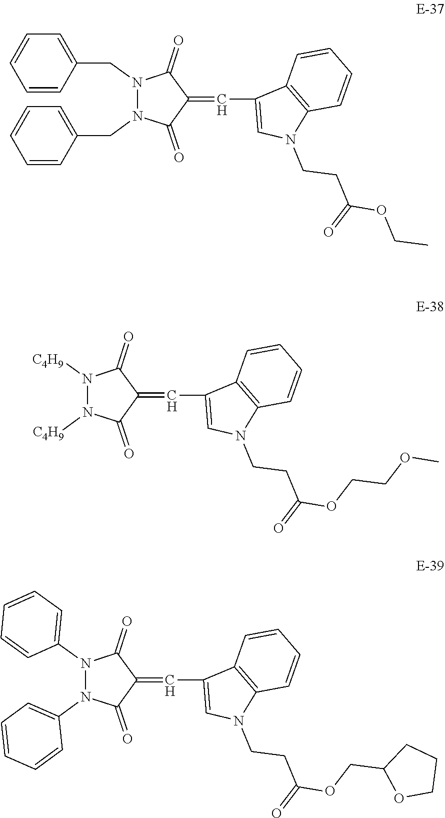

As the dye A, in addition to the coloring agent represented by General Formula (A1) or (A2), the compounds described in paragraphs [0012] to [0067] of JP2007-53241A (JP-H5-53241A) and the compounds described in paragraphs [0011] to [0076] of JP2707371B can also be preferably used.

(Dye B and dye C)

The dye B is not particularly limited as long as it exhibits the absorption waveform B in the light absorbing part, and various dyes can be used.

In addition, the dye C is not particularly limited as long as it exhibits the absorption waveform C in the light absorbing part, and various dyes can be used.

Specific examples of the dye B include individual coloring agents (dyes) which are based on, for example, pyrrole methine (PM), rhodamine (RH), boron dipyrromethene (BODIPY), and squaraine (SQ).

Specific examples of the dye C include individual coloring agents (dyes) which are based on, for example, tetraazaporphyrin (TAP), squaraine, and cyanine (CY).

Among these, From the viewpoint that the absorption waveform in the main absorption wavelength band easily satisfies the suitable range of the absorption waveform B or C, the dye B and the dye C are preferably a squaraine-based coloring agent, and more preferably a squaraine-based coloring agent represented by General Formula (1). In a using a coloring agent that satisfies the absorption waveforms B and C as the dye B and the dye C, a display device having an organic electroluminescent light emitting element or a micro light emitting diode as a light emitting unit, to which the optical member according to the embodiment of the present invention is applied, can display brightness without significantly impairing the brightness while satisfying the effect of suppressing external light reflection.

That is, in the light absorbing part, from the viewpoint of achieving both the suppression of external light reflection and the suppression of a decrease in brightness at a more excellent level, it is preferable that least one of the dye B or the dye C is a squaraine-based coloring agent (preferably, a squaraine-based coloring agent represented by General Formula (1)), and it is more preferable that both the dye B and the dye C are a squaraine-based coloring agent (preferably, a squaraine-based coloring agent represented by General Formula (1)).

In the present invention, in the coloring agent represented by each General Formula, a cation is present in a delocalized manner, and thus a plurality of tautomer structures are present. Therefore, in the present invention, in a case where at least one tautomer structure of a certain coloring agent matches with each general formula, the certain coloring agent shall be a coloring agent represented by the general formula. Therefore, a coloring agent represented by a specific general formula can also be said to be a coloring agent having at least one tautomer structure that can be represented by the specific general formula. In the present invention, a coloring agent represented by a general formula may have any tautomer structure as long as at least one tautomer structure of the coloring agent matches with the general formula.

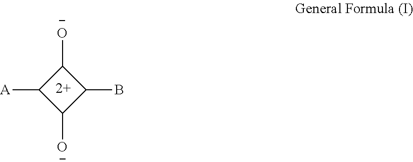

In General Formula (1), A and B each independently represent an aryl group which may have a substituent, a heterocyclic group which may have a substituent, or —CH=G. Here, G represents a heterocyclic group which may have a substituent.

The aryl group that can be employed as A or B is not particularly limited and may be a group consisting of a monocyclic ring or a group consisting of a fused ring. The aryl group preferably has 6 to 30 carbon atoms, more preferably 6 to 20 carbon atoms, and still more preferably 6 to 12 carbon atoms. Examples of the aryl group include groups respectively consisting of a benzene ring and a naphthalene ring, and a group consisting of a benzene ring is more preferable.

The heterocyclic group that can be employed as A or B is not particularly limited, and examples thereof include a group consisting of an aliphatic heterocyclic ring or an aromatic heterocyclic ring. A group consisting of an aromatic heterocyclic ring is preferable. Examples of the heteroaryl group that is an aromatic heterocyclic group include a heteroaryl group that can be employed as a substituent X described below. The aromatic heterocyclic group that can be employed as A or B is preferably a group of a 5-membered ring or a 6-membered ring and more preferably a group of a nitrogen-containing 5-membered ring. Specific examples thereof suitably include a group consisting of any of a pyrrole ring, a furan ring, a thiophene ring, an imidazole ring, a pyrazole ring, a thiazole ring, an oxazole ring, a triazole ring, an indole ring, an indolenine ring, an indoline ring, a pyridine ring, a pyrimidine ring, a quinoline ring, a benzothiazole ring, a benzoxazole ring, or a pyrazolotriazole ring. Among these, a group consisting of any of a pyrrole ring, a pyrazole ring, a thiazole ring, a pyridine ring, a pyrimidine ring, or a pyrazolotriazole ring is preferable. The pyrazolotriazole ring consists of a fused ring of a pyrazole ring and a triazole ring and may be a fused ring obtained by fusing at least one pyrazole ring and at least one triazole ring. Examples thereof include fused rings in General Formulae (4) and (5) described below.

A and B may be bonded to the squaric acid moiety (the 4-membered ring represented by General Formula (1)) at any portion (any ring-constituting atom) without particular limitation: however, they are preferably bonded at a carbon atom.

G in —CH=G that can be employed as A or B represents a heterocyclic group which may have a substituent, and examples thereof suitably include examples shown in the heterocyclic group that can be employed as A or B. Among these, a group consisting of any of a benzoxazole ring, a benzothiazole ring, an indoline ring, or the like is preferable.

At least one of A or B may have a hydrogen bonding group that forms an intramolecular hydrogen bond.

Each of A, B, and G may have the substituent X, and, in a case where A, B, or G has the substituent X, adjacent substituents may be bonded to each other to further form a ring structure. In addition, a plurality of substituents X may be present.

Examples of the substituent X include the following groups:
an alkyl group (it preferably has 1 to 20 carbon atoms, more preferably 1 to 15 carbon atoms, and still more preferably 1 to 8 carbon atoms; for example, methyl, ethyl, propyl, isopropyl, butyl, t-butyl, isobutyl, pentyl, hexyl, octyl, dodecyl, trifluoromethyl, cyclopentyl, or cyclohexyl);
an alkenyl group (it preferably has 2 to 20 carbon atoms, more preferably 2 to 12 carbon atoms, and still more preferably 2 to 8 carbon atoms; for example, vinyl, or allyl);
an alkynyl group (it preferably has 2 to 40 carbon atoms, more preferably 2 to 30 carbon atoms, and particularly preferably 2 to 25 carbon atoms; for example, ethynyl or propargyl);
an aryl group (it preferably has 6 to 30 carbon atoms, more preferably 6 to 20 carbon atoms, and still more preferably 6 to 12 carbon atoms; for example, phenyl or naphthyl);
a heterocyclic group (it includes an aromatic heterocyclic group and an aliphatic heterocyclic group; it includes a group consisting of a monocyclic ring or a fused ring, and it is preferably a monocyclic group or a group consisting of a fused ring having 2 to 8 rings, and more preferably a group consisting of a monocyclic ring or a fused ring having 2 to 4 rings; the number of heteroatoms constituting the ring is preferably 1 to 3, and examples of the heteroatom constituting the ring include a nitrogen atom, an oxygen atom, and a sulfur atom, where the ring is preferably a group consisting of a 5-membered ring or a 6-membered ring; the number of carbon atoms constituting the ring in the heteroaryl group is preferably 3 to 30, more preferably 3 to 18, and still more preferably 3 to 12; for example, furyl, thienyl, pyridyl, pyridazyl, pyrimidyl, pyrazil, triazil, imidazolyl, pyrazolyl, thiazolyl, benzimidazolyl, benzoxazolyl, quinazolyl, phthalazyl, pyrrolidyl, imidazolidyl, morpholyl, or oxazolidyl); an aralkyl group (an alkyl portion in the aralkyl group is the same as the alkyl group described above; an aryl portion in the aralkyl group is the same as the aryl group described above; and the aralkyl group preferably has 7 to 40 carbon atoms, more preferably 7 to 30 carbon atoms, and still more preferably 7 to 25 carbon atoms);
a ferrocenyl group;
—OR¹⁰ (examples thereof include a hydroxy group, an alkoxy group (methoxy, ethoxy, propyloxy, or the like), a cycloalkoxy group (cyclopentyloxy, cyclohexyloxy, or the like), an aryloxy group (phenoxy, naphthyloxy, or the like), and a heteroaryloxy group (an aromatic heterocyclic oxy group));
—C(═O)R¹¹ (examples thereof include acyl groups such as acetyl, ethylcarbonyl, propylcarbonyl, cyclohexylcarbonyl, octylcarbonyl, 2-ethylhexylcarbonyl, phenylcarbonyl, naphthylcarbonyl, and pyridylcarbonyl);
—C(═O)OR¹² (examples thereof include a carboxy group, an alkoxycarbonyl group (methyloxycarbonyl, ethyloxycarbonyl, butyloxycarbonyl, octyloxycarbonyl, or the like), and an aryloxycarbonyl group (phenyloxycarbonyl, naphthyloxycarbonyl, or the like);
—OC(═O)R¹³ (examples thereof include acyloxy groups such as acetyloxy, ethylcarbonyloxy, butylcarbonyloxy, octylcarbonyloxy, and phenylcarbonyloxy);
—NR¹⁴R¹⁵ (examples thereof include amino groups such as amino (—NH₂), ethylamino, dimethylamino, butylamino, dibutylamino, cyclopentylamino, 2-ethylhexylamino, dodecylamino, anilino, naphthylamino, and 2-pyridylamino);
—NHCOR¹⁶ (examples thereof include amide groups such as methylcarbonylamino, ethylcarbonylamino, dimethylcarbonylamino, propylcarbonylamino, pentylcarbonylamino, cyclohexylcarbonylamino, 2-ethylhexylcarbonylamino, octylcarbonylamino, dodecylcarbonylamino, and phenylcarbonylamino, naphthylcarbonylamino);
—CONR¹⁷R¹⁸ (examples thereof include carbamoyl groups such as aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, and naphthylaminocarbonyl, 2-pyridylaminocarbonyl);
—NHCONR¹⁹R²¹ (examples thereof include ureide groups such as methylureido, ethylureido, pentylureido, cyclohexylureido, octylureido, dodecylureido, phenylureido, naphthylureido, and 2-pyridyl amino ureido);
—NHCOOR²¹;
—SR²² (examples thereof include an alkylthio group (methylthio, ethylthio, propylthio, or the like), a cycloalkylthio group (cyclopentylthio, cyclohexylthio, or the like), an arylthio group (phenylthio, naphthylthio, or the like), and a heteroarylthio group (an aromatic heterocyclic thio group));
—SO₂R²³ (examples thereof include an alkylsulfonyl group (methylsulfonyl, ethylsulfonyl, butylsulfonyl, cyclohexylsulfonyl, 2-ethylhexylsulfonyl, or the like), and arylsulfonyl (phenylsulfonyl, naphthylsulfonyl, 2-pyridylsulfonyl, or the like));
—OSO₂R²⁴ (examples thereof include an alkylsulfonyloxy group such as methanesulfonyloxy);
—NHSO₂R²⁵ (examples thereof include sulfonylamide groups such as methylsulfonylamino, octylsulfonylamino, 2-ethylhexylsulfonylamino, and trifluoromethylsulfonylamino);
—SO₂NR²⁶R²⁷ (examples thereof include sulfamoyl groups such as aminosulfonyl, methylaminosulfonyl, dimethylaminosulfonyl, butylaminosulfonyl, cyclohexylaminosulfonyl, octylaminosulfonyl, phenylaminosulfonyl, and 2-pyridylaminosulfonyl);
—P(═O)(OR²⁸)₂ (examples thereof include phosphoryl groups such as dimethoxyphosphoryl and diphenylphosphoryl);
a halogen atom (a fluorine atom, a chlorine atom, a bromine atom, or an iodine atom);
a cyano group; and
a nitro group.

Further, it is also preferable that the substituent X has an electron migration-type antifading agent portion described later, in addition to the ferrocenyl group.

It is noted that R¹⁰ to R²⁸ each independently represent a hydrogen atom, an aliphatic group, an aromatic group, or a heterocyclic group. The aliphatic group and the aromatic group, which can be employed as R¹⁰ to R²⁸, are not particularly limited, and they can be appropriately selected from an alkyl group, an alkenyl group, and an alkynyl group, which are classified as the aliphatic group, and an aryl group which is classified as the aromatic group, in the substituent that can be employed as the substituent X. The heterocyclic group that can be employed as R¹⁰ to R²⁸ may be aliphatic or aromatic, and it can be appropriately selected from, for example, the heterocyclic groups (the aromatic heterocyclic group and the aliphatic heterocyclic group) which can be employed as the substituent X.

Each of the alkyl group, the alkenyl group, and the alkynyl group, which can be employed as the substituent X, may be linear, branched, or cyclic, and it is preferably linear or branched.

It is noted that in a case where R¹² of —COOR¹² is a hydrogen atom (that is, a carboxy group), the hydrogen atom may be dissociated (that is, a carbonate group) or may be in a salt state. In addition, in a case where R²⁴ of —SO₃R²⁴ is a hydrogen atom (that is, a sulfo group), the hydrogen atom may be dissociated (that is, a sulfonate group) or may be in a salt state.

The substituent that can be employed as the substituent X may further have a substituent. Examples of the substituent which may be further contained include the substituent X.

In addition, in a case where adjacent substituents X are bonded to each other to further form a ring structure, the two substituents X may form a ring by interposing a heteroatom such as a boron atom therebetween. The boron atom may be further substituted with a substituent, and examples of the substituent include substituents such as an alkyl group and an aryl group. Examples of a ring formed by bonding two substituents X include a ring formed by bonding two —NR¹⁴R¹⁵ and a ring formed by bonding two —NR¹⁴R¹⁵'s by interposing a boron atom therebetween. The size of the ring to be formed is not particularly limited; however, the ring is preferably a 5-membered ring or a 6-membered ring. Further, the number of rings to be formed is not particularly limited, and it may be one or may be two or more.

The ferrocenyl group that can be employed as the substituent X is preferably represented by General Formula (2M).

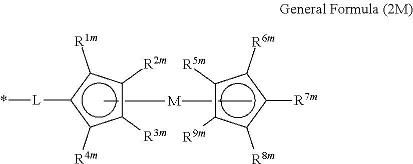

In General Formula (2M), L represents a single bond or a divalent linking group that does not conjugate with A, B, or G in General Formula (1). R^{1m} to R^{9m} each independently represent a hydrogen atom or a substituent. M represents an atom that can constitute a metallocene compound and represents Fe, Co, Ni, Ti, Cu, Zn, Zr, Cr, Mo, Os, Mn, Ru, Sn, Pd, Rh, V, or Pt. * represents a bonding site to A, B, or G.

In the present invention, in a case where L in General Formula (2M) is a single bond, a cyclopentadienyl ring directly bonded to A, B, or G (a ring having R^{1m} in General Formula (2M)) is not included in the conjugated structure which conjugates with A, B, or G.

The divalent linking group that can be employed as L is not particularly limited as long as it is a linking group that does not conjugate with A, B, or G, and it may have a conjugated structure in the inside thereof or at a cyclopentadiene ring side end part in General Formula (2M). Examples of the divalent linking group include an alkylene group having 1 to 20 carbon atoms, an arylene group having 6 to 20 carbon atoms, a divalent heterocyclic group obtained by removing two hydrogens from the heterocyclic ring, —CH═CH—, —CO—, —CS—, —NR— (R represents a hydrogen atom or a monovalent substituent), —O—, —S—, —SO₂—, or —N═CH—, or a divalent linking group formed by combining a plurality (preferably, 2 to 6) of these groups. The divalent linking group is preferably a group selected from the group consisting of an alkylene group having 1 to 8 carbon atoms, an arylene group having 6 to 12 carbon atoms, —CH═CH—, —CO—, —NR— (R is as described above), —O—, —S—, —SO₂—, and —N═CH—, or a divalent linking group in which two or more (preferably 2 to 6) selected from the above group are combined, and it is particularly preferably a group selected from the group consisting of an alkylene group having 1 to 4 carbon atoms, a phenylene group, —CO—, —NH—, —O—, and —SO₂—, or a linking group in which two or more (preferably 2 to 6) selected from the above group are combined. The divalent linking group combined is not particularly limited, and it is preferably a group containing —CO—, —NH—, —O—, or —SO₂—, and examples thereof include a linking group formed by combining two or more of —CO—, —NH—, —O—, or —SO₂—, or a linking group formed by combining at least one of —CO—, —NH—, —O—, or —SO₂— and an alkylene group or an arylene group. Examples of the linking group formed by combining two or more of —CO—, —NH—, —O—, or —SO₂— include —COO—, —OCO—, —CONH—, —NHCOO—, —NHCONH—, and —SO₂NH—. Examples of the linking group formed by combining at least one of —CO—, —NH—, —O—, or —SO₂— and an alkylene group or an arylene group include a group in which —CO—, —COO—, or —CONH— and an alkylene group or an arylene group are combined.

The substituent that can be employed as R is not particularly limited and has the same meaning as the substituent X.

L is preferably a single bond or a group selected from the group consisting of an alkylene group having 1 to 8 carbon atoms, an arylene group having 6 to 12 carbon atoms, —CH═CH—, —CO—, —NR— (R is as described above), —O—, —S—, —SO₂—, and —N═CH—, or a group in which two or more selected from the above group are combined.

L may have one or a plurality of substituents. The substituent which may be contained in L is not particularly limited, and for example, it has the same meaning as the substituent X. In a case where L has a plurality of substituents, the substituents bonded to adjacent atoms may be bonded to each other to further form a ring structure.

The alkylene group that can be employed as L may be linear, branched, or cyclic as long as the group has 1 to 20 carbon atoms, and examples thereof include methylene, ethylene, propylene, methylethylene, methylmethylene, dimethylmethylene, 1,1-dimethylethylene, butylene, 1-methylpropylene, 2-methylpropylene, 1,2-dimethylpropylene, 1,3-dimethylpropylene, 1-methylbutylene, 2-methylbutylene, 3-methylbutylene, 4-methylbutylene, 2,4-dimethylbutylene, 1,3-dimethylbutylene, pentylene, hexylene, heptylene, octylene, ethane-1,1-diyl, propane-2,2-diyl, cyclopropane-1,1-diyl, cyclopropane-1,2-diyl, cyclobutane-1,1-diyl, cyclobutane-1,2-diyl, cyclopentane-1,1-diyl, cyclopentane-1,2-diyl, cyclopentane-1,3-diyl, cyclohexane-1,1-diyl, cyclohexane-1,2-diyl, cyclohexane-1,3-diyl, cyclohexane-1,4-diyl, and methylcyclohexane-1,4-diyl.

In a case where a linking group containing at least one of —CO—, —CS—, —NR— (R is as described above), —O—, —S—, —SO₂—, or —N═CH— in the alkylene group is employed as L, the group such as —CO— may be incorporated at any site in the alkylene group, and the number of the groups incorporated is not particularly limited.

The arylene group that can be employed as L is not particularly limited as long as the group has 6 to 20 carbon atoms, and examples thereof include a group obtained by further removing one hydrogen atom from each group exemplified as the aryl group having 6 to 20 carbon atoms that can be employed as A in General Formula (1).

The heterocyclic group that can be employed as L is not particularly limited, and examples thereof include a group obtained by further removing one hydrogen atom from each group exemplified as the heterocyclic group that can be employed as A.

In General Formula (2M), the remaining partial structure excluding the linking group L corresponds to a structure (a metallocene structure portion) in which one hydrogen atom is removed from the metallocene compound. In the present invention, for the metallocene compound serving as the metallocene structure portion, a known metallocene compound can be used without particular limitation, as long as it is a compound conforming to the partial structure defined by General Formula (2M) (a compound in which a hydrogen atom is bonded instead of L). Hereinafter, the metallocene structure portion defined by General Formula (2M) will be specifically described.

In General Formula (2M), R^{1m} to R^{9m} each independently represent a hydrogen atom or a substituent. The substituents that can be employed as R^{1m} to R^{9m} are not particularly limited, and they can be selected from, for example, the substituents that can be employed as the substituent X. R^{1m} to R^{9m} each are preferably a hydrogen atom, a halogen atom, an alkyl group, an acyl group, an alkoxy group, an amino group, or an amide group, more preferably a hydrogen atom, a halogen atom, an alkyl group, an acyl group, or an alkoxy group, still more preferably a hydrogen atom, a halogen atom, an alkyl group, or an acyl group, particularly preferably a hydrogen atom, a halogen atom, or an alkyl group, and most preferably a hydrogen atom.

Among the alkyl groups that can be employed as the substituent X, the alkyl group that can be employed as R^{1m} to R^{9m} is preferably an alkyl group having 1 to 8 carbon atoms, and examples thereof include methyl, ethyl, propyl, isopropyl, butyl, sec-butyl, tert-butyl, isobutyl, pentyl, tert-pentyl, hexyl, octyl, and 2-ethylhexyl.

This alkyl group may have a halogen atom as a substituent. Examples of the alkyl group substituted with a halogen atom include, for example, chloromethyl, dichloromethyl, trichloromethyl, bromomethyl, dibromomethyl, tribromomethyl, fluoromethyl, difluoromethyl, trifluoromethyl, 2,2,2-trifluoroethyl, perfluoroethyl, perfluoropropyl, perfluorobutyl.

In addition, in the alkyl group that can be employed as R^{1m} or the like, at least one methylene group that forms a carbon chain may be substituted with —O— or —CO—. Examples of the alkyl group in which the methylene group is substituted with —O— include an alkyl group in which the end part methylene group of methoxy, ethoxy, propoxy, isopropoxy, butoxy, sec-butoxy, tert-butoxy, 2-methoxyethoxy, chloromethyloxy, dichloromethyloxy, trichloromethyloxy, bromomethyloxy, dibromomethyloxy, tribromomethyloxy, fluoromethyloxy, difluoromethyloxy, trifluoromethyloxy, 2,2,2-trifluoroethyloxy, perfluoroethyloxy, perfluoropropyloxy, or perfluorobutyloxy is substituted, as well as an alkyl group in which an internal methylene group of the carbon chain such as 2-methoxyethyl or the like is substituted. Examples of the alkyl group in which a methylene group is substituted with —CO— include acetyl, propionyl, monochloroacetyl, dichloroacetyl, trichloroacetyl, trifluoroacetyl, propane-2-one-1-yl, and butane-2-one-1-yl.

In General Formula (2M), M represents an atom that can constitute a metallocene compound, and represents Fe, Co, Ni, Ti, Cu, Zn, Zr, Cr, Mo, Os, Mn, Ru, Sn, Pd, Rh, V, or Pt. Among these, M is preferably Fe, Ti, Co, Ni, Zr, Ru, or Os, more preferably Fe, Ti, Ni, Ru, or Os, still more preferably Fe or Ti, and most preferably Fe.

The group represented by General Formula (2M) is preferably a group formed by combining preferred ones of L, R^{1m} to R^{9m}, and M. Examples thereof include a group formed by combining, as L, a single bond, or a group selected from the group consisting of an alkylene group having 2 to 8 carbon atoms, an arylene group having 6 to 12 carbon atoms, —CH═CH—, —CO—, —NR— (R is as described above), —O—, —S—, —SO₂—, and —N═CH—, or a group in which two or more selected from the above group are combined; as R^{1m} to R^{9m}, a hydrogen atom, a halogen atom, an alkyl group, an acyl group, or an alkoxy group; and as M, Fe.

The alkyl group, the alkenyl group, the alkynyl group, the aralkyl group, the aryl group, and the heteroaryl group which can be employed as the substituent X and the aliphatic group, the aromatic group, and the heterocyclic group which can be employed as R¹⁰ to R²⁸ each may further have a substituent or may be unsubstituted. The substituent which may be further contained therein is not particularly limited, and it is preferably a substituent selected from an alkyl group, an aryl group, an amino group, an alkoxy group, an aryloxy group, an aromatic heterocyclic oxy group, an acyl group, an alkoxycarbonyl group, an aryloxycarbonyl group, an acyloxy group, an acylamino group, an alkoxycarbonylamino group, an aryloxycarbonylamino group, a sulfonylamino group, an alkylthio group, an arylthio group, an aromatic heterocyclic thio group, a sulfonyl group, a ferrocenyl group, a hydroxy group, a mercapto group, a halogen atom, a cyano group, a sulfo group, or a carboxy group, and it is more preferably a substituent selected from an alkyl group, an aryl group, an alkoxy group, an aryloxy group, an aromatic heterocyclic oxy group, an acyl group, an alkoxycarbonyl group, an aryloxycarbonyl group, an acyloxy group, an alkylthio group, an arylthio group, an aromatic heterocyclic thio group, a sulfonyl group, a ferrocenyl group, a hydroxy group, a mercapto group, a halogen atom, a cyano group, a sulfo group, or a carboxy group. These groups can be appropriately selected from the substituents that can be employed as the substituent X.

One preferred embodiment of the coloring agent represented by General Formula (1) includes a coloring agent represented by General Formula (2).

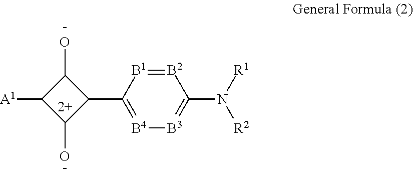

In General Formula (2), A¹ is the same as A in General Formula (1). Among these, a heterocyclic group which is a nitrogen-containing 5-membered ring is preferable.

In General Formula (2), R¹ and R² each independently represent a hydrogen atom or a substituent. R¹ and R² may be the same or different from each other, and they may be bonded together to form a ring.

The substituents that can be employed as R¹ and R² are not particularly limited, and examples thereof include substituents that can be employed as the substituent X.

Among these, an alkyl group, an alkenyl group, an aryl group, or a heteroaryl group is preferable, an alkyl group, an aryl group, or a heteroaryl group is more preferable, and an alkyl group is still more preferable.

The substituent that can be employed as R¹ and R² may further have a substituent. Examples of the substituent which may be further contained include the substituent X. In addition, R¹ and R² may be bonded to each other to form a ring, and R¹ or R² and the substituent of B² or B³ may be bonded to each other to form a ring.

The ring that is formed in this case is preferably a heterocyclic ring or a heteroaryl ring, and it is preferably a 5-membered ring or a 6-membered ring although the size of the ring to be formed is not particularly limited. Further, the number of rings to be formed is not particularly limited, and it may be one or may be two or more. Examples of the form in which two or more rings are formed include a form in which the substituents of R¹ and B² and the substituents of R² and B³ are respectively bonded to each other to form two rings.

In General Formula (2), B¹, B², B³, and B⁴ each independently represent a carbon atom or a nitrogen atom. The ring including B¹, B², B³, and B⁴ is an aromatic ring. It is preferable that at least two or more of B¹ to B⁴ are a carbon atom, and it is more preferable that all of B¹ to B⁴ are a carbon atom.

The carbon atom that can be employed as B¹ to B⁴ has a hydrogen atom or a substituent. Among carbon atoms that can be employed as B¹ to B⁴, the number of carbon atoms having a substituent is not particularly limited; however, it is preferably zero, one, or two, and more preferably one. Particularly, it is preferable that B¹ and B⁴ are a carbon atom and at least one of them has a substituent.

The substituent possessed by the carbon atom that can be employed as B¹ to B⁴ is not particularly limited, and examples thereof include the substituent X. Among these, it is preferably an alkyl group, an alkoxy group, an alkoxycarbonyl group, an aryl group, an acyl group, an amide group, a sulfonylamide group, a carbamoyl group, an alkylsulfonyl group, an arylsulfonyl group, an amino group, a cyano group, a nitro group, a halogen atom, or a hydroxy group, and it is more preferably an alkyl group, an alkoxy group, an alkoxycarbonyl group, an aryl group, an acyl group, an amide group, a sulfonylamide group, a carbamoyl group, an amino group, a cyano group, a nitro group, a halogen atom, or a hydroxy group.

The substituent possessed by the carbon atom that can be adopted as B¹ to B⁴ may further have a substituent. Examples of this substituent which may be further contained include the substituent X.

Examples of the substituent that can be possessed by the carbon atom that can be employed as B¹ and B⁴ still more preferably include an alkyl group, an alkoxy group, a hydroxy group, an amide group, a sulfonylamide group, or a carbamoyl group, and particularly preferably an alkyl group, an alkoxy group, a hydroxy group, an amide group, or a sulfonylamide group, and a hydroxy group, an amide group, or a sulfonylamide group is most preferable.

It is still more preferable that the substituent that can be possessed by the carbon atom that can be employed as B² and B³ is an alkyl group, an alkoxy group, an alkoxycarbonyl group, an acyl group, an amino group, a cyano group, a nitro group, or a halogen atom, and it is particularly preferable that the substituent as any one of B² or B³ is an electron-withdrawing group (for example, an alkoxycarbonyl group, an acyl group, a cyano group, a nitro group, or a halogen atom).

The coloring agent represented by General Formula (2) is preferably a coloring agent represented by any of General Formulae (3), (4), or (5).

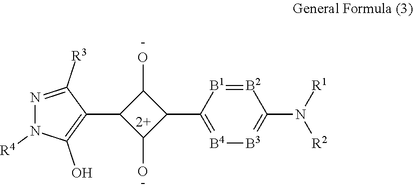

In General Formula (3), R¹ and R² each independently represent a hydrogen atom or a substituent, and they respectively have the same meanings as R¹ and R² in General Formula (2), where the same applies to the preferred ranges thereof.

In General Formula (3), B¹ to B⁴ each independently represent a carbon atom or a nitrogen atom, and they have respectively the same meanings as B¹ to B⁴ in General Formula (2), where the same applies to the preferred ranges thereof.

In General Formula (3), R³ and R⁴ each independently represent a hydrogen atom or a substituent. The substituent that can be employed as R³ and R⁴ is not particularly limited, and examples thereof include the same ones as the substituents that can be employed as R¹ and R².

However, the substituent that can be employed as R³ is preferably an alkyl group, an alkoxy group, an amino group, an amide group, a sulfonylamide group, a cyano group, a nitro group, an aryl group, a heteroaryl group, a heterocyclic group, an alkoxycarbonyl group, a carbamoyl group, or a halogen atom, more preferably an alkyl group, an aryl group, or an amino group, and still more preferably an alkyl group.

The substituent that can be employed as R⁴ is preferably an alkyl group, an aryl group, a heteroaryl group, a heterocyclic group, an alkoxy group, an alkoxycarbonyl group, an acyl group, an acyloxy group, an amide group, a carbamoyl group, an amino group, or a cyano group, more preferably an alkyl group, an alkoxycarbonyl group, an acyl group, a carbamoyl group, or an aryl group, and still more preferably an alkyl group.

The alkyl group that can be employed as R³ and R⁴ may be either linear, branched, or cyclic, and it is preferably linear or branched. The alkyl group preferably has 1 to 12 carbon atoms and more preferably 1 to 8 carbon atoms. An example of the alkyl group is preferably a methyl group, an ethyl group, an n-propyl group, an isopropyl group, a t-butyl group, a 2-ethylhexyl group, or a cyclohexyl group, and more preferably a methyl group or a t-butyl group.

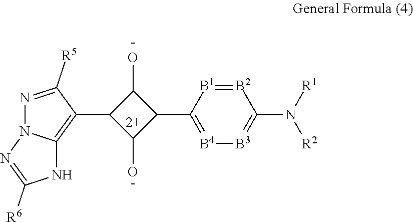

In General Formula (4), R¹ and R² each independently represent a hydrogen atom or a substituent, and they respectively have the same meanings as R¹ and R² in General Formula (2), where the same applies to the preferred ranges thereof.

In General Formula (4), B¹ to B⁴ each independently represent a carbon atom or a nitrogen atom, and they have respectively the same meanings as B¹ to B⁴ in General Formula (2), where the same applies to the preferred ranges thereof.

In General Formula (4), R⁵ and R⁶ each independently represent a hydrogen atom or a substituent. The substituent that can be employed as R⁵ and R⁶ is not particularly limited, and examples thereof include the same ones as the substituents that can be employed as R¹ and R².

However, the substituent that can be employed as R⁵ is preferably an alkyl group, an alkoxy group, an aryloxy group, an amino group, a cyano group, an aryl group, a heteroaryl group, a heterocyclic group, an acyl group, an acyloxy group, an amide group, a sulfonylamide group, an ureide group, or a carbamoyl group, more preferably an alkyl group, an alkoxy group, an acyl group, an amide group, or an amino group, and still more preferably an alkyl group.

The alkyl group that can be employed as R⁵ has the same meaning as the alkyl group that can be employed as R³ in General Formula (3), and the same applies to the preferred range thereof.

In General Formula (4), the substituent that can be employed as R⁶ is preferably an alkyl group, an alkenyl group, an aryl group, a heteroaryl group, a heterocyclic group, an alkoxy group, a cycloalkoxy group, an aryloxy group, an alkoxycarbonyl group, an acyl group, an acyloxy group, an amide group, a sulfonylamide group, an alkylsulfonyl group, an arylsulfonyl group, a carbamoyl group, an amino group, a cyano group, a nitro group, or a halogen atom, more preferably an alkyl group, an aryl group, a heteroaryl group, or a heterocyclic group, and still more preferably an alkyl group or an aryl group.

The alkyl group that can be employed as R⁶ has the same meaning as the alkyl group that can be employed as R⁴ in General Formula (3), and the same applies to the preferred range thereof.

The aryl group that can be employed as R⁶ is preferably an aryl group having 6 to 12 carbon atoms, and more preferably a phenyl group. This aryl group may have a substituent, and examples of such a substituent include a group included in the following substituent group A, and an alkyl group, a sulfonyl group, an amino group, an acylamino group, a sulfonylamino group, or the like, which have 1 to 10 carbon atoms, is particularly preferable. This substituent may further have a substituent. Specifically, the substituent is preferably an alkylsulfonylamino group.

—Substituent Group A—

A halogen atom, an alkyl group, an alkenyl group, an alkynyl group, an aryl group, a heterocyclic group, a cyano group, a hydroxy group, a nitro group, a carboxy group, an alkoxy group, an aminooxy group, an aryloxy group, a silyloxy group, a heterocyclic oxy group, an acyloxy group, a carbamoyloxy group, an amino group, an acylamino group, an aminocarbonylamino group, an alkoxycarbonylamino group, an aryloxycarbonylamino group, a sulfamoylamino group, a sulfonylamino group (including an alkyl or arylsulfonylamino group), a mercapto group, an alkylthio group, an arylthio group, a heterocyclic thio group, a sulfamoyl group, a sulfo group, an alkyl or arylsulfonyl group, a sulfonyl group (including an alkyl or arylsulfinyl group), an acyl group, an aryloxycarbonyl group, an alkoxycarbonyl group, a carbamoyl group, an aryl or heterocyclic azo group, an imide group, a phosphino group, a phosphinyl group, a phosphinyloxy group, a phosphinylamino group, a silyl group, and the like.

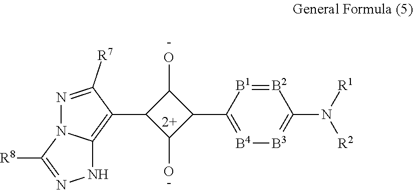

In General Formula (5), R¹ and R² each independently represent a hydrogen atom or a substituent, and they respectively have the same meanings as R¹ and R² in General Formula (2), where the same applies to the preferred ranges thereof.

In General Formula (5), B¹ to B⁴ each independently represent a carbon atom or a nitrogen atom, and they have respectively the same meanings as B¹ to B⁴ in General Formula (2), where the same applies to the preferred ranges thereof.

In General Formula (5), R⁷ and R⁸ each independently represent a hydrogen atom or a substituent. The substituent that can be employed as R⁷ and R¹ is not particularly limited, and examples thereof include the same ones as the substituents that can be employed as R¹ and R².

However, the preferred group, the more preferred group, and the still more preferred group of the substituent that can be employed as R⁷ are the same as those of the substituent that can be employed as R⁵ in General Formula (4). The alkyl group that can be employed as R⁵ has the same meaning as the alkyl group that can be employed as R³, and the same applies to the preferred range thereof.

In General Formula (5), the preferred range, the more preferred range, and the still more preferred range of the substituent that can be employed as R⁸ are the same as those of the substituent that can be employed as R⁶ in General Formula (4). The preferred ranges of the alkyl group and the aryl group that can be employed as R⁸ have the same meaning as the alkyl group and the aryl group that can be employed as R⁶ in General Formula (4), where the same applies to the preferred ranges thereof.

In the present invention, in a case where a squaraine-based coloring agent is used as the dye B or C, any squaraine-based coloring agent may be used without particular limitations as long as the squaraine-based coloring agent is the squaraine coloring agent represented by any one of General Formulae (1) to (5). Examples thereof include compounds described in, for example, JP2006-160618A, WO2004/005981A, WO2004/007447A, Dyes and Pigment, 2001, 49, p. 161 to 179, WO2008/090757A, WO2005/121098A, and JP2008-275726A.

Hereinafter, specific examples of the coloring agent represented by any one of General Formula (1) to General Formula (5) will be shown. However, the present invention is not limited thereto.

In the following specific examples, Me represents methyl, Et represents ethyl, Bu represents butyl, and Ph represents phenyl, respectively.

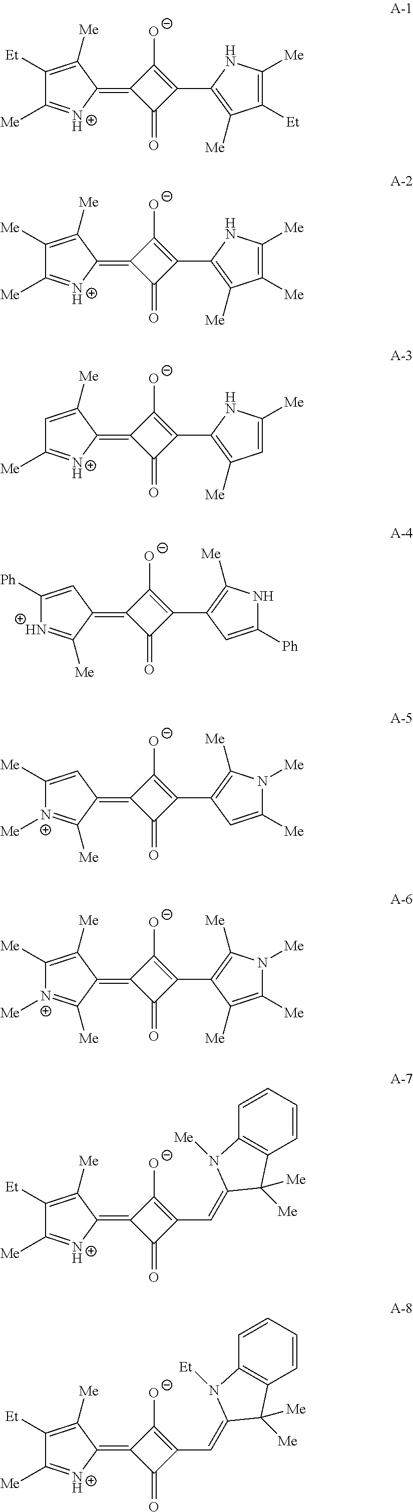

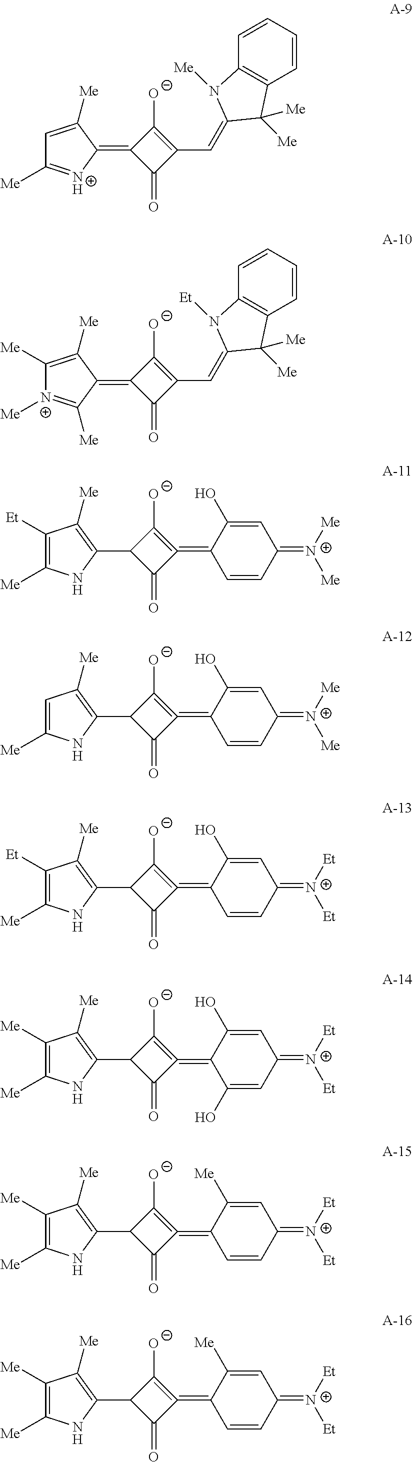

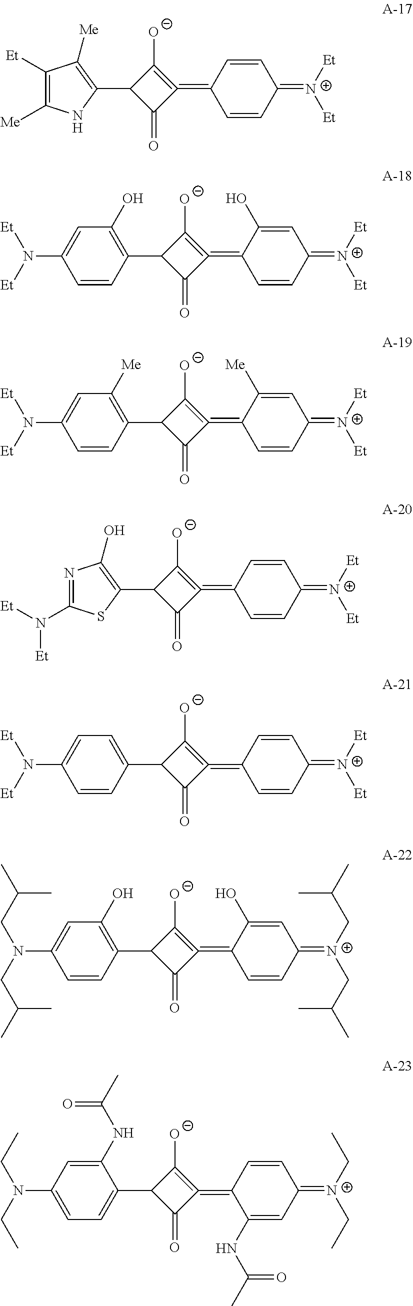

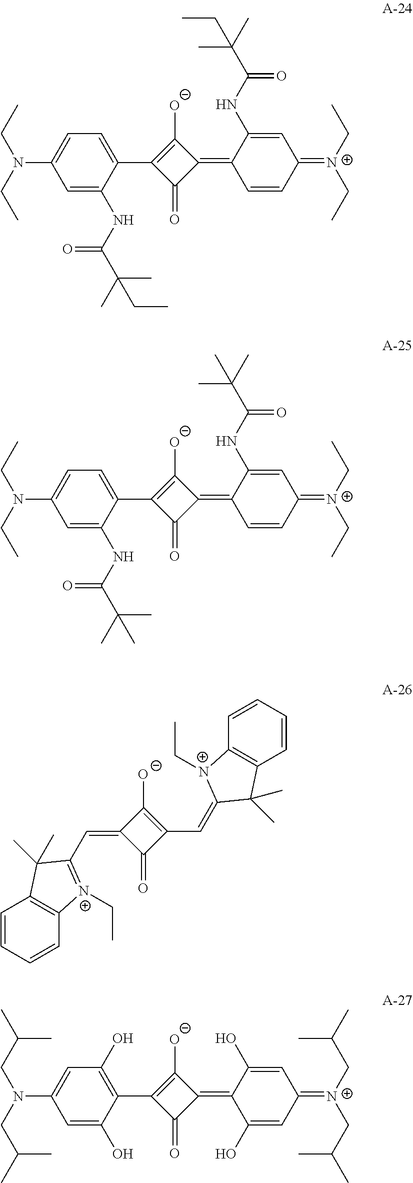 [SMILES: CCN(CC)c1ccc(C2=C([O-])/C(=C3/C=CC(=[N+](CC)CC)C=C3NC(=O)C(C)(C)CC)C2=O)c(NC(=O)C(C)(C)CC)c1 ; CCN(CC)c1ccc(C2=C([O-])/C(=C3/C=CC(=[N+](CC)CC)C=C3NC(=O)C(C)(C)C)C2=O)c(NC(=O)C(C)(C)C)c1 ; CC[N+]1=C(/C=C2\C(=O)C(/C=C3\[NH+](CC)c4ccccc4C3(C)C)=C2[O-])C(C)(C)c2ccccc21 ; CC(C)CN(CC(C)C)c1cc(O)c(C2=C([O-])C(=C3C(O)=CC(=[N+](CC(C)C)CC(C)C)C=C3O)C2=O)c(O)c1]

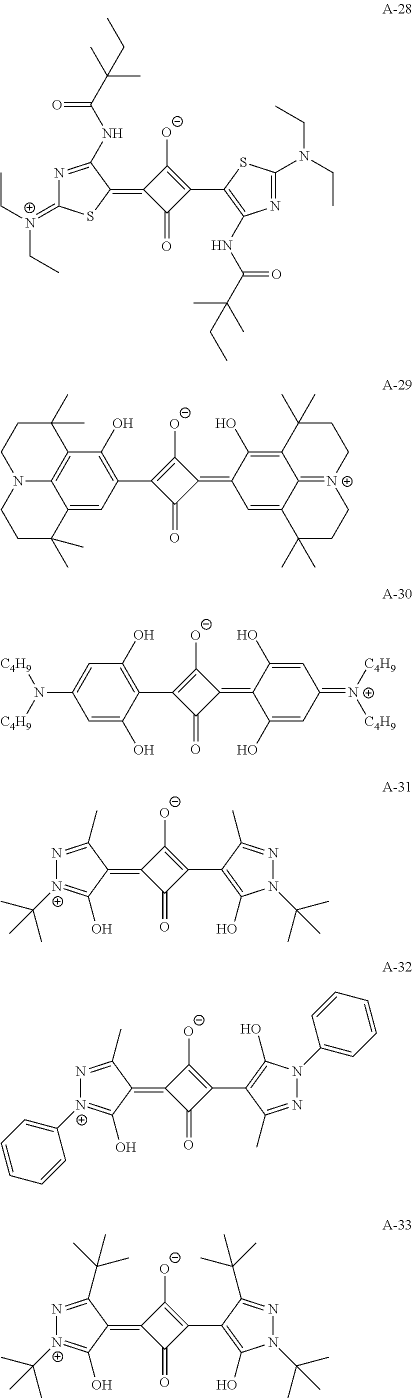

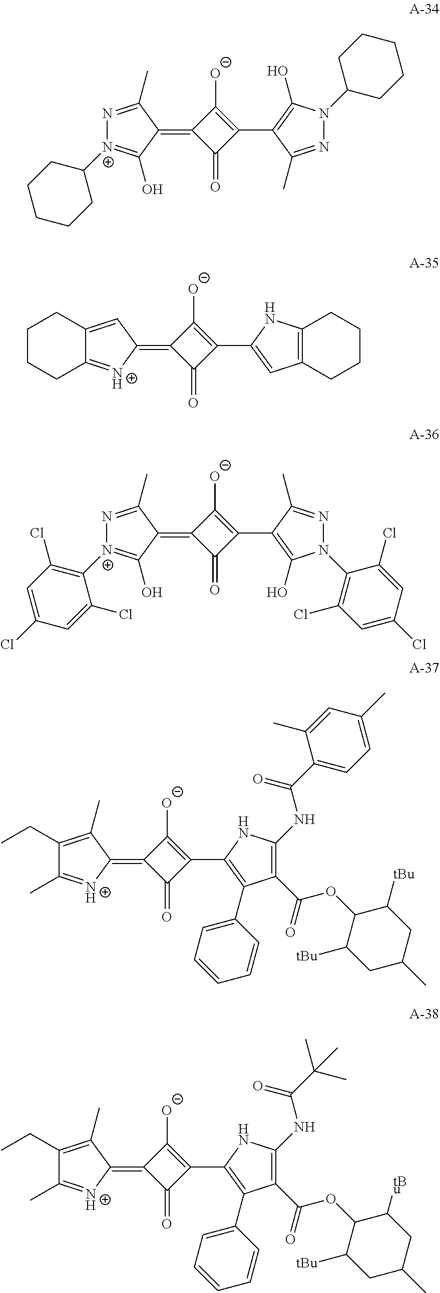

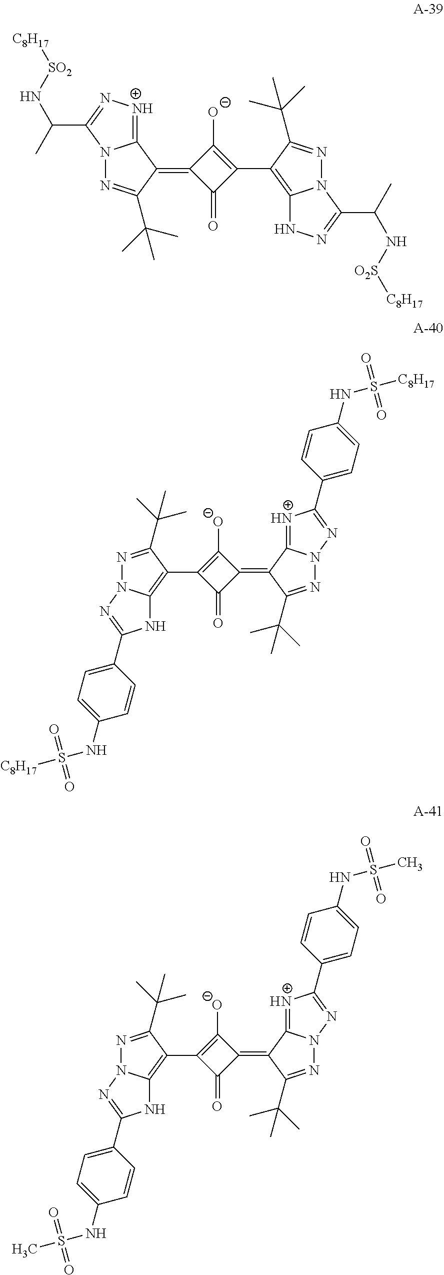

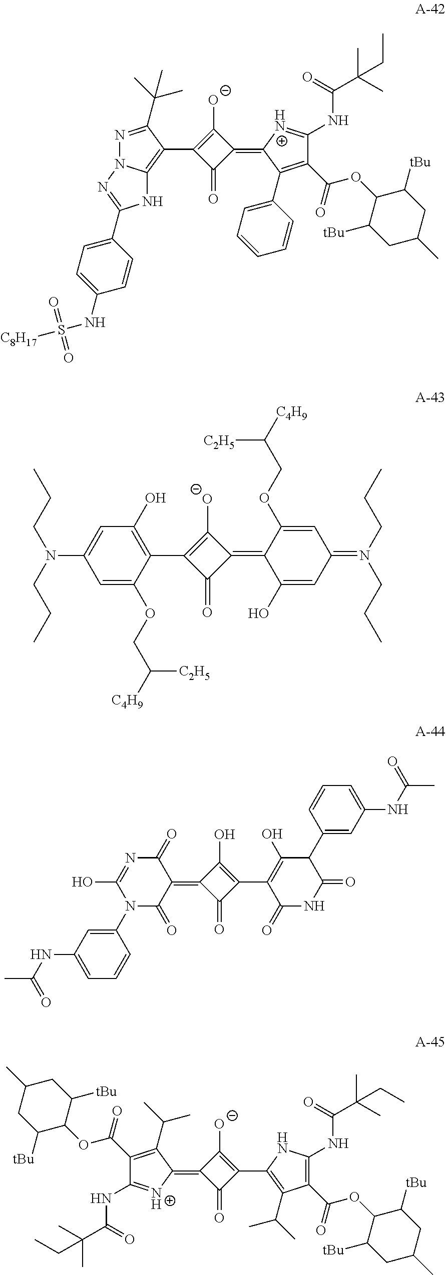

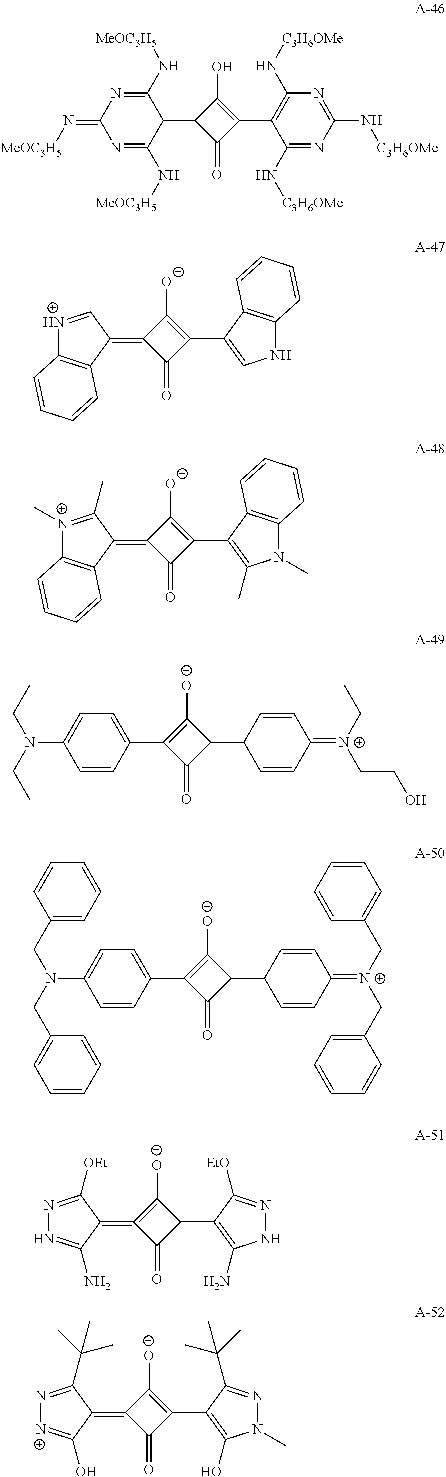

In addition to the above-described specific examples, specific examples of the coloring agents represented by any of General Formulae (3) to (5) will be shown. The substituent B in the following tables represents the following structures. In the following structures and the following tables, Me represents methyl, Et represents ethyl, i-Pr represents i-propyl, Bu represents n-butyl, t-Bu represents t-butyl, and Ph represents phenyl, respectively. In the following structures, * indicates a bonding site to a 4-membered carbon ring in each General Formula.

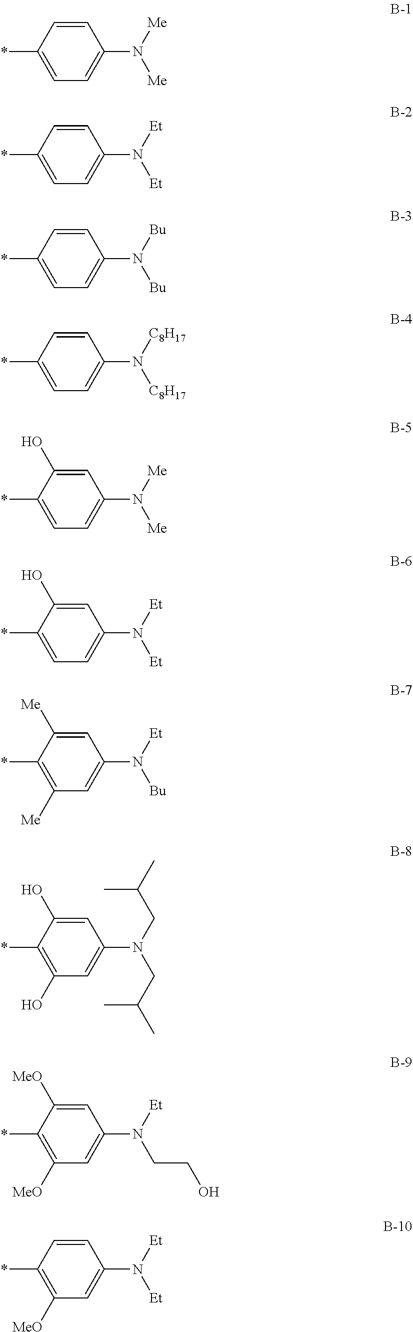

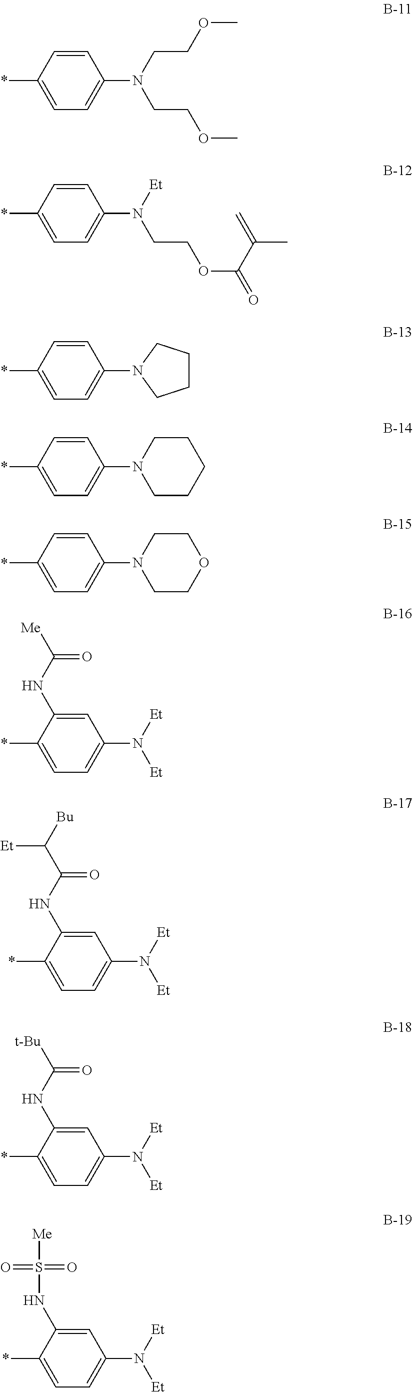

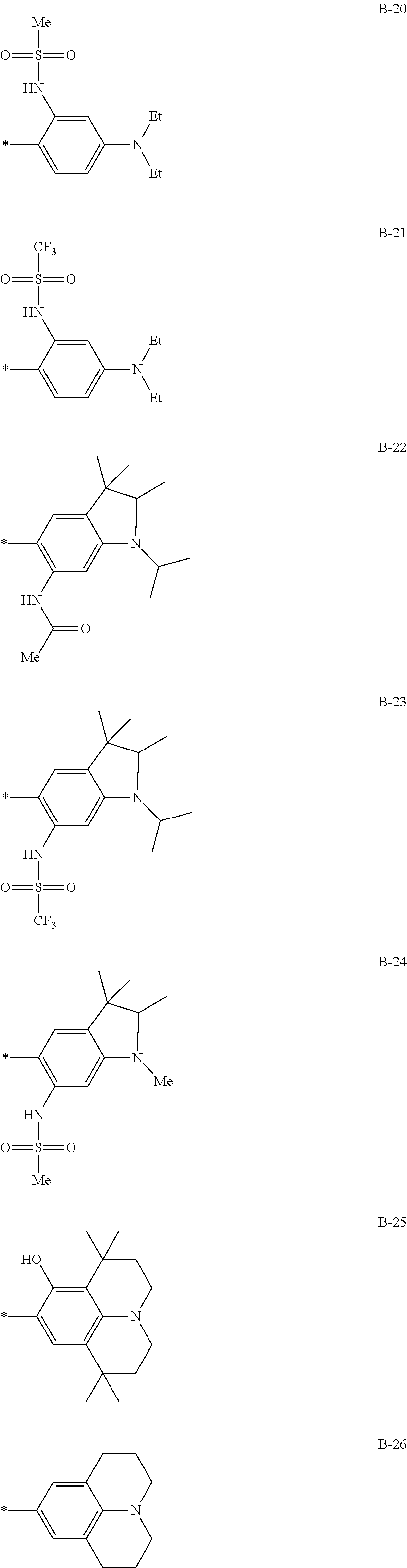

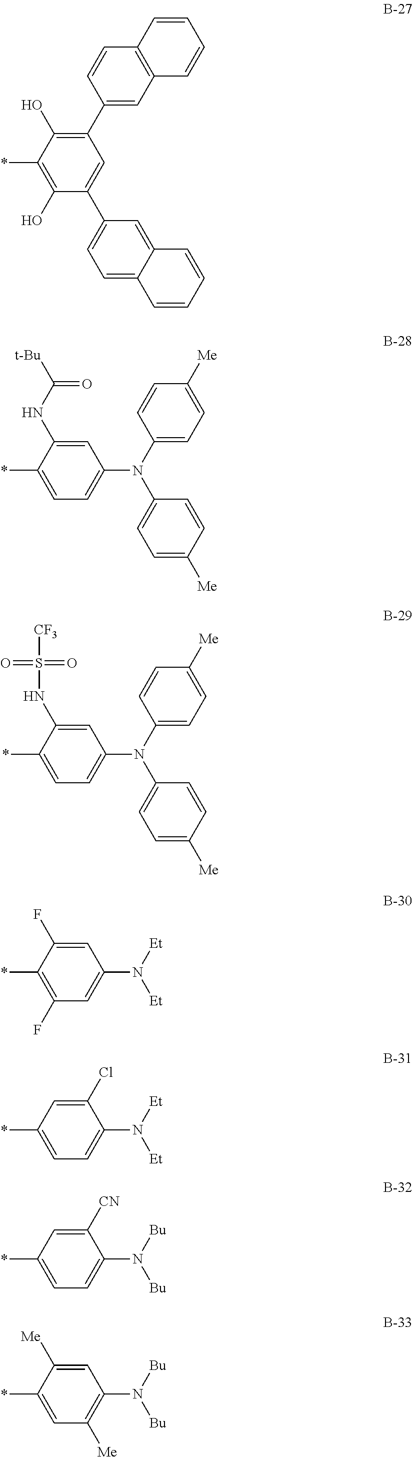

General Formula (3)

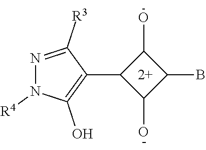

| Compound | | | |
|---|---|---|---|
| number | R³ | R⁴ | B |
| 3-1 | Me | Me | B-3 |
| 3-2 | Me | Me | B-4 |
| 3-3 | Me | Me | B-5 |
| 3-4 | Me | Me | B-10 |
| 3-5 | Me | Me | B-14 |
| 3-6 | Me | Me | B-16 |
| 3-7 | Me | Me | B-17 |
| 3-8 | Me | Me | B-18 |
| 3-9 | Me | Me | B-19 |
| 3-10 | Me | Me | B-20 |
| 3-11 | Me | Me | B-21 |
| 3-12 | Me | Me | B-22 |
| 3-13 | Me | Me | B-23 |
| 3-14 | Me | Me | B-26 |
| 3-15 | Me | Me | B-32 |
| 3-16 | Me | Me | B-33 |
| 3-17 | Me | Me | B-38 |
| 3-18 | Me | Me | B-49 |
| 3-19 | Et | 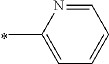 | B-28 |
| 3-20 | Me | 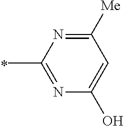 | B-29 |
| 3-21 | H | H | B-23 |
| 3-22 | Et | t-Bu | B-21 |
| 3-23 | t-Bu | Me | B-18 |
| 3-24 | CF₃ | i-Pr | B-12 |
| 3-25 | COOEt | Et | B-6 |
| 3-26 | CN | Ph | B-11 |
| 3-27 | NMe₂ | Me | B-2 |
| 3-28 | i-Pr | Me | B-17 |
| 3-29 | OEt | Bu | B-27 |
| 3-30 | NH₂ | i-Pr | B-9 |
| 3-31 | t-Bu | Me | B-17 |
| 3-32 | t-Bu | Bu | B-21 |
| 3-33 | CF₃ | Me | B-18 |
| 3-34 | OEt | Et | B-33 |
| 3-35 | NMe₂ | i-Pr | B-2 |
| 3-36 | Et | Me | B-17 |
| 3-37 | Bu | Me | B-18 |
| 3-38 | NH₂ | Ph | B-19 |
| 3-39 | OEt | 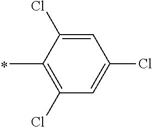 | B-25 |
| 3-40 | Me | 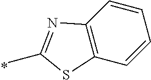 | B-2 |
| 3-41 | Me | Ph | B-17 |
| 3-42 | Me | Ph | B-21 |
| 3-43 | Me | Ph | B-36 |
| 3-44 | Me | t-Bu | B-17 |
| 3-45 | Me | t-Bu | B-18 |
| 3-46 | Me | t-Bu | B-10 |
| 3-47 | OEt | Me | B-17 |
| 3-48 | OEt | Me | B-10 |
| 3-49 | Me | 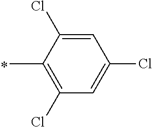 | B-17 |
| 3-50 | Me | 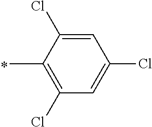 | B-19 |
| 3-51 | Me | 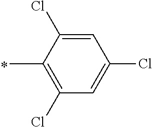 | B-21 |
| 3-52 | Me | 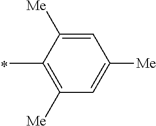 | B-17 |
| 3-53 | Me | 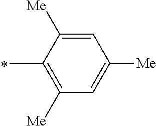 | B-20 |
| 3-54 | Me | 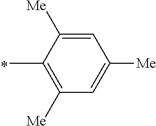 | B-21 |
| 3-55 | t-Bu | Me | B-17 |
| 3-56 | t-Bu | Me | B-10 |
| 3-57 | t-Bu | Me | B-44 |
| 3-58 | t-Bu | t-Bu | B-17 |
| 3-59 | t-Bu | t-Bu | B-10 |
| 3-60 | t-Bu | t-Bu | B-6 |
| 3-61 | NBu₂ | Me | B-17 |
| 3-62 | NBu₂ | Me | B-10 |
| 3-63 | t-Bu | 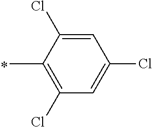 | B-17 |
| 3-64 | t-Bu | 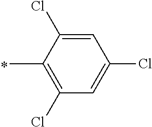 | B-19 |
| 3-65 | t-Bu | 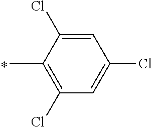 | B-21 |
| 3-66 | t-Bu | 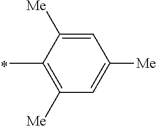 | B-17 |
| 3-67 | t-Bu | 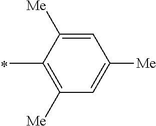 | B-20 |
| 3-68 | t-Bu | 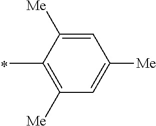 | B-21 |
| 3-69 | Me | t-Bu | B-51 |
| 3-70 | Me | t-Bu | B-52 |
| 3-71 | Me | t-Bu | B-54 |
| 3-72 | Me | t-Bu | B-55 |
| 3-73 | Me | t-Bu | B-58 |
| 3-74 | Me | t-Bu | B-60 |
| 3-75 | Me | t-Bu | B-65 |
| 3-76 | Me | t-Bu | B-67 |
| 3-77 | Me | t-Bu | B-68 |
| 3-78 | H | t-Bu | B-51 |
| 3-79 | Et | t-Bu | B-53 |
| 3-80 | Pr | 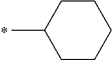 | B-64 |
| 3-81 | iPr | iPr | B-66 |
| 3-82 | Me | 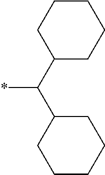 [SMILES: *C(C1CCCCC1)C1CCCCC1] | B-51 |
| 3-83 | Et | Bu | B-56 |
| 3-84 | Me | iPr | B-66 |
| 3-85 | Me | 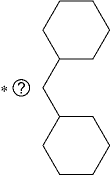 | B-54 |
| 3-86 | Me | 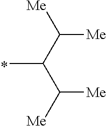 | B-57 |
| 3-87 | Et | 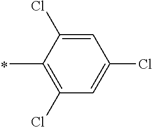 | B-60 |
| 3-88 | Me | iPr | B-65 |
| 3-89 | Me | t-Bu | B-69 |
| 3-90 | Me | 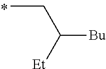 | B-50 |
| 3-91 | Me | 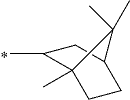 | B-61 |
| 3-92 | Me | 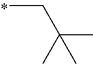 | B-51 |
| 3-93 | Me | 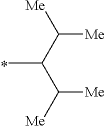 | B-51 |
| 3-94 | Me | 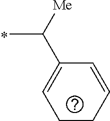 | B-67 |
| 3-95 | Me | 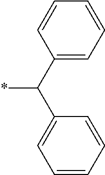 [SMILES: *C(c1ccccc1)c1ccccc1] | B-51 |
| 3-96 | Me | 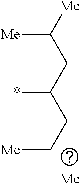 [SMILES: *C(CCC)CC(C)C ; "Me"] | B-51 |

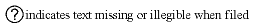

General Formula (4)

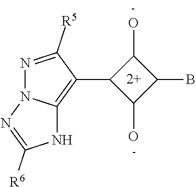

| Compound | | | |
|---|---|---|---|
| number | R⁵ | R⁶ | B |
| 4-1 | t-Bu | 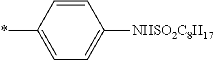 | B-2 |
| 4-2 | t-Bu | 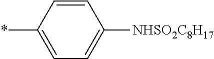 | B-6 |
| 4-3 | t-Bu | 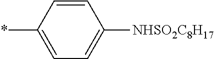 | B-10 |
| 4-4 | Me | 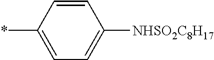 | B-4 |
| 4-5 | t-Bu | 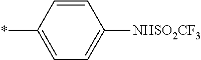 | B-6 |
| 4-6 | t-Bu | 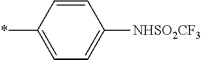 | B-14 |
| 4-7 | NHCOCH₃ | 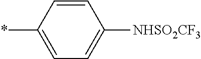 | B-1 |
| 4-8 | t-Bu | 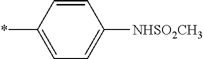 | B-6 |
| 4-9 | t-Bu | 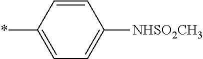 | B-16 |
| 4-10 | OEt | 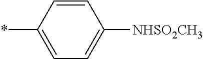 | B-11 |
| 4-11 | t-Bu | 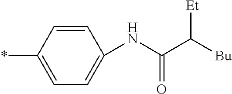 | B-6 |
| 4-12 | t-Bu | 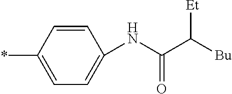 | B-12 |
| 4-13 | OEt | 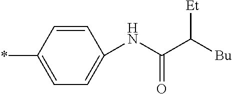 | B-31 |
| 4-14 | H | H | B-22 |
| 4-15 | Me | Me | B-23 |
| 4-16 | Me | Me | B-17 |
| 4-17 | Me | Et | B-18 |
| 4-18 | Ph | Ph | B-8 |
| 4-19 | Et | t-Bu | B-17 |
| 4-20 | OEt | t-Bu | B-3 |
| 4-21 | OEt | Bu | B-26 |
| 4-22 | OEt | 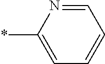 [SMILES: *c1ccccn1] | B-2 |
| 4-23 | CF3 | t-Bu | B-19 |
| 4-24 | NHCOCH₃ | t-Bu | B-2 |
| 4-25 | NHCOCH₃ | Me | B-1 |
| 4-26 | NMe₂ | t-Bu | B-6 |
| 4-27 | NMe₂ | Et | B-17 |
| 4-28 | H | Me | B-2 |
| 4-29 | t-Bu | t-Bu | B-18 |
| 4-30 | t-Bu | Me | B-17 |
| 4-31 | t-Bu | 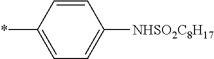 | B-51 |
| 4-32 | t-Bu | 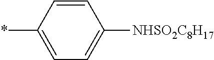 | B-52 |
| 4-33 | t-Bu | 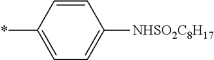 | B-54 |
| 4-34 | Me | 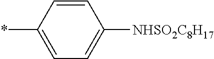 | B-55 |
| 4-35 | t-Bu | 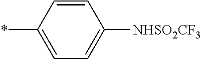 | B-60 |
| 4-36 | Me | Me | B-65 |
| 4-37 | Me | Et | B-67 |
| 4-38 | Ph | Ph | B-48 |
| 4-39 | Et | t-Bu | B-54 |
| 4-40 | Me | Me | B-51 |

General Formula (5)

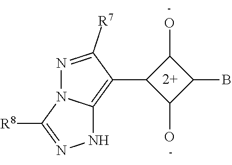

| Compound | | | |
|---|---|---|---|
| number | R⁷ | R⁸ | B |
| 5-1 | t-Bu | 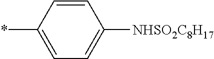 | B-2 |
| 5-2 | Me | 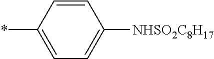 | B-6 |
| 5-3 | t-Bu | 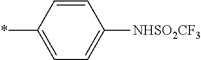 | B-4 |
| 5-4 | Me | 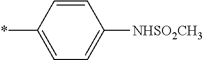 | B-10 |
| 5-5 | t-Bu | 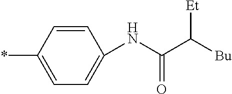 | B-6 |
| 5-6 | t-Bu | 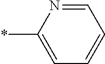 [SMILES: *c1ccccn1] | B-14 |
| 5-7 | Me | 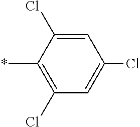 [SMILES: *c1c(Cl)cc(Cl)cc1Cl] | B-1 |
| 5-8 | Me | 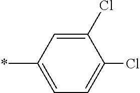 [SMILES: *c1ccc(Cl)c(Cl)c1] | B-6 |
| 5-9 | Me | 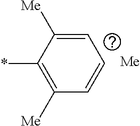 [SMILES: *c1c(C)cccc1C ; "Me"] | B-16 |
| 5-10 | t-Bu | 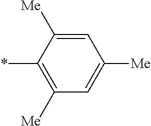 [SMILES: *c1c(C)cc(C)cc1C] | B-11 |
| 5-11 | Me | Me | B-17 |
| 5-12 | Me | t-Bu | B-18 |
| 5-13 | Ph | Ph | B-8 |
| 5-14 | Ph | 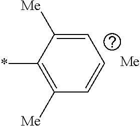 [SMILES: *c1c(C)cccc1C ; "Me"] | B-17 |
| 5-15 | Et | Ph | B-17 |
| 5-16 | OEt | t-Bu | B-3 |
| 5-17 | OEt | Bu | B-26 |
| 5-18 | CF3 | t-Bu | B-19 |
| 5-19 | NHCOCH3 | t-Bu | B-2 |
| 5-20 | NHCOCH3 | 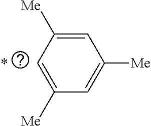 | B-1 |
| 5-21 | t-Bu | 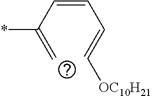 | B-2 |
| 5-22 | Me | 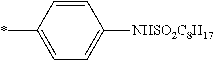 | B-51 |
| 5-23 | t-Bu | 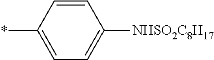 | B-52 |
| 5-24 | Me | 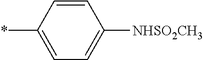 | B-55 |
| 5-25 | t-Bu | 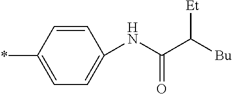 | B-60 |
| 5-26 | Me | Me | B-65 |
| 5-27 | Me | t-Bu | B-67 |
| 5-28 | Ph | Ph | B-50 |
| 5-29 | Ph | 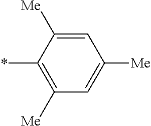 [SMILES: *c1c(C)cc(C)cc1C] | B-23 |
| 5-30 | Et | Ph | B-59 |

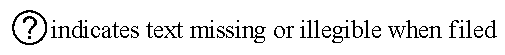

One preferred embodiment of the coloring agent represented by General Formula (1) includes a coloring agent represented by General Formula (6).

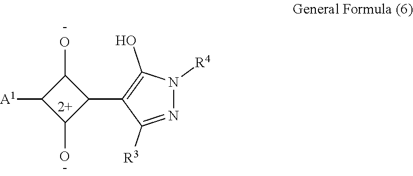

In General Formula (6), R³ and R⁴ each independently represent a hydrogen atom or a substituent and they respectively have the same meanings as R³ and R⁴ in General Formula (3), where the preferred ones thereof are also the same.

In General Formula (6), A² is the same as A in General Formula (1). Among these, a heterocyclic group which is a nitrogen-containing 5-membered ring is preferable.

The coloring agent represented by General Formula (6) is preferably a coloring agent represented by any of General Formulae (7), (8), or (9).

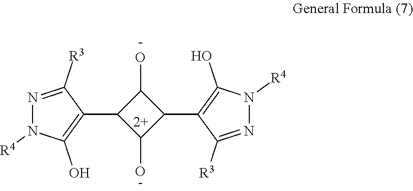

In General Formula (7), R³ and R⁴ each independently represent a hydrogen atom or a substituent, and they respectively have the same meanings as R³ and R⁴ in General Formula (3), where the same applies to the preferred ranges thereof. Two R³'s and two R⁴'s may be the same or different from each other.

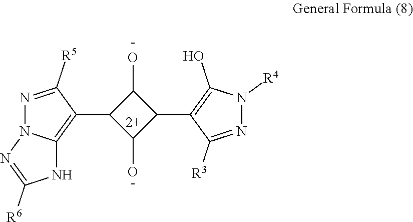

In General Formula (8), R³ and R⁴ each independently represent a hydrogen atom or a substituent, and they respectively have the same meanings as R³ in General Formula (3), where the same applies to the preferred ranges thereof.

In General Formula (8), R⁵ and R⁶ each independently represent a hydrogen atom or a substituent, and they respectively have the same meanings as R⁵ and R⁶ in General Formula (4), where the same applies to the preferred ranges thereof.

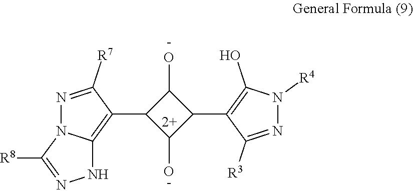

In General Formula (9), R³ and R⁴ each independently represent a hydrogen atom or a substituent, and they respectively have the same meanings as R³ in General Formula (3), where the same applies to the preferred ranges thereof.

In General Formula (9), R⁷ and R⁸ each independently represent a hydrogen atom or a substituent, and they respectively have the same meanings as R⁷ and R¹ in General Formula (5), where the same applies to the preferred ranges thereof.

In the present invention, in a case where a squaraine-based coloring agent is used as the dye B, any squaraine-based coloring agent may be used without particular limitations as long as the squaraine-based coloring agent is the squaraine-based coloring agent represented by any one of General Formulae (6) to (9). Examples thereof include the compounds described in JP2002-97383A and JP2015-68945A.

Hereinafter, specific examples of the coloring agent represented by any one of General Formula (6) to General Formula (9) will be shown. However, the present invention is not limited thereto.

In the following specific examples, Me represents methyl, Et represents ethyl, i-Pr represents i-propyl, t-Bu represents t-butyl, and Ph represents phenyl, respectively. In the following structures, * indicates a bonding site to a 4-membered carbon ring in each General Formula.

General Formula (7)

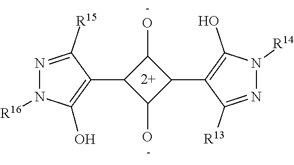

| Compound number | R¹³ | R¹⁴ | R¹⁵ | R¹⁶ |
|---|---|---|---|---|
| 7-1 | Me | Me | Me | Me |
| 7-2 | Et | Me | Et | Me |
| 7-3 | Me | 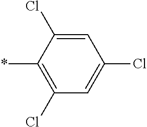 [SMILES: *c1c(Cl)cc(Cl)cc1Cl] | Me | 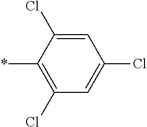 [SMILES: *c1c(Cl)cc(Cl)cc1Cl] |
| 7-4 | t-Bu | 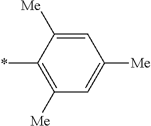 [SMILES: *c1c(C)cc(C)cc1C] | t-Bu | 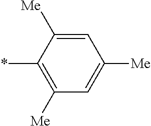 [SMILES: *c1c(C)cc(C)cc1C] |
| 7-5 | NMe₂ | Me | NMe₂ | Me |
| 7-6 | CN | Me | CN | Me |
| 7-7 | OEt | Me | OEt | Me |
| 7-8 | Me | 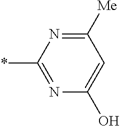 [SMILES: *c1nc(C)cc(O)n1] | Me | 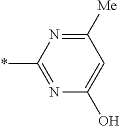 [SMILES: *c1nc(C)cc(O)n1] |
| 7-9 | Et | 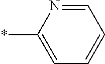 [SMILES: *c1ccccn1] | Et | 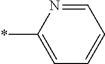 [SMILES: *c1ccccn1] |
| 7-10 | i-Pr | 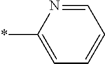 [SMILES: *c1ccccn1] | i-Pr | 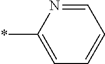 [SMILES: *c1ccccn1] |
| 7-11 | t-Bu | t-Bu | t-Bu | t-Bu |
| 7-12 | CF₃ | Ph | CF₃ | Ph |
| 7-13 | COOEt | Me | COOEt | Me |
| 7-14 | NH₂ | Me | NH₂ | Me |
| 7-15 | Me | Me | Me | 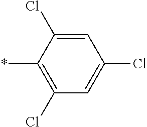 [SMILES: *c1c(Cl)cc(Cl)cc1Cl] |
| 7-16 | Me | Me | t-Bu | t-Bu |
| 7-17 | Me | Me | NMe₂ | Me |
| 7-18 | Me | Me | Me | Ph |
| 7-19 | Et | Me | Et | 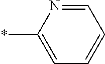 [SMILES: *c1ccccn1] |
| 7-20 | COOEt | Me | Me | 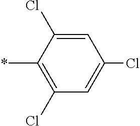 [SMILES: *c1c(Cl)cc(Cl)cc1Cl] |

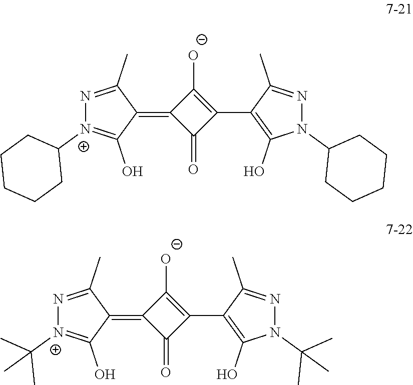 [SMILES: CC1=N[N+](C2CCCCC2)=C(O)/C1=C1\C(=O)C(c2c(C)nn(C3CCCCC3)c2O)=C1[O-] ; CC1=N[N+](C(C)(C)C)=C(O)/C1=C1\C(=O)C(c2c(C)nn(C(C)(C)C)c2O)=C1[O-]]

General Formula (8)

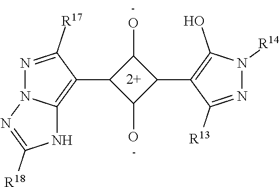

| Compound number | R¹³ | R¹⁴ | R¹⁷ | R¹⁸ |
|---|---|---|---|---|
| 8-1 | Me | Me | Me | Me |
| 8-2 | Me | Me | t-Bu | 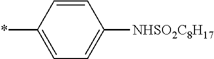 |
| 8-3 | Me | Me | t-Bu | 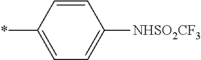 |
| 8-4 | Me | Me | t-Bu | 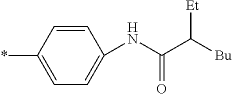 |
| 8-5 | Me | 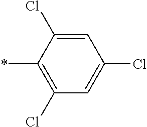 [SMILES: *c1c(Cl)cc(Cl)cc1Cl] | Me | Me |
| 8-6 | Me | 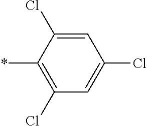 [SMILES: *c1c(Cl)cc(Cl)cc1Cl] | t-Bu | 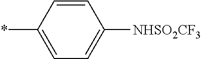 / |
| 8-7 | Me | Ph | t-Bu | 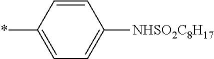 |
| 8-8 | Me | 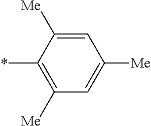 [SMILES: *c1c(C)cc(C)cc1C] | Me | Me |
| 8-9 | Et | Me | Me | Me |
| 8-10 | i-Pr | Me | Me | Me |
| 8-11 | t-Bu | Me | Me | Me |
| 8-12 | Me | Me | OEt | Bu |
| 8-13 | COOEt | Me | Me | Me |
| 8-14 | NH₂ | Me | Me | Me |
| 8-15 | Me | Me | CF₃ | t-Bu |

General Formula (9)

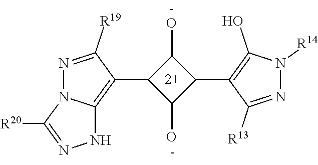

| Compound number | R¹³ | R¹⁴ | R¹⁹ | R²⁰ |
|---|---|---|---|---|
| 9-1 | Me | Me | Me | Me |
| 9-2 | Me | Me | t-Bu | 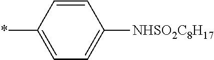 |
| 9-3 | Me | Me | Me | 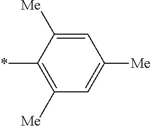 [SMILES: *c1c(C)cc(C)cc1C] |
| 9-4 | Me | Me | Me | 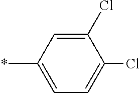 [SMILES: *c1ccc(Cl)c(Cl)c1] |
| 9-5 | Me | 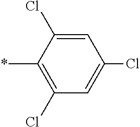 [SMILES: *c1c(Cl)cc(Cl)cc1Cl] | Me | Me |
| 9-6 | Me | 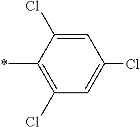 [SMILES: *c1c(Cl)cc(Cl)cc1Cl] | Me | 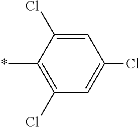 [SMILES: *c1c(Cl)cc(Cl)cc1Cl] |
| 9-7 | t-Bu | Me | t-Bu | 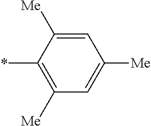 [SMILES: *c1c(C)cc(C)cc1C] |
| 9-8 | t-Bu | Me | Me | Me |
| 9-9 | Et | Me | t-Bu | Me |
| 9-10 | i-Pr | Me | Me | 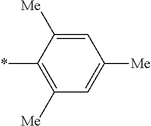 [SMILES: *c1c(C)cc(C)cc1C] |

(Quencher-Embedded Coloring Agent)

The squaraine-based coloring agent represented by General Formula (1) may be a quencher-embedded coloring agent in which a quencher moiety is linked to a coloring agent by a covalent bond through a linking group. The quencher-embedded coloring agent can also be preferably used as the coloring agent of at least one of the dye B or C. That is, the quencher-embedded coloring agent is counted as the dye B or dye C according to the wavelength having the main absorption wavelength band.

Examples of the quencher moiety include the ferrocenyl group in the above-described substituent X. Further, examples thereof include the quencher moieties in the quencher compounds described in paragraphs [0199] to [0212] and paragraphs [0234] to [0310] of WO2019/066043A.

Among the squaraine-based coloring agents represented by General Formula (1), specific examples of the coloring agent corresponding to the quencher-embedded coloring agent are shown below. However, the present invention is not limited thereto.

In the following specific examples, Me represents methyl, Et represents ethyl, and Bu represents butyl, respectively.

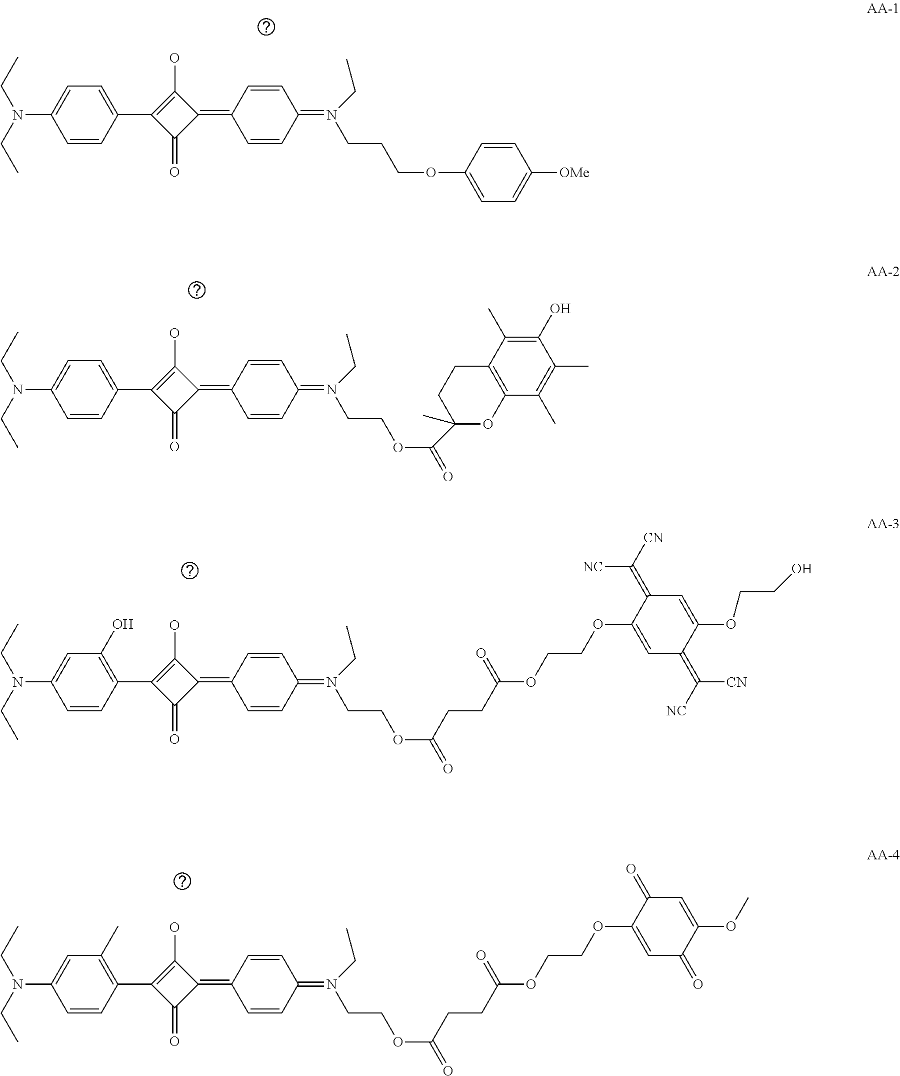

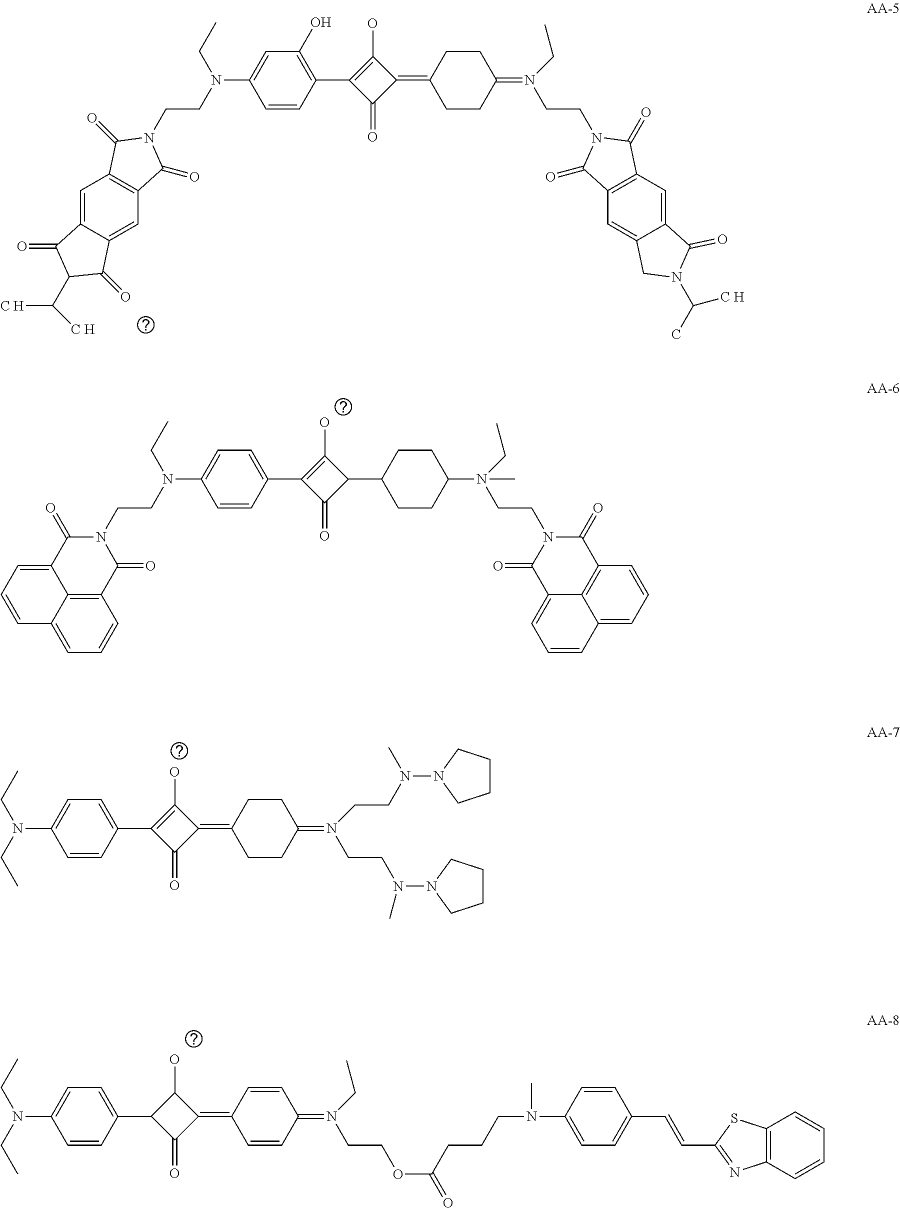

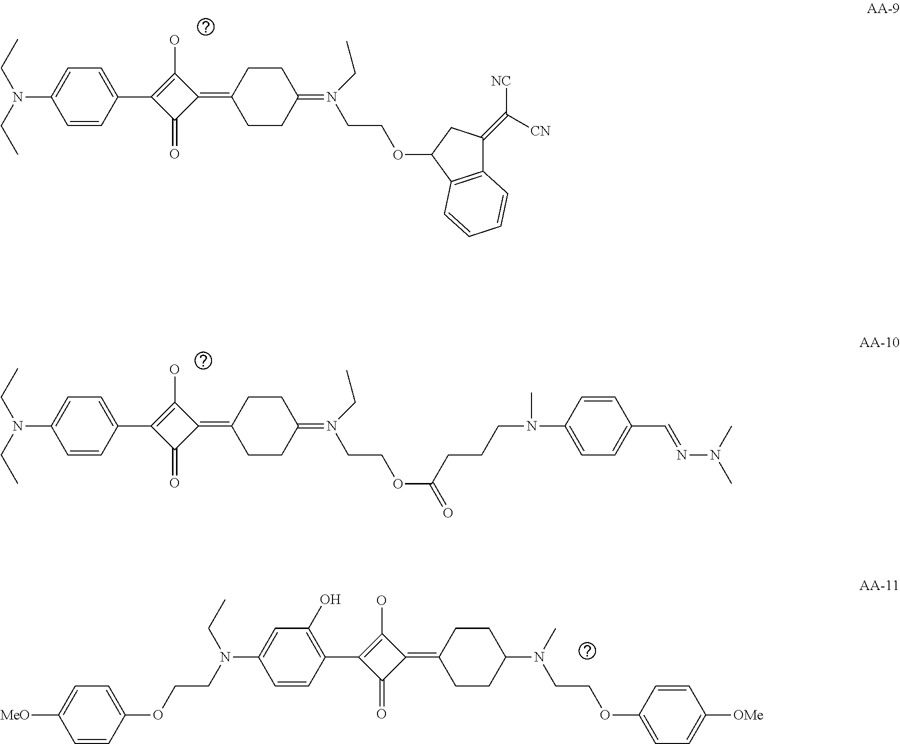

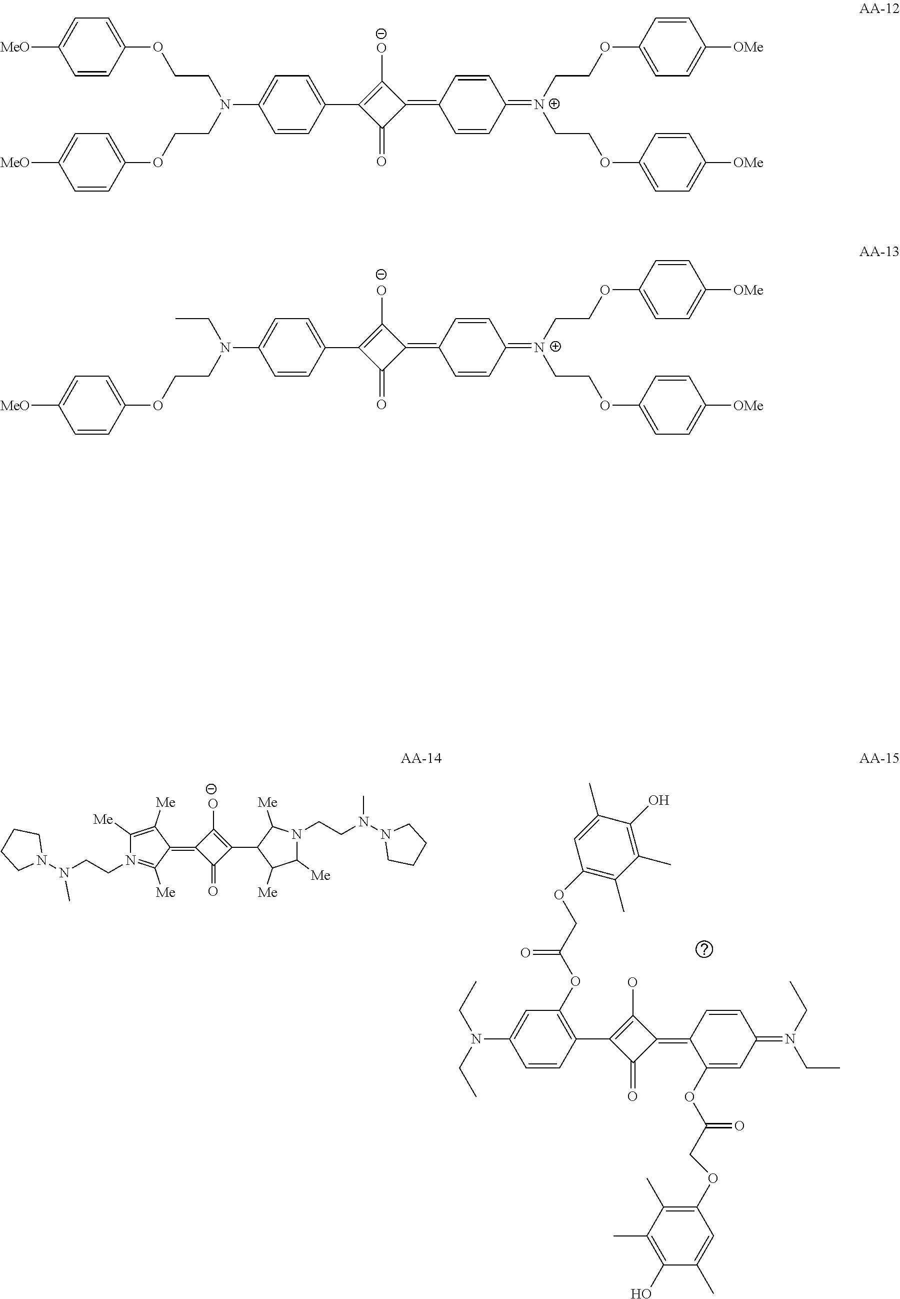

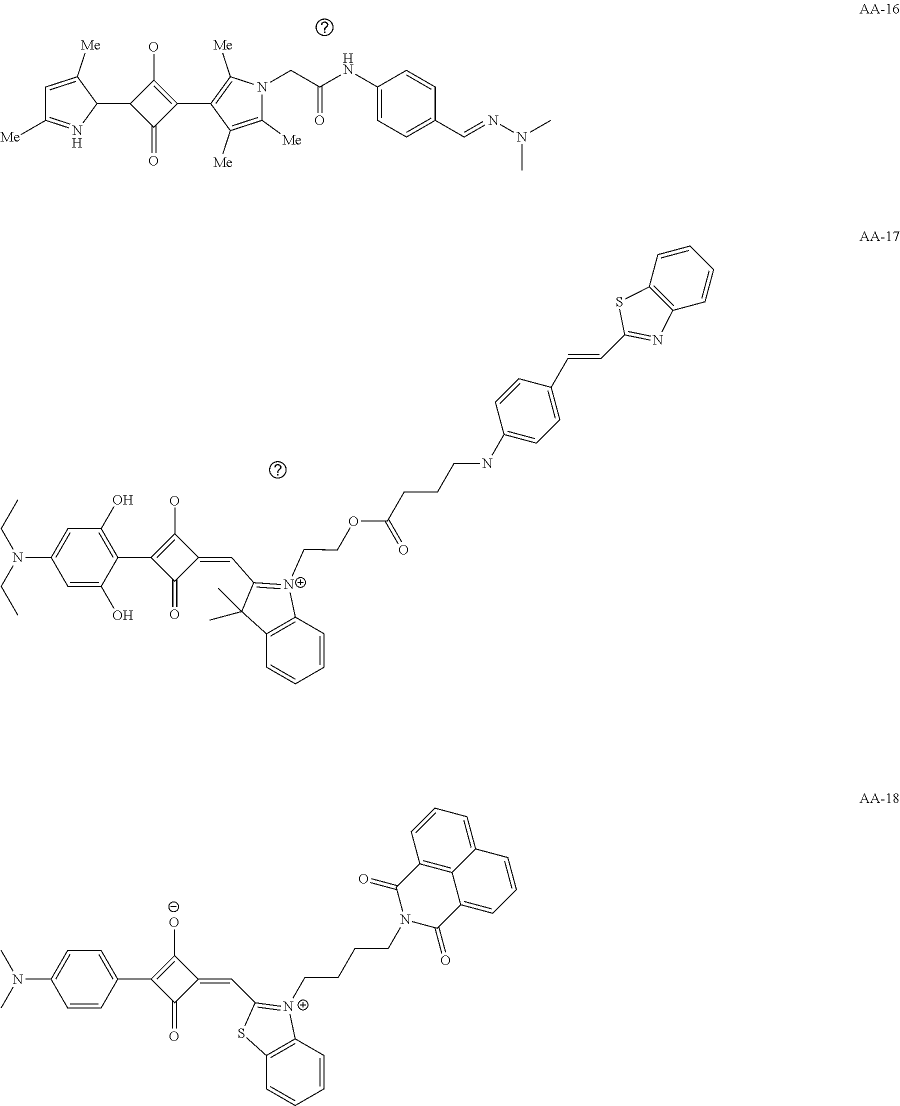

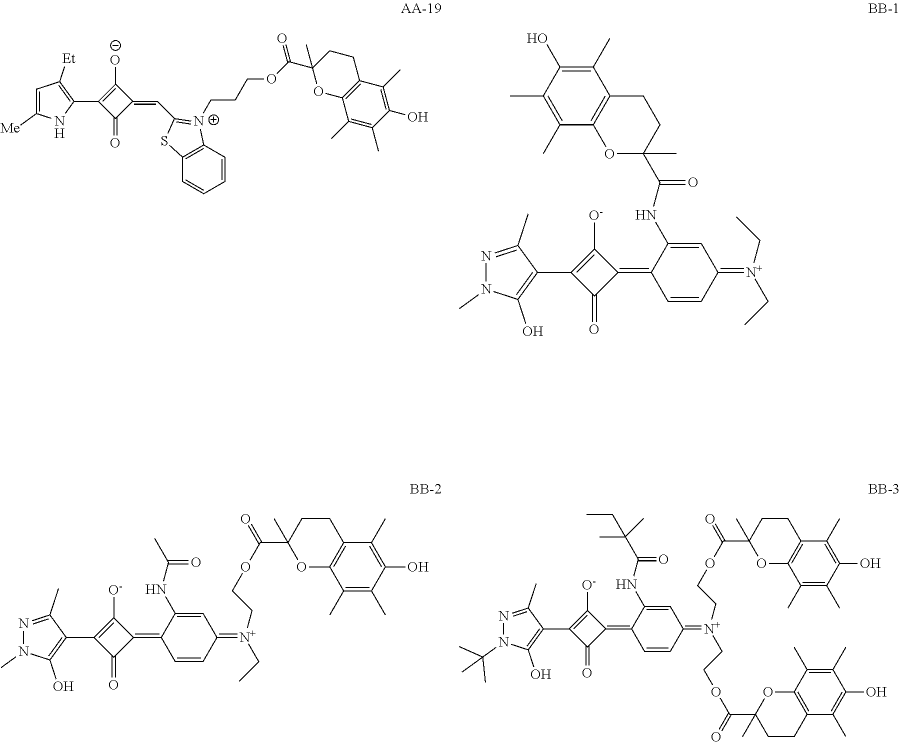 [SMILES: CCc1cc(C)[nH]c1C1=C([O-])/C(=C/c2sc3ccccc3[n+]2CCCOC(=O)C2(C)CCc3c(C)c(O)c(C)c(C)c3O2)C1=O ; CC[N+](CC)=C1C=C/C(=C2\C(=O)C(c3c(C)nn(C)c3O)=C2[O-])C(NC(=O)C2(C)CCc3c(C)c(O)c(C)c(C)c3O2)=C1 ; CC/[N+](CCOC(=O)C1(C)CCc2c(C)c(O)c(C)c(C)c2O1)=C1C=C/C(=C2\C(=O)C(c3c(C)nn(C)c3O)=C2[O-])C(NC(C)=O)=C\1 ; CCC(C)(C)C(=O)NC1=CC(=[N+](CCOC(=O)C2(C)CCc3c(C)c(O)c(C)c(C)c3O2)CCOC(=O)C2(C)CCc3c(C)c(O)c(C)c(C)c3O2)C=C/C1=C1\C(=O)C(c2c(C)nn(C(C)(C)C)c2O)=C1[O-]]

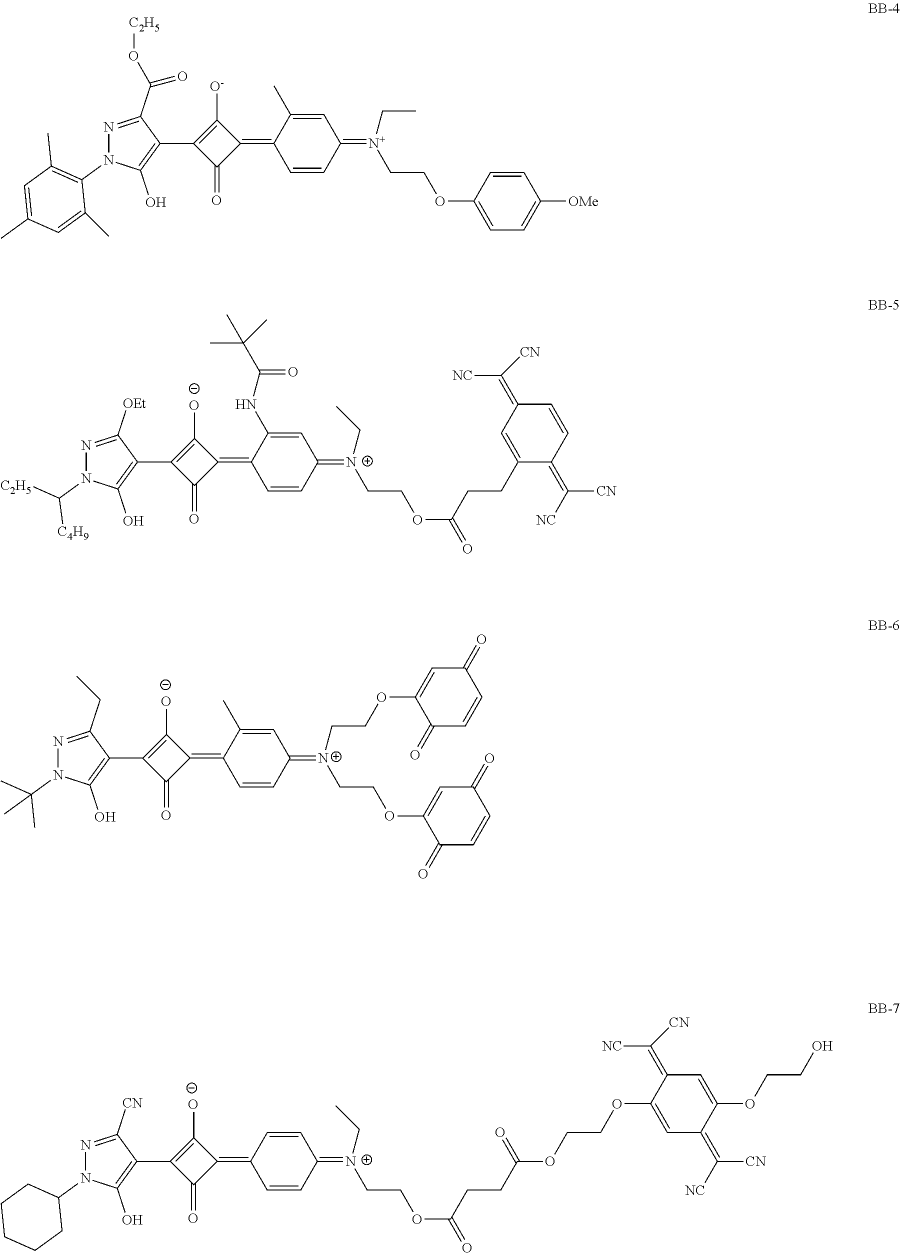

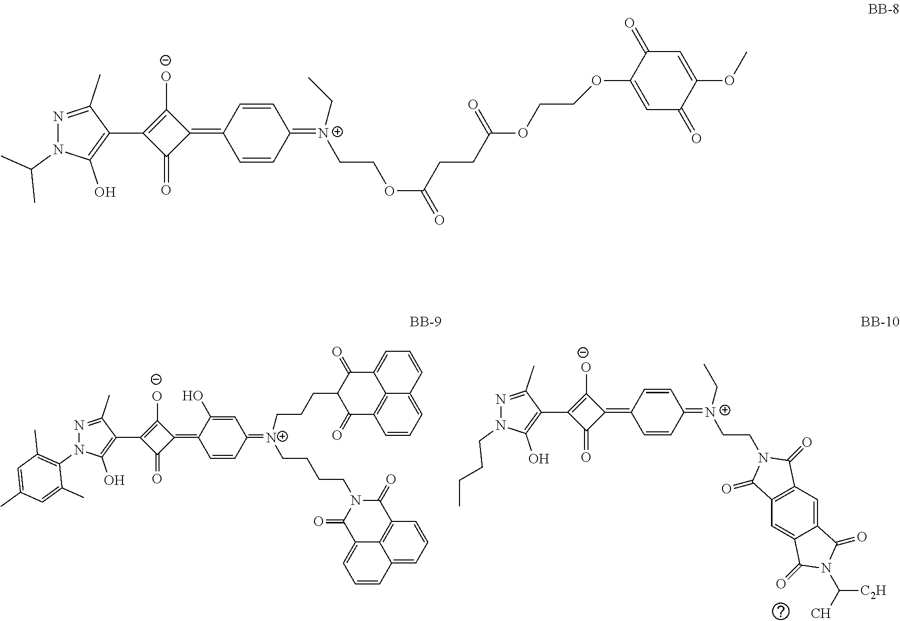

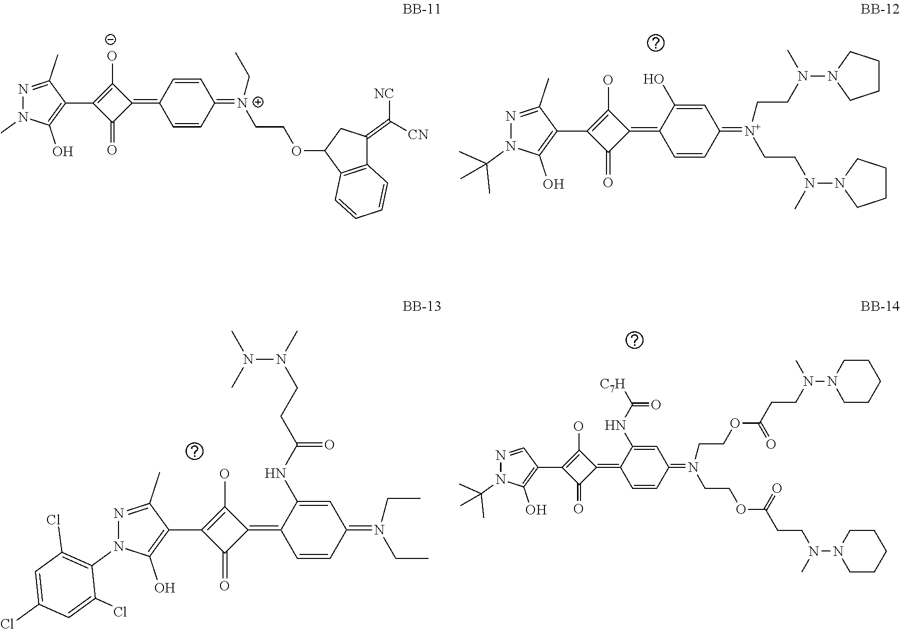

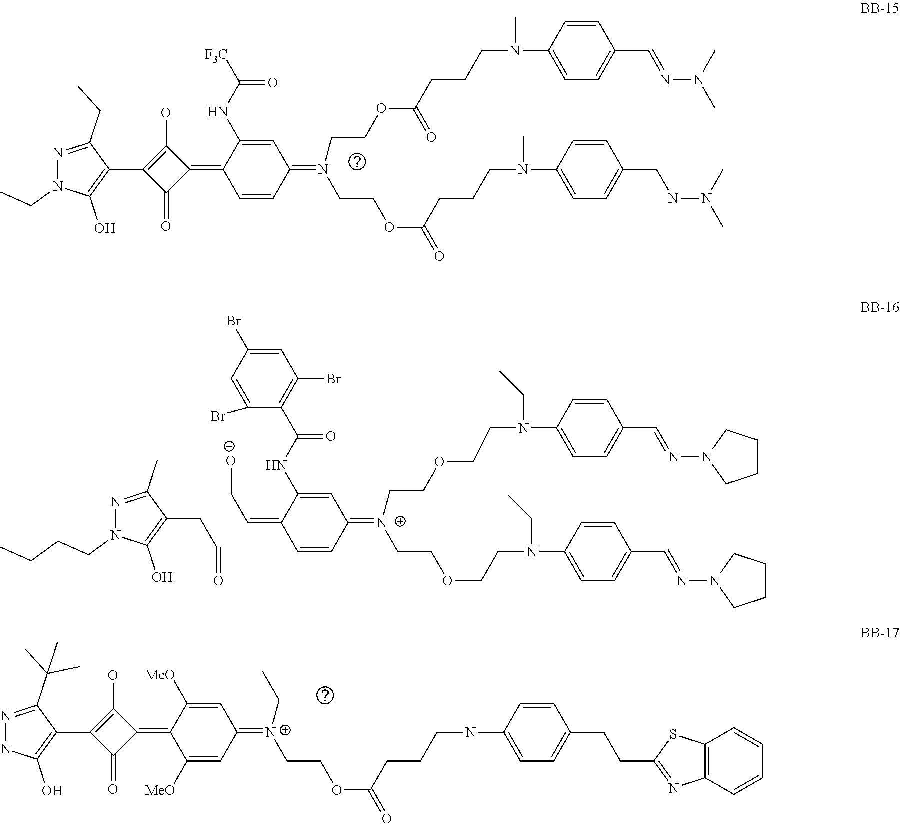

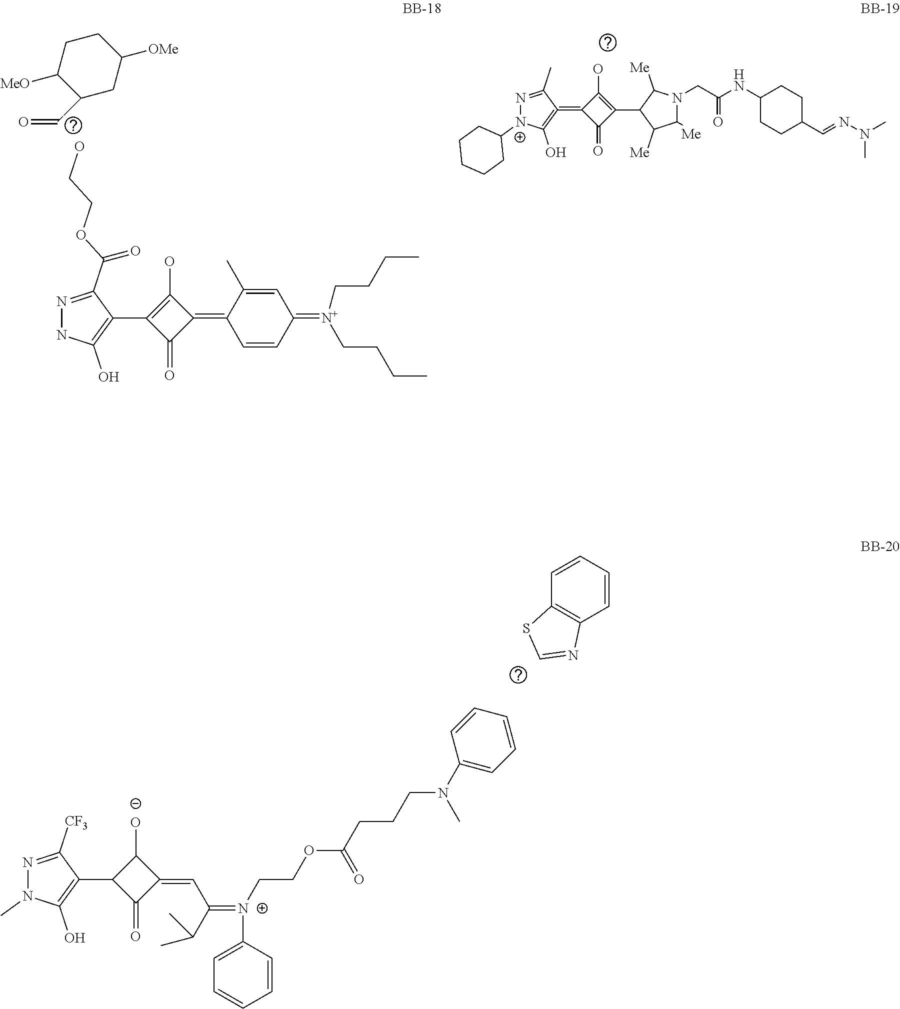

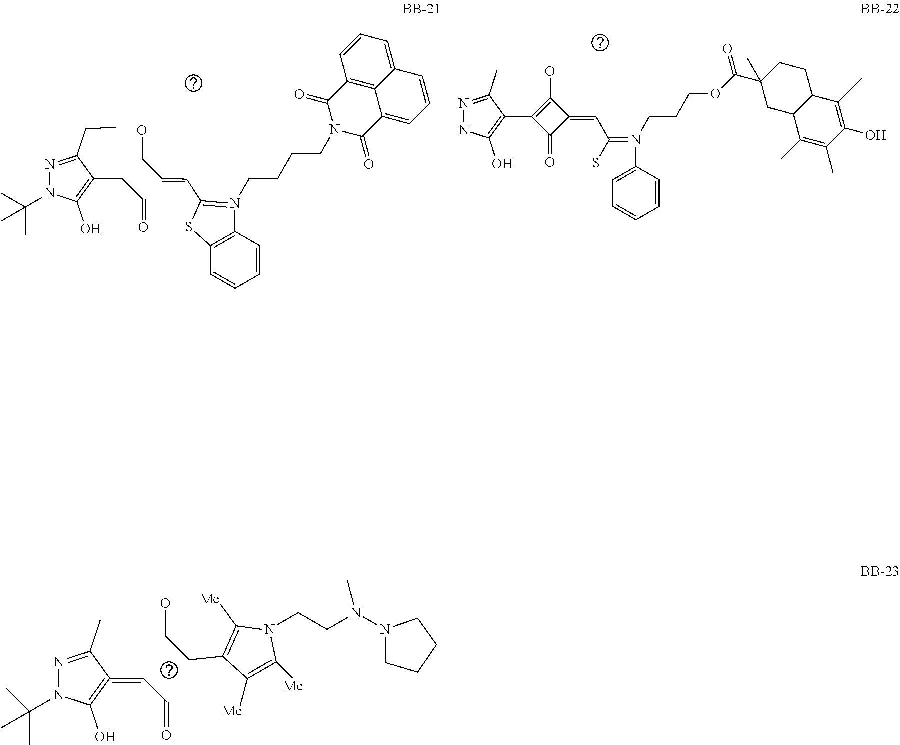

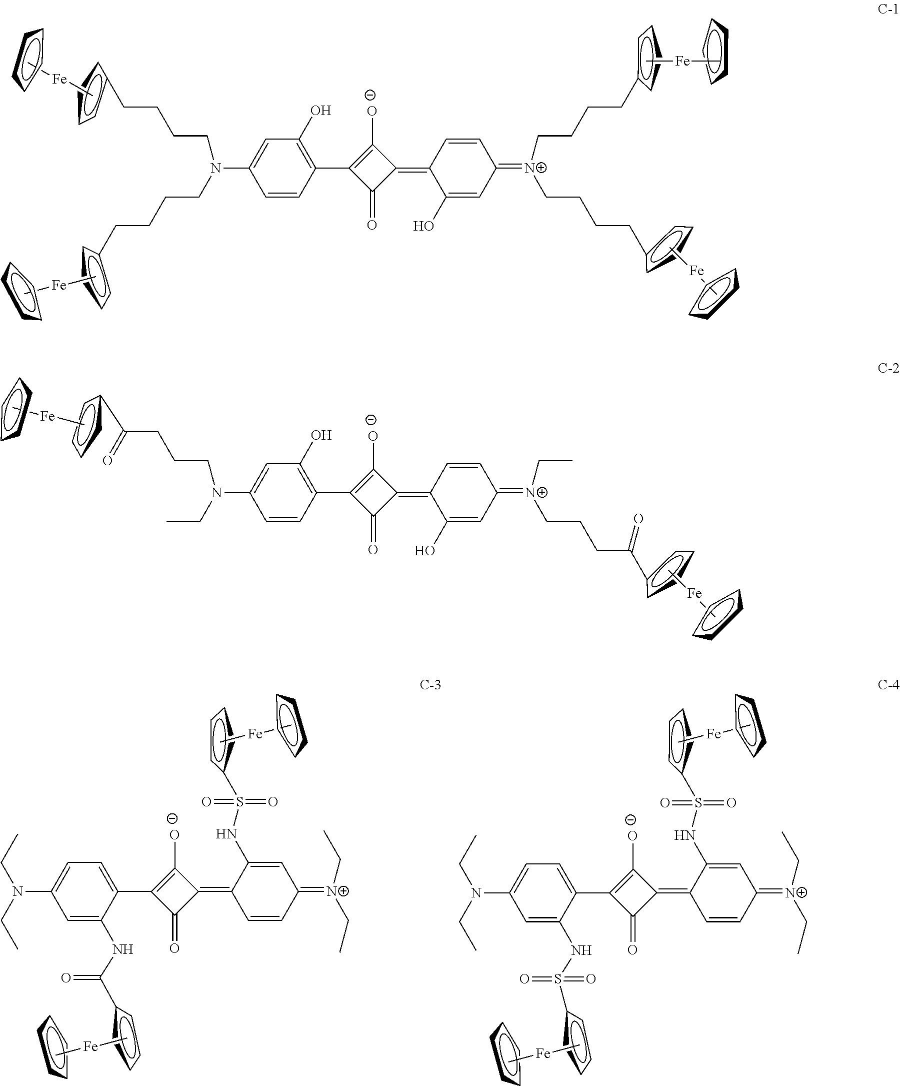

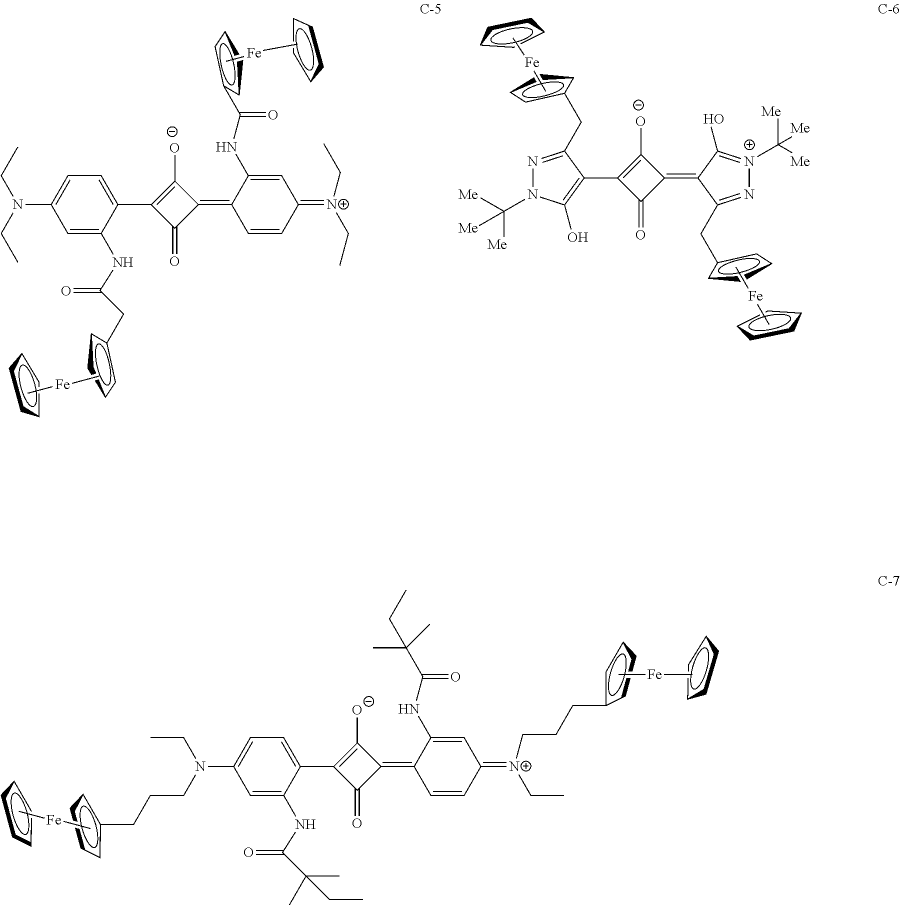

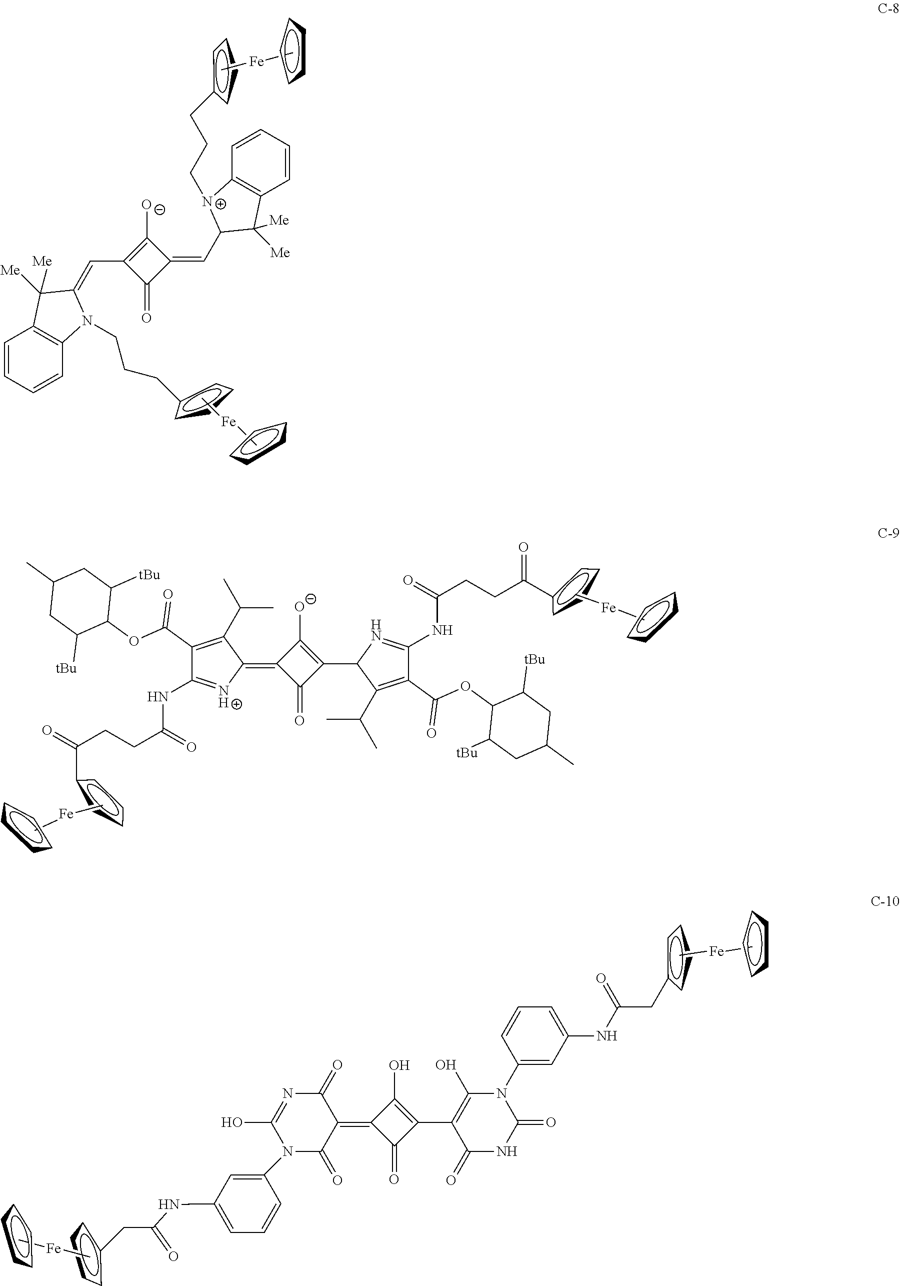

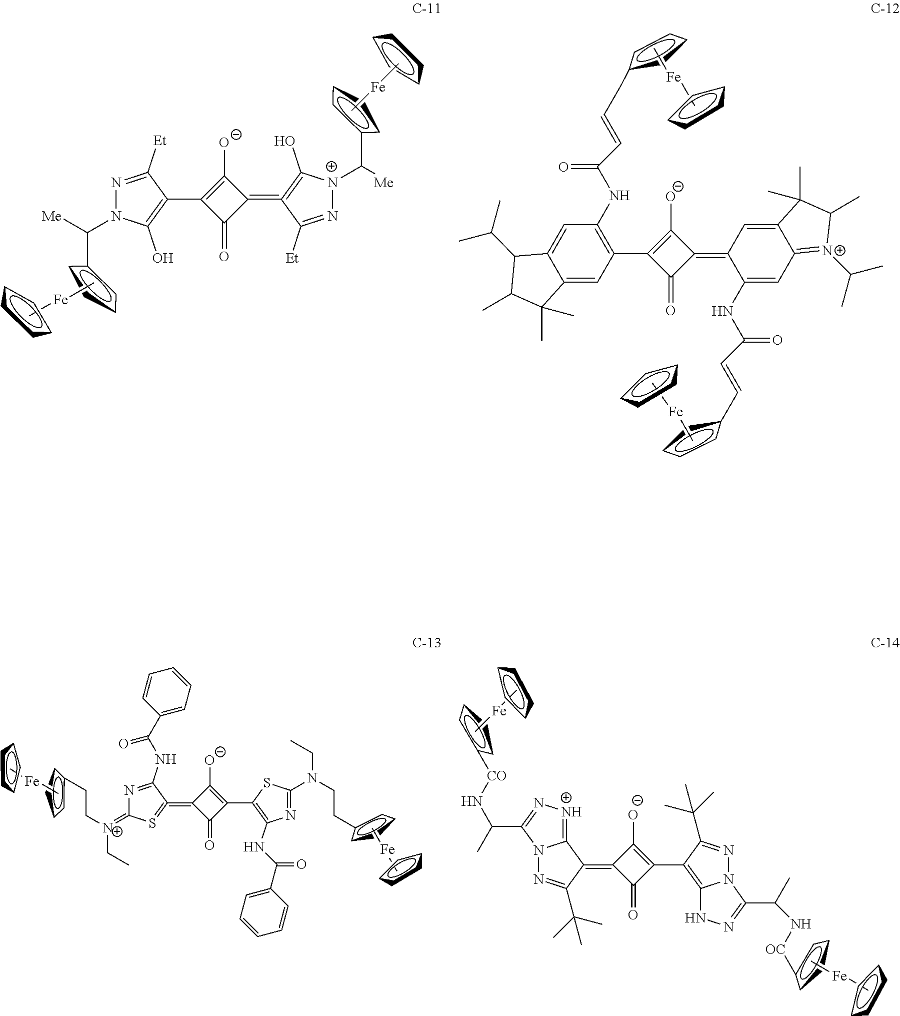

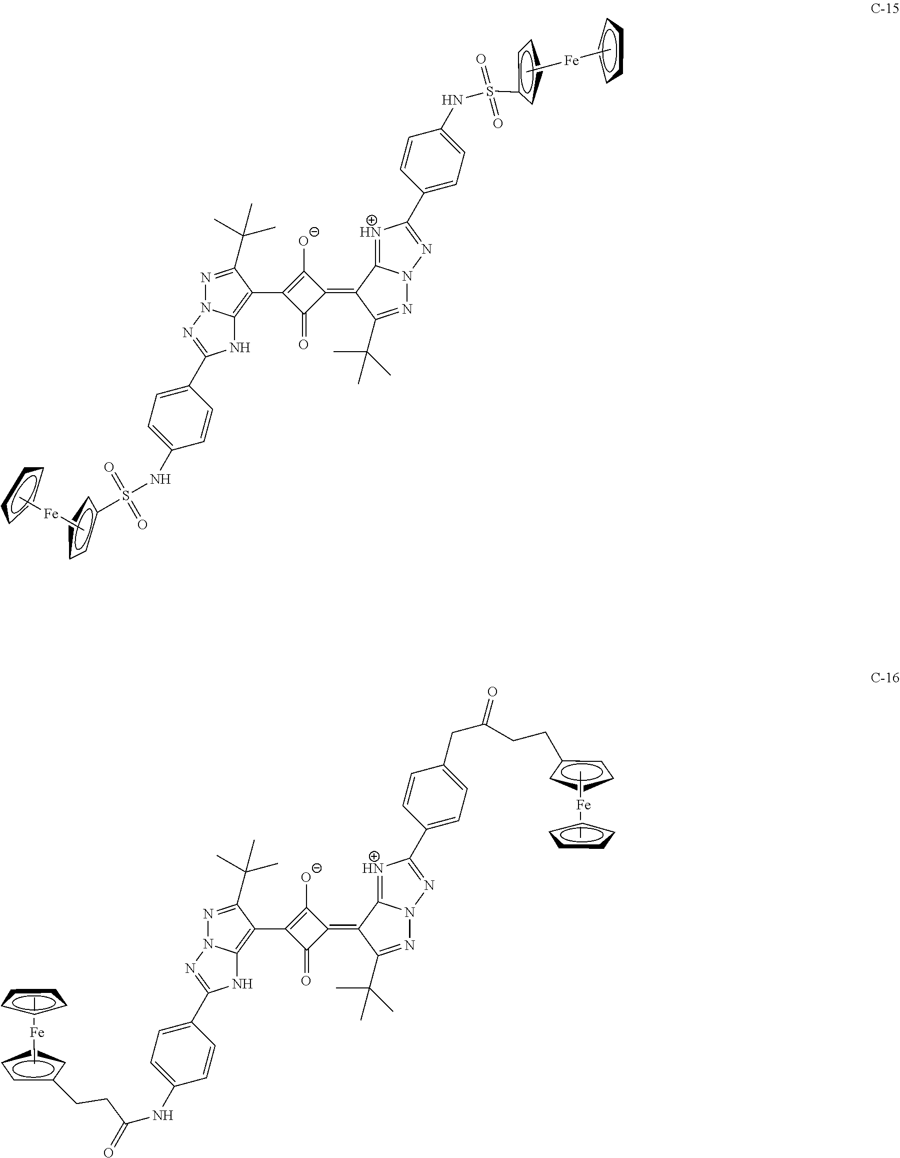

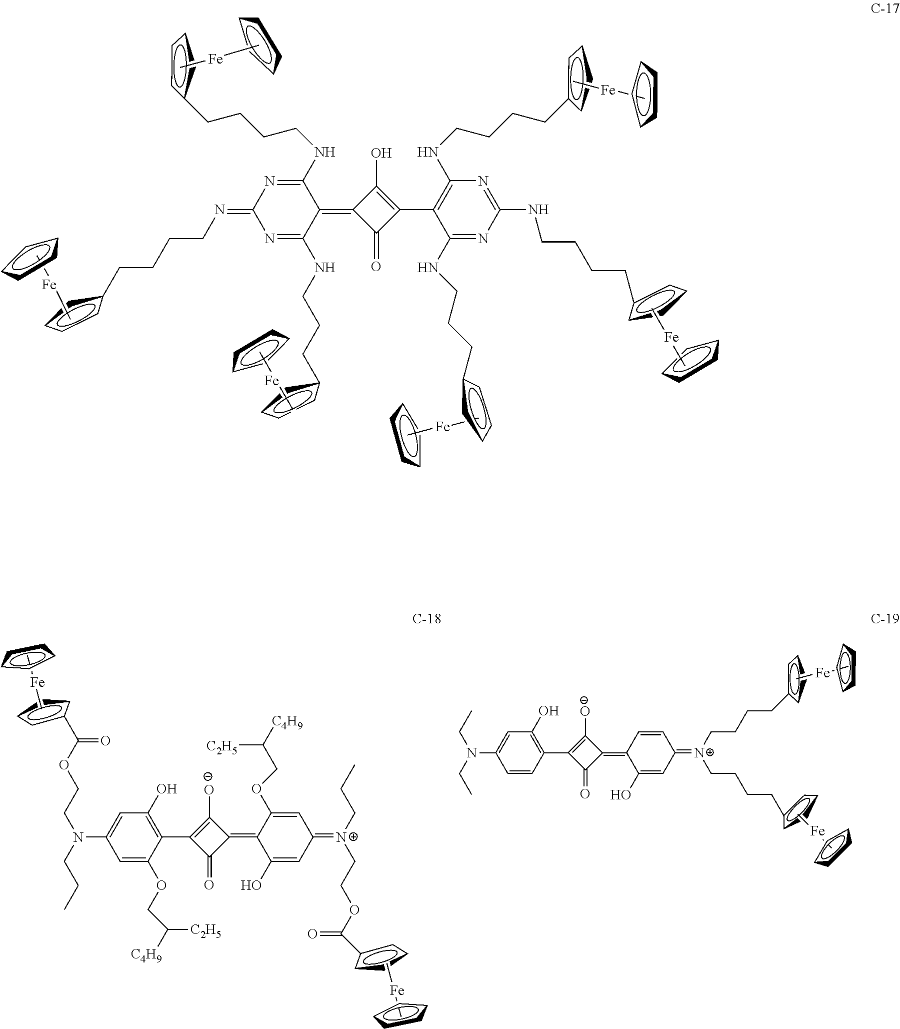

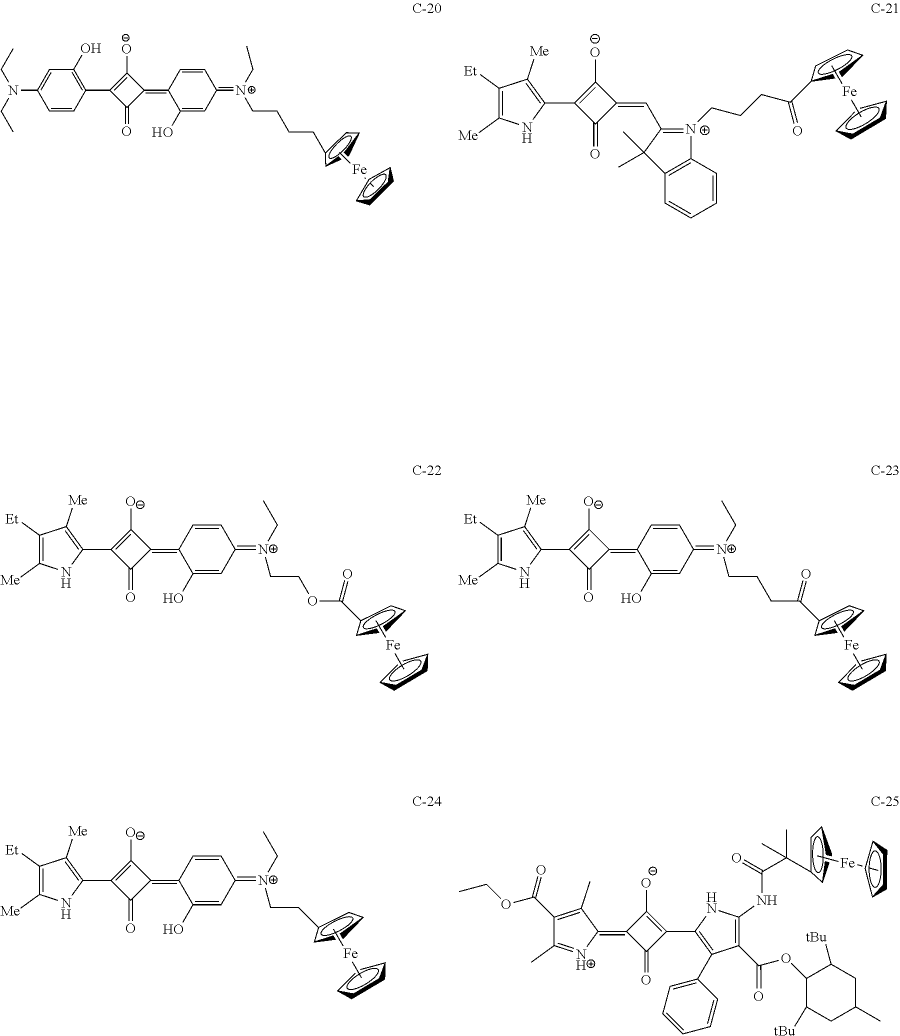

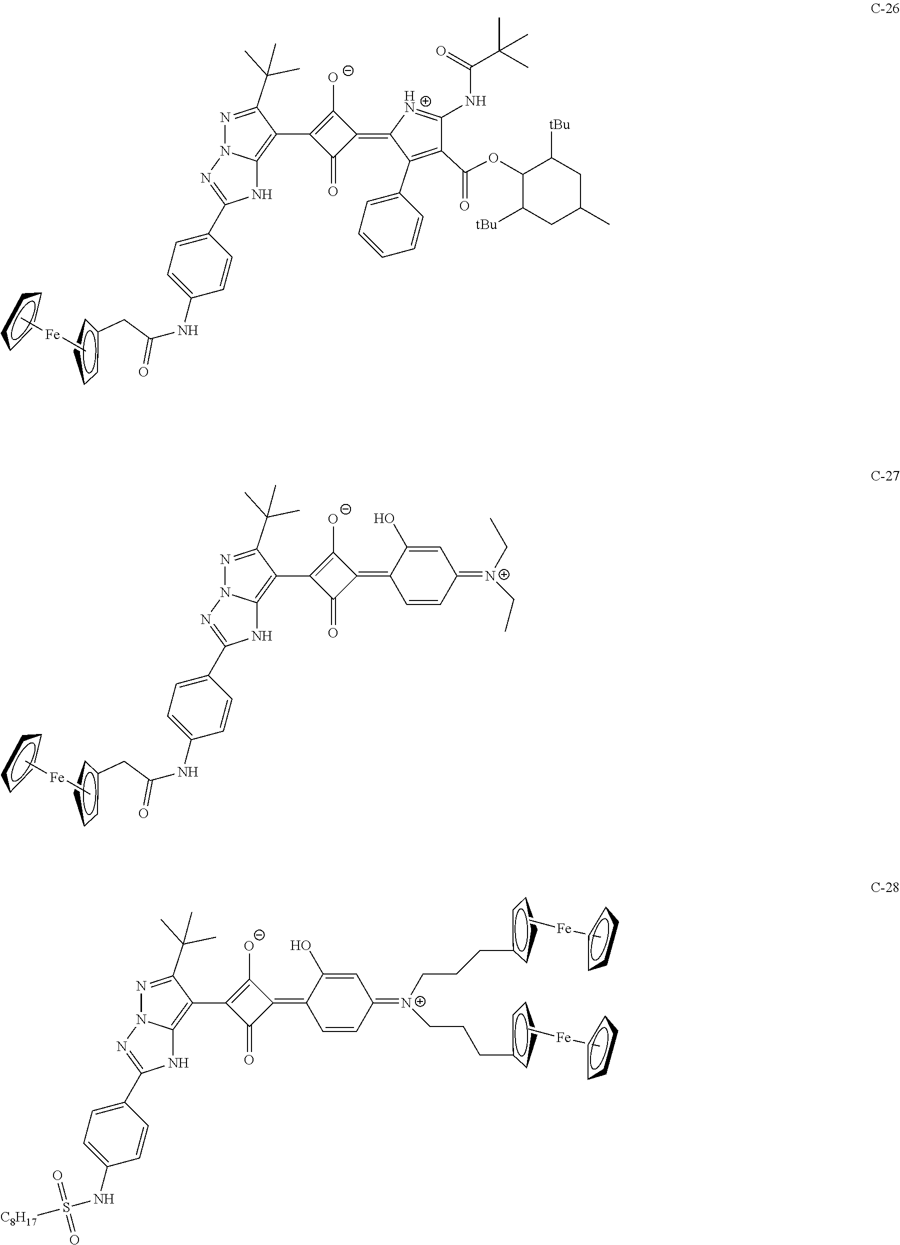

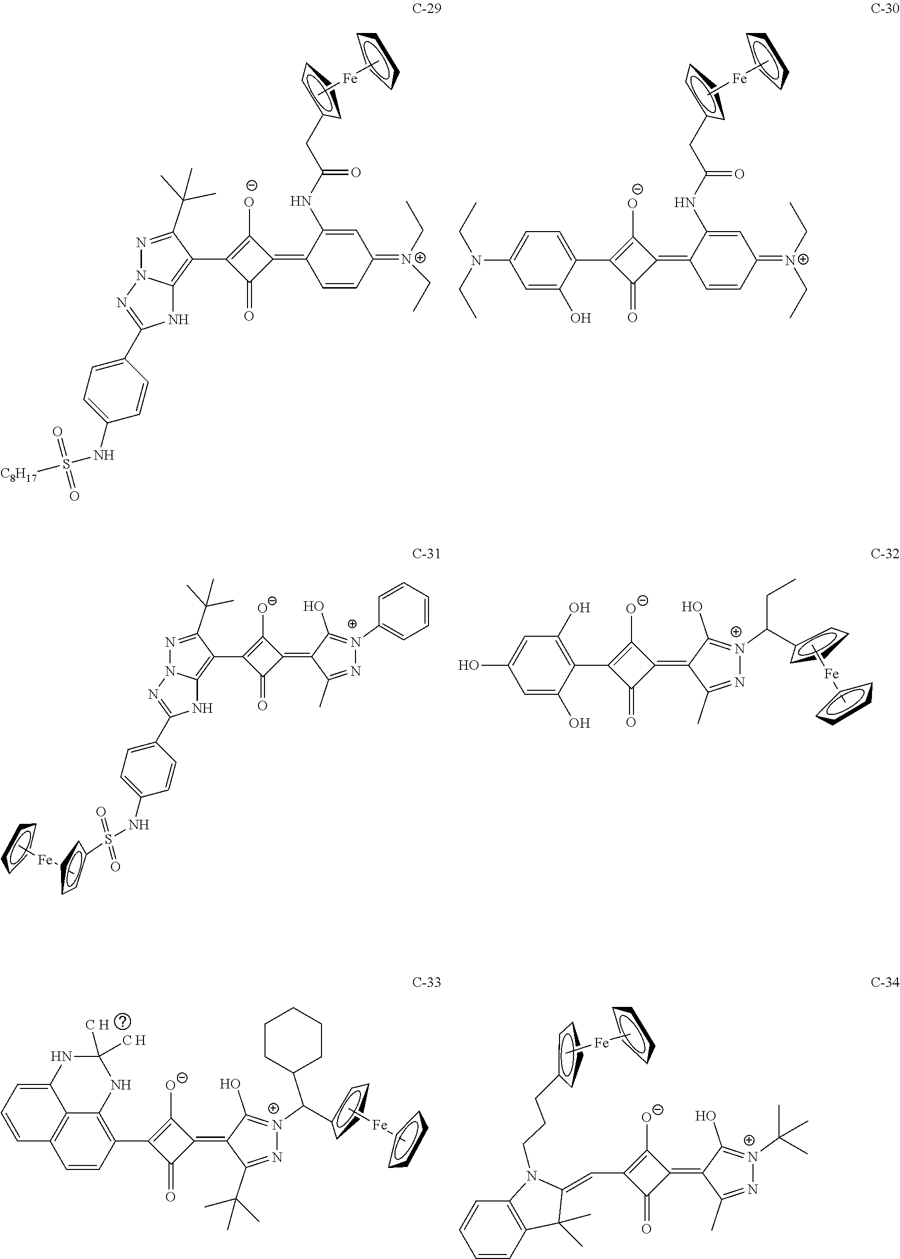

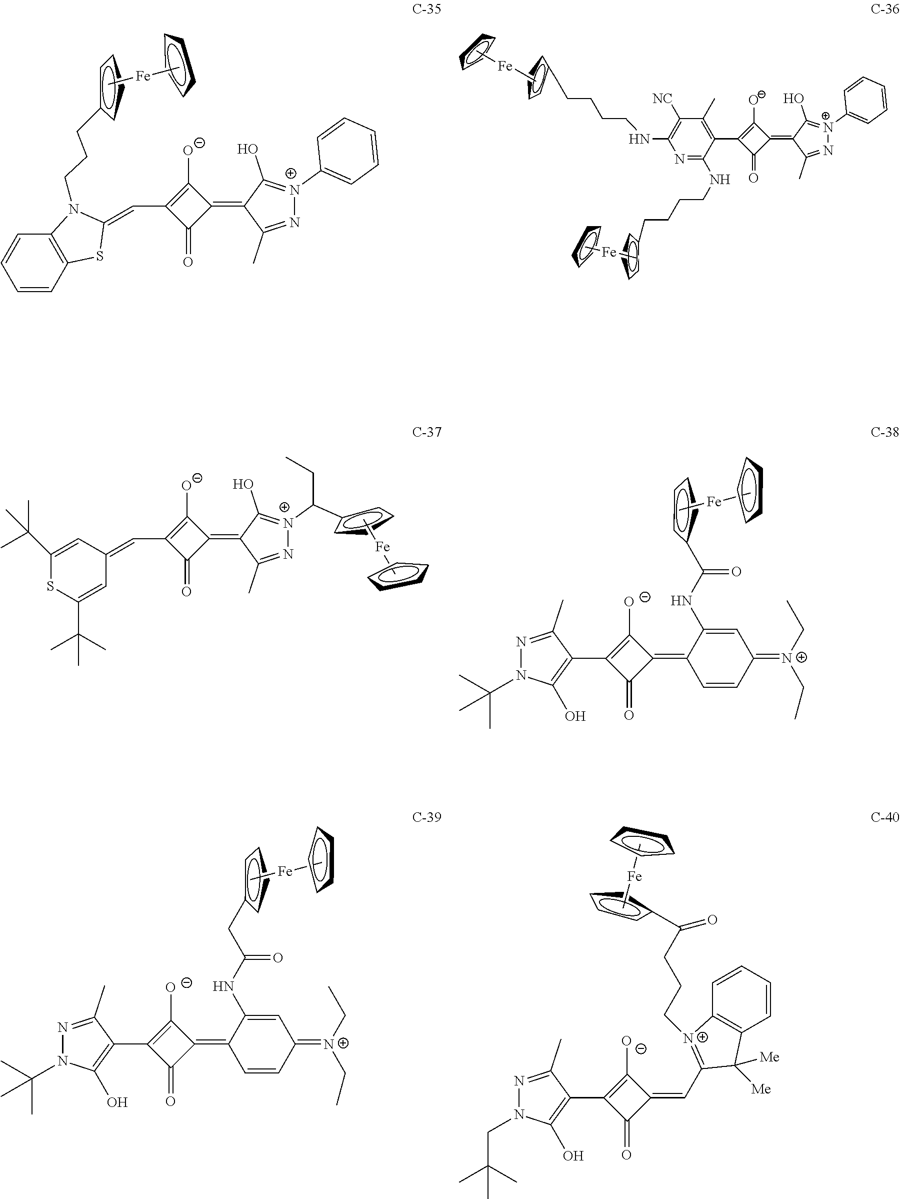

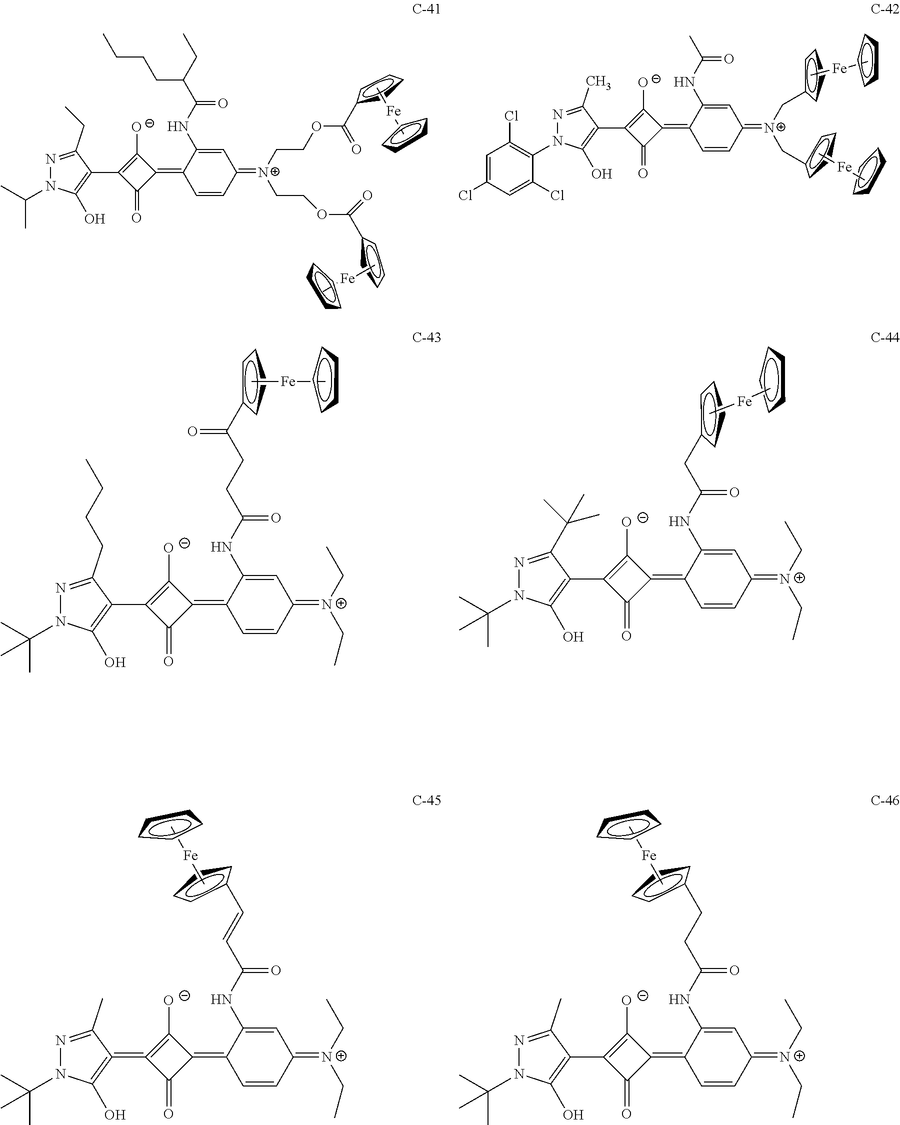

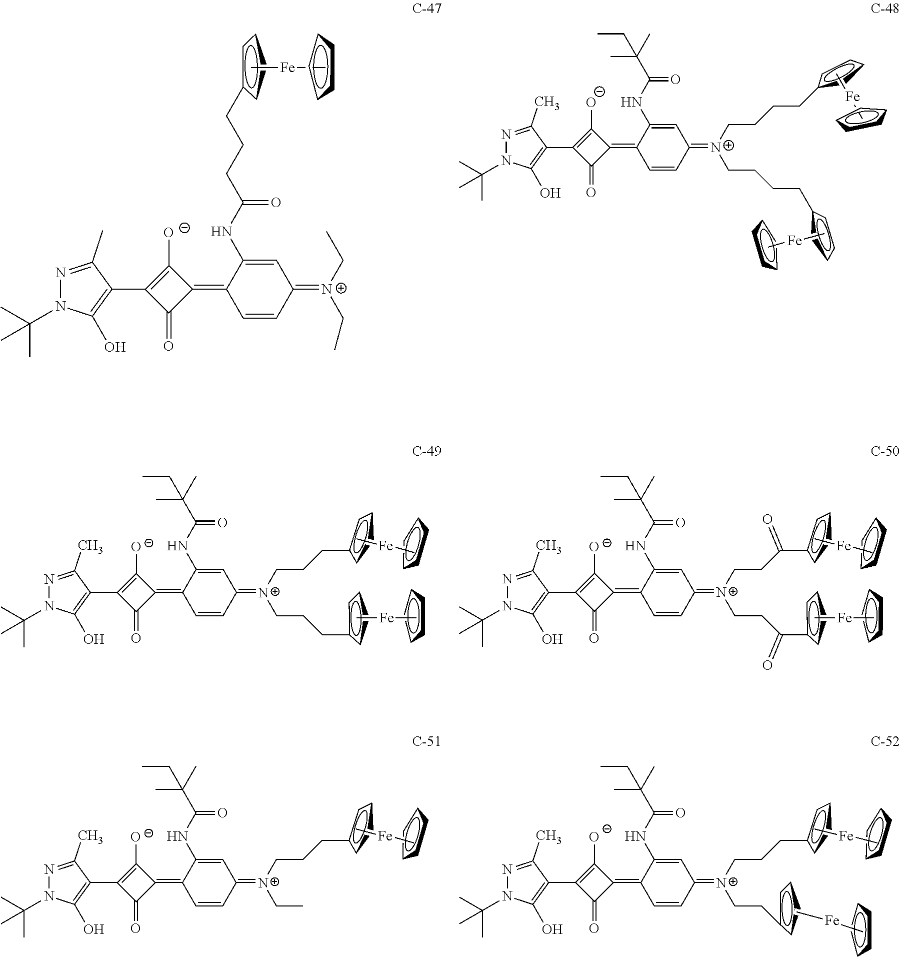

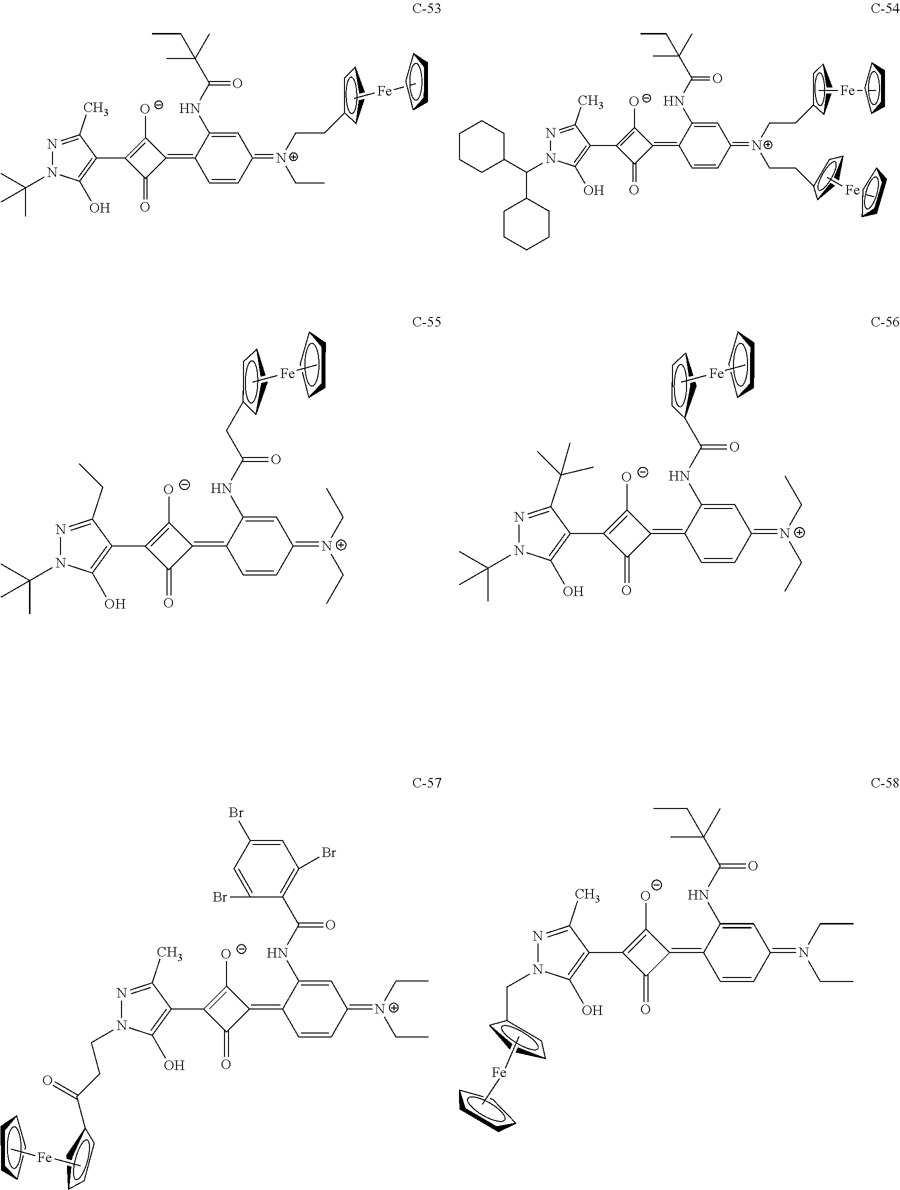

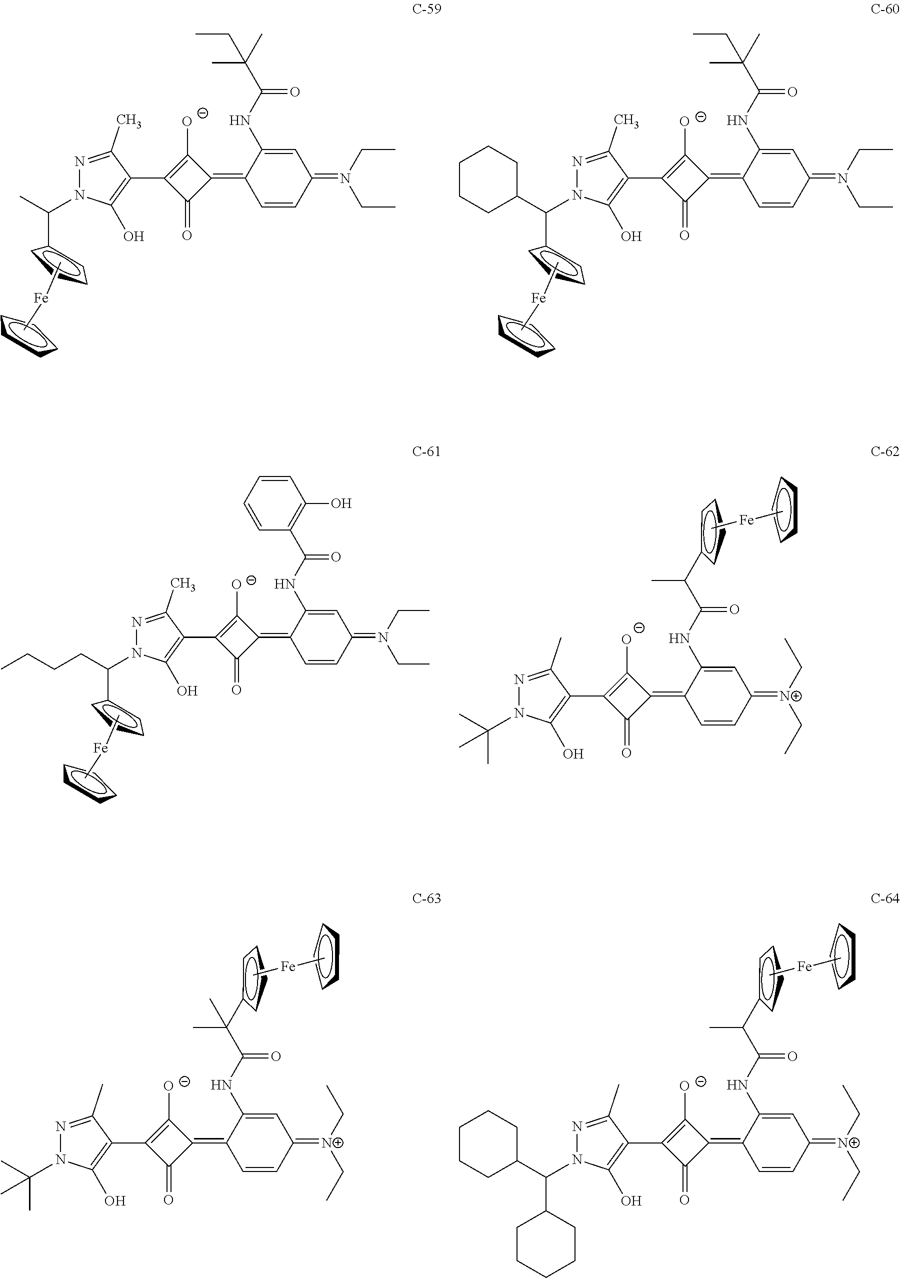

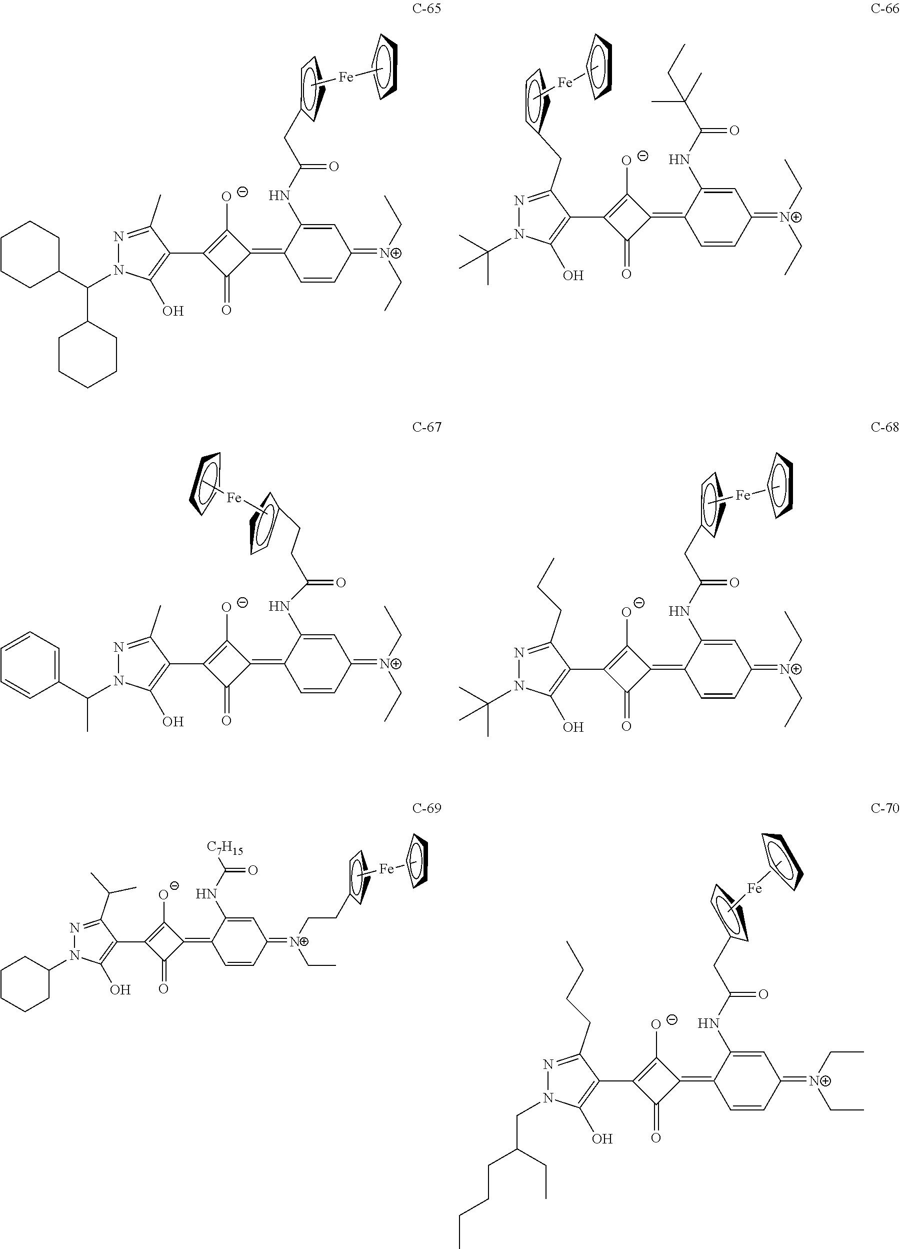

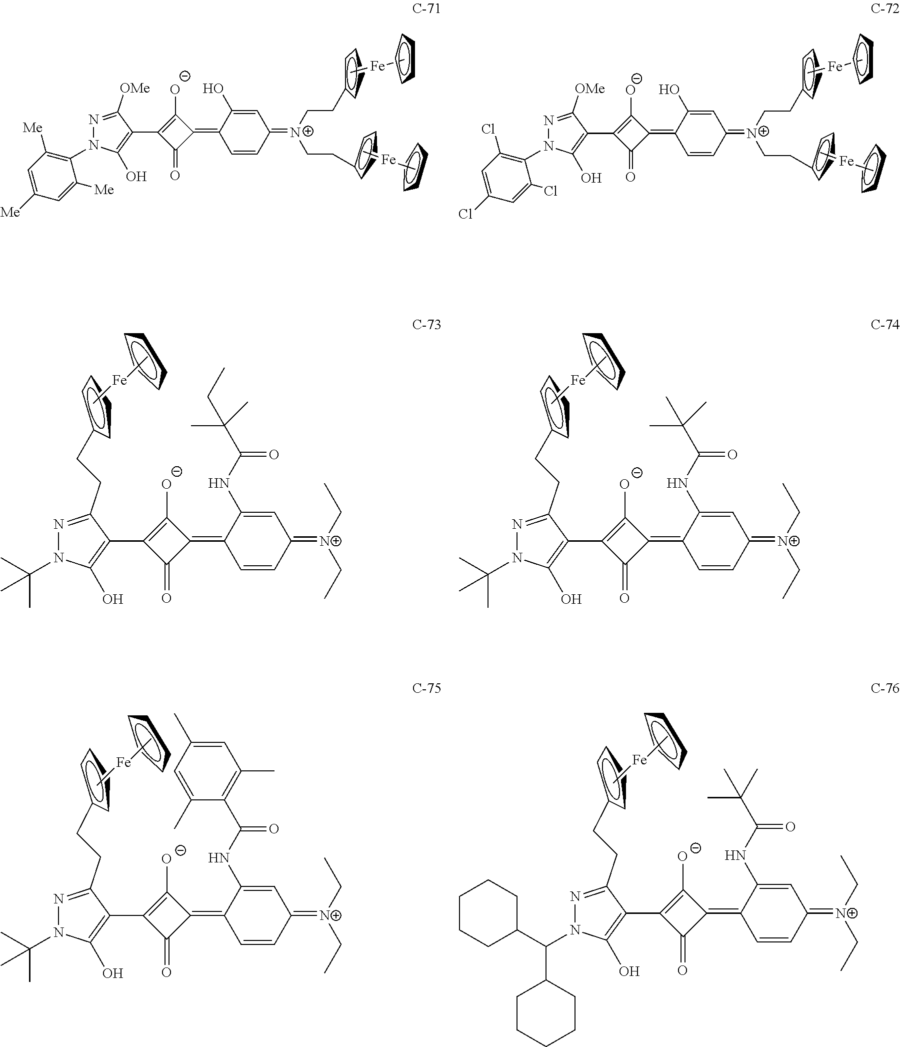

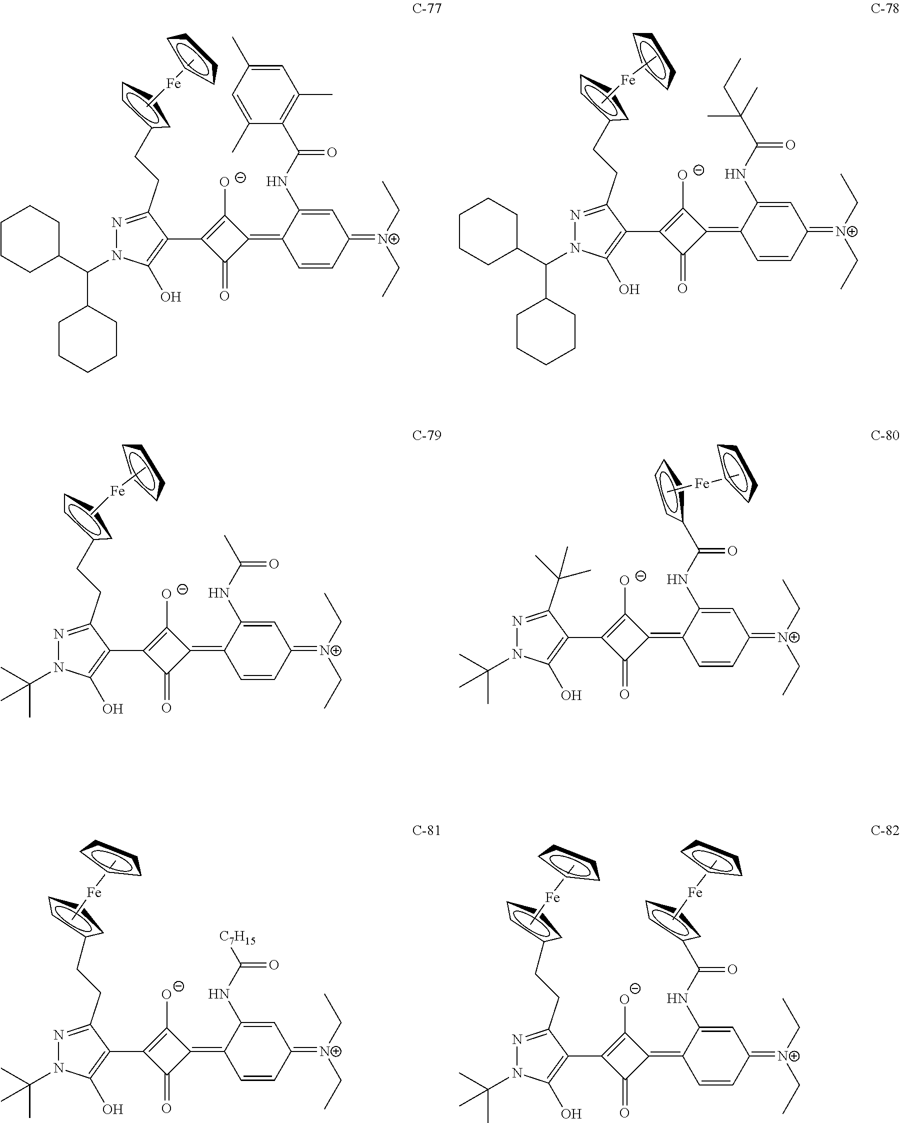

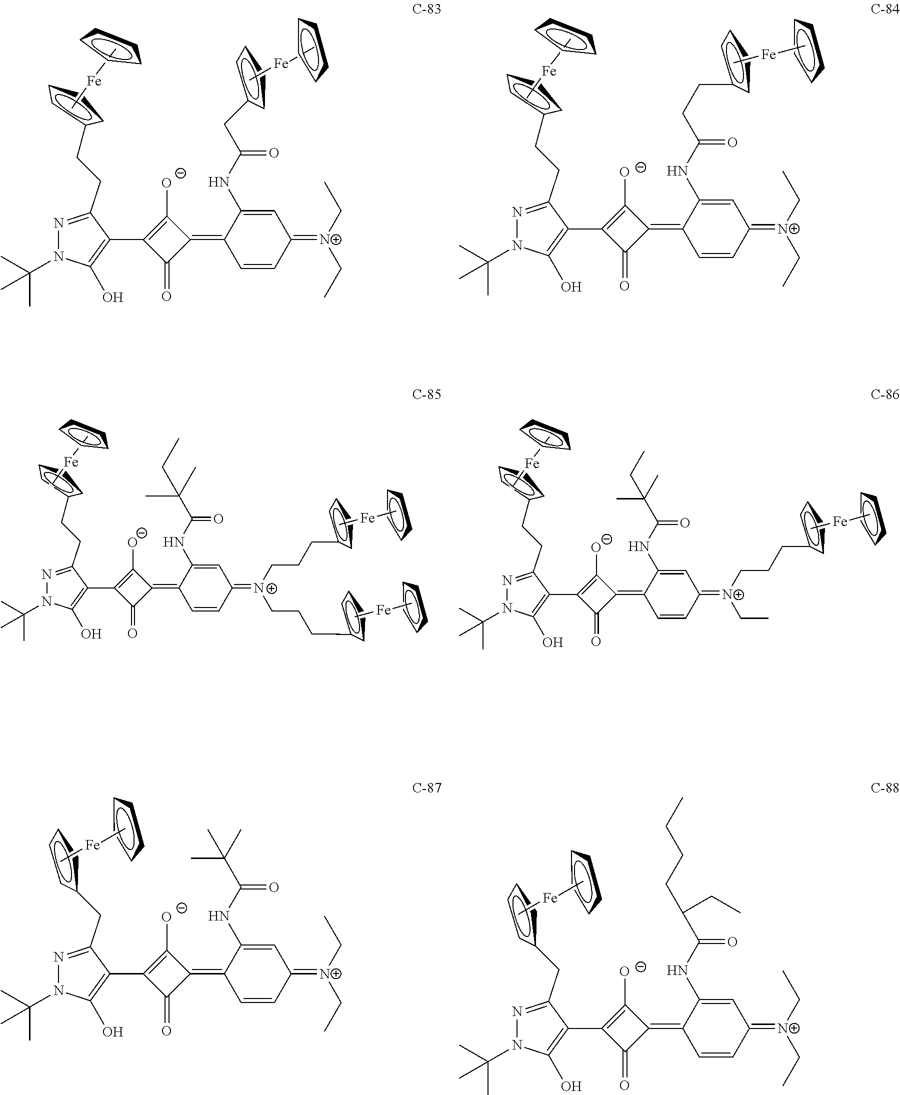

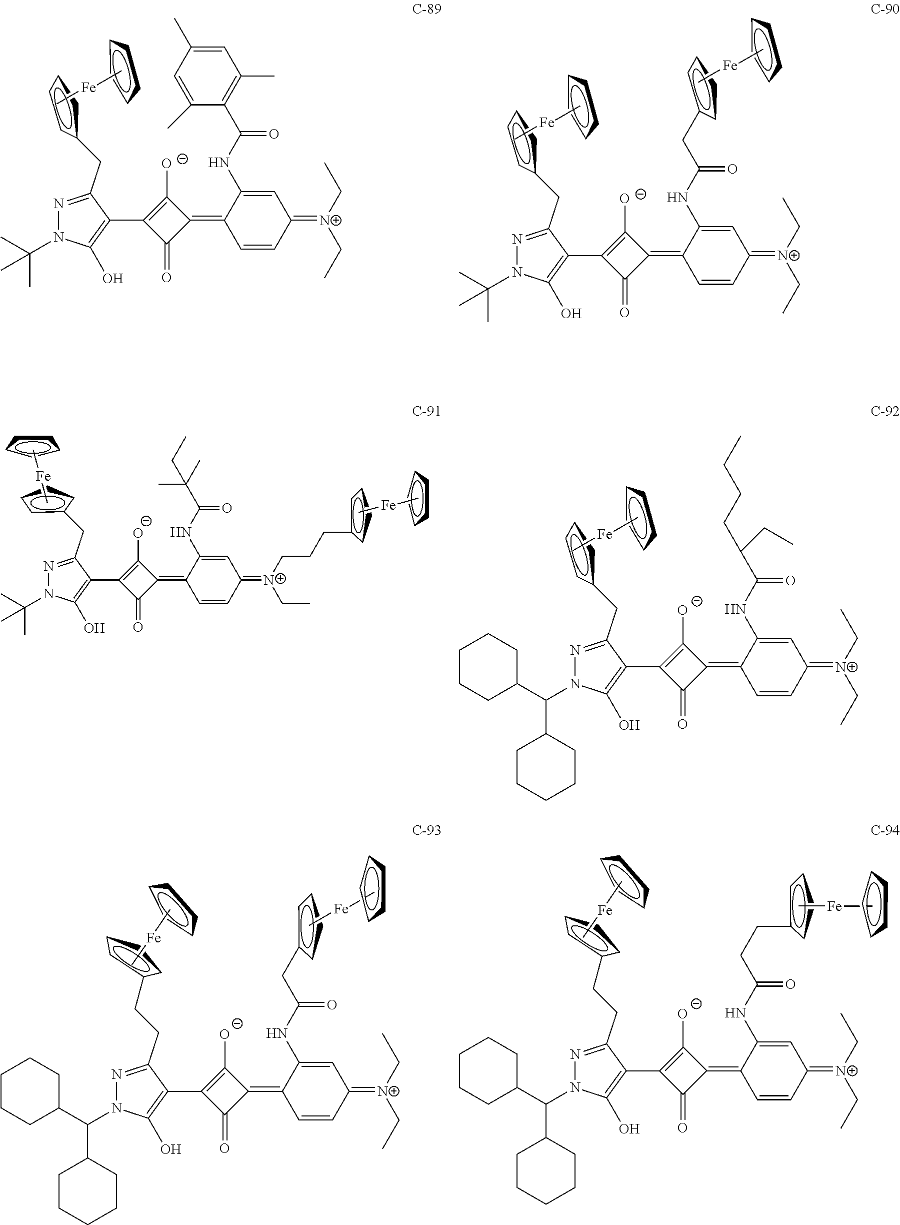

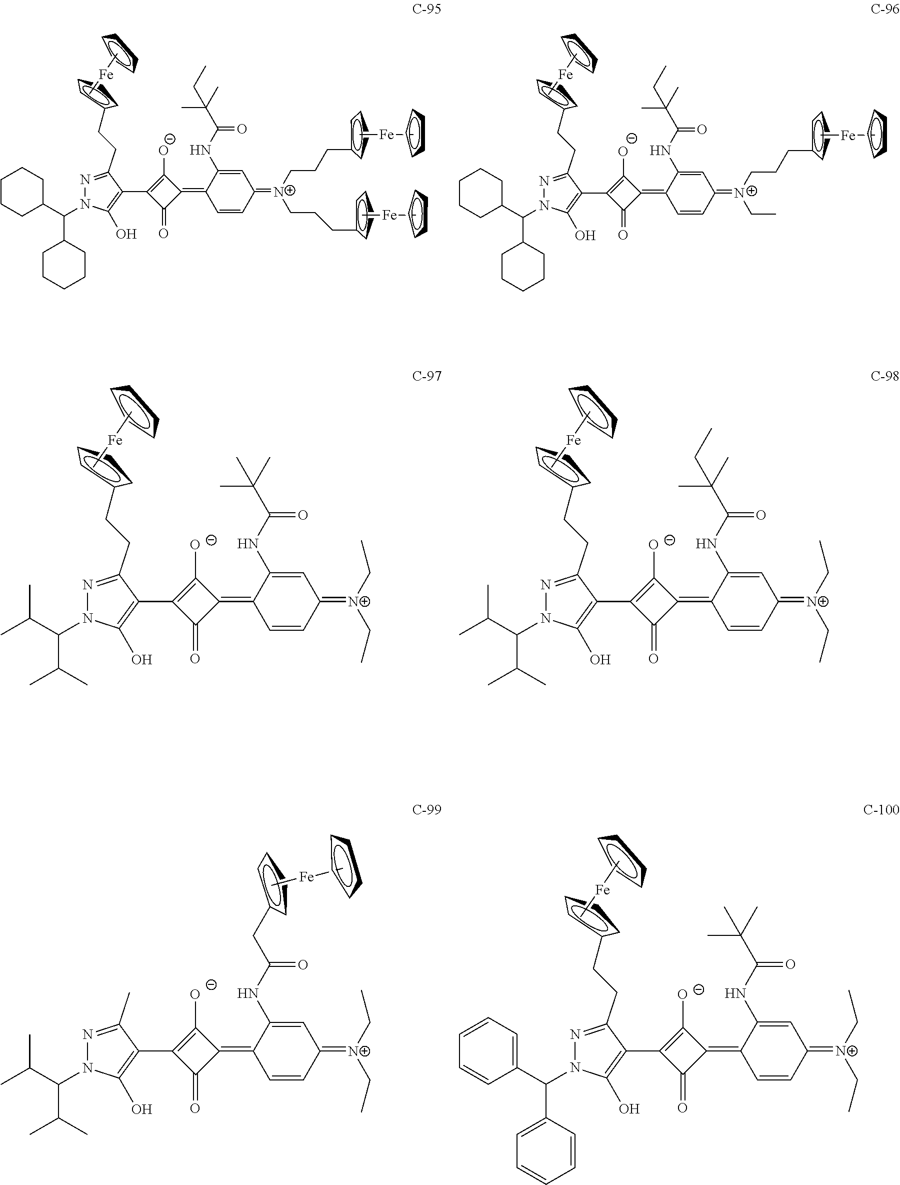

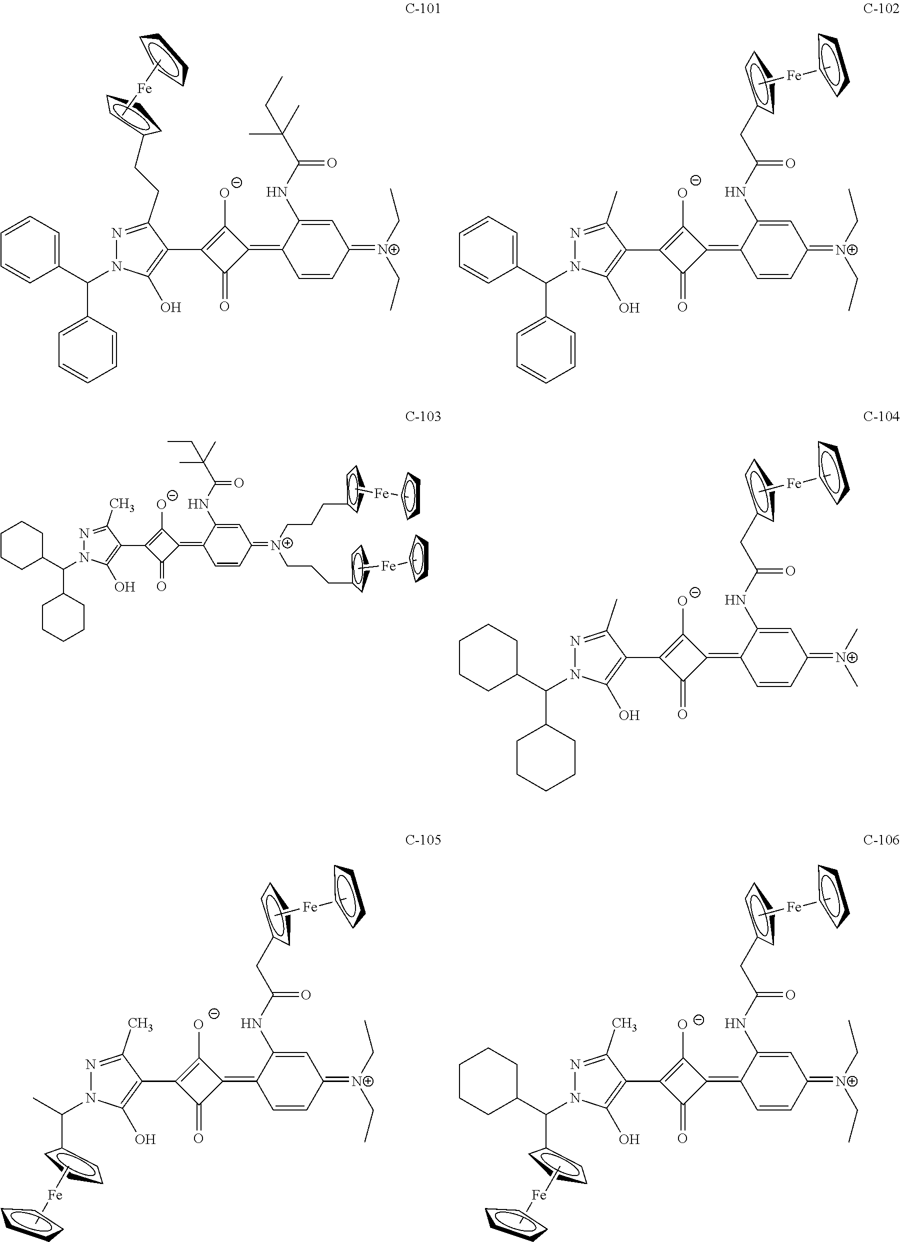

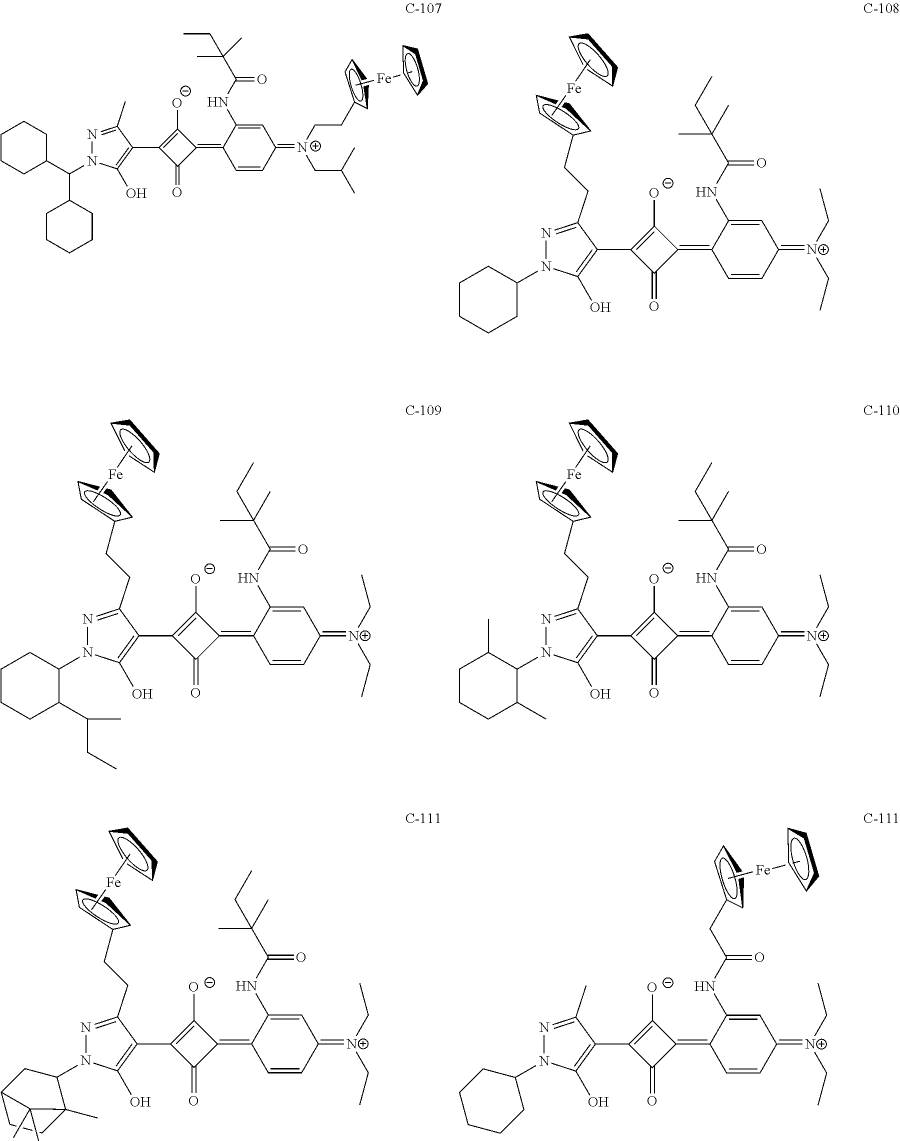

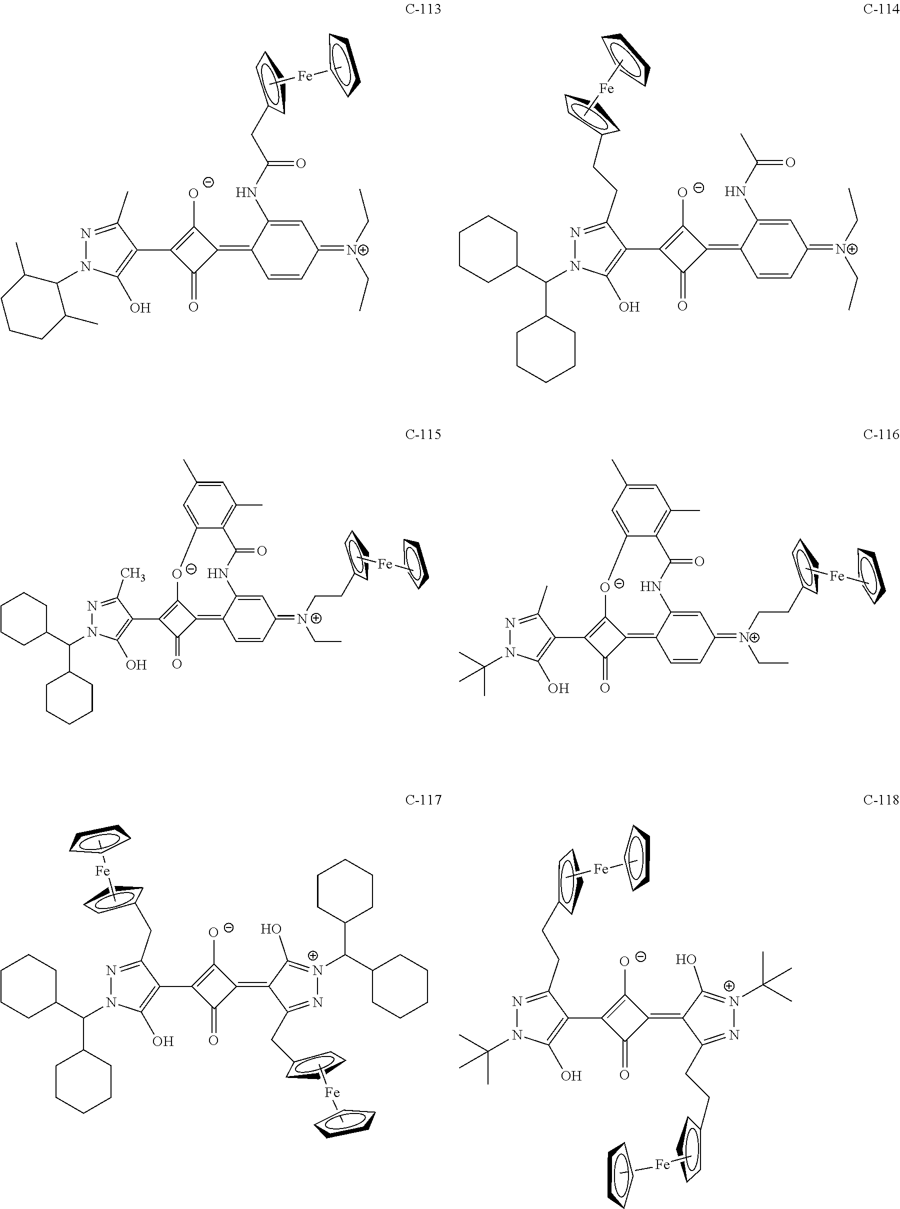

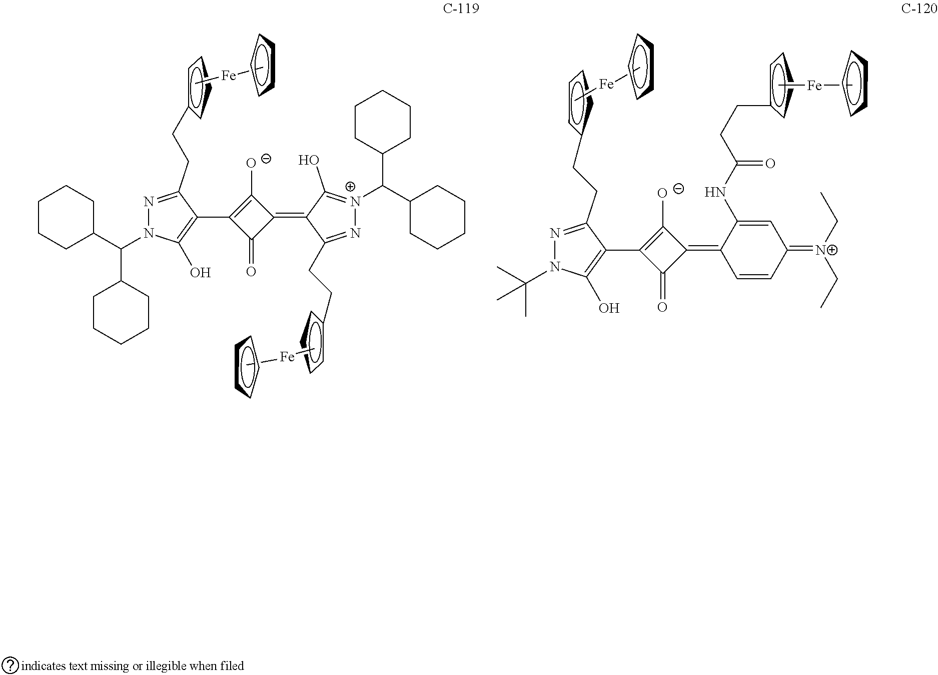

(Dye D)

The dye D is not particularly limited as long as it exhibits the absorption waveform D in the light absorbing part, and various dyes can be used.

Specific examples of the dye D include individual coloring agents (dyes) which are based on, for example, porphyrin, squaraine, and cyanine (CY).

The dye D is preferably at least one of the coloring agent represented by General Formula (D1) or the coloring agent represented by General Formula (1) described later from the viewpoint that a suitable range of the absorption waveform D can be easily satisfied, and a display device having an organic electroluminescent light emitting element or a micro light emitting diode as a light emitting unit, to which the optical member according to the embodiment of the present invention is applied, can display brightness without significantly impairing the brightness.

(Coloring Agent Represented by General Formula (D1))

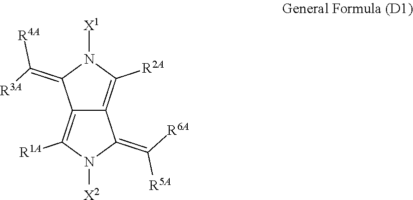

In General Formula (D1), R^{1A} and R^{2A} each independently represent an alkyl group, an aryl group, or a heteroaryl group, R^{4A} and R^{5A} each independently represent a heteroaryl group, and R^{3A} and R^{6A} each independently represent a substituent. X¹ and X² each independently represent —BR^{21a}R^{22a}, where R^{21a} and R^{22a} each independently represent a substituent, and R^{21a} and R^{22a} may be bonded to each other to form a ring.

R^{1A} and R^{2A} each independently represent an alkyl group, an aryl group, or a heteroaryl group.

The number of carbon atoms in the alkyl group is preferably 1 to 40. The lower limit thereof is more preferably 3 or more, still more preferably 5 or more, even still more preferably 8 or more, and particularly preferably 10 or more. The upper limit thereof is more preferably 35 or less and still more preferably 30 or less. The alkyl group may be linear, branched, or cyclic, and it is preferably linear or branched and particularly preferably branched. The number of carbon atoms in the branched alkyl group is preferably 3 to 40. The lower limit thereof is, for example, more preferably 5 or more, still more preferably 8 or more, and even still more preferably 10 or more. The upper limit thereof is more preferably 35 or less and still more preferably 30 or less. The number of branches in the branched alkyl group is, for example, preferably 2 to 10 and more preferably 2 to 8. In a case where the number of branches is in the above range, the solubility in a solvent is good.

The number of carbon atoms in the aryl group is preferably 6 to 30, more preferably 6 to 20, and still more preferably 6 to 12. Among the above, a phenyl group is preferable.

The heteroaryl group is preferably a monocyclic ring or a fused ring, preferably a monocyclic ring or a fused ring having the number of fusions of 2 to 8, and more preferably a monocyclic ring or a fused ring having the number of fusions of 2 to 4. The number of heteroatoms constituting the heteroaryl group is preferably 1 to 3. The heteroatom constituting the heteroaryl group is preferably a nitrogen atom, an oxygen atom, or a sulfur atom. The number of carbon atoms in the heteroaryl group is preferably 3 to 30, more preferably 3 to 18, more preferably 3 to 12, and particularly preferably 3 to 5. The heteroaryl group is preferably a 5-membered ring or a 6-membered ring. Specific examples of the heteroaryl group include an imidazolyl group, a pyridyl group, a pyrazyl group, a pyrimidyl group, a pyridazyl group, a triazyl group, a quinolyl group, a quinoxalyl group, an isoquinolyl group, an indolenyl group, a furyl group, a thienyl group, a benzoxazolyl group, a benzimidazolyl group, a benzothiazolyl group, a naphthiazolyl group, a m-carbazolyl group, and an azepinyl group.

The alkyl group, the aryl group, and the heteroaryl group as R^{1A} and R^{2A} may have a substituent or may be unsubstituted. Examples of the substituents that may be provided a hydrocarbon group which may have an oxygen atom, a heteroaryl group, an amino group, an acylamino group, an alkoxycarbonylamino group, an aryloxycarbonylamino group, a sulfonylamino group, a sulfamoyl group, a carbamoyl group, an alkylthio group, an arylthio group, a heteroarylthio group, an alkylsulfonyl group, an arylsulfonyl group, a sulfinyl group, a ureide group, a phosphate amide group, a mercapto group, a sulfo group, a carboxyl group, a nitro group, a hydroxamic acid group, a sulfino group, a hydrazino group, an imino group, a silyl group, a hydroxy group, a halogen atom, and a cyano group.

As the heteroaryl group, the description for the heteroaryl group as R^{1A} and R^{2A} can be preferably applied.

Examples of the halogen atom include a fluorine atom, a chlorine atom, a bromine atom, and an iodine atom.

Examples of the hydrocarbon group include an alkyl group, an alkenyl group, and an aryl group.

As the alkyl group, the description for the alkyl group as R^{1A} and R^{2A} can be preferably applied.

The number of carbon atoms in the alkenyl group is preferably 2 to 40. The lower limit thereof is, for example, more preferably 3 or more, still more preferably 5 or more, even still more preferably 8 or more, and particularly preferably 10 or more. The upper limit thereof is more preferably 35 or less and still more preferably 30 or less. The alkenyl group may be linear, branched, or cyclic, and it is preferably linear or branched, and particularly preferably branched. The number of carbon atoms in the branched alkenyl group is preferably 3 to 40. The lower limit thereof is, for example, more preferably 5 or more, still more preferably 8 or more, and even still more preferably 10 or more. The upper limit thereof is more preferably 35 or less and still more preferably 30 or less. The number of branches in the branched alkenyl group is preferably 2 to 10 and more preferably 2 to 8. In a case where the number of branches is in the above range, the solubility in a solvent is good.

The number of carbon atoms in the aryl group is preferably 6 to 30, more preferably 6 to 20, and still more preferably 6 to 12.

Examples of the hydrocarbon group containing an oxygen atom include a group represented by -L-R^{x1}.

L represents —O—, —CO—, —COO—, —OCO—, —(OR^{x2})ₘ— or —(R^{x2}O)ₘ—. R^{x1} represents an alkyl group, an alkenyl group, or an aryl group. R^{x2} represents an alkylene group or an arylene group. m represents an integer of 2 or more, and m R^{x2} may be the same or different from each other.

L is preferably —O—, —COO—, or —OCO—, and more preferably —O—.

The alkyl group, the alkenyl group, and the aryl group, which are represented by R^{x1}, have the same meanings as those described above, and the same applies to the preferred ranges thereof. R^{x1} is preferably an alkyl group or an alkenyl group, and more preferably an alkyl group. The number of carbon atoms in the alkylene group represented by R^{x2} is preferably 1 to 20, more preferably 1 to 10, and still more preferably 1 to 5. The alkylene group may be linear, branched, or cyclic, and it is preferably linear or branched.

The number of carbon atoms in the arylene group represented by R^{x2} is preferably 6 to 20, and more preferably 6 to 12.

m represents an integer of 2 or more, preferably 2 to 20, and more preferably 2 to 10.

The substituent which may be contained in the alkyl group, the aryl group, and the heteroaryl group as R^{1A} and R^{2A} is preferably a hydrocarbon group which may contain an oxygen atom, and more preferably a hydrocarbon group containing an oxygen atom.

The hydrocarbon group containing an oxygen atom is preferably a group represented by —O—R^{x1}. R^{x1} is preferably an alkyl group or an alkenyl group, more preferably an alkyl group, and particularly preferably a branched alkyl group. That is, the substituents represented by R^{1A} and R^{2A} each are preferably an alkoxy group. In a case where R^{1A} and R^{2A} are an alkoxy group, a dye can be suitably used as the dye D according to the embodiment of the present invention, as a near-infrared absorbing substance excellent in solubility in a solvent, light resistance, and visible transmittance.

The number of carbon atoms in the alkoxy group is preferably 1 to 40. The lower limit thereof is, for example, more preferably 3 or more, still more preferably 5 or more, even still more preferably 8 or more, and particularly preferably 10 or more. The upper limit thereof is more preferably 35 or less and still more preferably 30 or less. The alkoxy group may be linear, branched, or cyclic, and it is preferably linear or branched, and particularly preferably branched. The number of carbon atoms in the branched alkoxy group is preferably 3 to 40. The lower limit thereof is, for example, more preferably 5 or more, still more preferably 8 or more, and even still more preferably 10 or more. The upper limit thereof is more preferably 35 or less and still more preferably 30 or less. The number of branches in the branched alkoxy group is preferably 2 to 10 and more preferably 2 to 8.

R^{1A} and R^{2A} is preferably a heteroaryl group or an aryl group, more preferably an aryl group, and still more preferably a phenyl group having a substituent at the 3-position.

R^{3A} and R^{6A} each independently represent a substituent.

Examples of the substituent include an alkyl group, an alkenyl group, an alkynyl group, an aryl group, a heteroaryl group, an amino group (including an alkylamino group, an arylamino group, and a heterocyclic amino group), an alkoxy group, an aryloxy group, a heteroaryloxy group, an acyl group, an alkylcarbonyl group, an arylcarbonyl group, an alkoxycarbonyl group, an aryloxycarbonyl group, an acyloxy group, an acylamino group, an alkoxycarbonylamino group, an aryloxycarbonylamino group, a sulfonylamino group, a sulfamoyl group, a carbamoyl group, an alkylthio group, an arylthio group, a heteroarylthio group, an alkylsulfonyl group, an arylsulfonyl group, a sulfinyl group, a ureide group, a phosphate amide group, a hydroxy group, a mercapto group, a halogen atom, a cyano group, a sulfo group, a carboxyl group, a nitro group, a hydroxamic acid group, a sulfino group, a hydrazino group, an imino group, and a silyl group.

R^{3A} and R^{6A} are preferably an electron-withdrawing group.

A substituent having a positive value of the Hammett σp value (the sigma para value) acts as an electron-withdrawing group.

In the present invention, a substituent having a Hammett σp value of 0.2 or more can be exemplified as an electron-withdrawing group. The σp value is preferably 0.25 or more, more preferably 0.3 or more, and particularly preferably 0.35 or more. The upper limit thereof is not particularly limited, and it is preferably 0.80.

Specific examples of the electron-withdrawing group include a cyano group (0.66), a carboxyl group (—COOH: 0.45), an alkoxycarbonyl group (—COOMe: 0.45), an aryloxycarbonyl group (—COOPh: 0.44), a carbamoyl group (—CONH₂: 0.36), an alkylcarbonyl group (—COMe: 0.50), an arylcarbonyl group (—COPh: 0.43), an alkylsulfonyl group (—SO₂Me: 0.72), and an arylsulfonyl group (—SO₂Ph: 0.68). The cyano group is particularly preferable. Here, Me represents a methyl group, and Ph represents a phenyl group.

For the Hammett σp value, for example, paragraphs [0024] and [0025] of JP2009-263614A can be referred to, and the contents thereof are incorporated in the present specification.

R^{4A} and R^{5A} each independently represent a heteroaryl group.

The heteroaryl group is preferably a monocyclic ring or a fused ring, preferably a monocyclic ring or a fused ring having the number of fusions of 2 to 8, and more preferably a monocyclic ring or a fused ring having the number of fusions of 2 to 4. The number of heteroatoms constituting the heteroaryl group is preferably 1 to 3. The heteroatom constituting the heteroaryl group is preferably a nitrogen atom, an oxygen atom, or a sulfur atom. The number of carbon atoms in the heteroaryl group is preferably 3 to 30, more preferably 3 to 18, still more preferably 3 to 12, and particularly preferably 3 to 5. The heteroaryl group is preferably a 5-membered ring or a 6-membered ring. Specific examples of the heteroaryl group include those described in R^{1A} and R^{2A}, where a pyridyl group, a pyrimidyl group, a triazyl group, a quinolyl group, a quinoxalyl group, an isoquinolyl group, an indolenyl group, a benzoxazolyl group, or a benzothiazolyl group is preferable.

The heteroaryl group may have a substituent or may be unsubstituted. Examples of the substituent include an alkyl group, an alkenyl group, an alkynyl group, an aryl group, an amino group (including an alkylamino group, an arylamino group, and a heterocyclic amino group), an alkoxy group, an aryloxy group, an acyl group, an alkylcarbonyl group, an arylcarbonyl group, an alkoxycarbonyl group, an aryloxycarbonyl group, an acyloxy group, an acylamino group, an alkoxycarbonylamino group, an aryloxycarbonylamino group, a sulfonylamino group, a sulfamoyl group, a carbamoyl group, an alkylthio group, an arylthio group, a heteroarylthio group, a sulfonyl group, an alkylsulfonyl group, an arylsulfonyl group, a sulfinyl group, a ureide group, a phosphate amide group, a hydroxy group, a mercapto group, a halogen atom, a cyano group, a sulfo group, a carboxyl group, a nitro group, a hydroxamic acid group, a sulfino group, a hydrazino group, and an imino group, a silyl group. A halogen atom, an alkyl group, or an alkoxy group is preferable.

The halogen atom is preferably a fluorine atom, a chlorine atom, a bromine atom, or an iodine atom, and particularly preferably a chlorine atom.

The number of carbon atoms in the alkyl group is preferably 1 to 40, more preferably 1 to 30, and particularly preferably 1 to 25. The alkyl group may be linear, branched, or cyclic, and it is preferably linear or branched, and particularly preferably linear.

The number of carbon atoms in the alkoxy group is preferably 1 to 40, more preferably 1 to 30, and particularly preferably 1 to 25. The alkoxy group may be linear, branched, or cyclic, and it is preferably linear or branched, and particularly preferably linear.

R^{3A} and R^{4A} may be bonded to each other to form a ring, and R^{5A} and R^{6A} may be bonded to each other to form a ring.

In a case where R^{3A} and R^{4A}, and R^{5A} and R^{6A} are bonded to each other to form rings, respectively, they preferably form 5-membered to 7-membered rings (preferably 5-membered or 6-membered rings), respectively. The ring to be formed is preferably a ring that is used as an acidic nucleus in a merocyanine pigment. Specific examples thereof include the following rings.
(a) A 1,3-dicarbonyl ring: for example, 1,3-indandione, 1,3-cyclohexanedione, 5,5-dimethyl-1,3-cyclohexanedione, or 1,3-dioxane-4,6-dione.
(b) A pyrazolinone ring: for example, 1-phenyl-2-pyrazolin-5-one, 3-methyl-1-phenyl-2-pyrazolin-5-one, or 1-(2-benzothiazoyl)-3-methyl-2-pyrazolin-5-one.
(c) An isooxazolinene ring: for example, 3-phenyl-2-isooxazoline-5-one or 3-methyl-2-isooxazoline-5-one.
(d) An oxindole ring: for example, 1-alkyl-2,3-dihydro-2-oxindole.
(e) A 2,4,6-triketohexahydropyrimidine ring: for example, barbituric acid or 2-thiobarbituric acid, or a derivative thereof. Examples of the derivative thereof include a 1-alkyl derivative such as 1-methyl or 1-ethyl, a 1,3-dialkyl derivative such as 1,3-dimethyl, 1,3-diethyl, or 1,3-dibutyl, a 1,3-diaryl derivative such as 1,3-diphenyl, 1,3-di(p-chlorophenyl), or 1,3-di(p-ethoxycarbonylphenyl), a 1-alkyl-1-aryl derivative such as 1-ethyl-3-phenyl, and a 1,3-diheterocyclic derivative substituted at the 1,3-position such as 1,3-di(2-pyridyl).
(f) A 2-thio-2,4-thiazolidinedione ring: for example, rhodanine or a derivative thereof. Examples of the derivative thereof include a 3-alkyl rhodanine such as 3-methyl rhodanine, 3-ethyl rhodanine, or 3-allyl rhodanine; a 3-aryl rhodanine such as 3-phenyl rhodanine; and a rhodanine substituted with a heterocyclic ring at the 3-position such as 3-(2-pyridyl) rhodanine.
(g) A 2-thio-2,4-oxazolidinedione (2-thio-2,4-(3H,5H)-oxazoledione) ring: for example, 3-ethyl-2-thio-2,4-oxazolidinedione.
(h) A thianaphthenone ring: for example, 3(2H)-thianaphthenone-1,1-dioxide.
(i) A 2-thio-2,5-thiazolidinedione ring: for example, 3-ethyl-2-thio-2,5-thiazolidinedione.
(j) A 2,4-thiazolidinedione ring: for example, 2,4-thiazolidinedione, 3-ethyl-2,4-thiazolidinedione, or 3-phenyl-2,4-thiazolidinedione.
(k) A thiazoline-4-one ring: for example, 4-thiazolinone or 2-ethyl-4-thiazolinone.
(l) A 4-thiazolidinone ring: for example, 2-ethylmercapto-5-thiazolin-4-one or 2-alkylphenylamino-5-thiazolin-4-one.
(m) A 2,4-imidazolidinedione (hydantoin) ring: for example, 2,4-imidazolidinedione or 3-ethyl-2,4-imidazolidinedione.
(n) A 2-thio-2,4-imidazolidinedione (2-thiohydantoin) ring: for example, 2-thio-2,4-imidazolidinedione or 3-ethyl-2-thio-2,4-imidazolidinedione.
(o) An imidazoline-5-one ring: for example, 2-propyl mercapto-2-imidazolin-5-one.
(p) A 3,5-pyrazolidinedione ring: for example, 1,2-diphenyl-3,5-pyrazolidinedione or 1,2-dimethyl-3,5-pyrazolidinedione.
(q) A benzothiophene-3-one ring: for example, benzothiophene-3-one, oxobenzothiophene-3-one, or dioxobenzothiophene-3-one.
(r) An indanone ring: for example, 1-indanone, 3-phenyl-1-indanone, 3-methyl-1-indanone, 3,3-diphenyl-1-indanone, or 3,3-dimethyl-1-indanone.

The ring formed by R^{3A} and R^{4A} being bonded to each other and the ring formed by R^{5A} and R^{6A} being bonded to each other are preferably a 1,3-dicarbonyl ring, a pyrazolinone ring, a 2,4,6-triketohexahydropyrimidine ring (including thioketones), a 2-thio-2,4-thiazolidinedione ring, a 2-thio-2,4-oxazolidinedione ring, a 2-thio-2,5-thiazolidinedione ring, a 2,4-thiazolidinedione ring, a 2,4-imidazolidinedione ring, a 2-thio-2,4-imidazolidinedione ring, a 2-imidazoline-5-one ring, a 3,5-pyrazolidinedione ring, a benzothiophene-3-one ring, or an indanone ring, and still more preferably a 1,3-dicarbonyl ring, a 2,4,6-triketohexahydropyrimidine ring (including a thioketones), a 3,5-pyrazolidinedione ring, a benzothiophene-3-one ring, or an indanone ring.

In a case where R^{3A} and R^{4A}, and R^{5A} and R^{6A} are bonded to each other to form rings, respectively, it is not possible to specify the σp values of the R^{3A} to R^{6A} that forms the rings; however, in the present invention, it is regarded that R^{3A} to R^{6A} are substituted with partial structures of the respective rings, whereby the σp values in the case of ring formation shall be defined. For example, in a case where R^{3A} and R^{4A} are bonded to form a 1,3-indandione ring, it is conceived that R^{3A} and R^{4A} are substituted with benzoyl groups, respectively.

X¹ and X² each independently represent —BR²¹R²².

R²¹ and R²² each independently represent a substituent, and R²¹ and R²² may be bonded to each other to form a ring.

The substituent represented by R²¹ and R²² is preferably a halogen atom, an alkyl group, an alkoxy group, an aryl group, a heteroaryl group, or a group represented by Formula (2-4), more preferably a halogen atom, an aryl group, or a heteroaryl group, and still more preferably an aryl group.

The halogen atom is preferably a fluorine atom, a chlorine atom, a bromine atom, or an iodine atom, and particularly preferably a fluorine atom.

The number of carbon atoms in the alkyl group is preferably 1 to 40. The lower limit thereof is, for example, more preferably 3 or more. The upper limit thereof is, for example, more preferably 30 or less, and still more preferably 25 or less. The alkyl group may be linear, branched, or cyclic, and it is preferably linear or branched, and particularly preferably linear.

The number of carbon atoms in the alkoxy group is preferably 1 to 40. The lower limit thereof is, for example, more preferably 3 or more. The upper limit thereof is, for example, more preferably 30 or less, and still more preferably 25 or less. The alkoxy group may be linear, branched, or cyclic, and it is preferably linear or branched, and particularly preferably linear.

The number of carbon atoms in the aryl group is preferably 6 to 20 and more preferably 6 to 12. The aryl group is preferably a phenyl group.

The heteroaryl group may be monocyclic or polycyclic, and a monocyclic ring is preferable. The number of heteroatoms constituting the heteroaryl group is preferably 1 to 3. The heteroatom constituting the heteroaryl group is preferably a nitrogen atom, an oxygen atom, or a sulfur atom. The number of carbon atoms in the heteroaryl group is preferably 3 to 30, more preferably 3 to 18, still more preferably 3 to 12, and particularly preferably 3 to 5. The heteroaryl group is preferably a 5-membered ring or a 6-membered ring. Specific examples of the heteroaryl group include those described in R^{1A} and R^{2A}.

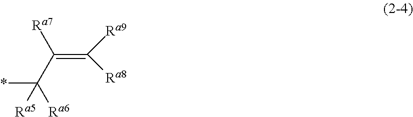

In Formula (2-4), R^{a5} to R^{a9} each independently represent a hydrogen atom or a substituent. * represents a bonding site to General Formula (D1). Examples of the substituent represented by R^{a5} to R^{a9} include an alkyl group, an alkoxy group, an aryl group, or a heteroaryl group, and an alkyl group is preferable.

R²¹ and R²² may be bonded to each other to form a ring. Examples of the ring formed by R²¹ and R²² being bonded to each other include the structures shown in (2-1) to (2-3) below. In the following formulae, R represents a substituent, R^{a1} to R^{a4} each independently represent a hydrogen atom or a substituent, and m1 to m3 each independently represent an integer of 0 to 4. Examples of the substituent represented by R and R^{a1} to R^{a4} include the substituents described in R²¹ and R²², and an alkyl group is preferable.

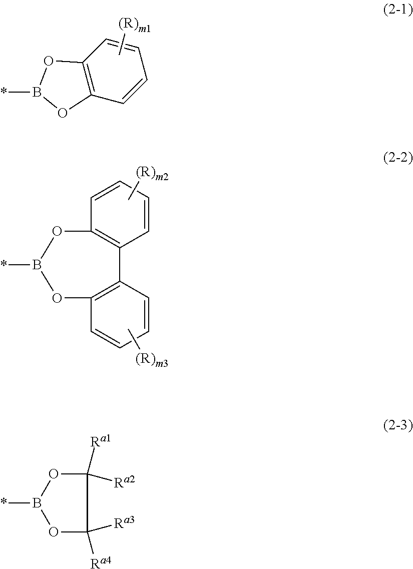

The coloring agent represented by General Formula (D1) is preferably a coloring agent represented by General Formula (D2).

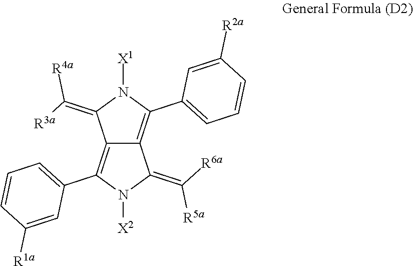

In General Formula (D2), R^{1a} and R^{2a} each independently represent a substituent, R^{3a} and R^{6a} each independently represent a substituent, and R^{4a} and R^{5a} each independently represent a heteroaryl group. R^{3a} and R^{4a} may be bonded to each other to form a ring, and R^{5a} and R^{6a} may be bonded to each other to form a ring. X^{1a} and X^{2a} each independently represent —BR^{21a}R^{22a}, R^{21a} and R^{22a} each independently represent a substituent, and R^{21a} and R^{22a} may be bonded to each other to form a ring.

In General Formula (D2), R^{3a} to R^{6a}, X^{1a}, X^{2a}, R^{21a}, and R^{22a} have the same meanings as R^{3A} to R^{6A}, X¹, X², R²¹, and R²², and the same applies to the preferred ranges thereof.

The substituents as R^{1a} and R^{2a} respectively have the same meaning as the substituents which may be contained in the alkyl group, the aryl group, and the heteroaryl group as R^{1A} and R^{2A}, and the same applies to the preferred ranges thereof.

The coloring agent represented by General Formula (D1) is more preferably a coloring agent represented by General Formula (D3).

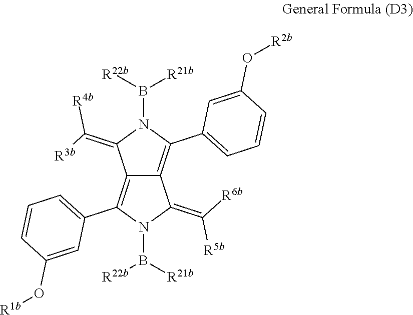

In General Formula (D3), R^{1b} and R^{2b} each independently represent a branched alkyl group, and R^{3b} and R^{6b} each independently represent a substituent, R^{4b} and R^{5b} each independently represent a heteroaryl group. R^{3b} and R^{4b} may be bonded to each other to form a ring, and R^{5b} and R^{6b} may be bonded to each other to form a ring. R^{21b} and R^{22b} each independently represent a substituent, and R^{21b} and R^{22b} may be bonded to each other to form a ring.

R^{1b} and R^{2b} each independently represent a branched alkyl group. The number of carbon atoms thereof is preferably 3 to 40. The lower limit thereof is, for example, more preferably 5 or more, still more preferably 8 or more, and even still more preferably 10 or more. The upper limit thereof is more preferably 35 or less and still more preferably 30 or less. The number of branches in the branched alkyl group is preferably 2 to 10 and more preferably 2 to 8.

R^{3b} to R^{6b}, and R^{21b} and R^{22b} respectively have the same meanings as R^{3A} to R^{6A}, R²¹, and R²², and the same applies to the preferred ranges thereof.

That is, R^{3b} and R^{6b} each are preferably an electron-withdrawing group and more preferably a cyano group.

R^{21b} and R^{22b} are each independently preferably a halogen atom, an alkyl group, an alkoxy group, an aryl group, or a heteroaryl group, more preferably a halogen atom, an aryl group, or an aryl group, and still more preferably an aryl group.

Specific examples of the dye D are shown below. Compounds D-1 to D-24 and D-28 to D-90 shown below are coloring agents represented by General Formula (D1).

In the following structural formulae, “i” in i-C₁₀H₂₁ and the like represents the corresponding compound is present in a branched state.

In addition, Bu represents a butyl group, and Ph represents a phenyl group.

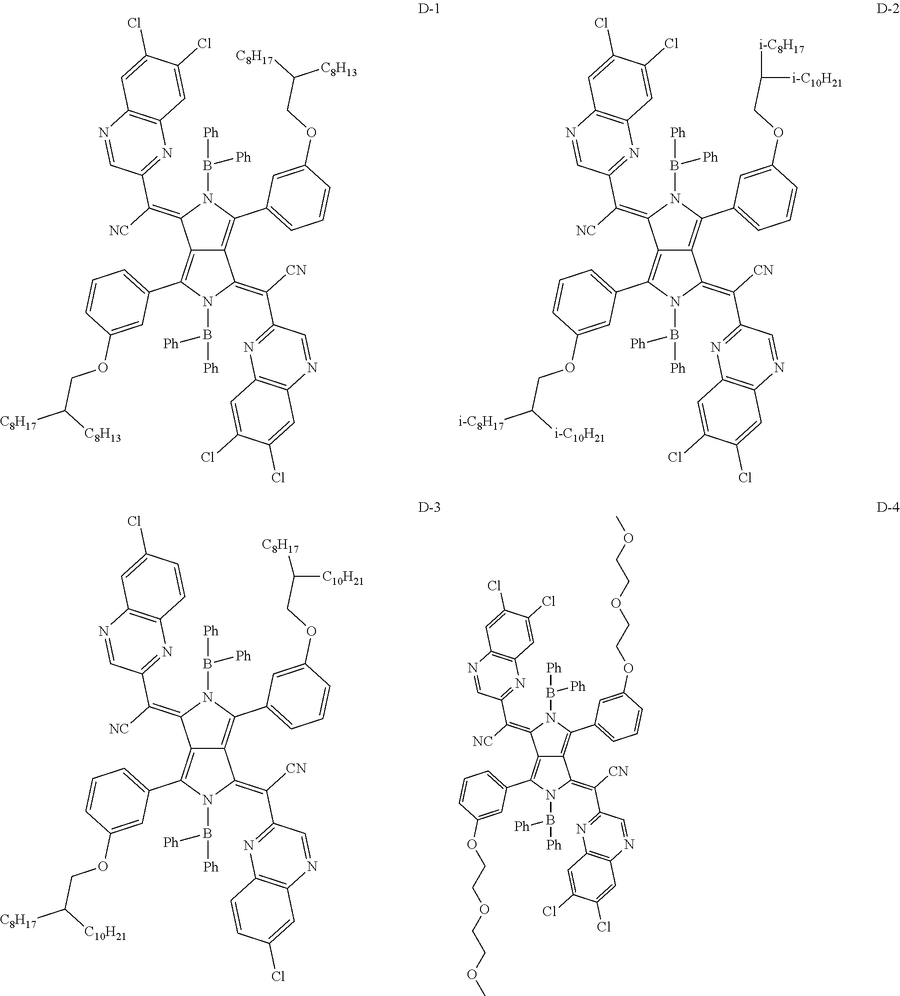

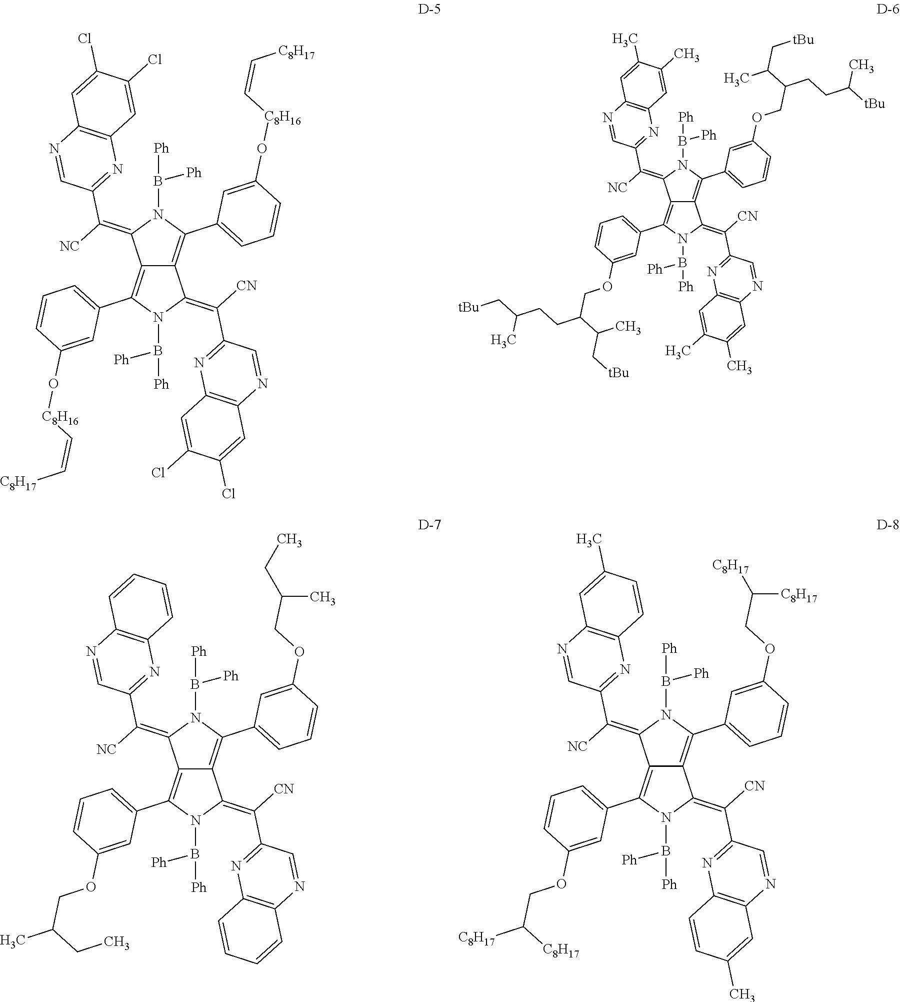

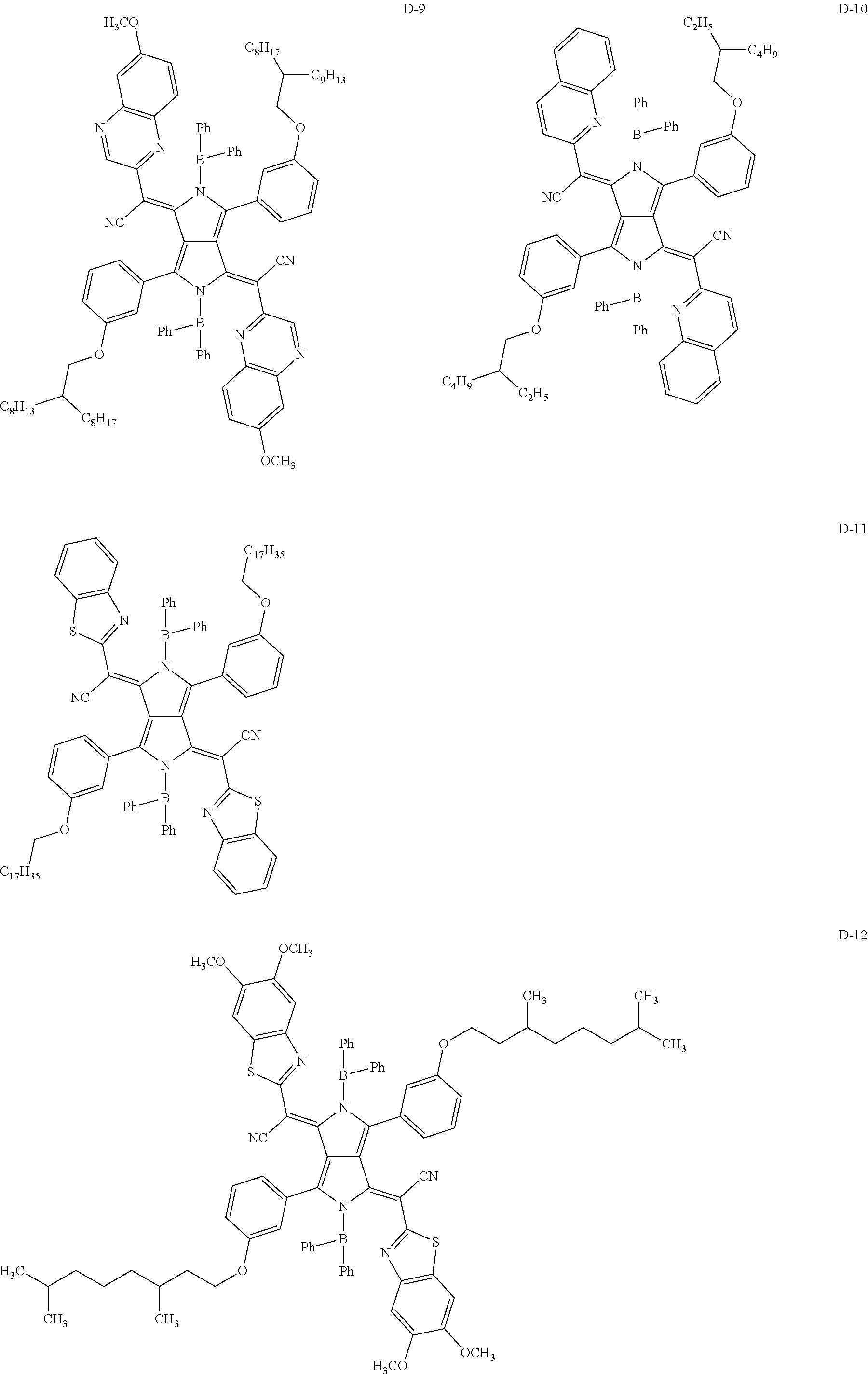

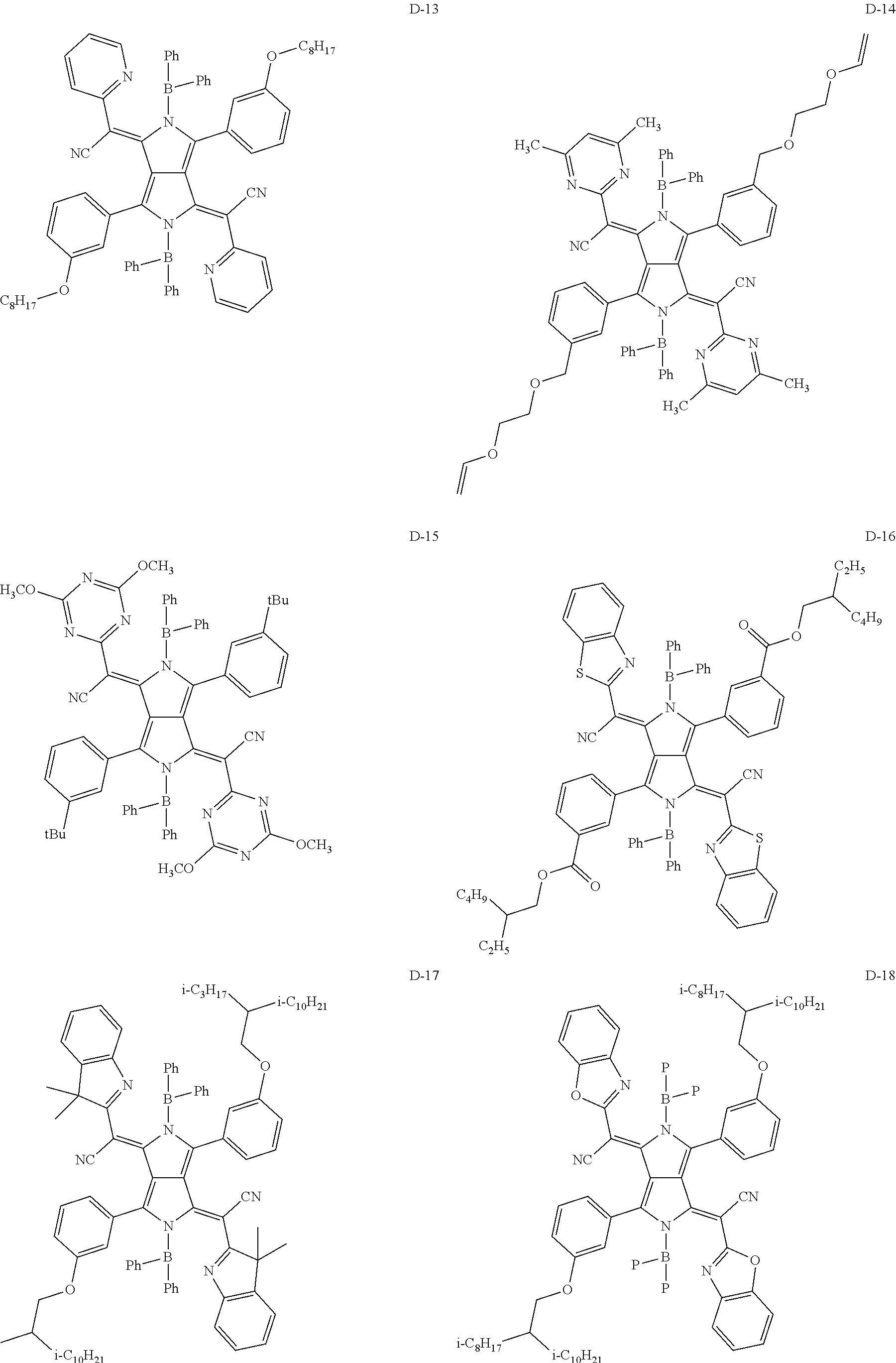

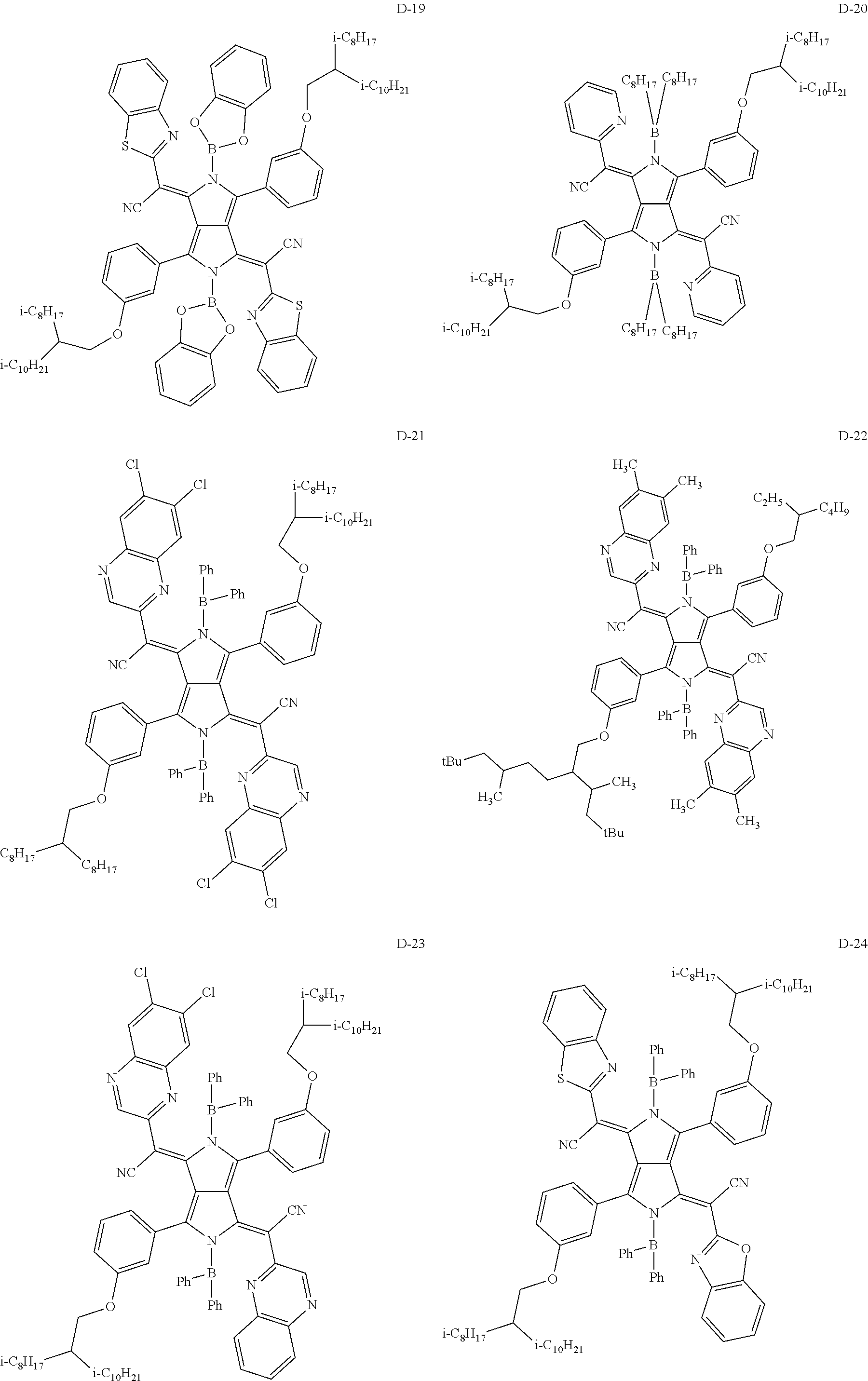

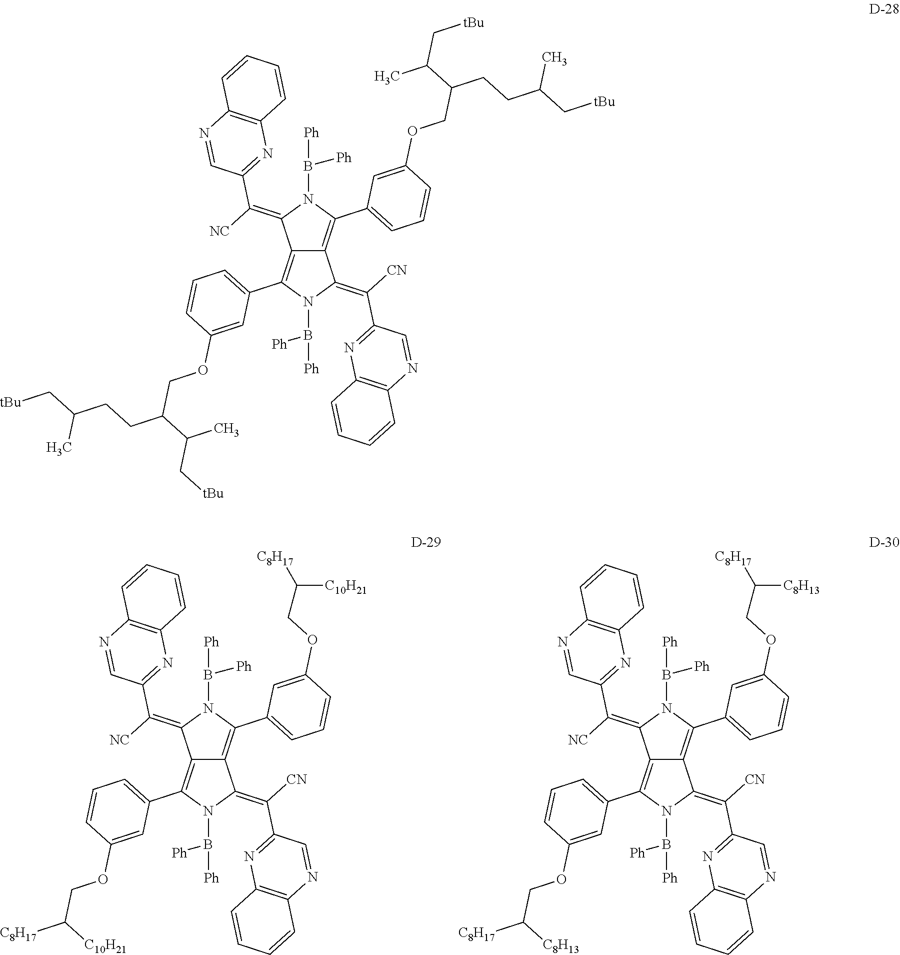

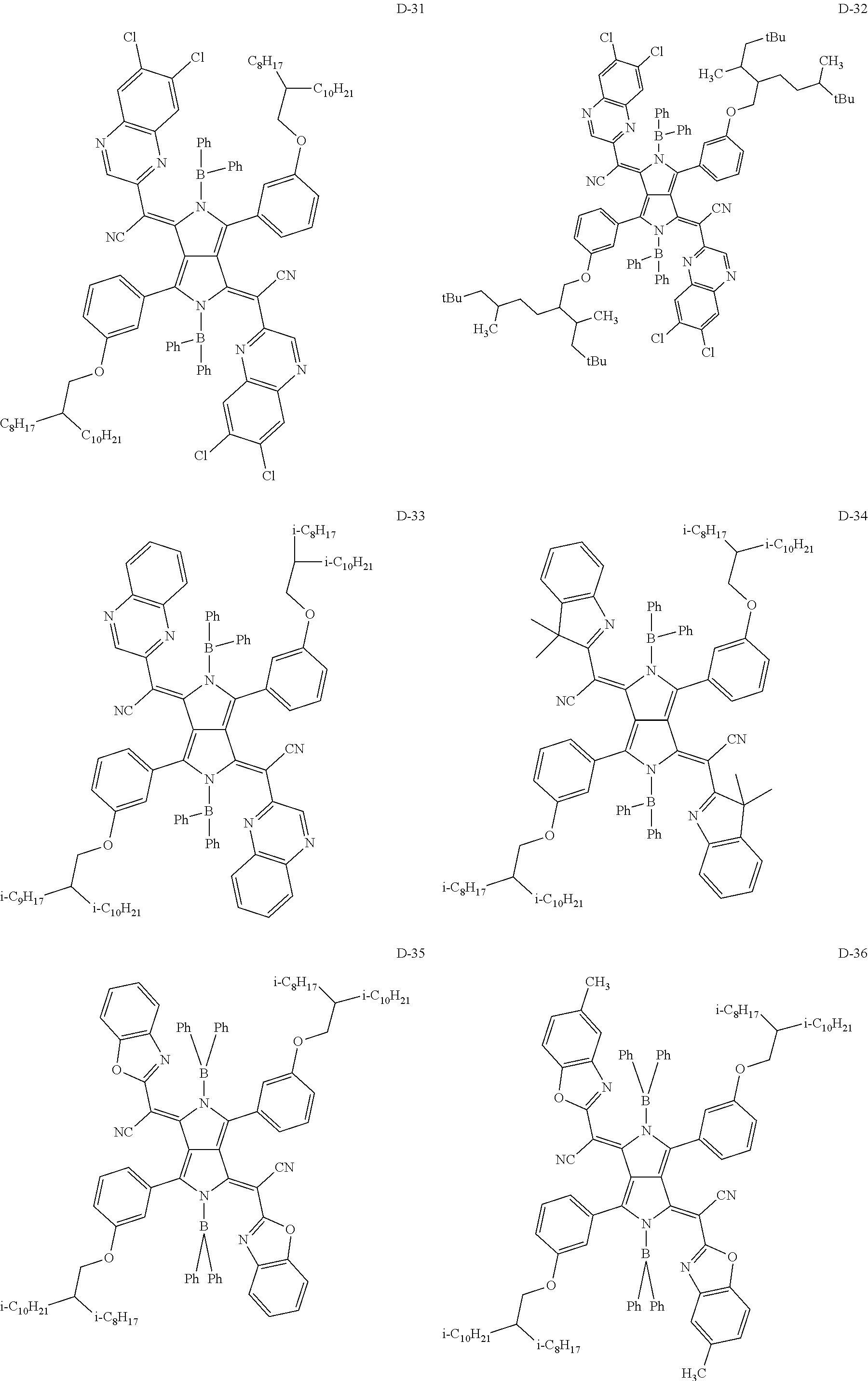

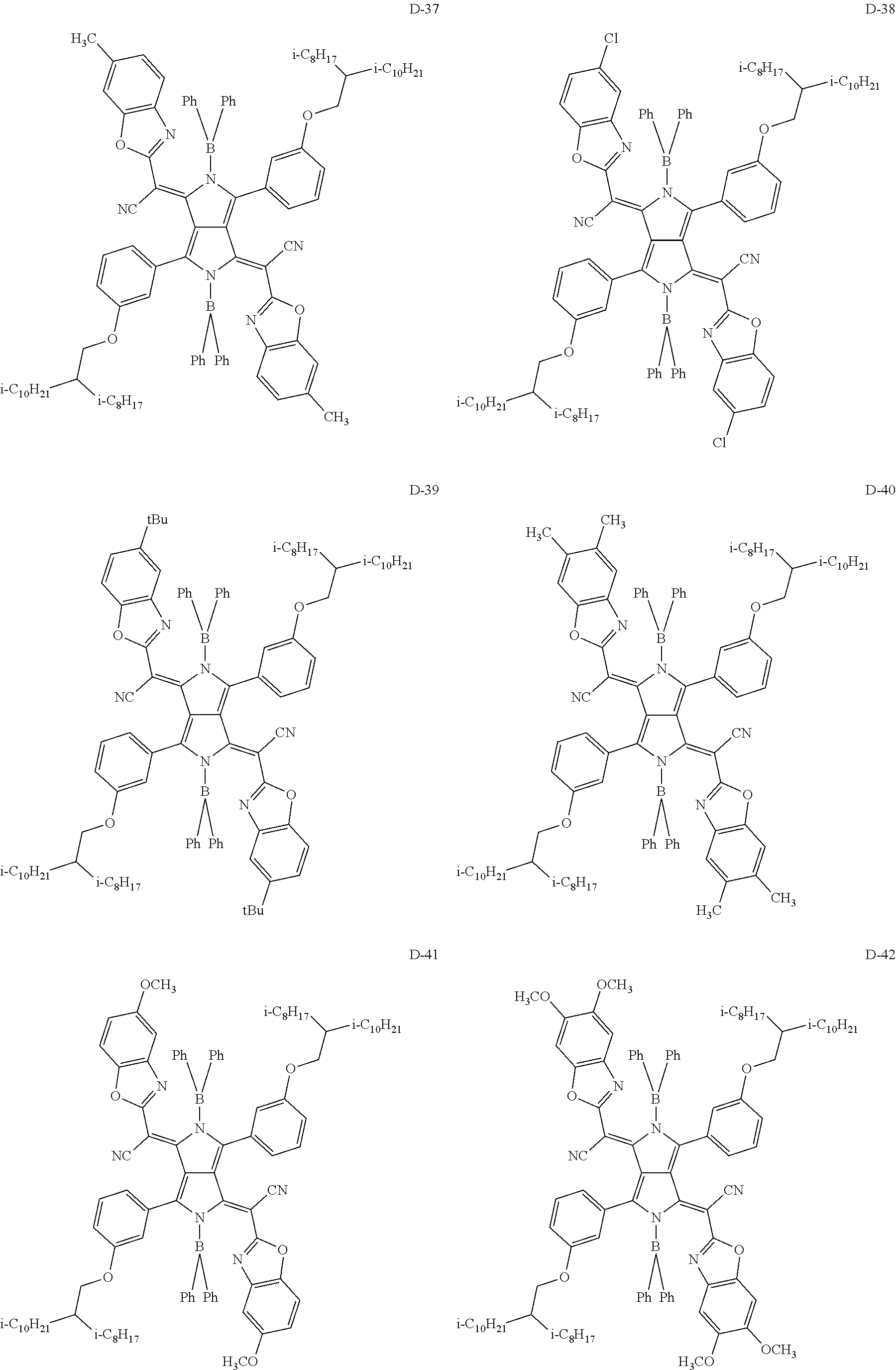

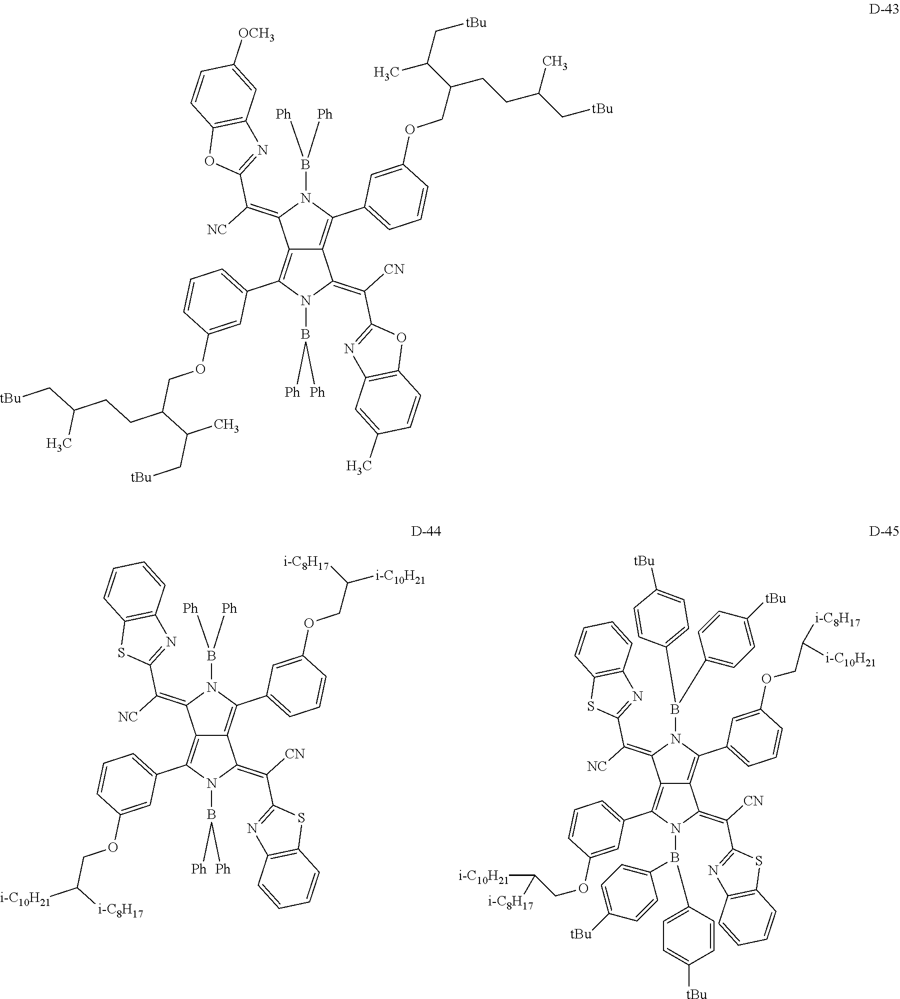

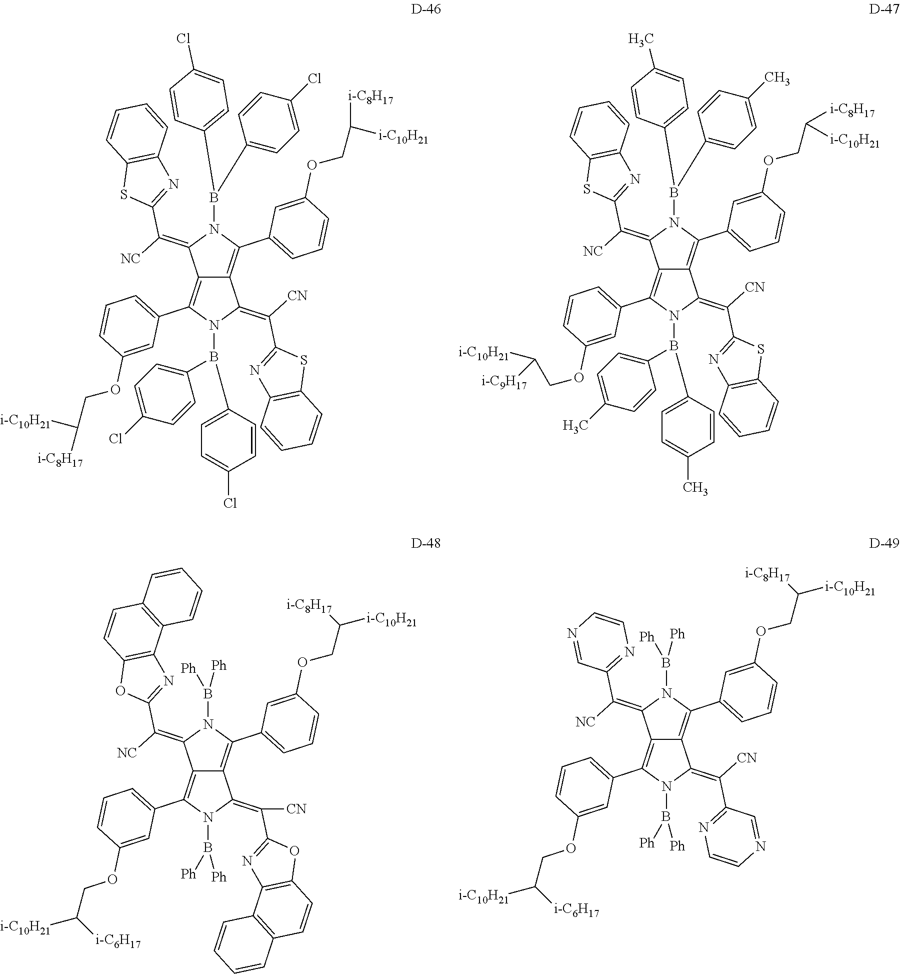

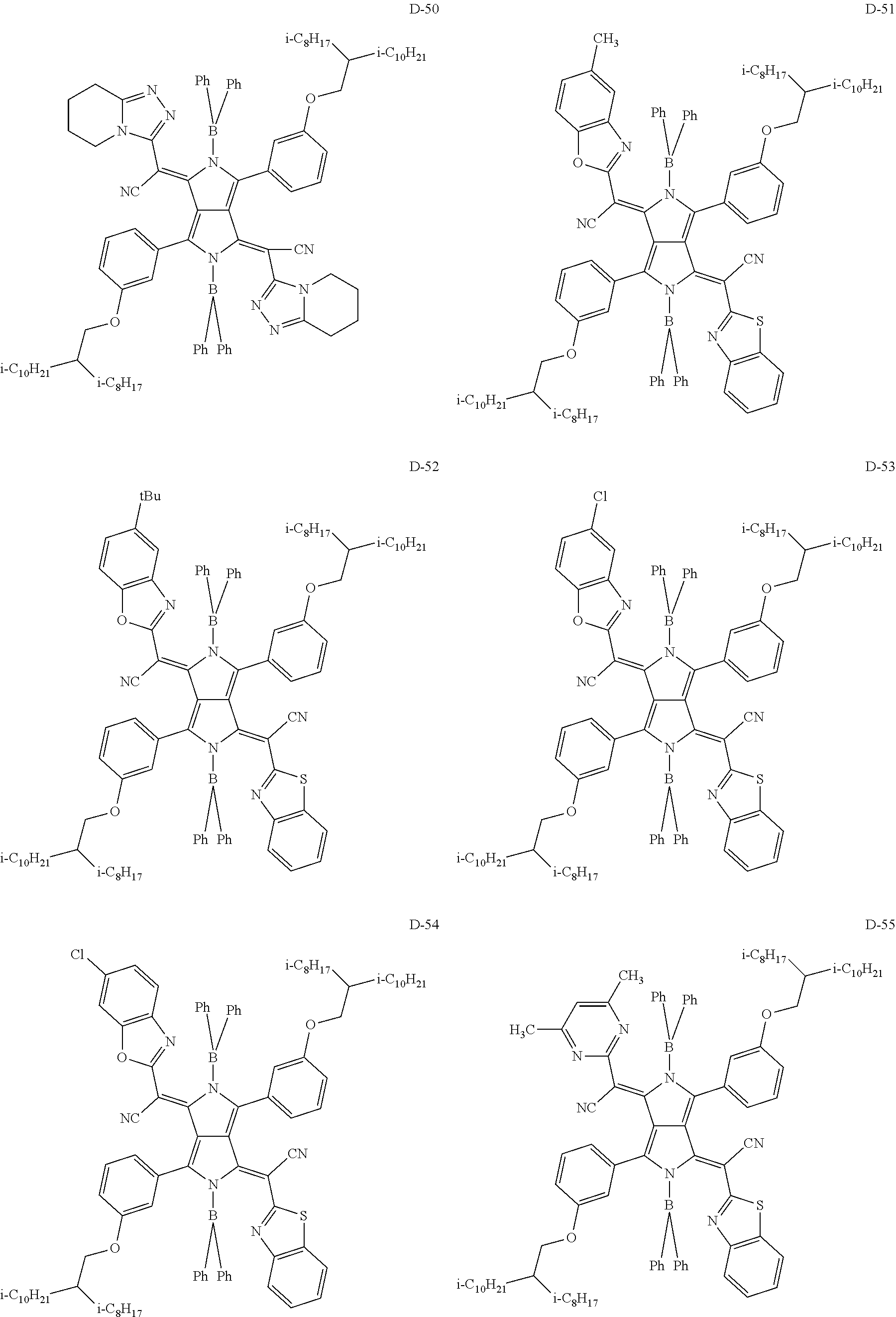

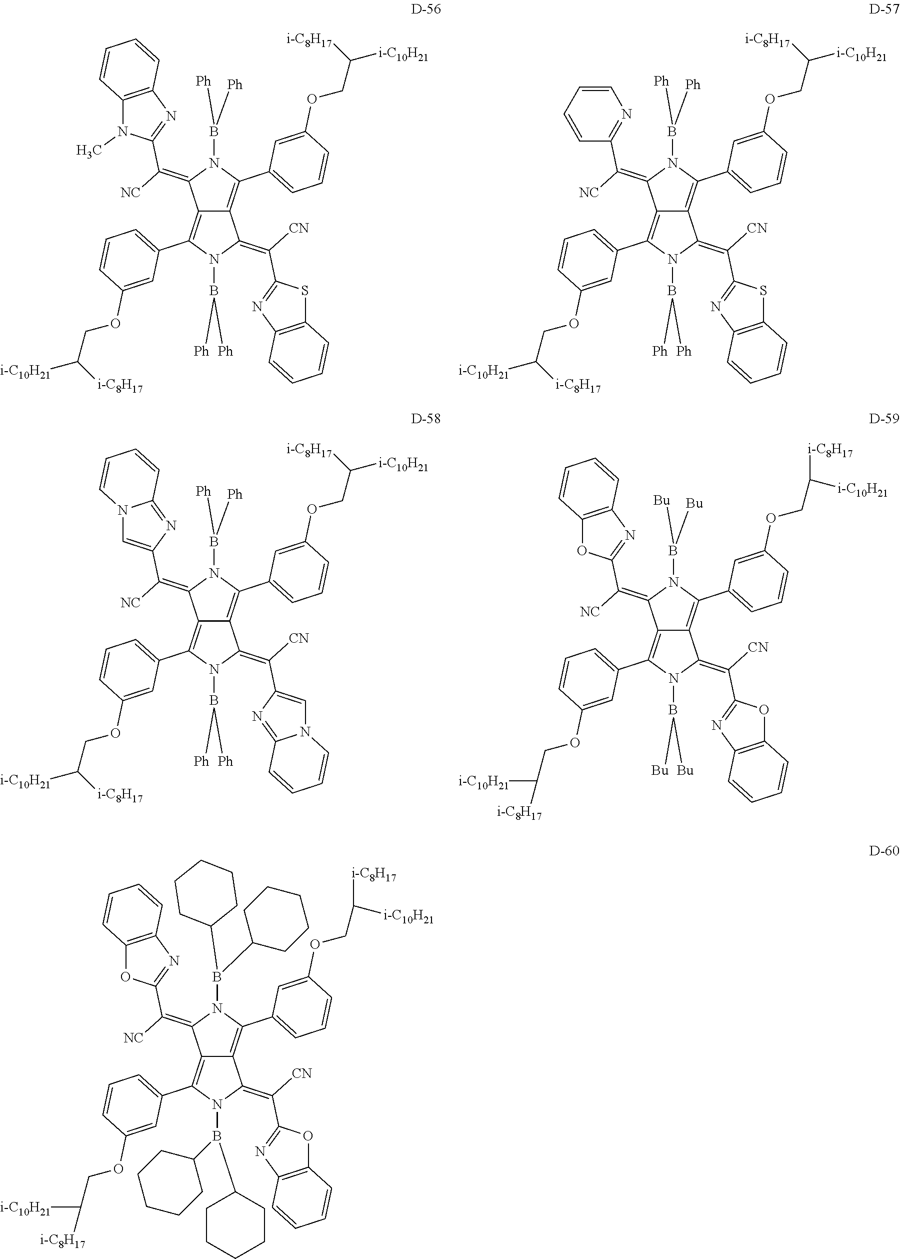

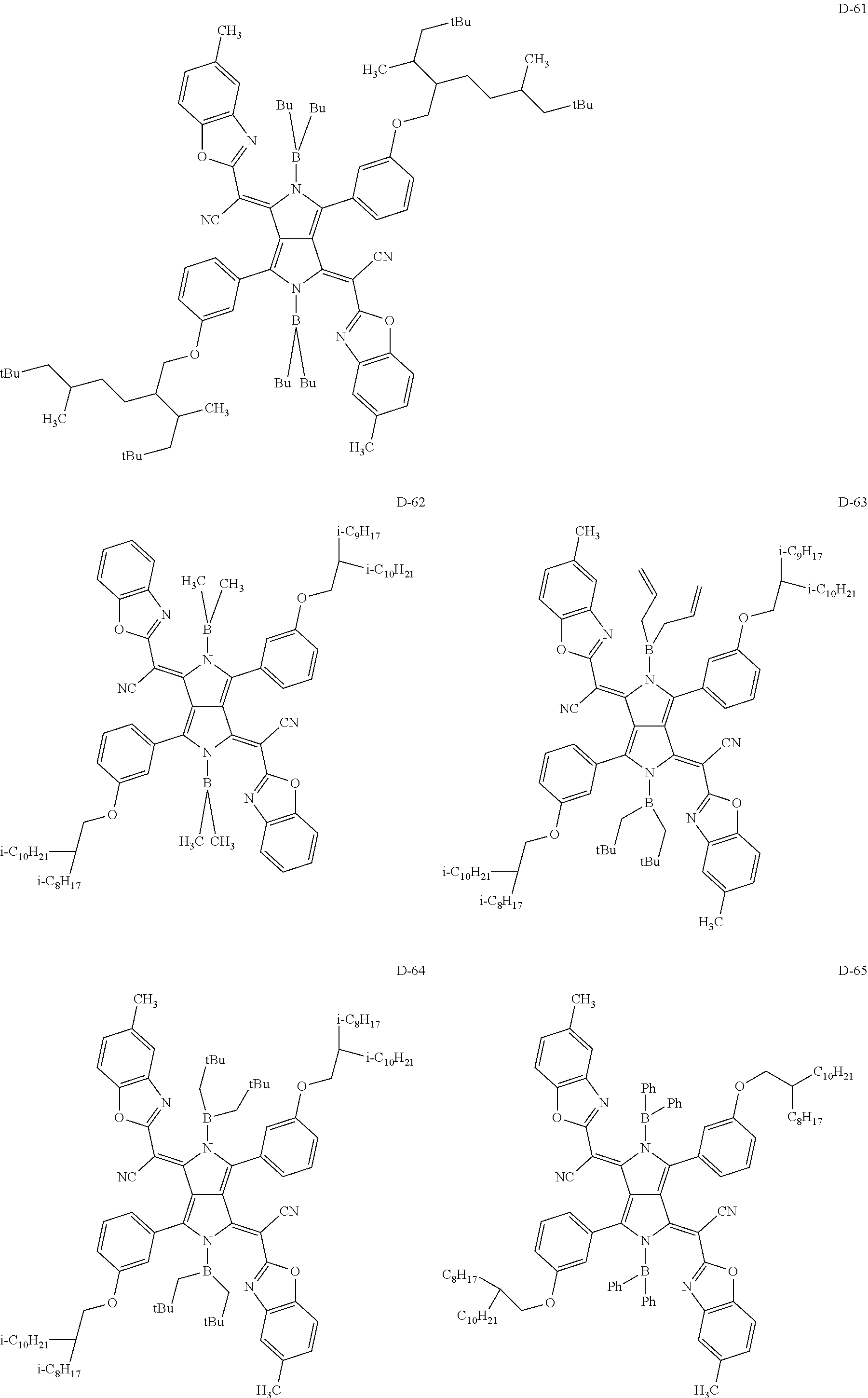

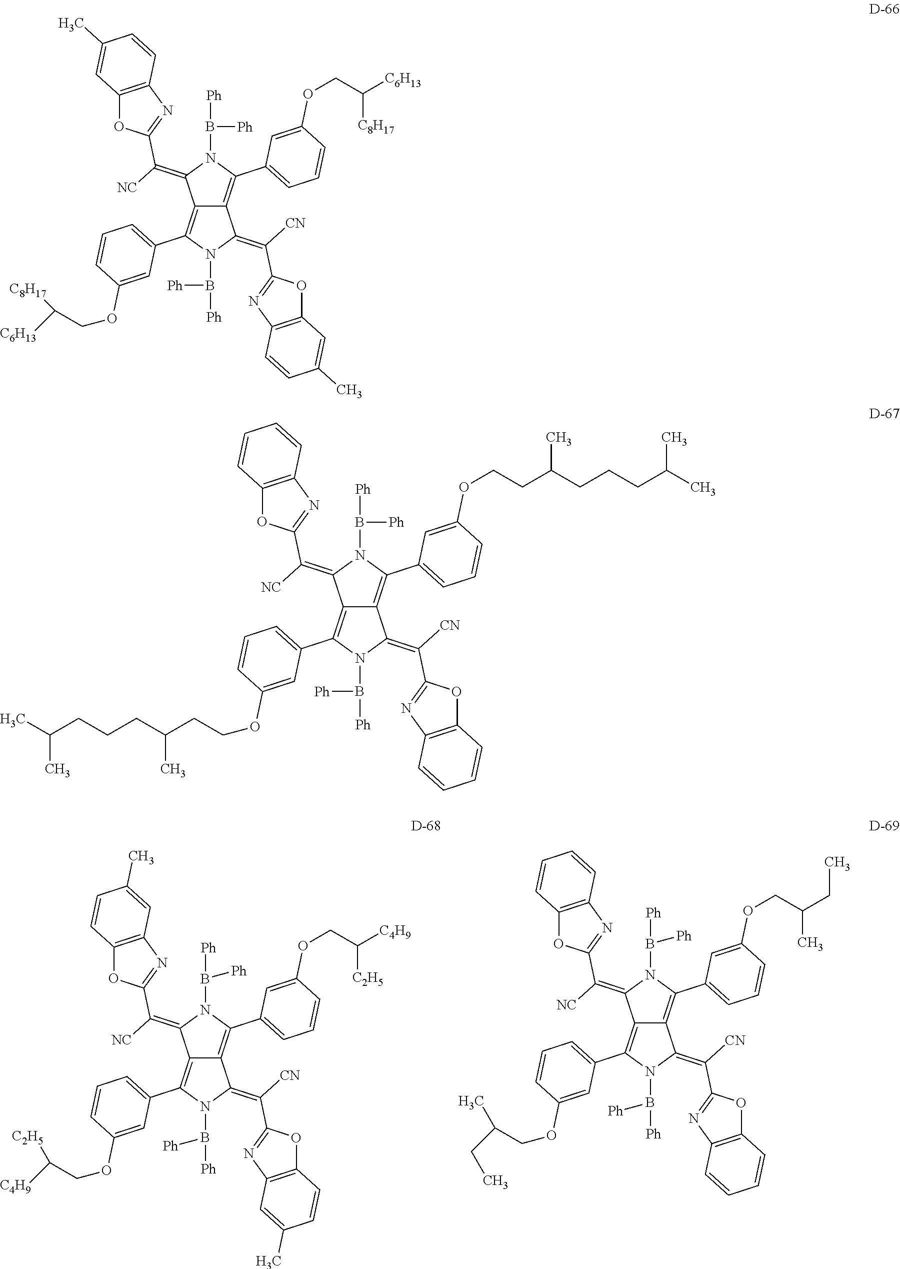

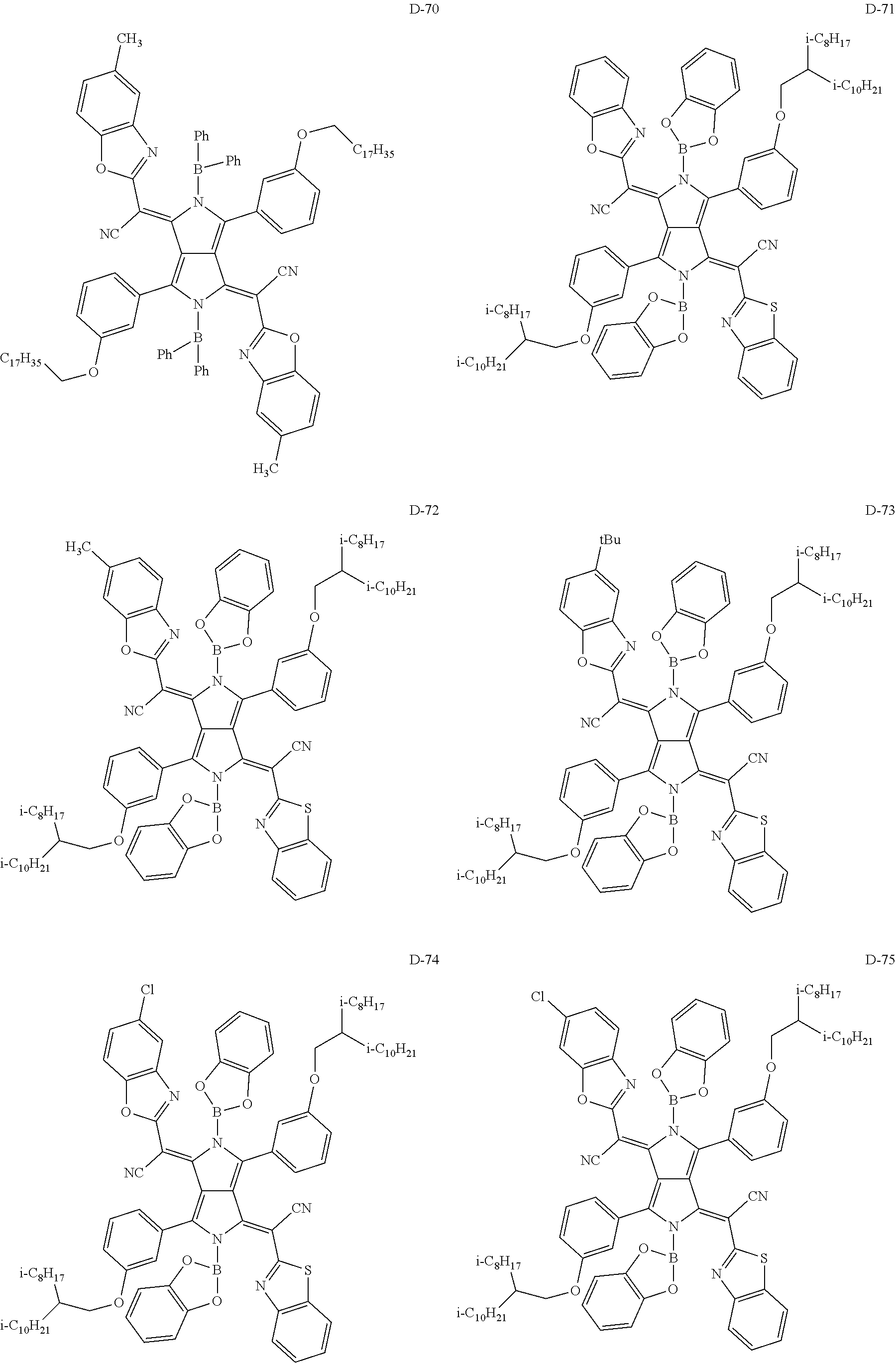

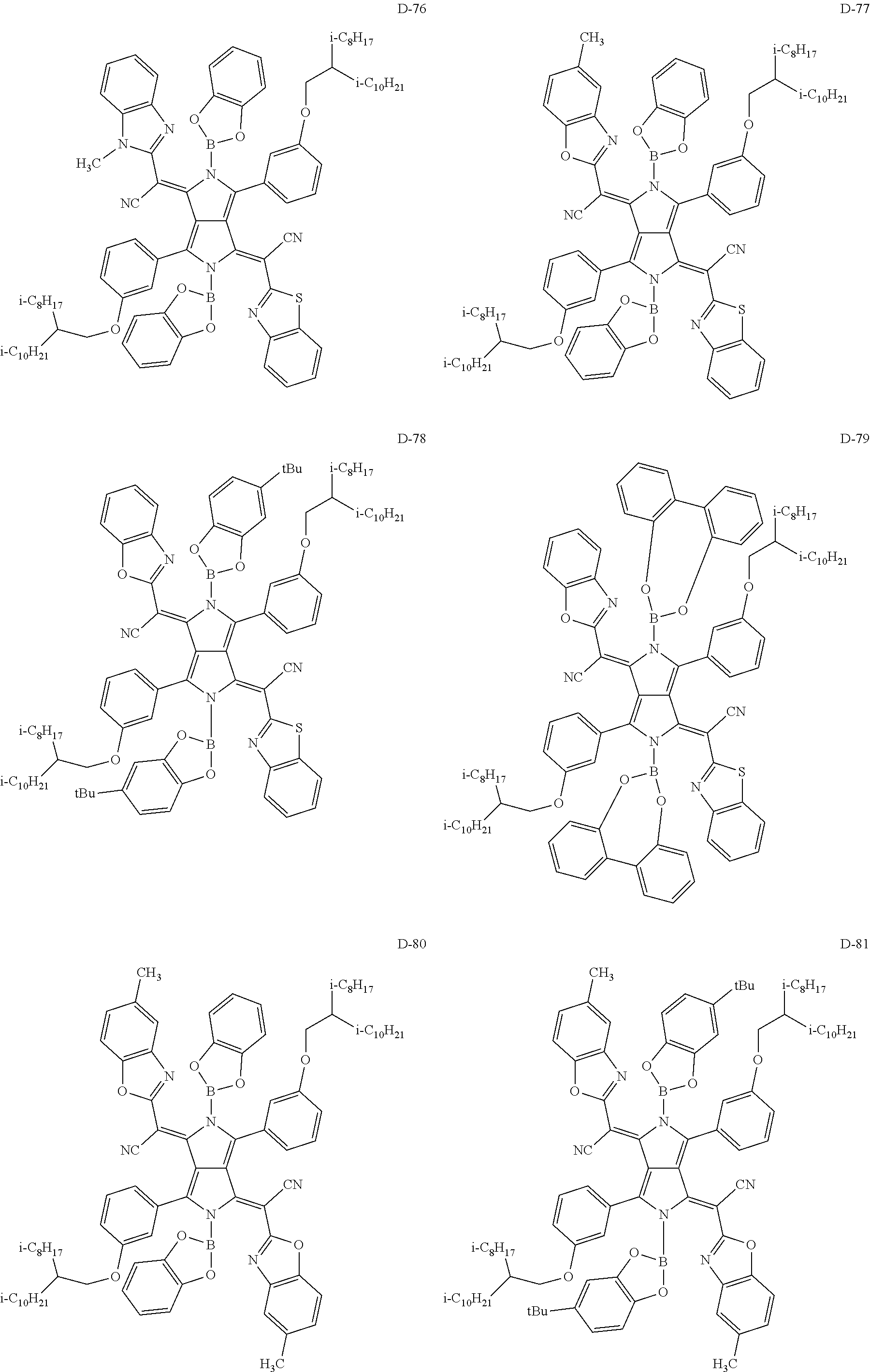

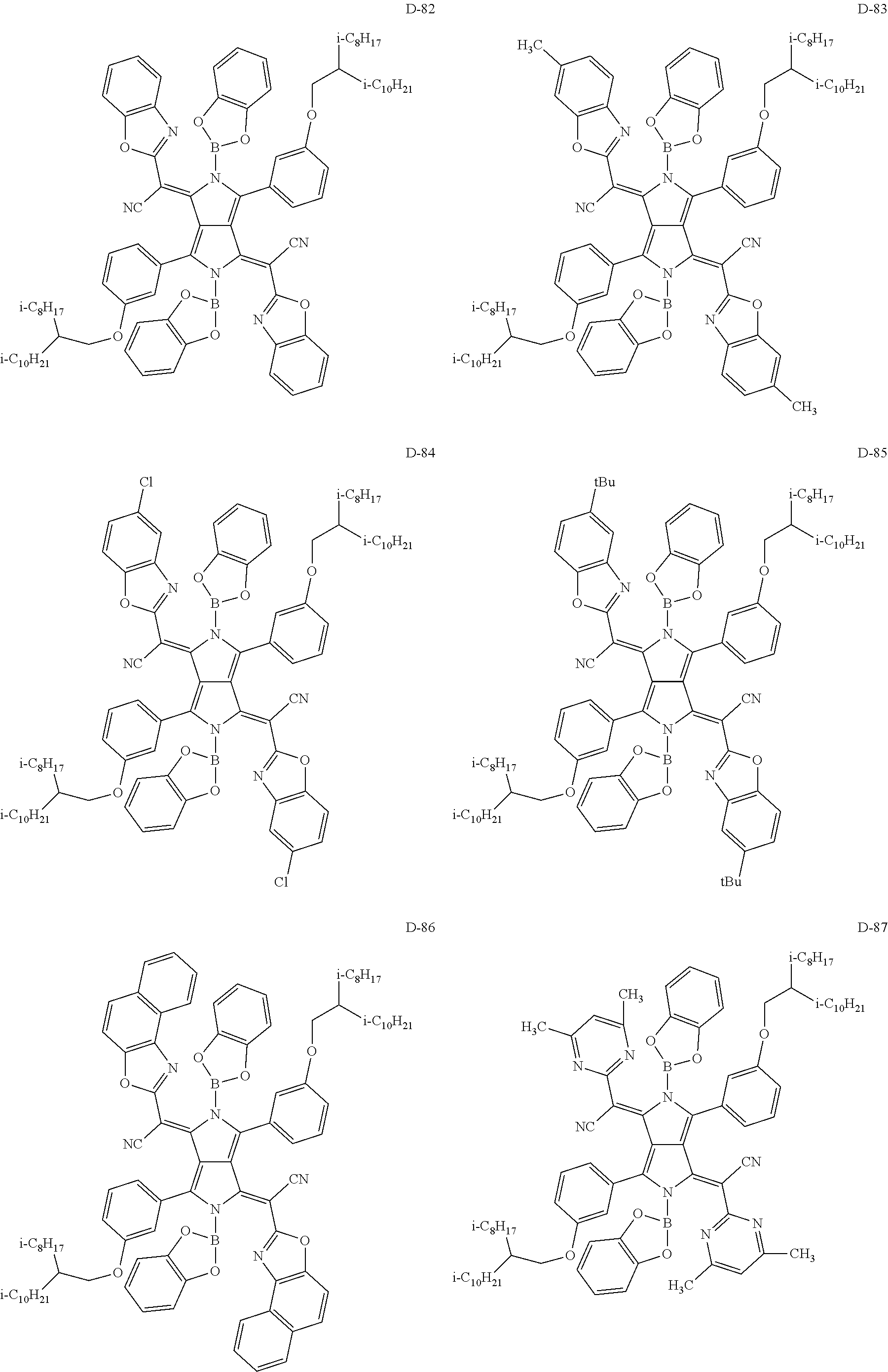

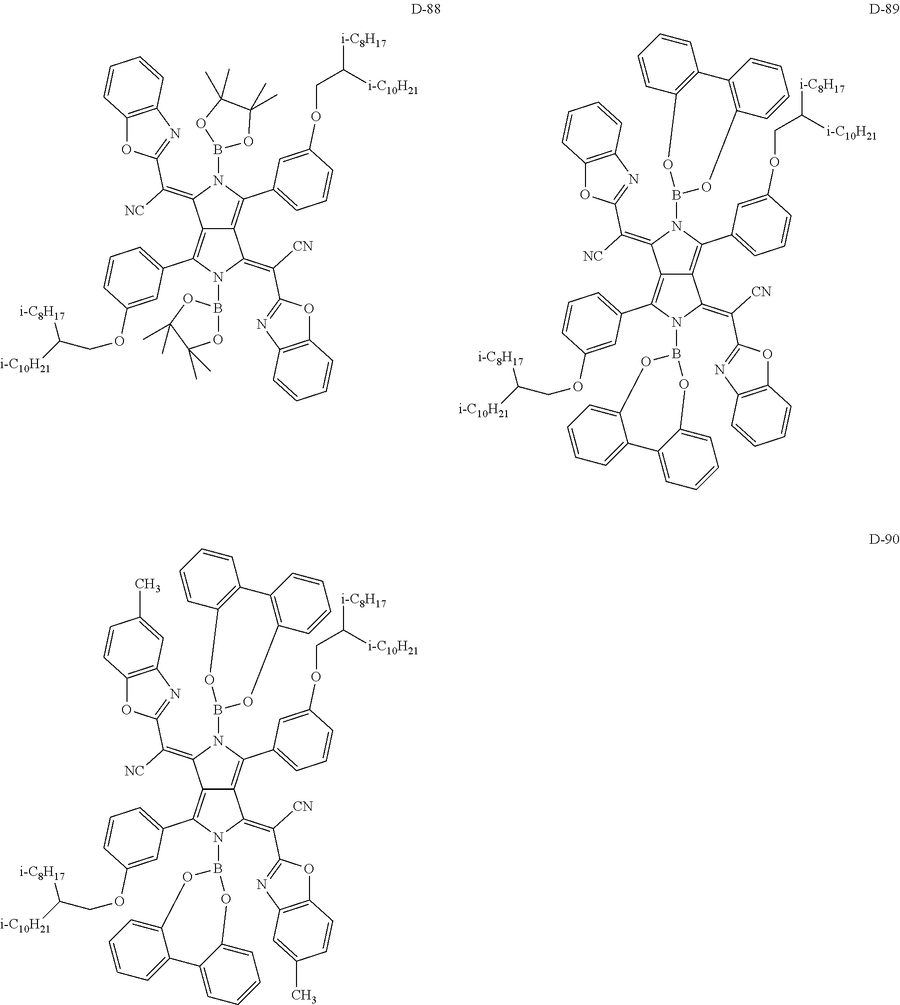

(Coloring Agent Represented by General Formula (1))

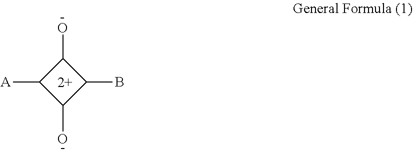

The form of the substituent that can be employed by A and B in General Formula (1) are respectively the same as those of A and B in General Formula (1) described in the above-described dye B and dye C.

In a case where the dye D is a coloring agent represented by General Formula (1), a coloring agent represented by General Formula (14) is preferable.

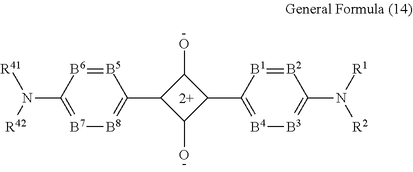

In General Formula (14), R¹ and R² respectively have the same meaning as R¹ and R² in General Formula (2) described above. R⁴¹ and R⁴² respectively have the same meaning as R¹ and R² in General Formula (2) described above.

Among the above, R¹, R², R⁴¹, and R⁴² are preferably an alkyl group, an alkenyl group, an aryl group, or a heteroaryl group, more preferably an alkyl group, an aryl group, or a heteroaryl group, and still more preferably an alkyl group or an aryl group is.

R¹, R², R⁴¹, and R⁴² may further have a substituent. Examples of the substituent which may be further contained include the substituent X.

B¹, B², B³, and B⁴ in General Formula (14) respectively have the same meaning as B¹, B², B³, and B⁴ in General Formula (2) described above. In addition, B⁵, B⁶, B⁷, and B¹ in General Formula (14) respectively have the same meaning as B¹, B², B³, and B⁴ in General Formula (2) described above.

The substituent possessed by the carbon atom that can be employed as B¹, B², B³, B⁴, B⁵, B⁶, B⁷, and B⁸ may further have a substituent. Examples of this substituent which may be further contained include the substituent X.

In General Formula (14), R¹ and R² may be bonded to each other to form a ring, and R¹ or R² and the substituent contained in B² or B³ may be bonded to each other to form a ring. In addition, R⁴¹ and R⁴² may be bonded to each other to form a ring, and R⁴¹ or R⁴² and the substituent contained in B⁶ or B⁷ may be bonded to each other to form a ring.

In the above description, the ring to be formed is preferably a heterocyclic ring or a heteroaryl ring, and it is preferably a 5-membered ring or a 6-membered ring although the size of the ring to be formed is not particularly limited. Further, the number of rings to be formed is not particularly limited, and it may be one or may be two or more. Examples of the form in which two or more rings are formed include a form in which the substituents of R¹ and B² and the substituents of R² and B³ are respectively bonded to each other to form two rings.

Among the dyes D, the squaraine-based coloring agent represented by General Formula (1) may be a quencher-embedded coloring agent. To the quencher-embedded coloring agent, the description related to the quencher-embedded coloring agent in the dye B or C described above can be applied.

Specific examples of the dye D are shown below. The following compounds F-1 to F-44 are coloring agents represented by General Formula (1). Among these, compounds F-24 to F-33 and F-44 correspond to quencher-embedded coloring agents.

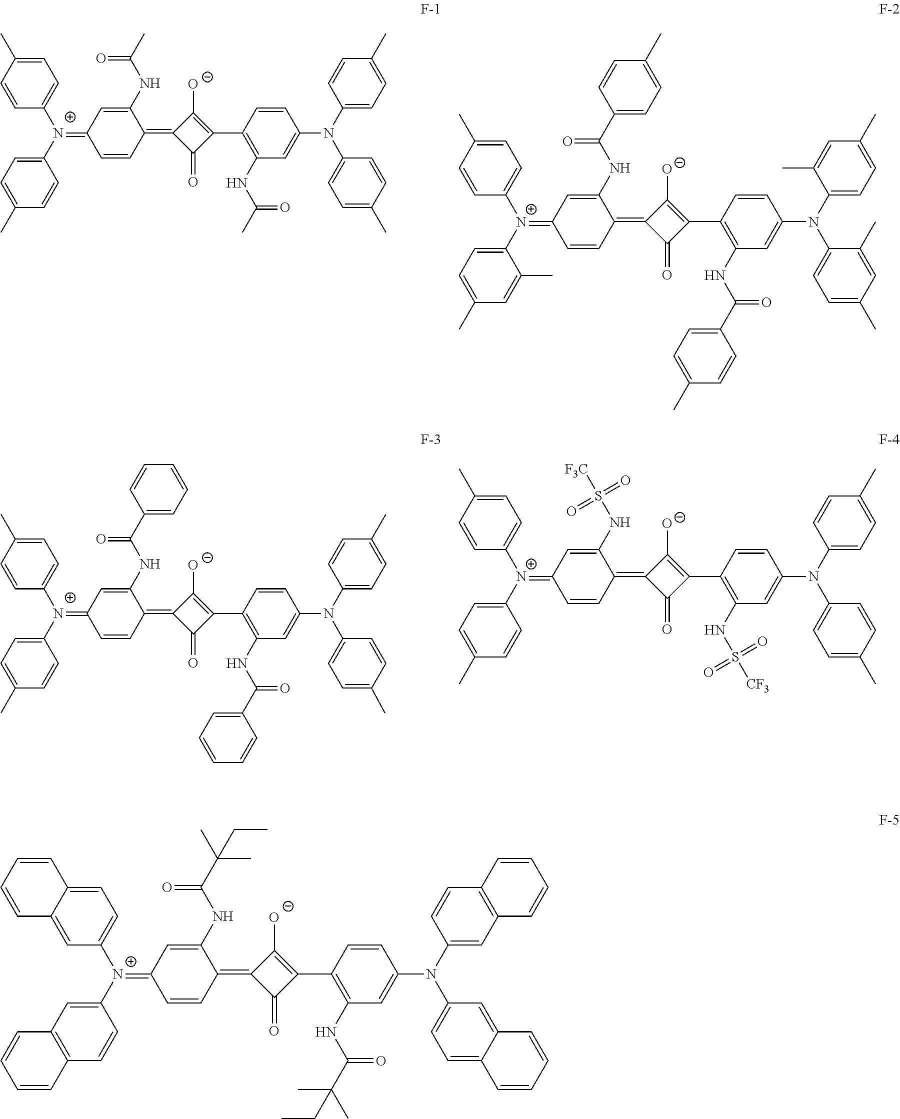

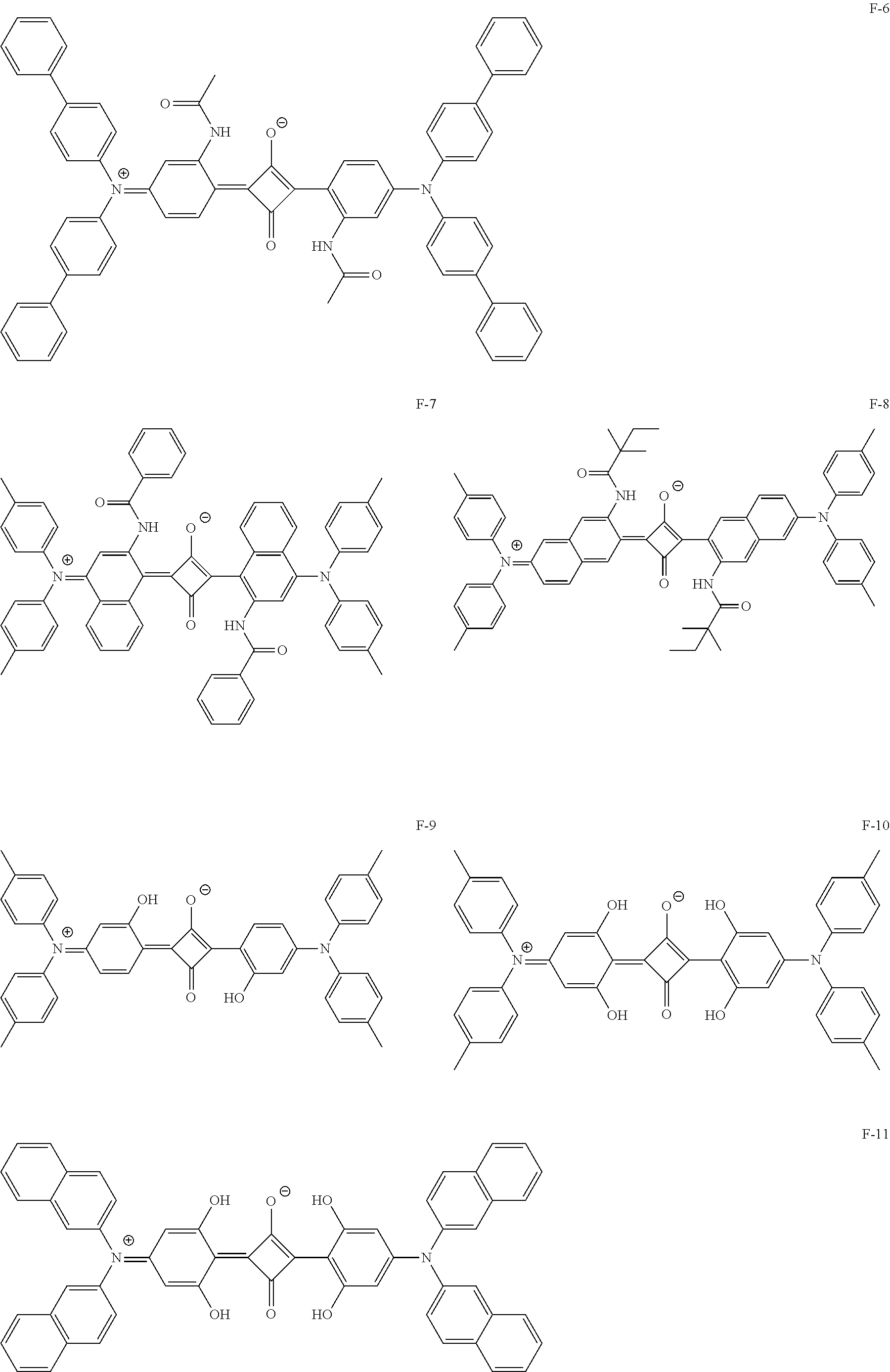

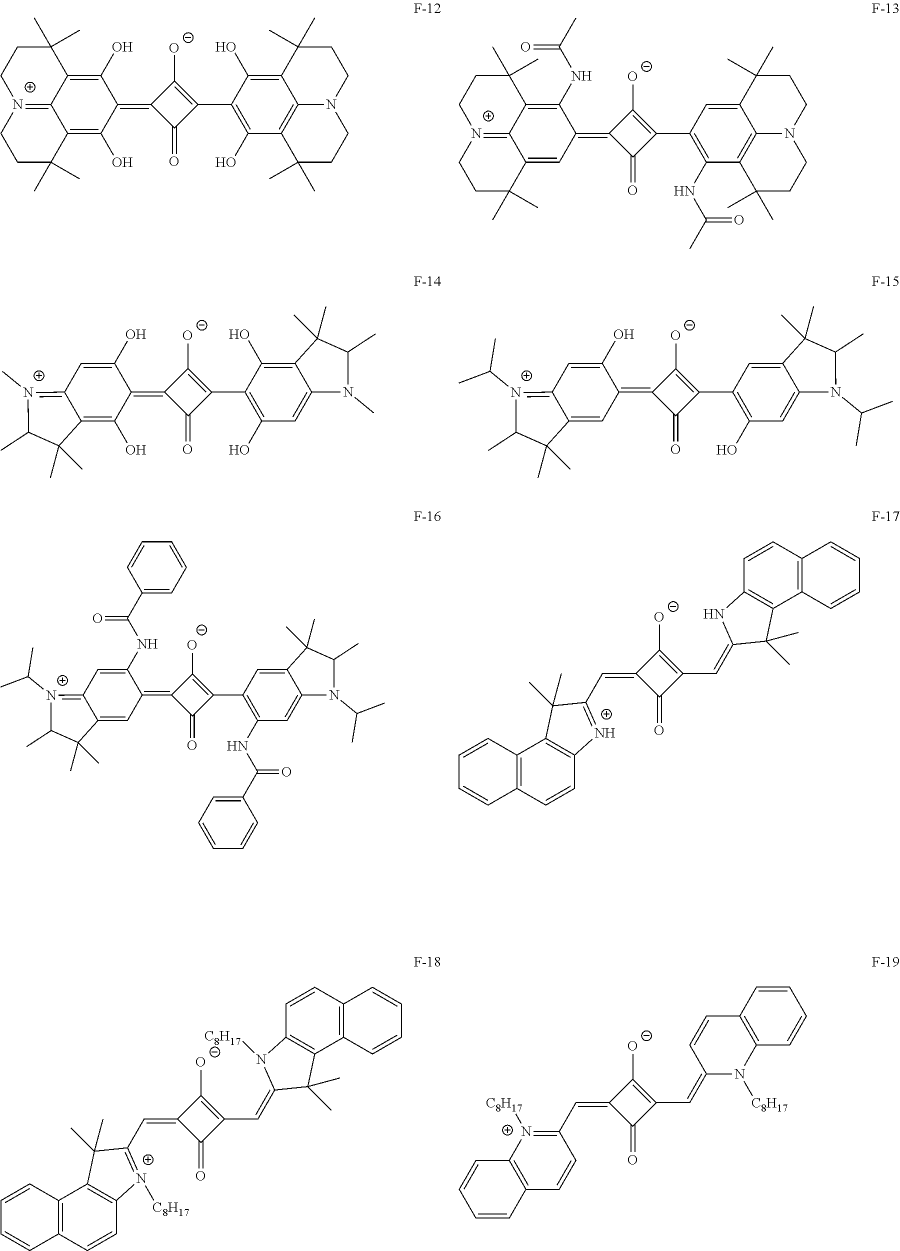

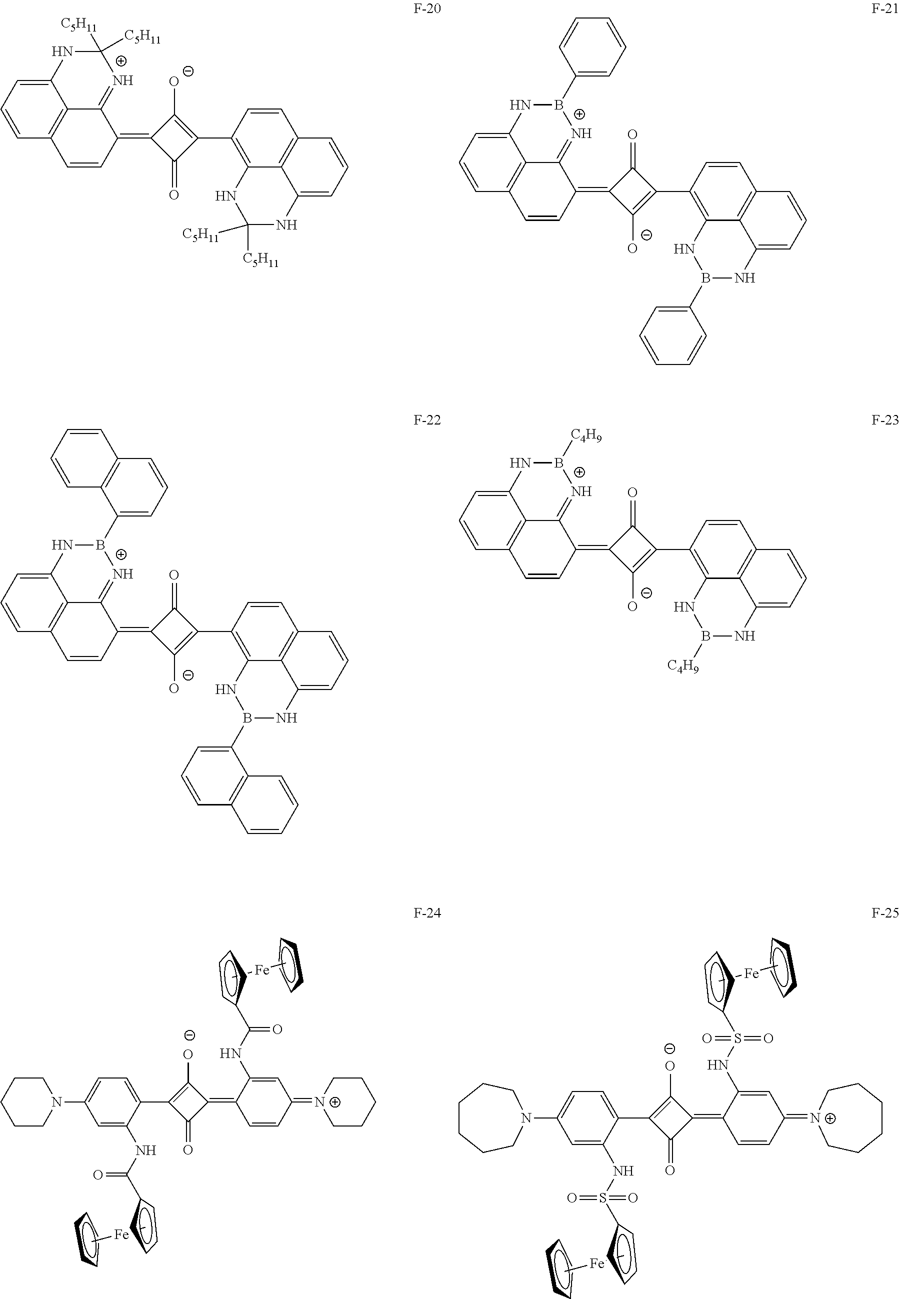

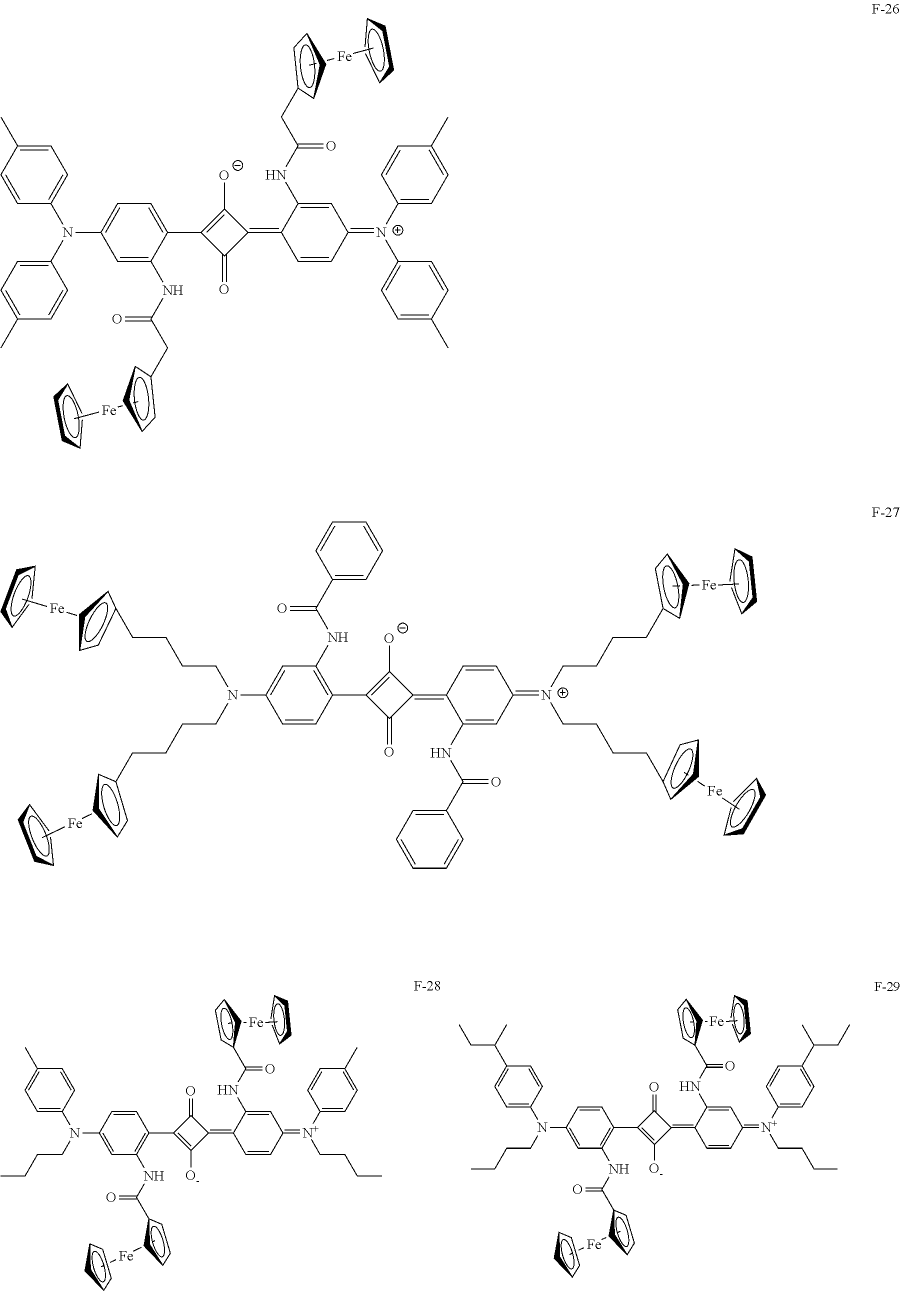

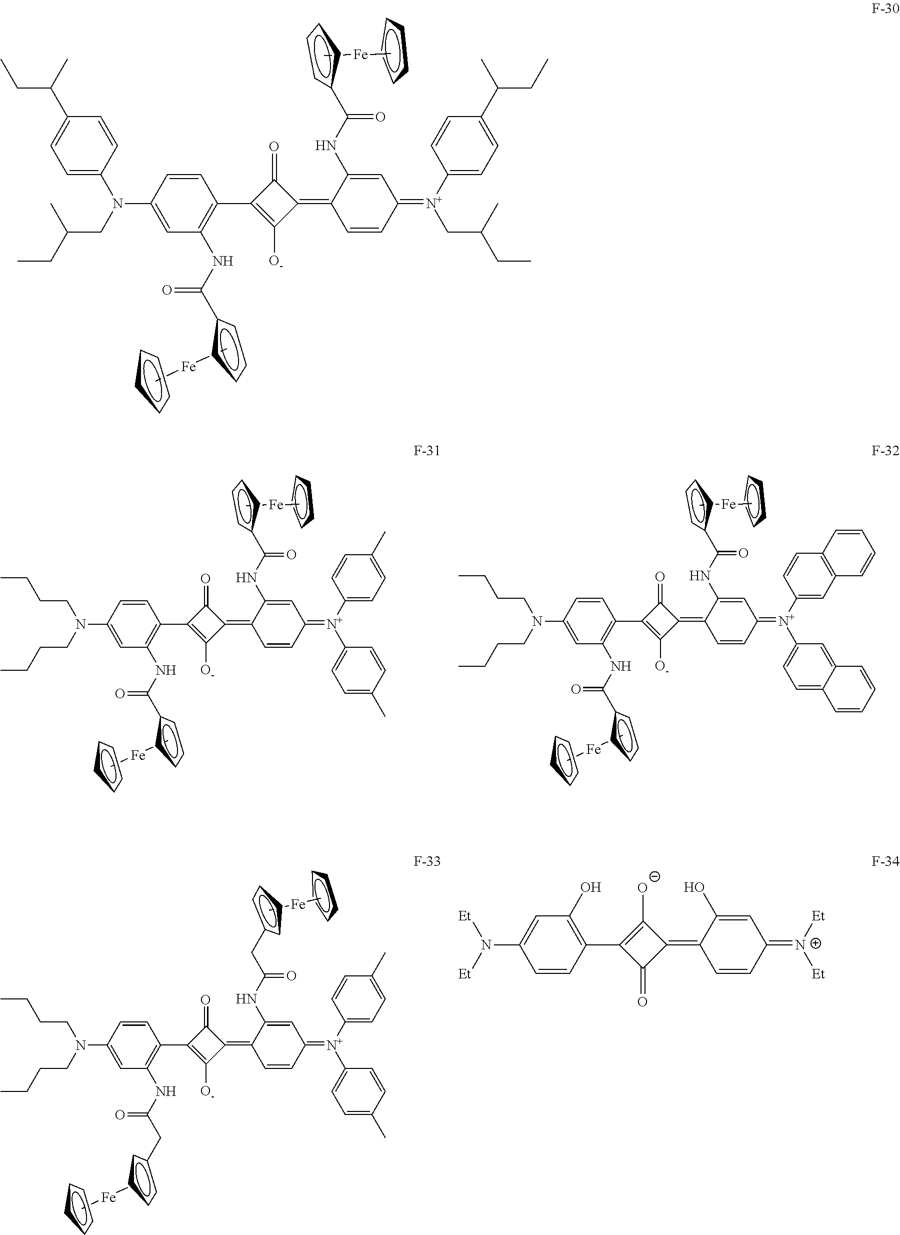

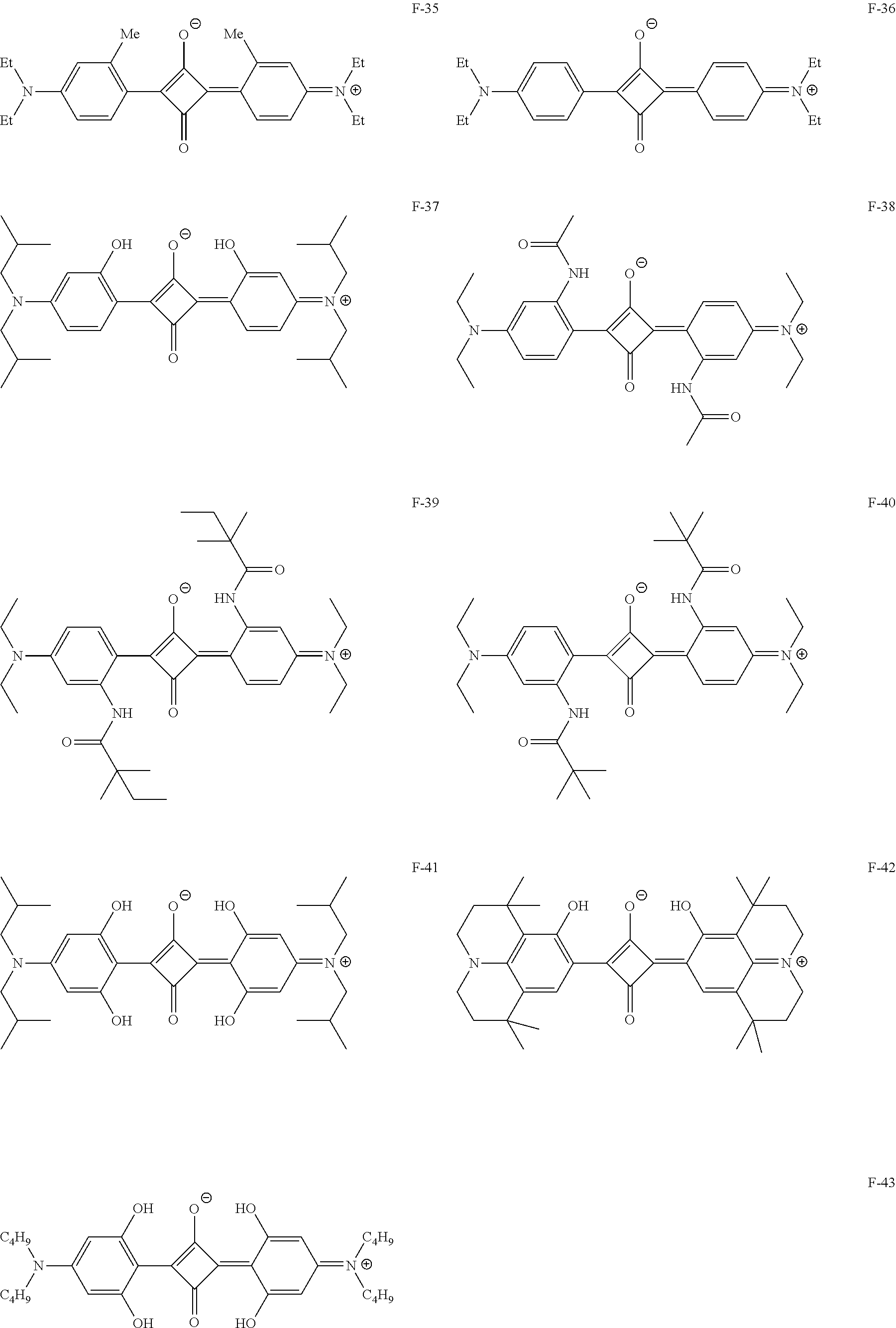

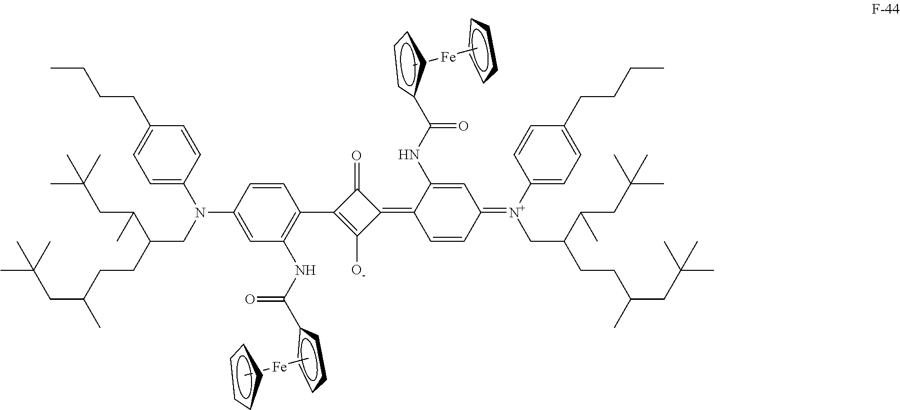

The total content of the dyes A to D in the light absorbing part according to the embodiment of the present invention is not particularly limited as long as the effect of the present invention is exhibited, and it is preferably 0.10% by mass or more, more preferably 0.50% by mass or more, still more preferably 1% by mass or more, and particularly preferably 5% by mass or more. In a case where the total content of the dyes A to D in the light absorbing part is equal to or larger than the above-described preferred lower limit value, a good effect of suppressing external light reflection can be obtained.

In addition, the total content of the dyes A to D in the light absorbing part according to the embodiment of the present invention is generally 50% by mass or less, preferably 40% by mass or less, and more preferably 35% by mass or less, from the viewpoint of the suppression of a decrease in brightness.

The content of each of the dyes A to D that can be contained in the light absorbing part is preferably as follows.

The content of the dye Ain the light absorbing part is preferably 0.01% to 45% by mass, more preferably 1% to 30% by mass, and still more preferably 5% to 30% by mass. The content of the dye B in the light absorbing part is preferably 0.01% to 45% by mass, more preferably 0.1% to 30% by mass, and still more preferably 0.1% to 20% by mass. The content of the dye C in the light absorbing part according to the embodiment of the present invention is preferably 0.01% to 30% by mass and more preferably 0.1% to 25% by mass. The content of the dye D in the light absorbing part is preferably 0.05% to 50% by mass, more preferably 0.2% to 40% by mass, and still more preferably 0.2% to 20% by mass.

In a case where the light absorbing part contains four dyes A to D, the content proportions of the respective dyes A to D in terms of the mass ratio (the dye A:the dye B:the dye C:the dye D) in the light absorbing part are preferably 1:0.05 to 10:0.05 to 5:0.1 to 10, and more preferably 1:0.1 to 5:0.1 to 3:0.2 to 5.

It is noted that in a case where at least one of the dye B or C is a quencher-embedded coloring agent, the content of the quencher-embedded coloring agent in the light absorbing part is preferably 0.1% by mass or more from the viewpoint of suppressing external light reflection. From the viewpoint of suppressing a decrease in brightness, the upper limit value thereof is preferably 45% by mass or less.

<Resin>

It is preferable that the light absorbing part contains a resin (hereinafter, also referred to as a “matrix resin”). The resin is not particularly limited as long as it can disperse (preferably dissolve) the dye and can achieve both the effect of suppressing external light reflection and the effect of suppressing a decrease in brightness at an excellent level. In addition, in a case where an antifading agent for a dye described below is contained in addition to the above-described dye, it is preferable that the antifading agent can be dispersed (preferably dissolved), and the decrease in light resistance of the dye due to the antifading agent can be suppressed. In addition, it is preferable that the original tint of the image of the display device can be maintained at an excellent level.

In a case where at least one of the dye B or C is a squaraine-based coloring agent represented by General Formula (1), the matrix resin is preferably a low-polarity matrix resin in which the squaraine-based coloring agent can suitably satisfy the absorption waveform B or C. In a case of using a squaraine-based coloring agent as the dye B or C exhibiting the absorption waveform B or C, a display device having an organic electroluminescent light emitting element or a micro light emitting diode as a light emitting unit, to which the optical member according to the embodiment of the present invention is applied, can display brightness without significantly impairing the brightness while satisfying the effect of suppressing external light reflection as described above.

Here, the low polarity means that an fd value defined by Relational Expression I is preferably 0.50 or more.

fd=δd/(δd+δp+δh) Relational Expression I:

In Relational Expression I, δd, δp, and δh respectively indicate a term corresponding to a London dispersion force, a term corresponding to a dipole-dipole force, and a term corresponding to a hydrogen bonding force with respect to a solubility parameter St calculated according to the Hoy method. A specific calculation method of fd will be described later. That is, fd indicates a ratio of δd to the sum of δd, δp, and δh.

In a case where the fd value is set to 0.50 or more, the suitable absorption waveforms B and C can be easily obtained.

Further, in a case where the light absorbing part contains two or more matrix resins, the fd value is calculated as follows.

fd=Σ(wᵢ·fdᵢ)

Here, wᵢ represents the mass fraction of the i-th matrix resin, and fdᵢ represents the fd value of the i-th matrix resin.

—Term δd Corresponding to London Dispersion Force—

The term δd corresponding to the London dispersion force refers to δd obtained for the Amorphous Polymers described in the column “2) Method of Hoy (1985, 1989)” on pages 214 to 220 of the document “Properties of Polymers 3^{rd}, ELSEVIER, (1990)”, and is calculated according to the description in the column of the document.

—Term δp Corresponding to Dipole-Dipole Force—

The term δp corresponding to the dipole-dipole force refers to δp obtained for Amorphous Polymers described in the column “2) Method of Hoy (1985, 1989)” on pages 214 to 220 of the document “Properties of Polymers 3^{rd}, ELSEVIER, (1990)”, and is calculated according to the description in the column of the document.

—Term δh Corresponding to Hydrogen Bonding Force—

The term δh corresponding to the hydrogen bonding force refers to δh obtained for the Amorphous Polymers described in the column “2) Method of Hoy (1985, 1989)” on pages 214 to 220 of the document “Properties of Polymers 3^{rd}, ELSEVIER, (1990)”, and is calculated according to the description in the column of the document.

In addition, in a case where the matrix resin is a resin exhibiting a certain hydrophobicity, a moisture content of the light absorbing part can be set to a low moisture content, for example, 0.5% or lower, and the light resistance of the optical member according to the embodiment of the present invention which includes the light absorbing part is improved, which is preferable.

The resin may contain any conventional component in addition to a polymer. However, the fd of the matrix resin is a calculated value for the polymer constituting the matrix resin.

Preferred examples of the matrix resin include a polystyrene resin and a cyclic polyolefin resin, where a polystyrene resin or a cyclic polyolefin resin is more preferably included. In general, the fd value of the polystyrene resin is 0.45 to 0.60, and the fd value of the cyclic polyolefin resin is 0.45 to 0.70. As described above, it is preferable to use the resin having an fd value of 0.50 or more.

Further, for example, in addition to these preferable resins, it is also preferable to use a resin component, that imparts functionality to the light absorbing part, such as an extensible resin component and a peelability control resin component, which will be described later. That is, in the present invention, the matrix resin is used to meant to include the extensible resin component and the peelability control resin component in addition to the above-described resins.

(Polystyrene Resin)

The polystyrene contained in the polystyrene resin means a polymer containing a styrene component. The polystyrene preferably contains 50% by mass or more of the styrene component. The light absorbing part may contain one kind of polystyrene or two or more kinds thereof. Here, the styrene component is a structural unit derived from a monomer having a styrene skeleton in the structure thereof.

The polystyrene more preferably contains 70% by mass or more of the styrene component, and still more preferably 85% by mass or more of the styrene component, in terms of controlling the photo-elastic coefficient and the hygroscopicity to values within a preferred range as the light absorbing part. It is also preferable that the polystyrene is composed of only a styrene component.

Among polystyrenes, examples of the polystyrene composed of only the styrene component include a homopolymer of a styrene compound and a copolymer of two or more kinds of styrene compounds. Here, the styrene compound is a compound having a styrene skeleton in the structure thereof and is meant to include, in addition to styrene, a compound in which a substituent is introduced within a range where an ethylenically unsaturated bond of styrene can act as a reactive (polymerizable) group.

Specific examples of the styrene compound include the following styrenes: alkylstyrene such as α-methylstyrene, o-methylstyrene, m-methylstyrene, p-methylstyrene, 3,5-dimethylstyrene, 2,4-dimethylstyrene, o-ethylstyrene, p-ethylstyrene, and tert-butyl styrene; and substituted styrene having a hydroxyl group, an alkoxy group, a carboxy group, or a halogen atom introduced into the benzene nucleus of styrene, such as hydroxystyrene, tert-butoxy styrene, vinyl benzoic acid, o-chlorostyrene, and p-chlorostyrene. Among these, the polystyrene is preferably a homopolymer of styrene (that is, polystyrene) from the viewpoints of availability and material cost.

The constitutional component other than the styrene component that may be contained in the polystyrene is not particularly limited. That is, the polystyrene may be a styrene-diene copolymer, a styrene-polymerizable unsaturated carboxylic acid ester copolymer, or the like. In addition, it is also possible to use a mixture of polystyrene and synthetic rubber (for example, polybutadiene and polyisoprene). Further, high impact polystyrene (HIPS) obtained by subjecting styrene to graft polymerization with synthetic rubber is also preferable. Further, a polystyrene obtained by dispersing a rubbery elastomer in a continuous phase of a polymer including a styrene component (for example, a copolymer of a styrene component and a (meth)acrylate ester component), and subjecting the copolymer to graft polymerization with a rubber-like elastic body (referred to as graft type high impact polystyrene “graft HIPS”) is also preferable. Furthermore, a so-called styrene-based elastomer can also be suitably used.

In addition, the polystyrene may be hydrogenated (may be a hydrogenated polystyrene). The hydrogenated polystyrene is not particularly limited, and it is preferably a hydrogenated styrene-diene-based copolymer such as a hydrogenated styrene-butadiene-styrene block copolymer (SEBS) obtained by hydrogenating a styrene-butadiene-styrene block copolymer (SBS) or hydrogenated styrene-isoprene-styrene block copolymer (SEPS) obtained by hydrogenating a styrene-isoprene-styrene block copolymer (SIS). Only one of these hydrogenated polystyrenes may be used, or two or more thereof may be used.

In addition, the polystyrene may be modified polystyrene. The modified polystyrene is not particularly limited, and examples thereof include polystyrene having a reactive group such as a polar group introduced therein. Specific examples thereof preferably include acid-modified polystyrene such as maleic acid-modified and epoxy-modified polystyrene.

As the polystyrene, a plurality of kinds of polystyrenes having different compositions, molecular weights, and the like may be used in combination.

The polystyrene-based resin can be obtained using a conventional method such as anion, bulk, suspension, emulsification, or a solution polymerization method. In addition, in the polystyrene, at least a part of the unsaturated double bond of the benzene ring of the conjugated diene and the styrene monomer may be hydrogenated. The hydrogenation rate can be measured by a nuclear magnetic resonance apparatus (NMR).

As the polystyrene resin, a commercially available product may be used, and examples thereof include “CLEAREN 530L” and “CLEAREN 730L” manufactured by Denka Company Limited, “TUFPRENE 126S” and “ASAPRENE T411” manufactured by Asahi Kasei Corporation, “KRATON D1102A”, “KRATON D1116A” manufactured by Kraton Corporation, “STYROLUX S” and “STYROLUX T” manufactured by INEOS Styrolution Group GmbH, “ASAFLEX 840” and “ASAFLEX 860” manufactured by Asahi Kasei Corporation (all are SBS), “679”, “HF77”, and “SGP-10” manufactured by PS Japan Corporation, “DIC STYRENE XC-515” and “DIC STYRENE XC-535” manufactured by DIC Corporation (all are GPPS), “475D”, “H0103”, and “HT478” manufactured by PS Japan Corporation, and “DIC STYRENE GH-8300-5” manufactured by DIC Corporation (all are HIPS). Examples of the hydrogenated polystyrene-based resin include “TUFTEC H series” manufactured by Asahi Kasei Chemicals Corporation, “KRATON G series” manufactured by Shell Japan Ltd. (all are SEBS), “DYNARON” manufactured by JSR Corporation (hydrogenated styrene-butadiene random copolymer), and “SEPTON” manufactured by Kuraray Co., Ltd. (SEPS). Examples of the modified polystyrene-based resin include “TUFTEC M series” manufactured by Asahi Kasei Chemicals Corporation, “EPOFRIEND” manufactured by Daicel Corporation, “Polar Group Modified DYNARON” manufactured by JSR Corporation, and “RESEDA” manufactured by Toagosei Co., Ltd.

The light absorbing part preferably contains a polyphenylene ether resin in addition to the polystyrene resin. By containing the polystyrene resin and the polyphenylene ether resin together, the toughness of the light absorbing part can be improved, and the occurrence of defects such as cracks can be suppressed even in a harsh environment such as high temperature and high humidity.

However, in the calculation of the fd value described above, the fd value of the polyphenylene ether resin is not taken into consideration, in a case where the light absorbing part according to the embodiment of the present invention contains a polyphenylene ether resin addition to the polystyrene resin.

As the polyphenylene ether resin, XYRON S201A, XYRON 202A, XYRON S203A, and the like, manufactured by Asahi Kasei Corporation, can be preferably used. In addition, a resin which the polystyrene resin and the polyphenylene ether resin are mixed in advance may also be used. As the mixed resin of the polystyrene resin and the polyphenylene ether resin, for example, XYRON 1002H, XYRON 1000H, XYRON 600H, XYRON 500H, XYRON 400H, XYRON 300H, XYRON 200H, and the like manufactured by Asahi Kasei Corporation can be preferably used.

In a case where the polystyrene resin and the polyphenylene ether resin are contained in the light absorbing part, the mass ratio of both resins is preferably 99/1 to 50/50, more preferably 98/2 to 60/40, and still more preferably 95/5 to 70/30, in terms of the polystyrene resin/polyphenylene ether resin. In a case where the formulation ratio of the polyphenylene ether resin is set in the above-described preferred range, the light absorbing part can have sufficient toughness, and the solvent can be properly volatilized in a case where a film is formed with a solution.

(Cyclic Polyolefin Resin)

The cyclic olefin compound that forms the cyclic polyolefin contained in the cyclic polyolefin resin is not particularly limited as long as the compound has a ring structure including a carbon-carbon double bond, and examples thereof include a norbornene compound and a monocyclic olefin compound, a cyclic conjugated diene compound, and a vinyl alicyclic hydrocarbon compound, which are not the norbornene compound.

Examples of the cyclic polyolefin include (1) polymers including a structural unit derived from a norbornene compound; (2) polymers including a structural unit derived from a monocyclic olefin compound other than the norbornene compound; (3) polymers including a structural unit derived from a cyclic conjugated diene compound; (4) polymers including a structural unit derived from a vinyl alicyclic hydrocarbon compound; and hydrides of polymers including a structural unit derived from each of the compounds (1) to (4).

In the present invention, ring-opening polymers of the respective compounds are included in the polymers including a structural unit derived from a norbornene compound and the polymers including a structural unit derived from a monocyclic olefin compound.

The cyclic polyolefin is not particularly limited; however, it is preferably a polymer having a structural unit derived from a norbornene compound, which is represented by General Formula (A-II) or (A-III). The polymer having the structural unit represented by General Formula (A-II) is an addition polymer of a norbornene compound, and the polymer having the structural unit represented by General Formula (A-III) is a ring-opening polymer of a norbornene compound.

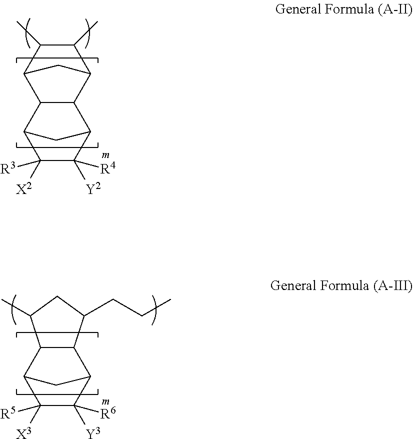

In General Formulae (A-II) and (A-III), m is an integer of 0 to 4 and preferably 0 or 1.

In General Formulae (A-II) and (A-III), R³ to R⁶ each independently represent a hydrogen atom or a hydrocarbon group having 1 to 10 carbon atoms.

The hydrocarbon group in General Formulae (A-I) to (A-III) is not particularly limited as long as the hydrocarbon group is a group consisting of a carbon atom and a hydrogen atom, and examples thereof include an alkyl group, an alkenyl group, an alkynyl group, and an aryl group (an aromatic hydrocarbon group). Among these, an alkyl group or an aryl group is preferable.

In General Formula (A-II) or (A-III), X² and X³, and Y² and Y³ each independently represent a hydrogen atom, a hydrocarbon group having 1 to 10 carbon atoms, a halogen atom, a hydrocarbon group having 1 to 10 carbon atoms, which is substituted with a halogen atom, —(CH₂)ₙCOOR¹¹, —(CH₂)ₙOCOR¹², —(CH₂)ₙNCO, —(CH₂)ₙNO₂, —(CH₂)ₙCN, —(CH₂)ₙCONR¹³R¹⁴, —(CH₂)ₙNR¹³R¹⁴, —(CH₂)ₙOZ or —(CH₂)ₙW, or (—CO)₂O or (—CO)₂NR⁵ which is formed by bonding X² and Y² or X³ and Y³ to each other.

Here, R¹¹ to R¹⁵ each independently represent a hydrogen atom or a hydrocarbon group having 1 to 20 carbon atoms, Z represents a hydrocarbon group or a hydrocarbon group substituted with halogen, W represents Si(R¹⁶)ₚD₍₃₋ₚ₎ (R¹⁶ represents a hydrocarbon group having 1 to 10 carbon atoms, D represents a halogen atom, —OCOR¹⁷, or —OR¹⁷ (R¹⁷ represents a hydrocarbon group having 1 to 10 carbon atoms), and p is an integer of 0 to 3). n is an integer of 0 to 10, preferably 0 to 8, and more preferably 0 to 6.

In General Formulae (A-II) and (A-III), R³ to R⁶ are each preferably a hydrogen atom or —CH₃, and, in terms of moisture permeability, more preferably a hydrogen atom.

X² and X³ are each preferably a hydrogen atom, —CH₃, or —C₂H₅ and more preferably a hydrogen atom in terms of moisture permeability.

Y² and Y³ are each preferably a hydrogen atom, a halogen atom (particularly a chlorine atom), or —(CH₂)ₙCOOR¹¹ (particularly —COOCH₃) and more preferably a hydrogen atom in terms of moisture permeability.

Other groups are appropriately selected.

The polymer having the structural unit represented by General Formula (A-II) or (A-III) may further include at least one or more structural units represented by General Formula (A-I).

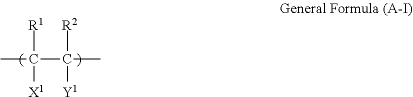

In General Formula (A-I), R¹ and R² each independently represent a hydrogen atom or a hydrocarbon group having 1 to 10 carbon atoms, and X¹ and Y¹ each independently represent a hydrogen atom, a hydrocarbon group having 1 to 10 carbon atoms, a halogen atom, a hydrocarbon group having 1 to 10 carbon atoms, which is substituted with a halogen atom, —(CH₂)ₙCOOR¹¹, —(CH₂)ₙOCOR¹², —(CH₂)ₙNCO, —(CH₂)ₙNO₂, —(CH₂)ₙCN, —(CH₂)ₙCONR¹³R¹⁴, —(CH₂)ₙNR¹³R¹⁴, —(CH₂)ₙOZ, —(CH₂)ₙW, or (—CO)₂O or (—CO)₂NR¹⁵ which is formed by bonding X¹ and Y¹ to each other.

Here, R¹¹ to R¹⁵ each independently represent a hydrogen atom or a hydrocarbon group having 1 to 20 carbon atoms, Z represents a hydrocarbon group or a hydrocarbon group substituted with halogen, W represents Si(R¹⁶)ₚD₍₃₋ₚ₎ (R¹⁶ represents a hydrocarbon group having 1 to 10 carbon atoms, D represents a halogen atom, —OCOR¹⁷, or —OR¹⁷ (R¹⁷ represents a hydrocarbon group having 1 to 10 carbon atoms), and p is an integer of 0 to 3). n is an integer of 0 to 10.

From the viewpoint of adhesiveness, the content of the structural unit derived from a norbornene compound in the cyclic polyolefin having the structural unit represented by General Formula (A-II) or (A-III) is preferably 90% by mass or less, more preferably 30% to 85% by mass, still more preferably 50% to 79% by mass, and most preferably 60% to 75% by mass with respect to the total mass of the cyclic polyolefin. Here, the proportion of the structural unit derived from a norbornene compound represents the average value in the cyclic polyolefin.

The addition (co)polymer of a norbornene compound is described in JP1998-7732A (JP-H10-7732A), JP2002-504184A, US2004/229157A1, and WO2004/070463A.

The polymer of a norbornene compound is obtained by the addition polymerization of norbornene compounds (for example, polycyclic unsaturated compounds of norbornene).

In addition, as the polymer of a norbornene compound, copolymers obtained by the addition copolymerization of, as necessary, a norbornene compound, olefin such as ethylene, propylene, and butene, conjugated diene such as butadiene and isoprene, unconjugated diene such as ethylidene norbornene, and an ethylenically unsaturated compound such as acrylonitrile, acrylic acid, methacrylic acid, maleic acid anhydride, acrylic acid ester, methacrylic acid ester, maleimide, vinyl acetate, and vinyl chloride are exemplified. Among these, a copolymer of a norbornene compound and ethylene is preferable.

Examples of the addition (co)polymers of a norbornene compound include APL8008T (Tg: 70° C.), APL6011T (Tg: 105° C.), APL6013T (Tg: 125° C.), and APL6015T (Tg: 145° C.), which are available from Mitsui Chemicals, Inc. under a product name of APEL and have glass transition temperatures (Tg) different from each other. In addition, pellets such as TOPAS8007, TOPAS6013, and TOPAS6015 are commercially available from Polyplastics Co., Ltd. Further, Appear 3000 is commercially available from Film Ferrania S. R. L.

As the polymer of a norbornene compound, a commercially available product can be used. For example, it is commercially available from JSR Corporation under a product name of Arton G or Arton F, and it is also commercially available from Zeon Corporation under a product name of Zeonor ZF14, ZF16, Zeonex 250, or Zeonex 280.

The hydride of a polymer of a norbornene compound can be synthesized by the addition polymerization or the metathesis ring-opening polymerization of a norbornene compound or the like and then the addition of hydrogen. The synthesis method is described in, for example, JP1989-240517A (JP-H1-240517A), JP1995-196736A (JP-H7-196736A), JP1985-26024A (JP-S60-26024A), JP1987-19801A (JP-S62-19801A), JP2003-159767A, and JP2004-309979A.

The molecular weight of the cyclic polyolefin is appropriately selected depending on the intended use, and it is a mass average molecular weight measured in terms of polyisoprene or polystyrene by the gel permeation chromatography of a cyclohexane solution (a toluene solution in a case where the polymer is not dissolved). Usually, it is preferably 5,000 to 500,000, more preferably 8,000 to 200,000, and still more preferably 10,000 to 100,000. A polymer having a molecular weight in the above-described range is capable of satisfying both the mechanical strength of a molded body and the molding workability of compacts at a high level in a well-balanced manner.

In the light absorbing part, the content of the matrix resin is preferably 5% by mass or more, more preferably 20% by mass or more, still more preferably 30% by mass or more, and particularly preferably 45% by mass or more.

The content of the matrix resin in the light absorbing part is generally 99.90% by mass or less and preferably 99.85% by mass or less.

Each of the components of the matrix resin contained in the light absorbing part may be two or more kinds, and polymers that differ in at least one of the compositional ratio or the molecular weight may be used in combination. In this case, the total content of the respective polymers is in the above range.

(Extensible Resin Component)

The light absorbing part can appropriately select and contain a component exhibiting extensibility (also referred to as an extensible resin component) as a resin component. Specific examples thereof include an acrylonitrile-butadiene-styrene resin (an ABS resin), a styrene-butadiene resin (an SB resin), an isoprene resin, a butadiene resin, a polyether-urethane resin, and a silicone resin. Further, these resins may be further hydrogenated as appropriate.

As the extensible resin component, it is preferable to use an ABS resin or an SB resin, and it is more preferable to use an SB resin.

As the SB resin, for example, a commercially available one can be used. Examples of such commercially available products include TR2000, TR2003, and TR2250 (all, product name, manufactured by JSR Corporation); CLEAREN 210M, 220M, and 730V (all, product name, manufactured by Denka Corporation); ASAFLEX 800S, 805, 810, 825, 830, and 840 (all, product name, manufactured by Asahi Kasei Corporation); and EPOREX SB2400, SB2610, and SB2710 (all, product name, Sumitomo Chemical Co., Ltd.).

The light absorbing part preferably contains an extensible resin component in the matrix resin in an amount of 15% to 95% by mass, more preferably 20% to 50% by mass, and still more preferably 25% to 45% by mass.

The extensible resin component is preferably an extensible resin component having a breaking elongation of 10% or more and more preferably an extensible resin component having a breaking elongation of 20% or more, in a case where a sample having a form with a thickness of 30 μm and a width of 10 mm is produced by using the extensible resin component alone and the breaking elongation at 25° C. is measured in accordance with JIS 7127.

(Peelability Control Resin Component)

The light absorbing part can contain, as a resin component, a component that controls the peelability (a peelability control resin component) in a case of being produced according to a method including a step of peeling a light absorbing part from a release film, among the manufacturing methods for a light absorbing part described later, which is preferable. By controlling the peelability of the light absorbing part from the release film, it is possible to prevent a peeling mark from being left on the light absorbing part after peeling, and it is possible to cope with various processing speeds in the peeling step. As a result, a preferred effect can be obtained for improving the quality and productivity of the light absorbing part.

The peelability control resin component is not particularly limited and can be appropriately selected depending on the kind of the release film. In a case where a polyester-based polymer film is used as the release film as described later, for example, a polyester resin (also referred to as a polyester-based additive) is suitable as the peelability control resin component.

The polyester-based additive can be obtained by a conventional method such as a dehydration condensation reaction of a polyhydric basic acid and a polyhydric alcohol and an addition of a dibasic anhydride to a polyhydric alcohol and a dehydration condensation reaction, and a polycondensation ester formed from a dibasic acid and a diol is preferable.

The mass average molecular weight (Mw) of the polyester-based additive is preferably 500 to 50,000, more preferably 750 to 40,000, and still more preferably 2,000 to 30,000.

In a case where the mass average molecular weight of the polyester-based additive is equal to or larger than the above-described preferred lower limit value, it is preferable from the viewpoint of brittleness and moisture-heat resistance, and in a case where the mass average molecular weight thereof is equal to or smaller than the above-described preferred upper limit value, it is preferable from the viewpoint of compatibility with the resin.

The mass average molecular weight of the polyester-based additive is a value of the mass average molecular weight (Mw) in terms of standard polystyrene measured under the following conditions. The molecular weight distribution (Mw/Mn) can also be measured under the same conditions. Mn is a number average molecular weight in terms of standard polystyrene.

GPC: Gel permeation chromatograph device (HLC-8220GPC manufactured by Tosoh Corporation,

column: Guard column HXL-H manufactured by Tosoh Corporation, where TSK gel G7000HXL, TSK gel GMHXL 2 pieces, and TSK gel G2000HXL are connected in sequence,

eluent: tetrahydrofuran,

flow velocity: 1 mL/min,

sample concentration: 0.7% to 0.8% by mass,

sample injection volume: 70 μL,

measurement temperature: 40° C.,

detector: differential refractometer (RI) meter (40° C.), and

standard substance: TSK standard polystyrene manufactured by Tosoh Corporation)

Preferred examples of the dibasic acid component constituting the polyester-based additive include dicarboxylic acid.

Examples of the dicarboxylic acid include an aliphatic dicarboxylic acid and an aromatic dicarboxylic acid. An aromatic dicarboxylic acid or a mixture of an aromatic dicarboxylic acid and an aliphatic dicarboxylic acid can be preferably used.

Among the aromatic dicarboxylic acids, an aromatic dicarboxylic acid having 8 to 20 carbon atoms is preferable, and an aromatic dicarboxylic acid having 8 to 14 carbon atoms is more preferable. Specifically, preferred examples thereof include at least one of phthalic acid, isophthalic acid, or terephthalic acid.

Among the aliphatic dicarboxylic acids, an aliphatic dicarboxylic acid having 3 to 8 carbon atoms is preferable, and an aliphatic dicarboxylic acid having 4 to 6 carbon atoms is more preferable. Specifically, preferred examples thereof include at least one of succinic acid, maleic acid, adipic acid, or glutaric acid, and at least one of succinic acid or adipic acid is more preferable.

Examples of the diol component constituting the polyester-based additive include an aliphatic diol and an aromatic diol, and aliphatic diol is preferable.

Among the aliphatic diols, an aliphatic diol having 2 to 4 carbon atoms is preferable, and an aliphatic diol having 2 to 3 carbon atoms is more preferable.

Examples of the aliphatic diol include ethylene glycol, diethylene glycol, 1,2-propylene glycol, 1,3-propylene glycol, 1,3-butylene glycol, and 1,4-butylene glycol. These aliphatic diols can be used alone, or two or more kinds thereof can be used in combination.

The polyester-based additive is particularly preferably a compound obtained by fusing at least one of phthalic acid, isophthalic acid, or terephthalic acid with an aliphatic diol.

The terminal of the polyester-based additive may be sealed by reacting with a monocarboxylic acid. The monocarboxylic acid that is used for sealing is preferably an aliphatic monocarboxylic acid. Preferred examples thereof include acetic acid, propionic acid, butanoic acid, benzoic acid, and a derivative thereof, where acetic acid or propionic acid is more preferable and acetic acid is still more preferable.

Examples of the commercially available polyester-based additive include ester-based resin polyesters manufactured by Nippon Synthetic Chemical Industry Co., Ltd. (for example, LP050, TP290, LP035, LP033, TP217, and TP220) and ester-based resins Byron manufactured by Toyobo Co., Ltd. (for example, Byron 245, Byron GK890, Byron 103, Byron 200, Byron 550, and Byron GK880).

The content of the peelability control resin component in the light absorbing part is preferably 0.05% by mass or more, and more preferably 0.1% by mass or more in the matrix resin. In addition, the upper limit value thereof is preferably 25% by mass or less, more preferably 20% by mass or less, and still more preferably 15% by mass or less. From the viewpoint of obtaining proper adhesiveness, the above-described preferred range is preferable.

<Antifading Agent>

The light absorbing part preferably contains the antifading agent for a dye (simply also referred to as an antifading agent) in order to prevent the fading of the dye. For example, the antifading agent is dispersed (preferably dissolved) in the resin to capture radicals such as singlet oxygen and to be oxidized instead of the dye, and can effectively suppress the fading of the dye. As the antifading agent, it is possible to use commonly used antifading agents without particular limitation, such as the antioxidants described in paragraphs [0143] to [0165] of WO2015/005398A, the radical scavengers described in paragraphs [0166] to [0199] of WO2015/005398A, and the deterioration preventing agents described in paragraphs [0205] to [206] of WO2015/005398A.

The compound represented by General Formula (IV) below can be preferably used as the antifading agent.

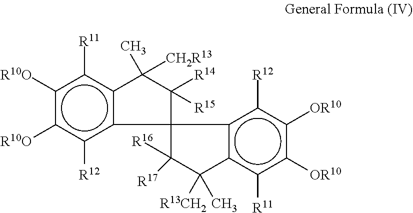

In General Formula (IV), R¹⁰'s each independently represent an alkyl group, an alkenyl group, an aryl group, a heterocyclic group, or a group represented by R¹⁸CO—, R¹⁹SO₂—, or R²⁰NHCO—. Here, R¹⁸, R¹⁹, and R²⁰ each independently represent an alkyl group, an alkenyl group, an aryl group, or a heterocyclic group. R¹¹ and R¹² each independently represent a hydrogen atom, a halogen atom, an alkyl group, an alkenyl group, an alkoxy group, or an alkenyloxy group, and R¹³ to R¹⁷ each independently represent a hydrogen atom, an alkyl group, an alkenyl group, or an aryl group.

However, the alkyl group in R¹⁰ to R²⁰ includes an aralkyl group.

Examples of the alkyl group represented by R¹⁰ in General Formula (IV) include methyl, ethyl, propyl, and benzyl; examples of the alkenyl group include allyl; examples of the aryl group include phenyl; and examples of the heterocyclic group include tetrahydropyranyl and pyrimidyl. R¹⁸, R¹⁹, and R²⁰ each independently represent an alkyl group (for example, methyl, ethyl, n-propyl, n-butyl, or benzyl), an alkenyl group (for example, allyl), an aryl group (for example, phenyl, or methoxyphenyl), or a heterocyclic group (for example, pyridyl, or pyrimidyl).

Examples of the halogen atom represented by R¹¹ and R¹² in General Formula (IV) include chlorine and bromine; examples of the alkyl group include methyl, ethyl, n-butyl, and benzyl; examples of the alkenyl group include allyl; examples of the alkoxy group include methoxy, ethoxy, and benzyloxy; and examples of the alkenyloxy group include 2-propenyloxy.

Examples of the alkyl group represented by R¹³, R¹⁴, R¹⁵, R¹⁶, and R¹⁷ in General Formula (IV) include methyl, ethyl, n-butyl, and benzyl; examples of the alkenyl group include 2-propenyl; and examples of the aryl group include phenyl, methoxyphenyl, and chlorophenyl.

R¹⁰ to R²⁰ may further have a substituent, and examples of the substituent include each group represented by R¹⁰ to R²⁰.

Specific examples of the compound represented by General Formula (IV) are shown below. However, the present invention is not limited thereto.

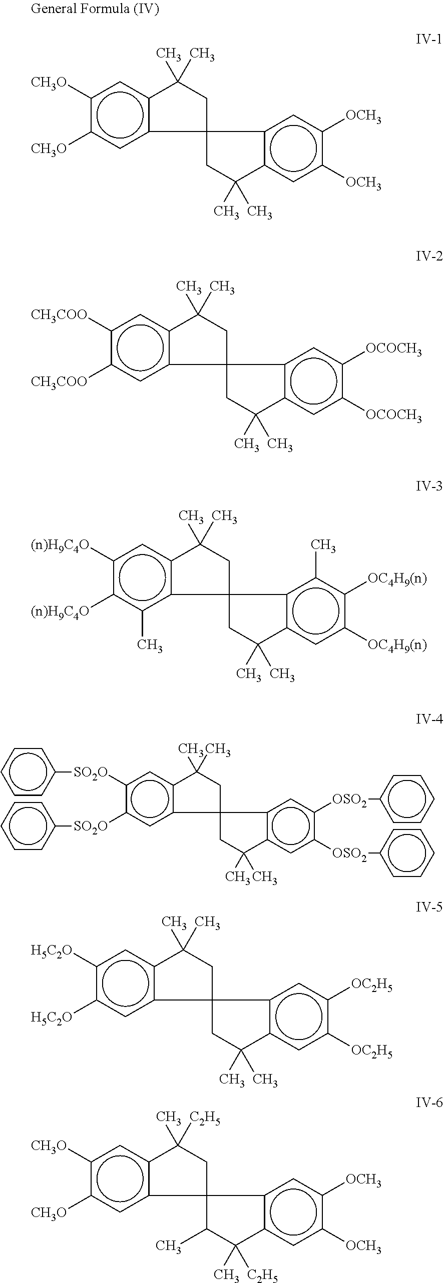

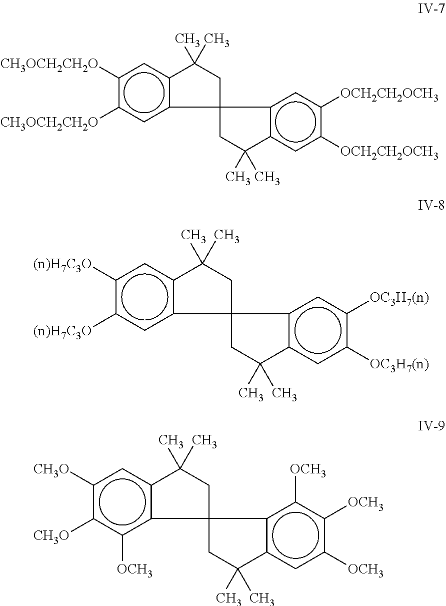

As the antifading agent, the compound represented by General Formula [III] can also be preferably used.

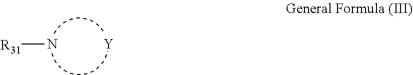

In General Formula [III], R³¹ represents an aliphatic group or an aromatic group, and Y represents a non-metal atomic group necessary for forming a 5- to 7-membered ring with a nitrogen atom.

Next, in General Formula [III], R³¹ represents an aliphatic group or an aromatic group, and is preferably an alkyl group, an aryl group, or a heterocyclic group (preferably, an aliphatic heterocyclic group), and more preferably an aryl group.

Examples of the heterocyclic ring formed by Y together with the nitrogen atom include a piperidine ring, a piperazine ring, a morpholine ring, a thiomorpholine ring, a thiomorpholine-1,1-dione ring, a pyrrolidine ring, and an imidazolidine ring.

In addition, the heterocyclic ring may further have a substituent, and examples of the substituent include an alkyl group and an alkoxy group.

Specific examples of the compound represented by General Formula [III] are shown below. However, the present invention is not limited thereto.

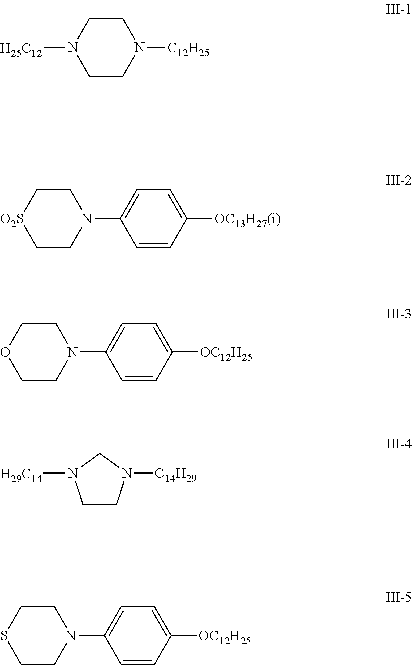

In addition to the above-described specific examples, specific examples of the compound represented by General Formula [III] above include exemplary compounds B-1 to B-65 described on pages 8 to 11 of JP1990-167543A (JP-H2-167543A), and exemplary compounds (1) to (120) described on pages 4 to 7 of JP1988-95439A (JP-S63-95439A).

The content of the antifading agent in the light absorbing part is preferably 0.1% to 15% by mass, more preferably 1% to 15% by mass, still more preferably 5% to 15% by mass, and particularly preferably 5% to 12.5% by mass, and among them, it is preferably 5% to 10% by mass and most preferably 5% to 8% by mass, in 100% by mass of the total mass of the light absorbing part.

In a case where the antifading agent is contained within the above-described preferred range, the optical member according to the embodiment of the present invention can improve the light resistance of the dye (the coloring agent) without causing side effects such as discoloration of the light absorbing part.

<Other Components>

The light absorbing part may contain a matting agent, a leveling (surfactant) agent, or the like as other components other than the dye, the matrix resin, and the antifading agent for a dye.

(Matting Agent)

It is preferable to add fine particles to the surface of the light absorbing part in order to impart sliding properties and prevent blocking. As the fine particles, silica (silicon dioxide, SiO₂) of which the surface is coated with a hydrophobic group and which has an aspect of secondary particles is preferably used. As the fine particles, in addition to or instead of silica, fine particles of titanium dioxide, aluminum oxide, zirconium oxide, calcium carbonate, talc, clay, calcined kaolin, calcined calcium silicate, hydrated calcium silicate, aluminum silicate, magnesium silicate, and calcium phosphate may be used. Examples of the commercially available product of the fine particles include the R972 or NX90S (product name, both manufactured by Nippon Aerosil Co., Ltd.).

The fine particles function as a so-called matting agent, and the addition of the fine particles forms fine unevenness on the surface of the light absorbing part. Due to the unevenness, even in a case where the light absorbing parts overlap each other or the light absorbing part of the present invention and other films overlap each other, the films do not stick to each other and sliding properties are secured.

In a case where the light absorbing part contains a matting agent as fine particles, the effect of improving sliding properties and blocking properties is particularly large in the fine unevenness due to the protrusions in which fine particles protrude from the filter surface in a case where there are 10⁴/mm² or more of protrusions having a height of 30 nm or more.

It is preferable to apply the matting agent fine particles particularly onto the surface layer in order to improve the blocking properties and the sliding properties. Examples of the method of applying fine particles onto the surface layer include methods such as multilayer casting and coating.

The content of the matting agent in the light absorbing part is appropriately adjusted depending on the intended purpose.

However, in a case where a gas barrier layer described later is provided in the optical member according to the embodiment of the present invention, the above-described matting agent fine particles are preferably applied onto the surface of the light absorbing part in contact with the gas barrier layer as long as the effect of the present invention is not impaired.

(Leveling Agent)

A leveling agent (surfactant) can be appropriately mixed with the light absorbing part. As the leveling agent, a commonly used compound can be used, and a fluorine-containing surfactant is particularly preferable. Specific examples thereof include the compounds described in paragraphs [0028] to [0056] of JP2001-330725A.

The content of the leveling agent in the light absorbing part is appropriately adjusted depending on the intended purpose.

The light absorbing part may contain, in addition to the above components, a low-molecular plasticizer, an oligomer-based plasticizer, a retardation modifier, an ultraviolet absorbing agent, a deterioration preventing agent, a peeling accelerating agent, an infrared absorbing agent, an antioxidant, a filler, a compatibilizer.

<Manufacturing Method for Light Absorbing Part>

The light absorbing part can be produced by a solution film-forming method, a melt extrusion method, or a method of forming a coating layer on a base material film (release film) (coating method) according to any method, according to a conventional method, and stretching can also be appropriately combined. The light absorbing part is preferably produced by a coating method.

(Solution Film-Forming Method)

In the solution film-forming method, a solution in which a material constituting the light absorbing part is dissolved in an organic solvent or water is prepared, a concentration step, a filtration step, and the like are appropriately carried out, and then the solution is uniformly cast on a support. Next, the raw dry film is peeled off from the support, both ends of a web are appropriately held by clips or the like, and the solvent is dried in the drying zone. In addition, stretching can be carried out separately while or after the film is dried.

(Melt Extrusion Method)

In the melt extrusion method, a material constituting the light absorbing part (hereinafter, also simply referred to as a “material of the light absorbing part”) is melted by heat, a filtration step or the like is appropriately carried out, and then the material is uniformly casted on a support. Next, a film solidified by cooling or the like can be peeled off and appropriately stretched. In a case where the main material of the light absorbing part is a thermoplastic polymer resin, a thermoplastic polymer resin can be selected as the main material of the release film, and the polymer resin in a molten state can be formed into a film by a known co-extrusion method. In this case, by adjusting the polymer kind of the light absorbing part and the release film and the additives mixed in each layer, or by adjusting the stretching temperature, the stretching speed, the stretching ratio, and the like of the co-extruded film, the adhesive force between the light absorbing part and the release film can be controlled.

Examples of the co-extrusion method include a co-extrusion T-die method, a co-extrusion inflation method, and a co-extrusion lamination method. Among these, the co-extrusion T-die method is preferable. The co-extrusion T-die method includes a feed block method and a multi-manifold method. Among these, the multi-manifold method is particularly preferable from the viewpoint that a variation in thickness can be reduced.

In a case where the co-extrusion T-die method is adopted, the melting temperature of the resin in an extruder having a T-die is set to be a temperature higher than the glass transition temperature (Tg) of each resin by preferably 80° C. or higher and more preferably 100° C. or higher, and the upper limit value thereof is set to be a temperature higher than the glass transition temperature (Tg) of each resin by preferably 180° C. or lower and more preferably 150° C. or lower. In a case where the melting temperature of the resin in the extruder is set to be equal to or larger than the lower limit value of the above-described preferred range, the fluidity of the resin can be sufficiently enhanced, and in a case where the melting temperature is set to the upper limit value or less of the above-described preferred range, the resin can be prevented from being deteriorated.

In general, the sheet-shaped molten resin extruded from the opening portion of the die is brought into close contact with the cooling drum. The method of bringing the molten resin into close contact with the cooling drum is not particularly limited, and examples thereof include an air knife method, a vacuum box method, and an electrostatic contact method.

The number of cooling drums is not particularly limited; however, it is generally 2 or more. In addition, the method of disposing the cooling drum is not particularly limited, and examples of the disposition form include a linear form, a Z form, and an L form. Further, the method of passing the molten resin extruded from the opening portion of the die through the cooling drum is not particularly limited.

The degree of close contact of the extruded sheet-shaped resin with the cooling drum changes depending on the temperature of the cooling drum. In a case where the temperature of the cooling drum is raised, the intimate attachment is improved, but in a case where the temperature is raised too much, the sheet-shaped resin may not be peeled off from the cooling drum and may be wound around the drum. Therefore, the temperature of the cooling drum is preferably (Tg+30°) C or lower, and more preferably in a range of (Tg−5°) C to (Tg−45°) C in a case where Tg is the glass transition temperature of the resin of the layer that is brought into contact with the drum in the resin extruded from the die. In a case where the cooling drum temperature is set within the above-described preferred range, problems such as sliding and scratches can be prevented.

Here, it is preferable to reduce the content of the residual solvent in the film before stretching. Examples of the method of reducing the content include methods of (1) reducing the amount of the residual solvent of the resin as the raw material; and (2) predrying the resin before forming the film before stretching. Predrying is carried out, for example, by making the resin into a form of a pellet or the like and using a hot air dryer or the like. The drying temperature is preferably 100° C. or higher, and the drying time is preferably 2 hours or longer. In a case of carrying out predrying, it is possible to reduce the residual solvent in the film before stretching and to prevent the extruded sheet-shaped resin from foaming.

(Coating Method)

In the coating method, a solution of a material of the light absorbing part is applied to a release film to form a coating layer. A release agent or the like may be appropriately applied to the surface of the release film in advance in order to control the adhesiveness to the coating layer. The coating layer can be used by peeling off the release film after being laminated with another member while interposing an adhesive layer in a later step. Any adhesive can be appropriately used as the adhesive constituting the adhesive layer. The whole release film can be appropriately stretched in a state where a solution of the material of the light absorbing part is applied on the release film or in a state where a coating layer is laminated on the release film.

The solvent that is used for the solution of the material of the light absorbing part can be appropriately selected from the viewpoints that the material of the light absorbing part can be dissolved or dispersed, that a uniform surface shape can be easily achieved during the coating step and drying step, liquid storability can be secured, and that a proper saturated vapor pressure is provided.

—Addition of Dye (Coloring Agent)—

The timing of adding the dye to the light absorbing part material is not particularly limited as long as the dye and the antifading agent are added at the time of film formation. For example, the dye may be added at the time of synthesizing the matrix resin, or may be mixed with the material of the light absorbing part at the time of preparing the coating liquid for the material of the light absorbing part. In addition, the same applies to various additives.

—Release Film—

The release film that is used for forming the light absorbing part by a coating method or the like preferably has a film thickness of 5 to 100 μm, more preferably 10 to 75 μm, and still more preferably 15 to 55 μm. In a case where the film thickness is equal to or larger than the above-described preferred lower limit value, sufficient mechanical strength can be easily secured, and failures such as curling, wrinkling, and buckling are less likely to occur. In addition, in a case where the film thickness is equal to or smaller than the above-described preferred upper limit value, in the storage of a multi-layer film of the release film and the light absorbing part, for example, in the form of a long roll, the surface pressure applied to the multi-layer film is easily adjusted to be in an appropriate range, and adhesion defect is less likely to occur.

The surface energy of the release film is not particularly limited, and by adjusting the relationship between the surface energy of the material of the light absorbing part or the coating solution and the surface energy of the surface of the release film on which the light absorbing part is to be formed, the adhesive force between the light absorbing part and the release film can be adjusted. In a case where the surface energy difference is reduced, the adhesive force tends to increase, and in a case where the surface energy difference is increased, the adhesive force tends to decrease, and thus the surface energy can be set appropriately.

The surface energy of the release film can be calculated from the contact angle value between water and methylene iodide using the Owen's method. For the measurement of the contact angle, for example, DM901 (contact angle meter, manufactured by Kyowa Interface Science Co., Ltd.) can be used.

The surface energy of the surface of the release film on which the light absorbing part is to be formed is preferably 41.0 to 48.0 mN/m and more preferably 42.0 to 48.0 mN/m. In a case where the surface energy is equal to or larger than the above-described preferred lower limit value, the evenness of the thickness of the light absorbing part is increased. In a case where the surface energy is equal to or smaller than the above-described preferred upper limit value, it is easy to control the peeling force of the light absorbing part from the release film within an appropriate range.

The surface unevenness of the release film is not particularly limited, and depending on the relationship between the surface energy of the light absorbing part surface, the hardness, and the surface unevenness, and the surface energy and hardness of the surface of the release film opposite to the side on which the light absorbing part is formed, for example, in order to prevent adhesion defect in a case where the multi-layer film of the release film and the light absorbing part is stored in the form of a long roll, the surface unevenness of the release film can be adjusted. In a case where the surface unevenness is increased, adhesion defect tends to be suppressed, and in a case where the surface unevenness is reduced, the surface unevenness of the light absorbing part tends to be decreased and the haze of the light absorbing part tends to be small. Thus, the surface unevenness can be set appropriately.

For such a release film, any material and film can be appropriately used. Specific examples of the material include a polyester-based polymer (including polyethylene terephthalate-based film), an olefin-based polymer, a cycloolefin-based polymer, a (meth)acrylic polymer, a cellulose-based polymer, and a polyamide-based polymer. In addition, a surface treatment can be appropriately carried out for the intended purpose of adjusting the surface properties of the release film. For example, a corona treatment, a room temperature plasma treatment, or a saponification treatment can be carried out to decrease the surface energy, and a silicone treatment, a fluorine treatment, an olefin treatment, or the like can be carried out to raise the surface energy.

—Peeling Force Between the Light Absorbing Part and the Release Film—

In a case where the light absorbing part is formed by a coating method, the peeling force between the light absorbing part and the release film can be controlled by adjusting the material of the light absorbing part, the material of the release film, the internal strain of the light absorbing part. The peeling force can be measured by, for example, a test of peeling off the release film in a direction of 90°, and the peeling force in a case of being measured at a rate of 300 mm/min is preferably 0.001 to 5 N/25 mm, more preferably 0.01 to 3 N/25 mm, and still more preferably 0.05 to 1 N/25 mm. In a case where the peeling force is equal to or larger than the above-described preferred lower limit value, peeling off the release film in a step other than the peeling step can be prevented, and in a case where the peeling force is equal to or smaller than the above-described preferred upper limit value, peeling failure in the peeling step (for example, zipping and cracking of the light absorbing part) can be prevented.

<Film Thickness of Light Absorbing Part>

The film thickness of the light absorbing part is not particularly limited, and is preferably 1 to 18 μm, more preferably 1 to 12 μm, and still more preferably 2 to 8 μm. In a case where the film thickness is equal to or smaller than the above-described preferred upper limit value, the decrease in the degree of polarization due to the fluorescence emitted by a dye (a coloring agent) can be suppressed by adding the dye to the thin film at a high concentration. In addition, the effects of the quencher and the antifading agent are easily exhibited. On the other hand, in a case where the film thickness is equal to or larger than the above-described preferred lower limit value, it becomes easy to maintain the evenness of the in-plane absorbance. In the present invention, the film thickness of 1 to 18 μm means that the thickness of the light absorbing part is within a range of 1 to 18 μm in a case of being measured at any portion. The same applies to the film thicknesses of 1 to 12 μm and 2 to 8 μm. The film thickness can be measured with an electronic micrometer manufactured by ANRITSU CORPORATION.

<Absorbance of Light Absorbing Part>

The absorbance of the absorption waveforms A to D in the light absorbing part can be appropriately adjusted depending on the kind and the adding amount of the dye within a range in which the effect of the present invention is exhibited.

<Moisture Content of Light Absorbing Part>

From the viewpoint of the durability, the moisture content of the light absorbing part is preferably 0.5% by mass or less, and more preferably 0.3% by mass or less, in conditions of 25° C. and 80% relative humidity, regardless of the film thickness.

In the present specification, the moisture content of the light absorbing part can be measured by using a sample having a thick film thickness as necessary. The moisture content can be calculated by humidity-conditioning the sample for 24 hours or longer, then measuring a moisture content (g) by the Karl Fischer method with a water measuring instrument and a sample drying apparatus “CA-03” and “VA-05” (both manufactured by Mitsubishi Chemical Corporation), and dividing the moisture content (g) by the sample mass (g, including the moisture content).

<Glass Transition Temperature (Tg) of Light Absorbing Part>

The glass transition temperature of the light absorbing part is preferably 50° C. or higher and 140° C. or lower. More preferably, the glass transition temperature is 60° C. or higher and 130° C. or lower, and still more preferably 70° C. or higher and 120° C. or lower. In a case where the glass transition temperature is equal to or higher than the above preferable lower limit value, deterioration of the polarizer in a case of being used at a high temperature can be suppressed, and in a case where the glass transition temperature is equal to or lower than the above preferable upper limit value, it is possible to suppress that the organic solvent used in the coating liquid easily remains in the light absorbing part.

The glass transition temperature of the light absorbing part can be measured according to the following method.

With a differential scanning calorimetry device (X-DSC7000 (manufactured by IT Measurement Control Co., Ltd.)), 20 mg of a light absorbing part is placed in a measurement pan, and the temperature of the pan is raised from 30° C. to 120° C. in a nitrogen stream at a speed of 10° C./min, and held for 15 minutes, and then cooled to 30° C. at −20° C./min. Thereafter, the temperature was raised again from 30° C. to 250° C. at a rate of 10° C./min, and the temperature at which the baseline began to deviate from the low temperature side was defined as the glass transition temperature Tg.

The glass transition temperature of the light absorbing part can be adjusted by mixing two or more kinds of polymers having different glass transition temperatures, or by changing the adding amount of a low-molecular weight compound such as an antifading agent.

<Treatment of Light Absorbing Part>

The light absorbing part may be subjected to a hydrophilic treatment by any of glow discharge treatment, corona discharge treatment, or alkali saponification treatment, and a corona discharge treatment is preferably used. It is also preferable to apply the method disclosed in JP1994-94915A (JP-H6-94915A) and JP1994-118232A (JP-H6-118232A).

As necessary, the obtained film may be subjected to a heat treatment step, a superheated steam contact step, an organic solvent contact step, or the like. In addition, a surface treatment may be appropriately carried out.

Further, as the pressure sensitive adhesive layer, a layer consisting of a pressure sensitive adhesive composition in which a (meth)acrylic resin, a styrene-based resin, a silicone-based resin, or the like is used as a base polymer, and a crosslinking agent such as an isocyanate compound, an epoxy compound, or an aziridine compound is added thereto can be applied.

Preferably, the description regarding the pressure sensitive adhesive layer described later, in the display device according to the embodiment of the present invention, can be applied.

<<Gas Barrier Layer>>

The optical member according to the embodiment of the present invention can also have a gas barrier layer on at least one surface of the light absorbing part. This gas barrier layer contains a crystalline resin, has a layer thickness of 0.1 μm to 10 μm, and has a layer oxygen permeability of 60 cc/m²·day·atm or less.

In the gas barrier layer, the “crystalline resin” is a resin having a melting point that undergoes a phase transition from a crystal to a liquid in a case where the temperature is raised, and it can impart gas barrier properties related to oxygen gas to the gas barrier layer.

In a case where the optical member according to the embodiment of the present invention includes the gas barrier layer at least on a surface that the light absorbing part comes into contact with air in a case where the optical member according to the embodiment of the present invention is used, it is possible to suppress a decrease in the absorption intensity of the dye in the light absorbing part. As long as the gas barrier layer is provided at an interface of the light absorbing part in contact with air, the gas barrier layer may be provided on only one surface of the light absorbing part, or may be provided on both surfaces.

(Crystalline Resin)

The crystalline resin contained in the gas barrier layer is a crystalline resin having gas barrier properties, and it can be used without particular limitation as long as a desired oxygen permeability can be imparted to the gas barrier layer.

Examples of the crystalline resin include polyvinyl alcohol and polyvinylidene chloride, and the polyvinyl alcohol is preferable from the viewpoint that a crystalline portion can effectively suppress the permeation of gas.

The polyvinyl alcohol may be modified or may not be modified. Examples of the modified polyvinyl alcohol include modified polyvinyl alcohol into which a group such as an acetoacetyl group and a carboxyl group is introduced.

The saponification degree of the polyvinyl alcohol is preferably 80.0% by mol or more, more preferably 90.0% by mol or more, still more preferably 97.0% by mol or more, and particularly preferably 98.0% by mol or more, from the viewpoint of further enhancing the oxygen gas barrier properties. The upper limit value thereof is not particularly limited, and it is practically 99.99% by mol or less. The saponification degree of the polyvinyl alcohol is a value calculated based on the method described in JIS K 6726 1994.

The gas barrier layer may contain any component generally contained in the gas barrier layer as long as the effect of the present invention is not impaired. For example, in addition to the above crystalline resin, organic-inorganic hybrid materials such as an amorphous resin material and a sol-gel material, and inorganic materials such as SiO₂, SiOₓ, SiON, SiNₓ, and Al₂O₃ may be contained.

Further, the gas barrier layer may contain a solvent such as water and an organic solvent derived from a manufacturing step as long as the effect of the present invention is not impaired. The content of the crystalline resin in the gas barrier layer is, for example, preferably 90% by mass or more and more preferably 95% by mass or more in 100% by mass of the total mass of the gas barrier layer. The upper limit value thereof is not particularly limited, and it can be set to 100% by mass.

The oxygen permeability of the gas barrier layer is 60 cc/m²·day·atm or less, preferably 50 cc/m²·day·atm or less, more preferably 30 cc/m²·day·atm or less, still more preferably 10 cc/m²·day·atm or less, particularly preferably 5 cc/m²·day·atm or less, and most preferably 1 cc/m²·day·atm or less. The practical lower limit value thereof is 0.001 cc/m²·day·atm or more, and it is preferably, for example, more than 0.05 cc/m²·day·atm. In a case where the oxygen permeability is within the above-described preferred range, the light resistance can be further improved.

The oxygen permeability of the gas barrier layer is a value measured based on the gas permeability test method based on JIS K 7126-2 2006. As the measuring device, for example, an oxygen permeability measuring device OX-TRAN2/21 (product name) manufactured by MOCON can be used. The measurement conditions are set to a temperature of 25° C. and a relative humidity of 50%.

For the oxygen permeability, (fm)/(s Pa) can be used as the SI unit. It is possible to carry out the conversion by (1 fm)/(s·Pa)=8.752 (cc)/(m²·day·atm). fm is read as femtometer and represents 1 fm=10⁻¹⁵ m.

The thickness of the gas barrier layer is preferably 0.5 μm to 5 μm, and more preferably 1.0 μm to 4.0 μm, from the viewpoint of further improving the light resistance.

The thickness of the gas barrier layer is measured, for example, by a method of capturing a cross-sectional image of the optical member according to the embodiment of the present invention using a field emission scanning electron microscope S-4800 (product name) manufactured by Hitachi High-Technologies Corporation.

The degree of crystallinity of the crystalline resin contained in the gas barrier layer is preferably 25% or more, more preferably 40% or more, and still more preferably 45% or more. The upper limit value thereof is not particularly limited, and it is practically 55% or less and preferably 50% or less.

The degree of crystallinity of the crystalline resin contained in the gas barrier layer is a value measured and calculated according to the following method based on the method described in J. Appl. Pol. Sci., 81, 762 (2001).

Using a differential scanning calorimeter (DSC), a temperature of a sample peeled from the gas barrier layer is raised at 10° C./min over the range of 20° C. to 260° C., and a heat of fusion 1 is measured. Further, as a heat of fusion 2 of the perfect crystal, the value described in J. Appl. Pol. Sci., 81, 762 (2001) is used. Using the obtained heat of fusion 1 and heat of fusion 2, the degree of crystallinity is calculated according to the following expression. [Degree of crystallinity (%)]=([heat of fusion 1]/[heat of fusion 2])×100 Specifically, the degree of crystallinity is a value measured and calculated according to the method described in Examples to be described later. The heat of fusion 1 and heat of fusion 2 may have the same unit, which is generally Jg⁻¹.

<Manufacturing Method for Gas Barrier Layer>

The method of forming the gas barrier layer is not particularly limited, and examples thereof include a forming method according to a conventional method, according to a casting method such as spin coating or slit coating. In addition, examples thereof can include a method of bonding a commercially available resin gas barrier film or a resin gas barrier film produced in advance to the light absorbing part.

<<Light Bending Part>>

The light bending part in the optical member according to the present invention has a function of bending and emitting a part of a light amount of incident straight light.

It is preferable that the light bending part bends 1% to 20% of the light amount of the incident straight light, that is, the bending rate is 1% to 20%.

For the bending rate, a Haze Meter NDH2000 (product name) manufactured by NIPPON DENSHOKU INDUSTRIES Co., Ltd. is used, irradiation is carried out with measurement light from on a side of low refractive index portion constituting a light bending part (preferably a light bending filter), a parallel line transmittance Pt and a total light transmittance Tt are measured, and a value R s calculated according to the following expression, and this value is used as the bending rate.

R=(Tt−Pt)/Tt×100 (Expression)

From the viewpoint of visibility in a case where the display device is turned on, the total light transmittance of the light bending part is preferably 99% or more. The upper limit value thereof is not particularly limited; however, it is practically 99.9% or less.

The total light transmittance is a value measured using a Haze Meter NDH2000 (product name) manufactured by NIPPON DENSHOKU INDUSTRIES Co., Ltd.

From the viewpoint of refracting light at an interface to bend a part of the incident straight light, the light bending part preferably has regions having refractive indexes different from each other, and more preferably has at least a region I and a region II exhibiting a refractive index different from that of the region I. It is noted that in the light bending part, both the region I and the region II may have one or more regions having a different refractive index.

Hereinafter, the description will be made assuming that the region I is a region where the refractive index is higher than that of the region II (hereinafter, referred to as a “high refractive index region”), and the region II is a region where the refractive index is lower than that of the region I (hereinafter, referred to as a “low refractive index region”).

Examples of the material constituting the high refractive index region include metals such as indium, tin, titanium, zinc, zirconium, niobium, magnesium, bismuth, cerium, tantalum, aluminum, germanium, potassium, antimony, neodymium, lanthanum, thorium, and hafnium, and alloys consisting of two or more kinds of these metals, as well as oxides, fluorides, sulfides, and nitrides thereof. Specific examples thereof include titanium oxide, niobium oxide, zirconium oxide, tantalum oxide, zinc oxide, indium oxide, and cerium oxide. These are preferably particles.

From the viewpoint of refractive index, the high refractive index region preferably contains zirconium oxide particles.

The particle diameter of the particles constituting the high refractive index region is not particularly limited; however, it is preferably 1 to 120 nm, more preferably 1 to 60 nm, and still more preferably 2 to 40 nm. The above-described particle diameter and a particle diameter described in Example described later are a value measured according to a measuring method for a particle diameter of a hollow particle described later.

It is preferable that the particles constituting the high refractive index region are contained in a resin.

The resin is not particularly limited; however, examples thereof include a cured product of urethane acrylate, a cured product of epoxy acrylate, a cured product of polyether acrylate, a cured product of polyester acrylate, and a cured product of polythiol.

The content of the particles in the high refractive index region is preferably 5% to 30% by mass, more preferably 10% to 30% by mass, and still more preferably 20% to 30% by mass.

The refractive index of the high refractive index region is not particularly limited as long as it exceeds the refractive index of the low refractive index region; however, it is preferably more than 1.49, more preferably 1.49 or more, still more preferably 1.53 or more, and particularly preferably 1.58 or more. The above-described refractive index and a refractive index described in Example described later are a value measured according to a measuring method for a refractive index in a low refractive index region described below.

The low refractive index region preferably contains a pressure sensitive adhesive or hollow particles.

(Pressure Sensitive Adhesive)

As a pressure sensitive adhesive contained in the low refractive index region, a general pressure sensitive adhesive can be used without particular limitation as long as a low refractivity can be imparted.

Examples thereof include a pressure sensitive adhesive containing an acrylic resin, a methacrylic resin, or the like.

As a commercially available product, for example, an Opteria D692 (product name) manufactured by LINTEC Corporation can be used.

(Hollow Particles)

In the present invention, the hollow particle means a particle having an outer shell layer, where the inside of the particle surrounded by the outer shell layer is porous or hollow, and the inside of the particle contains air. In a case of containing the hollow fine particles, the refractive index of the low refractive index region can be adjusted to be low.

The refractive index of the hollow particles is preferably 1.49 or less and more preferably 1.45 or less, from the viewpoint of imparting low refractivity.

The outer shell layer of the hollow particle may be either an organic substance or an inorganic substance.

Examples of the organic substance include a (meth)acrylic resin and a styrene-based resin.

Examples of the inorganic substance include metal oxides, and more specific examples thereof include silica, titania, zirconia, and antimony pentoxide.

The outer shell layer of the hollow particle is more preferably silica.

The shape of the hollow particle is not particularly limited; however, examples thereof include a true spherical shape, a substantially spherical shape such as a polyhedron shape that can be approximated to a rotational elliptical shape or a spherical shape, a chain shape, a needle shape, a plate shape, a flake shape, a rod shape, and a fiber shape.

More preferred examples thereof include a spherical shape.

The particle diameter of the hollow particles is not particularly limited. However, an average particle diameter defined as 50% particle diameter (d50 median diameter) in a case where a particle diameter distribution measured according to the dynamic light scattering method is indicated as a volume cumulative distribution (hereinafter, simply referred to as an “average particle diameter (d50)”) is preferably 5 to 120 nm, more preferably 10 to 100 nm, and most preferably 40 to 90 nm.

In a case where the average particle diameter (d50) of the hollow particles is equal to or smaller than the above-described upper limit value, the low refractive index region to be obtained is excellent in transparency, and in a case where it is equal to or larger than the above-described lower limit value, these hollow particles can be easily dispersed uniformly in the low refractive index region, and it is easy to impart low refractivity to the low refractive index region.

It is noted that the average particle diameter (d50) shall be as an average particle diameter (d50) of the primary particle diameters in a case where the hollow particles do not aggregate, or shall be an average particle diameter (d50) of the secondary particle diameters in a case where the hollow particles are aggregated particles.

In addition, the average particle diameter (d50) can be measured using a Microtrac particle diameter analyzer manufactured by Nikkiso Co., Ltd. or a Nanotrac particle diameter analyzer.

In addition, in a case where the low refractive index region is a cured product, the average particle diameter can be measured from a transmission electron microcopy (TEM) image or an SEM (scanning electron microcopy (SEM) image of the low refractive index region after curing. The average particle diameter of the hollow particles is not particularly limited; however, it is preferably 40 nm or more.

In the measuring method for the average particle diameter, particles are observed using, for example, a TEM image or an SEM image captured at a magnification of 500,000 to 2,000,000 times, and the average value of the particle diameters of 100 particles observed is used as the average particle diameter. It is noted that in a case where the shape of the hollow particle is a shape including the concept of the aspect ratio, such as a rotational ellipsoidal shape having a minor axis and a major axis or a rod shape, the particle diameter of the hollow particle is an average value of the minor axis and the major axis.

In addition, the average particle diameter measured from the TEM image or the SEM image shall be as an average particle diameter of the primary particle diameters in a case where the hollow particles do not aggregate, or shall be an average particle diameter of the secondary particle diameters in a case where the hollow particles are aggregated particles.

The content of the hollow particles is preferably 10 to 80 parts by mass with respect to 100 parts by mass of the binder resin described below. In a case where the content of the hollow particles is equal to or larger than the above-described lower limit value, it is easy to impart low refractivity, and in a case where the content thereof is equal to or smaller than the upper limit value, it is possible to improve the film strength of the low refractive index region to be formed.

The refractive index of the low refractive index region is not particularly limited as long as it is smaller than the refractive index of the high refractive index region; however, it is preferably 1.49 or less, more preferably 1.47 or less, and still more preferably 1.45 or less.

The refractive index can be measured with an Abbe refractive index meter (for example, RX-7000α manufactured by ATAGO CO., LTD.).

The light bending part is preferably a light bending filter having a high refractive index region and a low refractive index region on a supporting base material, and it is more preferably a light bending filter which has a high refractive index region in a stripe shape on a supporting base material, and in which a low refractive index region is provided on the surface having the high refractive index region to cover the exposed supporting base material and the stripe-shaped high refractive index region.

The supporting base material is not particularly limited as long as it does not impair the effect of the present invention. The supporting base material is preferably a film formed of a resin exhibiting optical isotropic properties and more preferably a triacetyl cellulose film.

<Film Thickness of Light Bending Part>

The film thickness of the light bending part is not particularly limited; however, it is preferably 30 to 70 μm and more preferably 45 to 65 μm in terms of the total thickness.

The thickness of the supporting base material is preferably 35 to 60 μm and more preferably 45 to 55 μm. The thickness of the high refractive index region (thickness of the thickest portion in a case of being provided in a stripe shape) is preferably 5 to 20 μm and more preferably 5 to 15 μm. The thickness of the low refractive index region (the thickness of the thickest portion) is preferably 10 to 30 μm and more preferably 10 to 20 μm.

The film thickness can be measured with an electronic micrometer manufactured by ANRITSU CORPORATION.

The manufacturing method for the light bending part is not particularly limited. For example, the light bending part can be manufactured by forming a high refractive index region on a supporting base material to have a desired shape by using a mold roll or the like and bonding a film exhibiting a low refractive index region.

To the light bending part (preferably the light bending filter) having a high refractive index region and a low refractive index region, for example, the description of the optical film having a high refractive index pattern layer and a low refractive index pattern layer in JP2014-123568A can be applied as long as the effect of the present invention is not impaired.

<Optical Film>

In addition to the light absorbing part, the light bending part, and the gas barrier layer, the optical member according to the embodiment of the present invention may appropriately have any optical film as long as the effect of the present invention is not impaired.

The optional optical film is not particularly limited in terms of any of optical properties and materials, and a film containing (or containing as a main component) at least any of a cellulose ester resin, an acrylic resin, a cyclic olefin resin, and a polyethylene terephthalate resin can be preferably used. It is noted that an optically isotropic film may be used, or an optically anisotropic phase difference film may be used. For the above-described optional optical film, for example, Fujitac TD80UL, Fujitac TG60UL, Fujitac TJ40UL (all manufactured by FUJIFILM Corporation), or the like can be used as an optical film containing a cellulose ester resin.

Regarding the optional optical film, as those containing an acrylic resin, an optical film containing a (meth)acrylic resin containing a styrene-based resin described in JP4570042B, an optical film containing a (meth)acrylic resin having a glutarimide ring structure in a main chain described in JP5041532B, an optical film containing a (meth)acrylic resin having a lactone ring structure described in JP2009-122664A, and an optical film containing a (meth)acrylic resin having a glutaric anhydride unit described in JP2009-139754A can be used.

Further, regarding the optional optical films, as those containing a cyclic olefin resin, cyclic olefin-based resin film described in paragraphs [0029] and subsequent paragraphs of JP2009-237376A, and cyclic olefin resin film containing an additive reducing Rth described in JP4881827B, JP2008-063536A can be used.

In addition, the above-described optional optical film may contain an ultraviolet absorbing agent. As the ultraviolet absorbing agent, a commonly used compound can be used without particular limitation.

The content of the ultraviolet absorbing agent in the ultraviolet absorbing layer is appropriately adjusted according to the intended purpose.

<<Manufacturing Method for Optical Member>>

The light absorbing part in the optical member according to the present invention can be produced by the above-described manufacturing method for the light absorbing part.

The light bending part in the optical member according to the present invention can be produced by the above-described manufacturing method for the light bending part.

It is preferable that the optical member according to the embodiment of the present invention is produced by bonding the light bending part and the light absorbing part manufactured by the above-described manufacturing method by interposing a pressure sensitive adhesive therebetween.

In addition, in a case where a gas barrier layer is provided, the gas barrier layer can be produced by the above-described manufacturing method for a gas barrier layer. Examples thereof include a method of directly producing the above-described gas barrier layer on the light absorbing part produced according to the above-described manufacturing method. In this case, it is also preferable to apply a corona treatment to the surface of the light absorbing part to which the gas barrier layer is provided.

Further, in a case where the above-described optional optical film is provided, it is also preferable to carry out bonding by interposing a pressure sensitive adhesive layer.

As the pressure sensitive adhesive, the description of the pressure sensitive adhesive in the display device according to the embodiment of the present invention described later can be preferably applied.

[Display Device According to Embodiment of Present Invention]

The display device according to the embodiment of the present invention includes an optical member for use in the display device according to the embodiment of the present invention and a light emitting unit, and the light emitting unit is an organic electroluminescent light emitting element (an organic EL light emitting element) or a micro light emitting diode (a micro LED).

Preferred examples of the light emitting unit include the organic electroluminescent light emitting element described in JP2020-187261A or the microLED described in WO2014/204694A. It is noted that to the optical member and the display device according to the embodiment of the present invention, the optical member according to the embodiment of the present invention can be applied even in a configuration that does not have the microcavity structure. Among the above, it can be suitably used in a display device having a microcavity structure.

The organic EL light emitting element has a configuration in which an anode electrode, a light emitting layer, and a cathode electrode are laminated in this order. In addition to the light emitting layer, a hole injection layer, a hole transport layer, an electron transport layer, an electron injection layer, and the like are included between the anode electrode and the cathode electrode. In addition, for example, the description in JP2014-132522A can also be referenced.

Even in a case where these light emitting elements have a microcavity structure, it is possible to neutrally adjust the tint in the oblique direction by using the optical member according to the embodiment of the present invention, and it is possible to achieve both the suppression of external light reflection and the suppression of a decrease in brightness at an excellent level.

For the display device according to the embodiment of the present invention, as long as the light emitting unit is an organic electroluminescent light emitting element or a micro light emitting diode, and the optical member according to the embodiment of the present invention is included in such a configuration that in the optical member according to the embodiment of the present invention, the light absorbing part is located close to the external light side with respect to the light emitting unit and is located close to the external light side with respect to the light bending part of the optical member, a configuration of a display device that is usually used can be used without particular limitation as the other configuration.

The display device can be used without particular limitation as long as it has the above-described specific light emitting unit, and for example, an OLED display device, a micro LED display device, or the like can be preferably used.

The configuration example of the display device according to the embodiment of the present invention is not particularly limited, and examples thereof include a display device including glass, a layer containing a thin film transistor (TFT), a light emitting unit, a barrier film, a color filter, glass, a pressure sensitive adhesive layer, the optical member according to the embodiment of the present invention, a pressure sensitive adhesive layer, and a surface film, in order from the opposite side to external light.

For the light emitting source according to the embodiment of the present invention, a single blue color may be used, or the three primary colors of blue, green, and red may be used. In a case where a single blue color is used for the light source, the blue light can be converted into green light and red light by a wavelength conversion material such as a phosphor or a quantum dot.

The wavelength conversion material means a material that absorbs light having a specific wavelength and emits light having a different wavelength on the long wavelength side with respect to the absorption wavelength, thereby converting the wavelength, and specific examples thereof include a phosphor containing quantum dots or the like.

In the display device according to the embodiment of the present invention, the wavelength conversion material may be installed so that it is incorporated in the LED light source or may be installed as a wavelength conversion sheet at a position other than the light source.

In a case of being provided at a position other than the light source, it can be provided as a wavelength conversion sheet on a viewer side with respect to the light emitting unit (light emitting element), and it is preferable to provide a quantum dot sheet (also referred to as QD) on a viewer side with respect to the light emitting unit (light emitting element). Since the QD sheet is a scatterer, in a case where a circularly polarizing plate is used as an antireflection application, the polarization of the circularly polarizing plate is eliminated and thus the function of suppressing reflectivity is not exhibited. In contrast, in the display device according to the embodiment of the present invention, due to the synergistic effect of the diffusion of light in the QD sheet and the absorption of the specific wavelength range by the light absorbing part, it is possible to suppress external light reflection at a more excellent level while achieving both the suppression of external light reflection and the suppression of a decrease in brightness.

Among the above, a method of stacking a color filter on a layer consisting of a wavelength conversion material such as a quantum dot is preferable from the viewpoint that light transmittance is high and display light having high color purity can be obtained as compared with the method in the related art, in which white light is caused to be incident on the color filter.

Hereinafter, the wavelength conversion material will be described.

(Green Phosphor)

The green phosphor is a wavelength conversion material that absorbs a part of the emitted light of the blue LED, and emits green light having an emission peak in a wavelength range of 500 to 595 nm. Examples of the green phosphor include Y₃Al₅O₁₂:Ce³⁺, Tb₃Al₅O₁₂:Ce³⁺, BaY₂SiAl₄O₁₂:Ce³⁺, Ca₃Sc₂Si₃O₁₂:Ce³⁺, (Ba, Sr)₂SiO₄:Eu²⁺, CaSc₂O₄:CE³⁺, Ba₃Si₆O₂N₂:EU²⁺, β-SiAlON:Eu²⁺, SrGa₂S₄:Eu²⁺, LaSiN:Ce³⁺, CaSi₂O₂N₂:Eu²⁺, Lu₃Al₅O₁₂:Ce³⁺ (LAG), and SrSi₂O₂N₂:Eu²⁺.

(Red Phosphor)

The red phosphor is a wavelength conversion material that absorbs at least one of a part of the emitted light of the blue LED or a part of the emitted light of the green phosphor, and emits red light having an emission peak in a wavelength range of 600 to 690 nm. Examples of the red phosphor include Ca-α-SiAlON:Eu²⁺, CaAlSiN₃:Eu²⁺, (Sr, Ca)AlSiN₃:Eu²⁺, Sr₂Si₅N₈:Eu²⁺, Sr₂(Si, Al)₅(N, O)₈:Eu²⁺, CaS:Eu²⁺, La₂O₂S:Eu³⁺, and K₂SiF₆:Mn⁴⁺.

(Quantum Dot)

As the wavelength conversion material, a quantum dot is particularly preferable in that it provides a sharp emission spectrum. The quantum dots are particles having a major axis of about 1 to 100 nm, and they have discrete energy levels. Since the energy state of a quantum dot depends on the size of the quantum dot, the luminescence wavelength can be freely selected by changing the size. Examples of the quantum dot include a compound of a Group 12 element and a Group 16 element, a compound of a Group 13 element and a Group 16 element, and a compound of a Group 14 element and a Group 16 element, and include CdSe, CdTe, ZnS, CdS, InP, PbS, PbSe, and CdHgTe. As quantum nanomaterials, quantum rods and the like can be used in addition to the quantum dot.

(Matrix that Absorbs or Scatters External Light)

From the viewpoint of further enhancing the effect of suppressing external light reflection, the display device according to the present invention may include a matrix that absorbs or scatters external light (hereinafter, also simply referred to as a “matrix”), and It is preferable to have the matrix between the light emitting elements that constitute the light emitting unit.

Among the above-described matrices, examples of the matrix that absorbs external light include the black matrix that is disposed between RGB color filters for respective colors and prevents reflected light, which is described in paragraph [0069] of JP2018-18807A. In a case of disposing such a black matrix between the light emitting units for respective colors of the display device according to the embodiment of the present invention, it is possible to absorb external light entering the display device according to the embodiment of the present invention and further enhance the effect of suppressing external light reflection.

Among the above-described matrices, examples of the matrix that scatters external light include the structure body having an uneven surface described in JP2019-82594A. In a case of disposing such a structure body in the light emitting units for respective colors of the display device according to the embodiment of the present invention, it is possible to scatter external light entering the display device according to the embodiment of the present invention and further enhance the effect of suppressing external light reflection.

In a case where the display device according to the embodiment of the present invention includes a matrix, the included matrix may be one kind or may be two or more kinds.

Further, as the color filter, in addition to a typical color filter, a color filter in which quantum dots are laminated can also be used.

A resin film can be used instead of the above glass.

The method of forming a color image applicable to the display device according to the embodiment of the present invention is not particularly limited, and any of a three-color painting method, a color conversion method, and a color filter method of red (R), green (G), and blue (B) can be used, and the three-color painting method can be suitably used.

As a result, as the light source of the display device according to the embodiment of the present invention, each light emitting layer corresponding to the above image forming method can be applied.

<Pressure Sensitive Adhesive Layer>

In the display device according to the embodiment of the present invention, it is preferable that the optical member according to the embodiment of the present invention is bonded to glass (a base material) by interposing a pressure sensitive adhesive layer such that the light absorbing part is on the external light side with respect to the light bending part.

The composition of the pressure sensitive adhesive composition that is used for forming the pressure sensitive adhesive layer is not particularly limited, and for example, a pressure sensitive adhesive composition containing a base resin having a mass average molecular weight (Mw) of 500,000 or more may be used. In a case where the mass average molecular weight of the base resin is less than 500,000, the durability reliability of the pressure sensitive adhesive may decrease due to a decrease in cohesive force causing bubbles or peeling phenomenon under at least one of the high temperature condition or the high humidity condition. The upper limit of the mass average molecular weight of the base resin is not particularly limited. However, in a case where the mass average molecular weight is excessively increased, the coating property may deteriorate due to the increase in viscosity, and thus the upper limit thereof is preferably 2,000,000 or less.

The specific kind of the base resin is not particularly limited, and examples thereof include an acrylic resin, a silicone-based resin, a rubber-based resin, and an ethylene-vinyl acetate (EVA)-based resin. In a case of being applied to an optical device such as a liquid crystal display device, an acrylic resin is mainly used in that the acrylic resin is excellent in transparency, oxidation resistance, and resistance to yellowing, and it is not limited thereto.

In addition, the pressure sensitive adhesive composition may contain other components (additives) such as a crosslinking agent, an antistatic agent, a coordination-bonding compound, and a tackifying resin.

Regarding the components that may be contained in the acrylic resin and the pressure sensitive adhesive composition, the description of the other components (additives) such as an acrylic resin and a crosslinking agent, an antistatic agent, a coordination-bonding compound, and a tackifying resin, which are described in paragraphs [0296] to [0347] of WO2021/014973A, can be applied to the present invention without any particular limitation.

<Base Material>

In the display device according to the embodiment of the present invention, it is preferable that the optical member according to the embodiment of the present invention is bonded to glass (a base material) by interposing a pressure sensitive adhesive layer such that the light absorbing part is on the external light side with respect to the light bending part.

The method of forming the pressure sensitive adhesive layer is not particularly limited, and it is possible to use, for example, a method of applying the pressure sensitive adhesive composition to the light absorbing part by a usual means such as a bar coater, drying, and curing the pressure sensitive adhesive composition; and a method of applying the pressure sensitive adhesive composition first to the surface of a peelable base material, and drying the composition, and then transferring the pressure sensitive adhesive layer using the peelable base material to the light absorbing part and then aging and curing the composition.

The peelable base material is not particularly limited, and a predetermined peelable base material can be used. For example, the release film in the manufacturing method for the light absorbing part described above is exampled.

In addition, the conditions of application, drying, aging, and curing can be appropriately adjusted based on a conventional method.

### EXAMPLES

Hereinafter, the present invention will be described in more detail based on Examples. The materials, using amount, ratio, details of treatment, procedures of treatment, and the like described in Examples below can be appropriately changed without departing from the spirit of the present invention. Therefore, it is to be understood that the scope of the present invention is not limited to Examples described below.

It is noted that “parts” and “%” that indicate the composition in Examples below are based on mass unless otherwise specified. In addition, Xma in each dye means the maximal absorption wavelength at which the maximum absorbance derived from each dye is exhibited in the measurement of the absorption waveform of the light absorbing filter to be described later.

### EXAMPLES

[1] Production of Light Absorbing Filter

Materials used to produce the light absorbing filter are shown below.

<Matrix Resin>

(Resin 1)

Polystyrene resin (PSJ-polystyrene GPPS SGP-10 (product name), manufactured by PS Japan Corporation)

(Resin 2)

A polyphenylene ether resin (manufactured by Asahi Kasei Corporation, XYRON S201A (product name), poly(2,6-dimethyl-1,4-phenylene oxide), Tg: 210° C.)

(Peelability Control Resin Component 1)

Byron 550 (product name, manufactured by Toyobo Co., Ltd., a polyester-based additive)

<Dye>

The following dyes were used as the dyes.

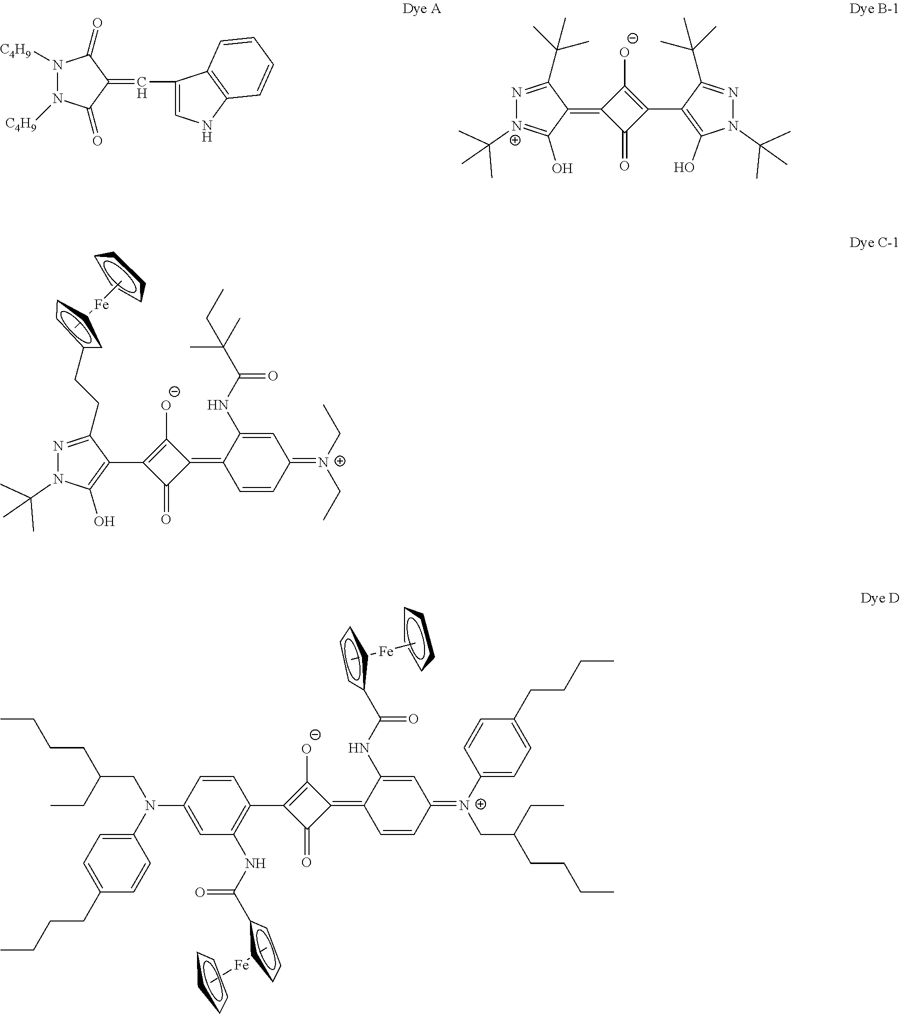

Dye B-2: 1-(methylamino)anthraquinone (purchased from Tokyo Chemical Industry Co., Ltd.)

Dye C-2: manufactured by YAMADA CHEMICAL CO., LTD., FDG-007 (product name)

Dye C-3: Quinizarin Blue (purchased from Tokyo Chemical Industry Co., Ltd.)

(Antifading Agent 1)

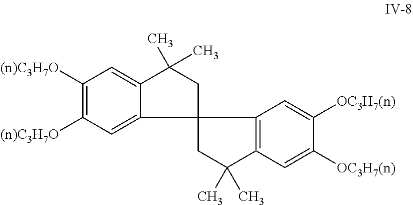

(Leveling Agent 1)

A polymer surfactant composed of the following constitutional components was used as a leveling agent 1. In the following structural formulae, the proportion of each constitutional component is in terms of a molar ratio, and t-Bu means a tert-butyl group.

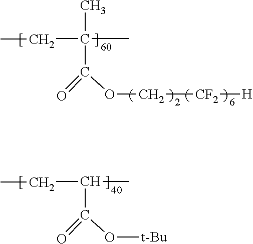

(Base Material 1)

A polyethylene terephthalate film, LUMIRROR XD-510P (product name, film thickness: 50 μm, Manufactured by Toray Industries, Inc.) was Used as a Base Material 1.

<Production of Base Material-Attached Light Absorbing Filter 1>

(1) Preparation of Light Absorbing Filter Forming Liquid 1

Each component was mixed with the composition shown below to prepare a light absorbing filter forming liquid 1.

Composition of light absorbing filter forming liquid 1

| | | |
|---|---|---|
| Resin 1 | 49.2 | parts by mass |
| Resin 2 | 17.5 | parts by mass |
| Peelability control resin component 1 | 0.20 | parts by mass |
| Leveling agent 1 | 0.08 | parts by mass |
| Dye A | 13.8 | parts by mass |
| Dye C-1 | 11.7 | parts by mass |
| Antifading agent 1 | 7.5 | parts by mass |
| Toluene (solvent) | 1710.0 | parts by mass |
| Cyclohexanone (solvent) | 190.0 | parts by mass |

Subsequently, the obtained light absorbing filter forming liquid 1 was filtered using a filter having an absolute filtration precision of 5 μm (product name: Hydrophobic Fluorepore Membrane, manufactured by Millex).

(2) Production of Base Material-Attached Light Absorbing Filter 1

The light absorbing filter forming liquid 1 after the filtration treatment was applied onto a base material 1 by using a bar coater so that the film thickness after drying was 2.5 μm, and dried at 120° C. to produce a base material-attached light absorbing filter 1.

<Production of Base Material-Attached Light Absorbing Filters 2 to 7 and C1 to C5>

Base material-attached light absorbing filters 2 to 7 and C1 to C5 were produced in the same manner in the same manner as in the production of the base material-attached light absorbing filter 1, except that the kind and the content of the dye were changed to the contents described in Table 1 below.

(Absorption Waveform of Light Absorbing Filter)

Using a UV3150 spectrophotometer (product name) manufactured by Shimadzu Corporation, the absorbance of a base material-attached light absorbing filter in the wavelength range of 380 nm to 800 nm was measured every 1 nm. An absorbance difference Abₓ (λ)−Ab₀ (λ) between an absorbance Abₓ (λ) at each wavelength λ nm of the base material-attached light absorbing filter containing no dyes and an absorbance Ab₀ (λ) of the base material-attached light absorbing filter was calculated. In addition, the maximum value of this absorbance difference was taken as the absorption maximal value, and then the wavelength at which this absorption maximal value (maximum absorbance) was exhibited was denoted as the maximal absorption wavelength λₘₐₓ, the two wavelengths λ_{half max} that gives an absorbance of half of the absorption maximal value, and the width FWHM between these two wavelengths λ_{half max} were determined.

(Determination on Exhibition of Absorption Waveforms a to D Defined in the Present Invention)

Whether or not each of the dyes exhibited the absorption waveforms A to D defined in the present invention was determined as follows.

As the maximum emission wavelengths λ_{BMax}, λ_{GMax}, and λ_{RMax}, exhibited by the blue emission, green emission, and red emission of the display device, and the widths x, y, and z between two wavelengths that give an absorbance of half of the maximum emission exhibited by each emission, the value of the emission spectrum S (k) of the display used in the evaluation of the suppression of a decrease in brightness, which will be described later, was used. That is, λ_{BMax} is 449 nm, λ_{GMax} is 535 nm, λ_{RMax} is 631 nm, x is 19 nm, y is 37 nm, and z is 39 nm.

Using these values, it was determined whether or not each dye exhibited the absorption waveforms A to D defined in the present invention based on the determination criteria 1 and 2 shown in Table A below.

These results are summarized in Table A.

TABLE A

| | Dye A | Dye B-1 | Dye B-2 | Dye C-1 | Dye C-2 | Dye C-3 | Dye D |
|---|---|---|---|---|---|---|---|
| λmax | 410 | 513 | 503 | 593 | 594 | 582 | 698 |
| λhalf max | 377 | 489 | 455 | 577 | 585 | 513 | 675 |
| | 434 | 527 | 548 | 605 | 603 | 636 | 724 |
| FWHM | 57 | 38 | 93 | 28 | 18 | 123 | 49 |
| Absorption | A | B | — | C | — | — | D |
| waveform | | | | | | | |
| Determination | Has a main | Two λhalf max are present in | | Two λhalf max are present | | | Has a main |
| standard 1 | absorption | wavelength range exceeding | | in a wavelength range | | | absorption |
| | wavelength | λ_{BMax} and smaller than λ_{GMax} | | exceeding λ_{GMax} | | | wavelength |
| | band in a | | | and smaller than λ_{RMax} | | | band in a |
| | wavelength | | | | | | wavelength range |
| | range smaller | | | | | | exceeding λ_{RMax} |
| | than λ_{BMax} | | | | | | |
| Determination | ◯ | ◯ | X | ◯ | ◯ | X | ◯ |
| | (410 < 449) | (449 < 489 < | (449 < 455 < | (535 < 577 < | 535 < 585 < | (535 ≮ 513 < | (631 < 698) |
| | | 535, 449 < | 535, 449 < | 631, 535 < | 631, 535 < | 631, 535 < | |
| | | 527 < 535) | 548 ≮ 535) | 606 < 631) | 603 < 631) | 636 ≮ 631) | |
| Determination | | FWHM is 50 − x/2 − | | FWHM is 60 − y/2 − z/2 = 22 or more | | | |
| standard 2 | | y/2 = 22 or more | | | | | |
| Determination | | ◯ (38 > 22) | ◯ (93 > 22) | ◯ (28 > 22) | X (18 ≯ 22) | ◯ (123 > 22) | |

(Note in Table)

The unit of any wavelength in the table is nm.

In the column of the absorption waveform, A to D respectively mean that the absorption waveforms A to D defined in the present invention are satisfied, and “-” means that any of the absorption waveforms A to D defined in the present invention is not satisfied. It is noted that the description in the table describes that the dyes A, B-1, C-1, and D satisfy the absorption waveforms A to D defined in the present invention, which are different from the specific absorption waveforms exhibited by the dyes A, B-1, C-1, and D, and the general absorption waveforms of the absorption waveforms A to D defined in the present invention shown in FIG. 3.

In the determination column, “o” means that the determination criterion described in the upper row is satisfied, and “x” means that the determination criterion described in the upper row is not satisfied.

As described in Table A, in a case where a light absorbing filter containing each of the above-described dyes is used in the display used in the evaluation of the suppression of a decrease in brightness described later, the dyes A, B-1, C-1, and D respectively exhibit the absorption waveforms A to D defined in the present invention.

On the other hand, in the dyes B-2 and C-3, at least one of the two wavelengths that give an absorbance of half of the maximal absorption of the dye is present outside the range of the wavelength range between the maximum emission wavelengths of the emission of the display device, which are located on both sides of the absorption (it means a wavelength range of more than λ_{BMax} and less than λ_{GMax} between the blue emission and the green emission, and it means a wavelength range of more than λ_{GMax} and less than λ_{RMax} between the green emission and the red emission), each of the dyes B-2 and C-3 does not exhibit the absorption waveform B or C defined in the present invention. In addition, the dye C-2 does not satisfy the absorption width defined by Relational Expression (2) and does not exhibit the absorption waveform C defined in the present invention.

[2] Production of Light Bending Part

While supplying a urethane acrylate composition (containing 20% by mass of zirconium oxide particles having a particle diameter of 20 nm) constituting a high refractive index portion 22 between a supporting base material 21 composed of a cellulose acylate film 1 produced as described below and a mold roll having a specific shape, the mold roll and a nip roll were rotated. In this way, the urethane acrylate composition overlaid on the cellulose acylate film 1 along the surface shape of the mold roll, and light (ultraviolet rays) was applied from the side of the overlaid urethane acrylate composition by a light irradiation device, whereby the urethane acrylate composition was cured.

As described above, a film A having a desired shape of a film having the high refractive index portion 22 composed of the cured product of the urethane acrylate composition was obtained, on the supporting base material 21 composed of the cellulose acylate film 1.

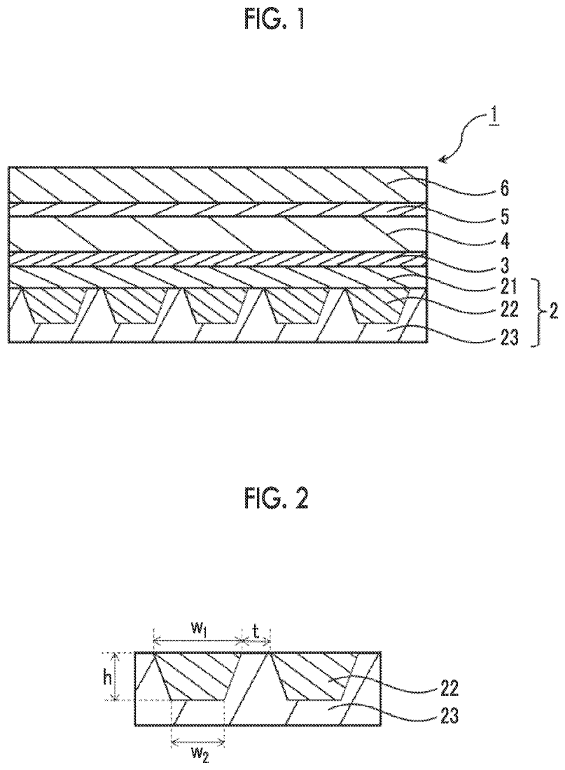

In this film A, in the cured product (the high refractive index portion 22) of the urethane acrylate, a cross-sectional shape in a case of being cut in a plane perpendicular to the rotation axis of the mold roll and the nip roll has a trapezoid shape in which as shown in FIG. 1 and FIG. 2, the width w₁ on the side in contact with the cellulose acylate film 1 (the supporting base material 21) is 15 μm, the width w₂ on the side facing the cellulose acylate film 1 (the supporting base material 21) is 13 μm, and the thickness h of the high refractive index portion 22 is 10 μm, the distance t between the adjacent high refractive index portions on the side in contact with the cellulose acylate film 1 (the supporting base material 21) is 2 μm, and the cross-sectional shape has a striped shape which is continuously connected in a direction parallel to the rotation axis of the mold roll and the nip roll. The refractive index of the high refractive index portion 22 was 1.60.

Opteria D692 (product name, a pressure sensitive adhesive, thickness: 15 μm) manufactured by LINTEC Corporation was bonded to a surface of the film A obtained above on the side on which the high refractive index portion 22 was formed, thereby providing low refractive index portion 23 composed of this pressure sensitive adhesive. The refractive index of the low refractive index portion 23 was 1.49. The thickness of the low refractive index portion 23 (the thickness of the thickest portion from the supporting base material 21 side) was m.

In this way, a light bending part 2 which is a laminate in which the cellulose acylate film 1 (the supporting base material 21), the high refractive index portion 22, and the low refractive index portion 23 are laminated in this order was produced.

<Production of Cellulose Acylate Film 1>

(1) Production of Core Layer Cellulose Acylate Dope

The following composition was introduced into a mixing tank and stirred to dissolve the respective components to prepare a cellulose acetate solution for use as a core layer cellulose acylate dope.

Core layer cellulose acylate dope

| | |
|---|---|
| Cellulose acetate having an acetyl substitution degree of | 100 parts by mass |
| 2.88 | |
| Polyester compound B described in Example of | 12 parts by mass |
| JP2015-227955A | |
| Compound F shown below | 2 parts by mass |
| Methylene chloride (first solvent) | 430 parts by mass |
| Methanol (second solvent) | 64 parts by mass |

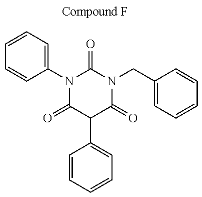 [SMILES: O=C1C(c2ccccc2)C(=O)N(c2ccccc2)C(=O)N1Cc1ccccc1]

(2) Production of Outer Layer Cellulose Acylate Dope

10 parts by mass of the following matting agent dispersion liquid were added to 90 parts by mass of the core layer cellulose acylate dope to prepare a cellulose acetate solution to be used as an outer layer cellulose acylate dope.

Matting agent dispersion liquid

| | | |
|---|---|---|
| Silica particles with average particle size of 20 nm | 2 | parts by mass |
| (Product name: AEROSIL R972, manufactured by | | |
| Nippon Aerosil Co., Ltd.) | | |
| Methylene chloride (first solvent) | 76 | parts by mass |
| Methanol (second solvent) | 11 | parts by mass |
| Core layer cellulose acylate dope described above | 1 | part by mass |

(Production of Cellulose Acylate Film 1)

The core layer cellulose acylate dope and the outer layer cellulose acylate dope were filtered through a filter paper having an average pore diameter of 34 μm and a sintered metal filter having an average pore diameter of 10 μm, and then a band casting machine was used to simultaneously cast the three layers onto a drum at 20° C. from a casting port to form a three-layer configuration in which the filtered the outer layer cellulose acylate dope was arranged on both sides of the filtered core layer cellulose acylate dope

Next, the cast film was stripped from the drum in a state where the solvent content was substantially 20% by mass, both ends of the film in the width direction were fixed with tenter clips, and the film was dried while being stretched in the lateral direction at a stretching ratio of 1.1 times. Thereafter, the film was further dried by being transported between rolls of a heat treatment device to produce an optical film (transparent support) having a thickness of 40 μm, and this was used as a cellulose acylate film 1.

[3] Production of Laminate

Laminates of Nos. 101 to 107 and c11 to c17 for measuring reflectivity described in Table 1, which include at least any light absorbing filter (light absorbing part) in the base material-attached light absorbing filters 1 to 7 and C1 to C5 produced above or a circularly polarizing plate, and the light bending part (light bending filter) produced above, were produced as follows.

The laminates of Nos. 101 to 107 are laminates including the light absorbing part and the light bending part used in the present invention, and the laminates of Nos. c11 to c17 are laminates for comparison which do not include the light absorbing part used in the present invention.

Here, it was confirmed that the light bending part produced above bends 1% to 20% of the light amount of the incident straight light, and the total light transmittance is 99% or more, based on the above-described measurement method.

It is noted that an aluminum foil in the laminate for measuring reflectivity shown below is provided assuming the external light reflection in the metal plate of the light emitting unit of the display device.

(1) Production of a Laminate Having No QD Sheet

A commercially available aluminum foil, a triacetyl cellulose film (a TAC film, product name: Fujitac TD80UL, manufactured by FUJIFILM Corporation) were bonded with a pressure sensitive adhesive A (product name: SK2057, manufactured by Soken Chemical Co., Ltd.) having a thickness of about 20 μm being interposed therebetween. Subsequently, the low refractive index portion 23 side of the light bending part 2 produced above was bonded to the matte surface side of the bonded aluminum foil by interposing the pressure sensitive adhesive A. Further, the coating film side of the base material-attached light absorbing filter produce above was bonded to the cellulose acylate film 1 (the supporting base material 21) side of the light bending part 2 by interposing the pressure sensitive adhesive A, and the base material 1 of the base material-attached light absorbing filter was peeled off. The obtained laminate has a configuration in which the TAC film/the pressure sensitive adhesive A/the aluminum foil/the pressure sensitive adhesive A/the light bending part 2/the pressure sensitive adhesive A/the light absorbing part 4 consisting of the light absorbing filter are laminated in this order.

It is noted that in a case where a circularly polarizing plate is provided instead of the base material-attached light absorbing filter produced above as the antireflection unit, a laminate including a circularly polarizing plate was produced in the same manner, except that the production of the laminate, a circularly polarizing plate was used instead of the base material-attached light absorbing filter.

(2) Production of Laminate Having QD Sheet

A commercially available aluminum foil, a triacetyl cellulose film (a TAC film, product name: Fujitac TD80UL, manufactured by FUJIFILM Corporation) were bonded with the pressure sensitive adhesive A being interposed therebetween. Subsequently, the QD sheet taken out from the display device 8XKB2D6ALBT (product name, manufactured by SEC) was bonded to the matte surface side of the bonded aluminum foil by interposing the pressure sensitive adhesive A. Further, the low refractive index portion 23 side of the light bending part 2 produced above was bonded to the QD sheet side by interposing the pressure sensitive adhesive A. Further, the coating film side of the base material-attached light absorbing filter produce above was bonded to the cellulose acylate film 1 (the supporting base material 21) side of the light bending part 2 by interposing the pressure sensitive adhesive A, and the base material 1 of the base material-attached light absorbing filter was peeled off. The obtained laminate has a configuration in which the TAC film/the pressure sensitive adhesive A/the aluminum foil/the pressure sensitive adhesive A/the QD sheet/the pressure sensitive adhesive A/the light bending part 2/the pressure sensitive adhesive A/the light absorbing part 4 consisting of the light absorbing filter are laminated in this order.

It is noted that in a case where a circularly polarizing plate is provided instead of the base material-attached light absorbing filter produced above as the antireflection unit, a laminate including a circularly polarizing plate was produced in the same manner, except that the production of the laminate, a circularly polarizing plate was used instead of the base material-attached light absorbing filter.

[Evaluation]

For each of the laminates produced in [3] above, the effect of suppressing external light reflection was evaluated as follows. In addition, the effect of suppressing a decrease in brightness was evaluated as follows. The results are summarized in Table 1.

<1. Effect of Suppressing External Light Reflection>

Using a spectrophotometer (manufactured by Konica Minolta, Inc., product name: CM2022), the measurement was carried out three times with changing the measurement position in the plane so that the measurement light was incident from the side of the light absorbing part 4 of the laminate or the circularly polarizing plate, and then using, as the reflectivity, an average value of a value of Y in the Specular Component Include (SCI) measurement method in the three times of the measurement. the effect of suppressing external light reflection was evaluated according to the following evaluation standards.

—Evaluation Standard—

A: The reflectivity is less than 5.0%.

B: The reflectivity is 5.0% or more and less than 5.7%.

C: The reflectivity is 5.7% or more and less than 6.3%.

D: The reflectivity is 6.3% or more and less than 7.0%.

E: The reflectivity is 7.0% or more.

<2. Effect of Suppressing Decrease in Brightness>

The relative brightness in a case where the light absorbing filter produced as described above was used was calculated as follows.

The emission spectrum S (k) of the display was calculated using the backlight spectrum of 55 “Q7F (quantum dot type liquid crystal television, product name) manufactured by Samsung. Further, the transmission spectrum of the light absorbing filter was denoted as T (λ).

The brightness in a case where the light absorbing filter was not used was calculated by carrying out luminous efficiency correction on the spectrum S (λ), and this brightness was set to 100 (reference value). The brightness of the spectrum S (λ)×T (λ) in a case where the light absorbing filter was used was calculated as the relative brightness with respect to the brightness in a case where the above light absorbing filter was not used.

It is noted that in a case where a circularly polarizing plate was used instead of the light absorbing filter (Nos. c11 and c12), the measurement was carried out to measure transmittance % T of the circularly polarizing plate at 550 nm with a UV3150 spectrophotometer (product name) manufactured by Shimadzu Corporation, and the value of this transmittance was taken as the relative brightness.

Using the relative brightness values obtained in the above simulation, the effect of suppressing the brightness decrease was evaluated based on the following evaluation standards.

—Evaluation Standard—

A: 35<relative brightness≤100

B: 0≤relative brightness≤35

TABLE 1

| | | | | | | | | | | | Effect of | |
|---|---|---|---|---|---|---|---|---|---|---|---|---|
| | Antireflection means | | | | | | | | | QD sheet | suppressing | Effect of |
| | Light absorbing part | | | | | | | | Circularly | for wave- | external | suppressing |
| | | Dye A | Dye B-1 | Dye B-2 | Dye C-1 | Dye C-2 | Dye C-3 | Dye D | polarizing | length | light | decrease in |
| No. | Kind | Content | Content | Content | Content | Content | Content | Content | plate | conversion | reflection | brightness |
| 101 | Light | 13.8 | — | — | 11.7 | — | — | — | — | — | B | A |
| | absorbing | | | | | | | | | | | |
| | part 1 | | | | | | | | | | | |
| 102 | Light | 12.4 | 2.5 | — | 3.0 | — | — | — | — | — | B | A |
| | absorbing | | | | | | | | | | | |
| | part 2 | | | | | | | | | | | |
| 103 | Light | 10.6 | 1.8 | — | 2.2 | — | — | 5.2 | — | — | B | A |
| | absorbing | | | | | | | | | | | |
| | part 3 | | | | | | | | | | | |
| 104 | Light | 10.6 | 1.8 | — | 2.2 | — | — | 5.2 | — | Present | A | A |
| | absorbing | | | | | | | | | | | |
| | part 4 | | | | | | | | | | | |
| 105 | Light | — | 7.4 | — | — | — | — | — | — | — | B | A |
| | absorbing | | | | | | | | | | | |
| | part 5 | | | | | | | | | | | |
| 106 | Light | — | — | — | 12.2 | — | — | — | — | — | B | A |
| | absorbing | | | | | | | | | | | |
| | part 6 | | | | | | | | | | | |
| 107 | Light | — | 4.2 | — | — | 5.4 | — | — | — | — | B | A |
| | absorbing | | | | | | | | | | | |
| | part7 | | | | | | | | | | | |
| c11 | — | — | — | — | — | — | — | — | Present | — | D | A |
| c12 | — | — | — | — | — | — | — | — | Present | Present | E | A |
| c13 | Light | — | — | — | — | 16.5 | — | — | — | — | D | A |
| | absorbing | | | | | | | | | | | |
| | part C1 | | | | | | | | | | | |
| c14 | Light | — | — | 20.1 | — | — | — | — | — | — | B | B |
| | absorbing | | | | | | | | | | | |
| | part C2 | | | | | | | | | | | |
| c15 | Light | — | — | — | — | — | 27.0 | — | — | — | B | B |
| | absorbing | | | | | | | | | | | |
| | part C3 | | | | | | | | | | | |
| c16 | Light | — | 4.2 | — | — | — | 11.9 | — | — | — | B | B |
| | absorbing | | | | | | | | | | | |
| | part C4 | | | | | | | | | | | |
| c17 | Light | — | — | 10.6 | 5.2 | — | — | — | — | — | B | B |
| | absorbing | | | | | | | | | | | |
| | part C5 | | | | | | | | | | | |

(Note in Table)

The content of the dye means the content proportion of the dye in the light absorbing filter in terms of the mass ratio, and the unit thereof is % by mass.

The dyes respectively mean the above-described dyes A, B-1, B-2, C-1, C-2, C-3, and D.

The notation of “-” in the columns of the kind and dye in the light absorbing part, the circularly polarizing plate, and the QD sheet for wavelength conversion means that the corresponding kind and dye in the light absorbing part and the circularly polarizing plate are not provided.

From the results in Table 1, the following facts can be seen.

The laminates of Nos. c11 and c12 have, as the antireflection unit, a circularly polarizing plate instead of the light absorbing part defined in the present invention, and further has a light bending part. In these laminates of Nos. c11 and c12 for comparison, the polarization was eliminated in the light bending part, and thus the reflection suppression of the circularly polarizing plate could not sufficiently function, and the external light reflection could not be sufficiently suppressed.

In addition, as shown in Table A, in the laminate of No. c13, the absorption waveform derived from the dye C-2 does not satisfy Relational Expression (2) defined in the present invention. This laminate of No. c13 for comparison could not sufficiently suppress the external light reflection.

In addition, as shown in Table A, in the laminate of No. c14, regarding the absorption waveform derived from the dye B-2, one of two wavelengths that give an absorbance of half of the maximal absorption wavelength λₘₐₓ is not present in a wavelength range between the maximum emission wavelength λ_{BMax} 449 nm and λ_{GMax} 535 nm of the display device, and thus the definition of the absorption waveform in the present invention is not satisfied. As shown in Table A, in the laminate of No. c15, regarding the absorption waveform derived from the dye C-3, both of two wavelengths that give an absorbance of half of the maximal absorption wavelength λₘₐₓ are not present in a wavelength range between the maximum emission wavelength λ_{GMax} 535 nm and λ_{RMax} 631 nm of the display device, and thus the definition of the absorption waveform in the present invention is not satisfied. In these laminates of Nos. c14 and c15 for comparison, the decrease in brightness could not be sufficiently suppressed.

In addition, although No. c16 has the dye B-1 which exhibits the light reflection waveform B defined in the present invention, it has the dye C-3 which does not satisfy the absorption waveform defined in the present invention, and although No. c17 contains the dye C-1 which exhibits the light reflection waveform C defined in the present invention, it has the dye B-2 which does not satisfy the absorption waveform defined in the present invention. In these laminates of Nos. c16 and c17 for comparison, the decrease in brightness could not be also sufficiently suppressed.

On the other hand, all of the laminates Nos. 101 to 107 which have the light absorbing part and the light bending part defined in the present invention were excellent in both suppressing external light reflection and suppressing a decrease in brightness. Among them, the comparison between the laminate of No. 106 and the laminate of No. c13 clearly shows that the effect of suppressing external light reflection can be obtained in a case of satisfying Relational Expression (2) in the absorption waveform C. It is conceived that this is an effect caused by the width of the absorption wavelength of the dye, and it is conceived that the effect of suppressing external light reflection can be similarly obtained in a case where Relational Expression (1) in the absorption waveform B is satisfied as well. In addition, the comparison between the laminate of No. 105 and the laminate of No. c14, and the comparison between the laminate of No. 106 and the laminate of No. c15 clearly show that the effect of suppressing a decrease in brightness can be obtained in a case of satisfying the definition in the present invention so that two wavelengths that give an absorbance half of the absorption maximum absorption are present inside the maximum emission wavelength of the emission located on both sides of the absorption in each of the absorption located between the wavelength ranges of the blue emission and the green emission of the display device and the absorption located between the wavelength ranges of the green emission and the red emission of the display device.

In addition, from the comparison between laminates Nos. 103 and 104 which have the light absorbing part and the light bending part defined in the present invention, it can be seen that the diffusion of light in the QD sheet occurs by providing a QD sheet for wavelength conversion on the visible side with respect to the light emitting unit, and thus it is possible to suppress external light reflection at a more excellent level while achieving both the suppression of external light reflection and the suppression of a decrease in brightness. It is conceived that this effect of improving the suppression of external light reflection can be obtained by the same principle as long as the light absorbing part defined in the present invention is provided. For example, with respect to the laminates of Nos. 101, 102, and 105 to 107 as well, it is possible to suppress the external light reflection at a more excellent level by providing a QD sheet for wavelength conversion on the visible side with respect to the light emitting unit.

On the other hand, from the comparison between the laminate of No. c11 and the laminate of No. c12, which have, as the antireflection unit, a circularly polarizing plate instead of the light absorbing part defined in the present invention, and further have the light bending part, it can be seen that by providing the QD sheet, the polarization is eliminated due to the diffusion of light in the QD sheet, the reflection suppression by the circularly polarizing plate cannot sufficiently function, and thus external light reflection increases.

Although the present invention has been described with reference to the embodiments, it is the intention of the inventors of the present invention that the present invention should not be limited by any of the details of the description unless otherwise specified and rather be construed broadly within the spirit and scope of the invention appended in WHAT IS CLAIMED IS.

### Explanation of References

1: optical member
2: light bending part
21: supporting base material
22: high refractive index portion
23: low refractive index portion
3: pressure sensitive adhesive
4: light absorbing part
5: pressure sensitive adhesive
6: surface film
w₁: width of high refractive index portion on supporting base material side
w₂: width of high refractive index portion on side facing supporting base material
h: thickness of high refractive index portion
t: distance between adjacent high refractive index portions
λ_{BMax}: maximum emission wavelength exhibited by blue emission of display device
λ_{GMax}: maximum emission wavelength exhibited by green emission of display device
λ_{RMax}: maximum emission wavelength exhibited by red emission of display device
x: width between two wavelengths that give half of absorbance of maximum emission exhibited by blue emission of display device
y: width between two wavelengths that give half of absorbance of maximum emission exhibited by green emission of display device
z: a width between two wavelengths that give an absorbance of half of a maximum emission exhibited by the red emission of the display device.

What is claimed is:

1. An optical member for use in a display device,
wherein the display device has a light emitting unit, and the light emitting unit is an organic electroluminescent light emitting element or a micro light emitting diode,
the optical member includes a light bending part that bends and emits a part of a light amount of incident straight light, and a light absorbing part that contains a dye, and
an absorption waveform of the light absorbing part is selected from the following absorption waveforms A to D, and the light absorbing part has the following absorption waveform B or C,
the absorption waveform A: an absorption waveform having a main absorption wavelength band in a wavelength range smaller than λ_{BMax}
the absorption waveform B: an absorption waveform in which two wavelengths that give an absorbance of half of an absorption maximum are present in a wavelength range larger than λ_{BMax} and smaller than λ_{GMax}, and a width FWHM_{b} between the two wavelengths satisfies a relationship of Expression (1)
FWHM_{b}≥50−x/2−y/2 Expression (1)
the absorption waveform C: an absorption waveform in which two wavelengths that give an absorbance of half of an absorption maximum are present in a wavelength range larger than λ_{GMax} and smaller than λ_{RMax}, and a width FWHM_{c} between the two wavelengths satisfies a relationship of Expression (2)
FWHM_{c}≥60−y/2−z/2 Expression (2)
the absorption waveform D: an absorption waveform having a main absorption wavelength band in a wavelength range larger than λ_{RMax}
in description regarding the absorption waveforms A to D, each reference numeral has the following meaning, and
units of all the wavelengths are nm in Expressions (1) and (2),
λ_{BMax}: a maximum emission wavelength exhibited by blue emission of the display device
λ_{GMax}: a maximum emission wavelength exhibited by green emission of the display device
λ_{RMax}: a maximum emission wavelength exhibited by red emission of the display device
x: a width between two wavelengths that give an absorbance of half of a maximum emission exhibited by the blue emission of the display device
y: a width between two wavelengths that give an absorbance of half of a maximum emission exhibited by the green emission of the display device
z: a width between two wavelengths that give half of absorbance of maximum emission exhibited by the red emission of the display device.

2. The optical member for use in a display device according to claim 1,
wherein the optical member includes a light bending filter that forms the light bending part and a light absorbing filter that forms the light absorbing part.

3. The optical member for use in a display device according to claim 2,
wherein the light bending filter bends 1% to 20% of the light amount of the incident straight light.

4. The optical member for use in a display device according to claim 2,
wherein a total light transmittance of the light bending filter is 99% or more.

5. The optical member for use in a display device according to claim 2,
wherein the light bending filter has at least a region I and a region II exhibiting a refractive index different from a refractive index of the region I.

6. The optical member for use in a display device according to claim 5,
wherein the region I contains zirconium oxide particles.

7. The optical member for use in a display device according to claim 5,
wherein the region II contains a pressure sensitive adhesive or hollow particles.

8. The optical member for use in a display device according to claim 2,
wherein a dye contained in a light absorbing filter exhibiting the absorption waveform B or C includes a squaraine-based coloring agent represented by General Formula (1), 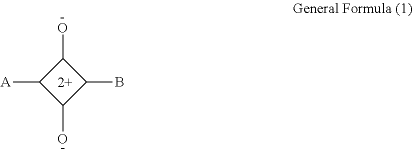
in the formula, A and B each independently represent an aryl group which may have a substituent, a heterocyclic group which may have a substituent, or —CH=G, where G represents a heterocyclic group which may have a substituent.

9. The optical member for use in a display device according to claim 2,
wherein a dye contained in a light absorbing filter exhibiting the absorption waveform A includes a coloring agent represented by General Formula (A1), 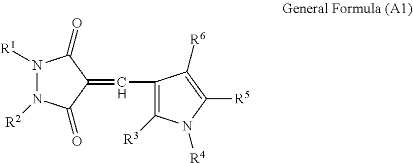
in the formula, R¹ and R² each independently represent an alkyl group or an aryl group, R³ to R⁶ each independently represent a hydrogen atom or a substituent, and R⁵ and R⁶ may be bonded to each other to form a 6-membered ring.

10. The optical member for use in a display device according to claim 2,
wherein a dye contained in a light absorbing filter exhibiting the absorption waveform D includes at least one of a coloring agent represented by General Formula (D1) or a coloring agent represented by General Formula (1), 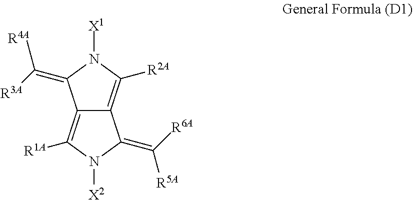
in the formula, R^{1A} and R^{2A} each independently represent an alkyl group, an aryl group, or a heteroaryl group, R^{4A} and R^{5A} each independently represent a heteroaryl group, R^{3A} and R^{6A} each independently represent a substituent, and X¹ and X² each independently represent —BR^{21a}R^{22a}, where R^{21a} and R^{22a} each independently represent a substituent, and R^{21a} and R^{22a} may be bonded to each other to form a ring, 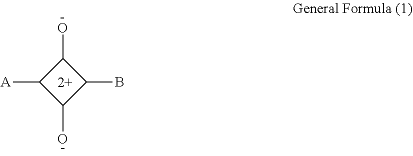
in the formula, A and B each independently represent an aryl group which may have a substituent, a heterocyclic group which may have a substituent, or —CH=G, where G represents a heterocyclic group which may have a substituent.

11. The optical member for use in a display device according to claim 2,
wherein the light absorbing filter contains an antifading agent represented by General Formula (IV), 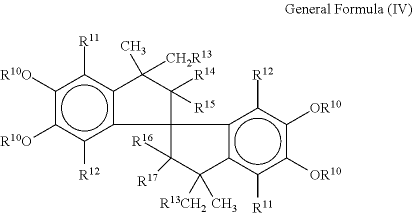
in the formula, R¹⁰'s each independently represent an alkyl group, an alkenyl group, an aryl group, a heterocyclic group, or a group represented by R¹⁸CO—, R¹⁹SO₂—, or R²¹NHCO—, where R¹⁸, R¹⁹, and R²⁰ each independently represent an alkyl group, an alkenyl group, an aryl group, or a heterocyclic group, R¹¹ and R¹² each independently represent a hydrogen atom, a halogen atom, an alkyl group, an alkenyl group, an alkoxy group, or an alkenyloxy group, and R¹³ to R¹⁷ each independently represent a hydrogen atom, an alkyl group, an alkenyl group, or an aryl group.

12. The optical member for use in a display device according to claim 2,
wherein the light absorbing filter contains a polystyrene resin or a cyclic polyolefin resin.

13. The optical member for use in a display device according to claim 2,
wherein the light absorbing filter exhibits all of the absorption waveforms A to D.

14. A display device comprising:
the optical member for use in a display device according to claim 1; and
a light emitting unit,
wherein the light emitting unit is an organic electroluminescent light emitting element or a micro light emitting diode.

15. The display device according to claim 14, further comprising:
a quantum dot sheet for wavelength conversion, on a visible side of the light emitting unit of the display device.

16. The display device according to claim 14, further comprising:
a matrix that absorbs or scatters external light,
wherein the matrix is disposed between light emitting elements constituting the light emitting unit.
